(19) United States
(12) Patent Application Publication
(10) Pub. No.: US 2020/0111977 A1
(43) Pub. Date: Apr. 9, 2020

(54) ORGANOMETALLIC COMPOUND AND ORGANIC LIGHT-EMITTING DEVICE INCLUDING THE SAME

(71) Applicant: Samsung Electronics Co., Ltd., Suwon-si (KR)

(72) Inventors: Hyeonho CHOI, Seoul (KR); Seungyeon KWAK, Suwon-si (KR); Sangdong KIM, Seongnam-si (KR); Sukekazu ARATANI, Hwaseong-si (KR); Whail CHOI, Seoul (KR); Sunghan KIM, Seongnam-si (KR); Byoungki CHOI, Hwaseong-si (KR); Kyuyoung HWANG, Anyang-si (KR)

(21) Appl. No.: 16/594,295

(22) Filed: Oct. 7, 2019

(30) Foreign Application Priority Data
Oct. 8, 2018 (KR) 10-2018-0119964
Oct. 4, 2019 (KR) 10-2019-0122836

(51) Int. Cl. H01L 51/00; C07F 15/00; C09K 11/06

(52) U.S. Cl. CPC H01L 51/0087; C07F 15/0086; H01L 51/5016; C07F 15/0033; H01L 51/0085; C09K 11/06

(57) ABSTRACT

An organometallic compound and an organic light-emitting device including the same are disclosed. The organometallic compound includes a transition metal and at least one organic ligand, wherein the organometallic compound satisfies predetermined conditions described in the specification.

This application claims priority to Korean Patent Applications No. 10-2018-0119964, filed on Oct. 8, 2018, and No. 10-2019-0122836, filed on Oct. 4, 2019, in the Korean Intellectual Property Office, an all the benefits accruing therefrom, the contents of which are incorporated herein in their entirety by reference.

### BACKGROUND

### 1. Field

One or more embodiments relate to an organometallic compound and an organic light-emitting device including the same.

### 2. Description of the Related Art

Organic light-emitting devices (OLEDs) are self-emission devices, which have superior characteristics in terms of a viewing angle, a response time, a brightness, a driving voltage, and a response speed, and which produce full-color images.

In an example, an organic light-emitting device includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

Aspects of the present disclosure provide an organometallic compound and an organic light-emitting device including the organometallic compound.

Additional aspects will be set forth in part in the description which follows and, in part, will be apparent from the description, or may be learned by practice of the presented embodiments.

An aspect of the present disclosure provides an organometallic compound including a transition metal and at least one organic ligand, wherein the organometallic compound satisfies Condition 1, and the organometallic compound has a radiative decay rate of 2.5×10⁵ s⁻¹ or more:
Condition 1
1.02−x≤y≤1.95−2.7x.

In Condition 1, x is an x coordinate value in a principal moments of inertia diagram of the organometallic compound, wherein x is I₁/I₃ of the organometallic compound,

in Condition 1, y is a y coordinate value in the principal moments of inertia diagram of the organometallic compound, wherein y is I₂/I₃ of the organometallic compound,

I₁, I₂, and I₃ are three principal moments of inertia of the organometallic compound, which satisfy a relationship of I₁≤I₂≤I₃,

I₁, I₂, and I₃ are evaluated using a density functional theory method for the organometallic compound,
the radiative decay rate of the organometallic compound is a value calculated from a time-resolved photoluminescence spectrum with respect to film 1, and
the film 1 is a 40-nanometer-thick film obtained by vacuum-codepositing 1,3-bis(N-carbazolyl)benzene (mCP) and the organometallic compound on a quartz substrate at a weight ratio of 90:10 to 99:1.

Another aspect of the present disclosure provides an organic light-emitting device including:

a first electrode;

a second electrode; and

an organic layer disposed between the first electrode and the second electrode,

wherein the organic layer includes an emission layer, and wherein the organic layer includes at least one organometallic compound.

The organometallic compound may be included in the emission layer of the organic layer and may act as a dopant.

### BRIEF DESCRIPTION OF THE DRAWINGS

These and/or other aspects will become apparent and more readily appreciated from the following description of the embodiments, taken in conjunction with the accompanying drawings in which:

FIG. 1 is a principal moments of inertia (PMI) diagram in which regions of an x coordinate value and a y coordinate value satisfying Condition 1 are indicated by a shaded triangle; and

FIG. 2 is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or 5% of the stated value.

In an embodiment, an organometallic compound is provided. The organometallic compound according to an embodiment may include a transition metal and at least one organic ligand.

For example, the transition metal may be a first-row transition metal, a second-row transition metal, or a third-row transition metal of the Periodic Table of Elements.

In an embodiment, the transition metal may be iridium (Ir), platinum (Pt), osmium (Os), titanium (Ti), zirconium (Zr), hafnium (Hf), europium (Eu), terbium (Tb), thulium (Tm), or rhodium (Rh).

In an embodiment, the transition metal may be platinum, palladium, gold, or iridium, but embodiments of the present disclosure are not limited thereto.

The organic ligand included in the organometallic compound may be the same as described below.

The organometallic compound may satisfy Condition 1:

Condition 1

1.02−x≤y≤1.95−2.7x.

In Condition 1, x is an x coordinate value in a principle of moments of inertia (PMI) diagram of the organometallic compound, which is I₁/I₃ of the organometallic compound and y is a y coordinate value in the PMI diagram of the organometallic compound, which is I₂/I₃ of the organometallic compound.

The I₁, I₂, and I₃ are three PMIs of the organometallic compound and may have a relationship of I₁≤I₂≤I₃. For example, the I₁, I₂, and I₃ of the organometallic compound may have a relationship of I₁≤I₂≤I₃, I₁<I₂≤I₃, or I₁<I₂<I₃.

The I₁, I₂, and I₃ may be evaluated using a density functional theory (DFT) method. For example, the I₁, I₂, and I₃ may be evaluated using a density functional theory (DFT) method in which a B3LYP/LanL2DZ function is used for a transition metal included in the organometallic compound and a B3LYP/6-31G(D,P) function is used for an organic ligand included in the organometallic compound in molecular structure optimization of the organometallic compound.

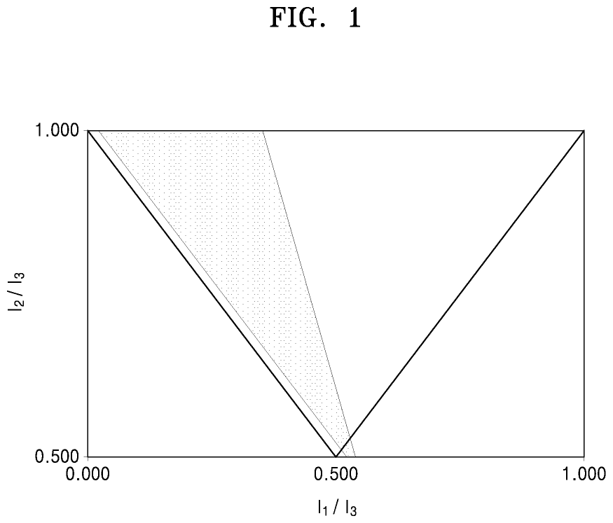

FIG. 1 is a PMI diagram in which regions of an x coordinate value and a y coordinate value satisfying Condition 1 are expressed by a shaded triangle.

In an embodiment, the organometallic compound may satisfy Condition 2:

Condition 2

1.06−x≤y≤1.95−2.7x.

In one or more embodiments, the organometallic compound may satisfy Condition 3:

Condition 3

1.06−x≤y≤4.70−10.0x.

In one or more embodiments, the transition metal included in the organometallic compound may be platinum, and the organometallic compound may satisfy Condition 4:

Condition 4

1.02−x≤y≤1.16−x.

In one or more embodiments, the transition metal included in the organometallic compound may be iridium, and the organometallic compound may satisfy Condition 5:

Condition 5

1.00−0.5x≤y≤1.95−2.7x.

The definitions of x and y in Conditions 1 to 5 may be the same as described herein.

In one or more embodiments, the transition metal included in the organometallic compound may be platinum, and the organometallic compound may satisfy at least one of Condition 1, Condition 2, Condition 3 and Condition 4.

In one or more embodiments, the transition metal included in the organometallic compound may be iridium, and the organometallic compound may satisfy at least one of Condition 1, Condition 2, Condition 3 and Condition 5.

In one or more embodiments, the transition metal included in the organometallic compound may be iridium, and the organometallic compound may satisfy at least one of Condition 1, Condition 2, and Condition 5.

In one or more embodiments, x in the PMI diagram of the organometallic compound may be in a range of 0.08 to 0.39 or 0.10 to 0.39, but embodiments of the present disclosure are not limited thereto.

In one or more embodiments, y in the PMI diagram of the organometallic compound may be in a range of 0.30 to 1.00 or 0.75 to 1.00, but embodiments of the present disclosure are not limited thereto.

The organometallic compound may have a radiative decay rate of 2.5×10⁵ reverse seconds (s⁻¹) or more.

The radiative decay rate of the organometallic compound is a value calculated from a time-resolved photoluminescence (TRPL) spectrum with respect to film 1, and the film 1 is a 40-nanometer-thick (40-nm-thick) film obtained by vacuum-codepositing 1,3-bis(N-carbazolyl)benzene (mCP) and the organometallic compound on a quartz substrate at a weight ratio of 90:10 to 99:1 (for example, 96:4 or 98:2) (for example, at a vacuum degree of 10⁻⁷ torr).

In an embodiment, the organometallic compound may have a radiative decay rate of 2.5×10⁵ s⁻¹ to 2.0×10⁶ s⁻¹ or 4.0×10⁵ s⁻¹ to 1.5×10⁶ s⁻¹, but embodiments of the present disclosure are not limited thereto.

In other embodiment, the transition metal of the organometallic compound may be a platinum and the organometallic compound may have a radiative decay rate of 4.0×10⁵ s⁻¹ to 2.0×10⁶ s⁻¹.

In other embodiment, the transition metal of the organometallic compound may be an iridium and the organometallic compound may have a radiative decay rate of 6.70×10⁵s⁻¹ to 2.0×10⁶s⁻¹.

In other embodiment, the transition metal of the organometallic compound may be an iridium and the organometallic compound may have a radiative decay rate of 8.05×10⁵ s⁻¹ to 2.0×10⁶ s⁻¹.

In other embodiment, the transition metal of the organometallic compound may be an iridium and the organometallic compound may have a radiative decay rate of 1.20×10⁶ s⁻¹ to 2.0×10⁶ s⁻¹.

The organometallic compound may have a horizontal orientation ratio of a transition dipole moment in a range of 85% to 100%.

For example, the horizontal orientation ratio of the transition dipole moment of the organometallic compound may be in a range of, for example, 80% to 100%, 81% to 100%, 82% to 100%, 83% to 100%, 84% to 100%, 85% to 100%, 86% to 100%, 87% to 100%, 88% to 100%, 89% to 100%, 90% to 100%, 91% to 100%, 92% to 100%, 93% to 100%, 94% to 100%, 95% to 100%, 96% to 100%, 97% to 100%, 98% to 100%, 99% to 100%, or 100%, but embodiments of the present disclosure are not limited thereto.

Since the organometallic compound has a high horizontal orientation ratio of a transition dipole moment, a large electric field traveling in a direction parallel to the plane of the film including the organometallic compound (i.e., a horizontal direction) may be emitted and a loss of light due to a waveguide mode and/or a surface plasmon polariton mode may be reduced. Light emitted due to such a mechanism may have high external extraction efficiency (that is, efficiency of extraction of light emitted in the organometallic compound from a device (for example, an organic light-emitting device) including a film (for example, an emission layer described below) including the organometallic compound to the outside). Thus, an electronic device, for example, an organic light-emitting device, which includes the organometallic compound, may have high luminescent efficiency.

The organic ligand included in the organometallic compound may include a tetradentate organic ligand, and the tetradentate organic ligand may include a C₃-C₈ nitrogen-containing condensed ring system in which a five membered ring and a six membered ring are condensed to each other. For example, the tetradentate organic ligand may include a benzimidazole ring system, a benzoxazole ring system, a benzothiazole ring system, or a benzotriazole ring system. In an embodiment, the tetradentate organic ligand may include a benzimidazole ring system. In this embodiment, the transition metal included in the organometallic compound may be platinum, palladium, or gold.

In an embodiment, the tetradentate organic ligand may include a benzimidazole ring system substituted with a substituted phenyl group and the substituted phenyl group is substituted with both at least one phenyl group and at least one tert-butyl group.

In an embodiment, the organic ligand comprises a bidentate organic ligand, and the bidentate organic ligand may comprise i) a C₃-C₁₅ nitrogen-containing condensed ring system in which at least two six membered rings are condensed to each other or ii) a C₃-C₈ condensed ring system in which a (e.g., one) five membered ring and a (e.g., one) six membered ring are condensed to each other. In this embodiment, the transition metal included in the organometallic compound may be iridium.

In an embodiment, the organic ligand may comprise 1) a bidentate organic ligand comprising a quinoline ring and a benzene ring, a bidentate organic ligand comprising an isoquinoline ring and a benzene ring, a bidentate organic ligand comprising an azabenzothiophene ring and a benzene ring, a bidentate organic ligand comprising an azabenzofuran ring and a benzene ring, a bidentate organic ligand comprising a benzoquinoline ring and a benzene ring, or a bidentate organic ligand comprising an benzoisoquinoline ring and a benzene ring; and 2) a bidentate organic ligand linked to the transition metal via oxygen. In this embodiment, the transition metal included in the organometallic compound may be iridium.

In an embodiment,

a) the transition metal included in the organometallic compound may be iridium,
b) the organic ligand included in the organometallic compound may comprise i) a bidentate organic ligand comprising a quinoline ring and a benzene ring, or ii) a bidentate organic ligand comprising an isoquinoline ring and a benzene ring, and
c) the organometallic compound may have a radiative decay rate of 7.20×10⁵ s⁻¹ to 1.5×10⁶ s⁻¹ or 8.05×10⁵ s⁻¹ to 1.0×10⁶ s⁻¹.

In an embodiment,

a) the transition metal included in the organometallic compound may be iridium,
b) the organic ligand included in the organometallic compound may comprise i) a bidentate organic ligand comprising an azabenzothiophene ring and a benzene ring, or
ii) a bidentate organic ligand comprising an azabenzofuran ring and a benzene ring, and
c) the organometallic compound may have a radiative decay rate of 2.00×10⁵ s⁻¹ to 2.0×10⁶s⁻¹ or 3.00×10⁵ s⁻¹ to 1.5×10⁶s⁻¹.

In an embodiment,

a) the transition metal included in the organometallic compound may be iridium,
b) the organic ligand included in the organometallic compound may comprise i) a bidentate organic ligand comprising a benzoquinoline ring and a benzene ring, or ii) a bidentate organic ligand comprising an benzoisoquinoline ring and a benzene ring, and
c) the organometallic compound may have a radiative decay rate of 1.20×10⁶ s⁻¹ to 2.0×10⁶ s⁻¹.

For example, the organometallic compound may be represented by one of Formulae 1A to 1K, but embodiments of the present disclosure are not limited thereto:

Description of Formula 1A

The organometallic compound may be represented by Formula 1A below:

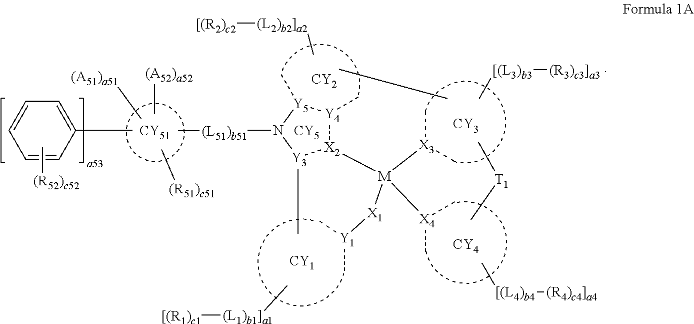

The organometallic compound represented by Formula 1A may include at least one deuterium; a C₁-C₆₀ alkyl group substituted with at least one deuterium; or any combination thereof. The number of deuterium atoms in the organometallic compound represented by Formula 1A may be from 1 to 20, for example, from 1 to 15, from 1 to 10, or from 1 to 5.

In Formula 1A, M may be a transition metal. For example, M may be Pt, Pd, or Au.

In Formula 1A, X₁ may be O or S, and a bond between X₁ and M may be a covalent bond. For example, X₁ may be O.

In Formula 1A, X₂ to X₄ may each independently be C or N. For example, X₂ and X₃ may each independently be C or N, and X₄ may be N.

In an embodiment, in Formula 1A, X₂ and X₄ may each independently be N, and X₃ may be C, but embodiments of the present disclosure are not limited thereto.

In Formula 1A, one bond of a bond between X₂ and M, a bond between X₃ and M, or a bond between X₄ and M may be a covalent bond, and the others thereof may be a coordinate bond. Therefore, the organometallic compound represented by Formula 1A may be electrically neutral.

In an embodiment, a bond between X₂ and M and a bond between X₄ and M may be a coordinate bond, and a bond between X₃ and M may be a covalent bond, but embodiments of the present disclosure are not limited thereto.

In Formula 1A, Y₁ and Y₃ to Y₅ may each independently be C or N. For example, Y₁ and Y₃ to Y₅ may be C.

In Formula 1A, a bond between X₂ and Y₃, a bond between X₂ and Y₄, and a bond between Y₄ and Y₅ may be a chemical bond (for example, a single bond, a double bond, or the like).

In Formula 1A, ring CY₁ to ring CY₄ and ring CY₅₁ may each independently be a C₅-C₃₀ carbocyclic group or a C₁-C₃₀ heterocyclic group. Each of the ring CY₁ to ring CY₄ and the ring CY₅₁ in Formula 1A may include at least one deuterium; a C₁-C₆₀ alkyl group substituted with at least one deuterium; or any combination thereof.

For example, ring CY₁ to ring CY₄ and ring CY₅₁ may each independently be i) a first ring, ii) a second ring, iii) a condensed ring in which at least two first rings are condensed, iv) a condensed ring in which at least two second rings are condensed, or v) a condensed ring in which at least one first ring and at least one second ring are condensed.

In an embodiment, the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and the second ring may be an adamantane group, a norbornene group, a bicyclo[1.1.1]pentane group, a bicyclo[2.1.1]hexane group, a bicyclo[2.2.1]heptane group, a bicyclo[2.2.2]octane group, a cyclohexane group, a cyclohexene group, a benzene group, a pyridine group, a pyrimidine group, a pyrazine group, a pyridazine group, or a triazine group.

In an embodiment, in Formula 1A, ring CY₁ to ring CY₄ and ring CY₅₁ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In one or more embodiments, in Formula 1A, ring CY₄ may not be a benzimidazole group.

In Formula 1A, a cyclometalated ring formed by ring CY₅, ring CY₂, ring CY₃, and M may each independently be a 6-membered ring.

In Formula 1A, Ti may be a single bond, a double bond, *—N(R₅)—*′, *—B(R₅)—*′, *—P(R₅)—*′, *—C(R₅)(R₆)—*′, *—Si(R₅)(R₆)—*′, *—Ge(R₅)(R₆)—*′, *—O—*′, *—C(═O)—*′, *—S(═O)—*′, *—S(═O)₂—*′, *—C(R₅)=*′, *═C(R₅)—*′, *—C(R₅)═C(R₆)—*′, *—C(═S)—*′, or *—C≡C—*′, wherein * and *′ each indicate a binding site to a neighboring atom. Here, R₅ and R₆ are defined the same as R₁ in Formula 1A, and may optionally be linked to each other via a single bond, a double bond, *—N(R′)—*′, *—B(R′)—*′, *—P(R′)—*′, *—C(R′)(R″)—*′, *—Si(R′)(R″)—*′, *—Ge(R′)(R″)—*′, *—S—*′, *—Se—*′, *—C(═O)—*′, *—S(═O)—*′, *—S(═O)₂—*′, *—C(R′)=*′, *═C(R′)—*′, *—C(R′)═C(R″)—*′, *—C(═S)—*′, or *—C≡C—*′ to form a C₅-C₃₀ carbocyclic group that is unsubstituted or substituted with at least one R₁₀ₐ or a C₁-C₃₀ heterocyclic group that is unsubstituted or substituted with at least one R₁₀ₐ. R′, R″, and R₁₀ₐ are each independently defined the same as R₁ in Formula 1A.

For example, in Formula 1A, T₁ may be a single bond, but embodiments of the present disclosure are not limited thereto.

In Formula 1A, L₁ to L₄ and L₅₁ may each independently be a single bond, a C₅-C₃₀ carbocyclic group that is unsubstituted or substituted with at least one R₁₀ₐ or a C₁-C₃₀ heterocyclic group that is unsubstituted or substituted with at least one R₁₀ₐ. Here, R₁₀ₐ is defined the same as R₁ in Formula 1A.

For example, in Formula 1A, L₁ to L₄ and L₅₁ may each independently be:
a single bond; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with at least one R₁₀ₐ. Here, R₁₀ₐ is defined the same as R₁ in Formula 1A.

In an embodiment, in Formula 1A, L₁ to L₄ and L₅₁ may each independently be:
a single bond; or
a benzene group unsubstituted or substituted with at least one R₁₀ₐ group,
but embodiments of the present disclosure are not limited thereto.

In an embodiment, in Formula 1A,

Y₁ and X₃ may be C, and X₂ and X₄ may be N,

ring CY₁ to ring CY₃ and ring CY₅₁ may be a benzene group, and ring CY₄ may be a pyridine group, and

L₄ and L₅₁ may each independently be:
a single bond; or
a benzene group unsubstituted or substituted with at least one R₁₀ₐ group.

In Formula 1A, b1 to b4 and b51 each indicate the number of groups L₁ to L₄ and L₅₁, respectively, and may each independently be 1, 2, 3, 4 or 5. When b1 is two or more, two or more groups L₁ may be identical to or different from each other, when b2 is two or more, two or more groups L₂ may be identical to or different from each other, when b3 is two or more, two or more groups L₃ may be identical to or different from each other, when b4 is two or more, two or more groups L₄ may be identical to or different from each other, and when b51 is two or more, two or more groups L₅₁ may be identical to or different from each other.

For example, in Formula 1A, b1 to b4 and b51 may each independently be 1, 2 or 3, but embodiments of the present disclosure are not limited thereto.

In Formula 1A, R₁ to R₆, R₅₁, and R₅₂ may each independently be hydrogen, deuterium, —Cl, —Br, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₅)(Q₉), or —P(Q₅)(Q₉), wherein Q₁ to Q₉ are each independently the same as described herein.

For example, R₁ to R₆, R₅₁, and R₅₂ may each independently be:
a hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, C₁-C₂₀ alkyl group, or a C₁-C₂₀ alkoxy group;
a C₁-C₂₀ alkyl group and a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or any combination thereof;

a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₂-C₂₀ alkyl group (for example, *—C(CD₃)₃), a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(C₂₈)(Q₉).

In Formula 1A, c1 to c4, c51, and c52 each indicate the number of groups R₁ to R₄, R₅₁, and R₅₂, respectively, and may each independently be 1, 2, 3, 4 or 5. When c1 is two or more, two or more groups R₁ may be identical to or different from each other, when c2 is two or more, two or more groups R₂ may be identical to or different from each other, when c3 is two or more, two or more groups R₃ may be identical to or different from each other, when c4 is two or more, two or more groups R₄ may be identical to or different from each other, when c51 is two or more, two or more groups R₅₁ may be identical to or different from each other, and when c52 is two or more, two or more groups R₅₂ may be identical to or different from each other. For example, c1 to c3, c51, and c52 may each independently be 1 or 2, but embodiments of the present disclosure are not limited thereto.

In Formula 1A, A₅₁ may be a C₄-C₆₀ alkyl group, and A₅₂ may be deuterium or a deuterium-containing C₁-C₆₀ alkyl group unsubstituted or substituted with at least one C₃-C₁₀ cycloalkyl group.

In an embodiment, in Formula 1A, A₅₁ may be a linear or branched C₄-C₁₀ alkyl group, and A₅₂ may be deuterium or a deuterium-containing linear or branched C₁-C₂₀ alkyl group unsubstituted or substituted with at least one C₃-C₁₀ cycloalkyl group.

In an embodiment, in Formula 1A, A₅₁ may be an n-butyl group, a sec-butyl group, an iso-butyl group, a tert-butyl group, an n-pentyl group, a tert-pentyl group, a neo-pentyl group, an iso-pentyl group, a sec-pentyl group, a 3-pentyl group, or a sec-iso-pentyl group, unsubstituted or substituted with a methyl group, an ethyl group, an n-propyl group, an iso-propyl group, an n-butyl group, a sec-butyl group, an iso-butyl group, a tert-butyl group, an n-pentyl group, a tert-pentyl group, a neo-pentyl group, an iso-pentyl group, a sec-pentyl group, a 3-pentyl group, a sec-iso-pentyl group, or any combination thereof.

In an embodiment, in Formula 1A, A₅₂ may be a deuterium-containing linear or branched C₁-C₂₀ alkyl group unsubstituted or substituted with at least one C₃-C₁₀ cycloalkyl group, in which the linear or branched C₁-C₂₀ alkyl group may be a methyl group, an ethyl group, an n-propyl group, an iso-propyl group, an n-butyl group, a sec-butyl group, an iso-butyl group, a tert-butyl group, an n-pentyl group, a tert-pentyl group, a neo-pentyl group, an iso-pentyl group, a sec-pentyl group, a 3-pentyl group, or a sec-iso-pentyl group, unsubstituted or substituted with a methyl group, an ethyl group, an n-propyl group, an iso-propyl group, an n-butyl group, a sec-butyl group, an iso-butyl group, a tert-butyl group, an n-pentyl group, a tert-pentyl group, a neo-pentyl group, an iso-pentyl group, a sec-pentyl group, a 3-pentyl group, a sec-iso-pentyl group, or any combination thereof.

The organometallic compound represented by Formula 1A may include a deuterium, a deuterium-containing C₁-C₆₀ alkyl group unsubstituted or substituted with at least one C₃-C₁₀ cycloalkyl group, or any combination thereof. The number of deuterium atoms in the organometallic compound represented by Formula 1A may be from 1 to 20, for example, from 1 to 15, from 1 to 10, or from 1 to 5.

In an embodiment, regarding Formula 1A,
R₁ to R₆, R₅₁, and R₅₂ may each independently be:
hydrogen, deuterium, —F, a cyano group, a nitro group, —SF₅, —CH₃, —CD₃, —CD₂H, —CDH₂, —CF₃, —CF₂H, —CFH₂, a group represented by one of Formulae 9-1 to 9-66, a group represented by one of Formulae 9-1 to 9-66 in which at least one hydrogen is substituted with deuterium, a group represented by one of Formulae 10-1 to 10-118, a group represented by one of Formulae 10-1 to 10-118 in which at least one hydrogen is substituted with deuterium, a group represented by one of Formulae 10-201 to 10-342, or a group represented by one of Formulae 10-201 to 10-342 in which at least one hydrogen is substituted with deuterium, and/or
A₅₁ may be a group represented by one of Formulae 9-4 to 9-36, and/or
A₅₂ may be a group represented by one of Formulae 9-1 to 9-63 in which at least one hydrogen is substituted with deuterium, and/or
a group represented by

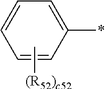

in Formula 1A may be a group represented by one of Formulae 10-10 to 10-118, or a group represented by one of Formulae 10-10 to 10-118 in which at least one hydrogen is substituted with deuterium:

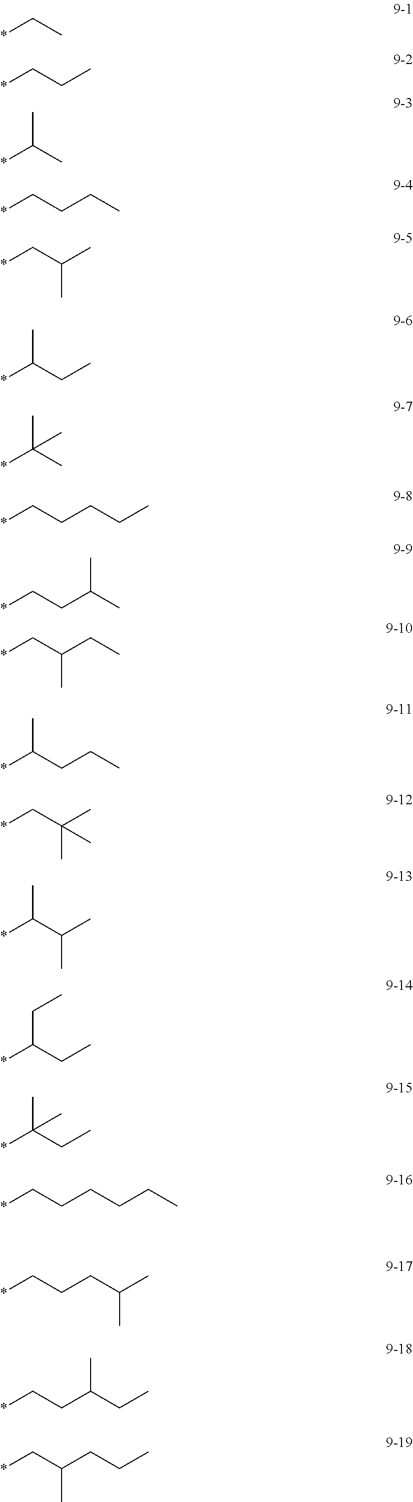

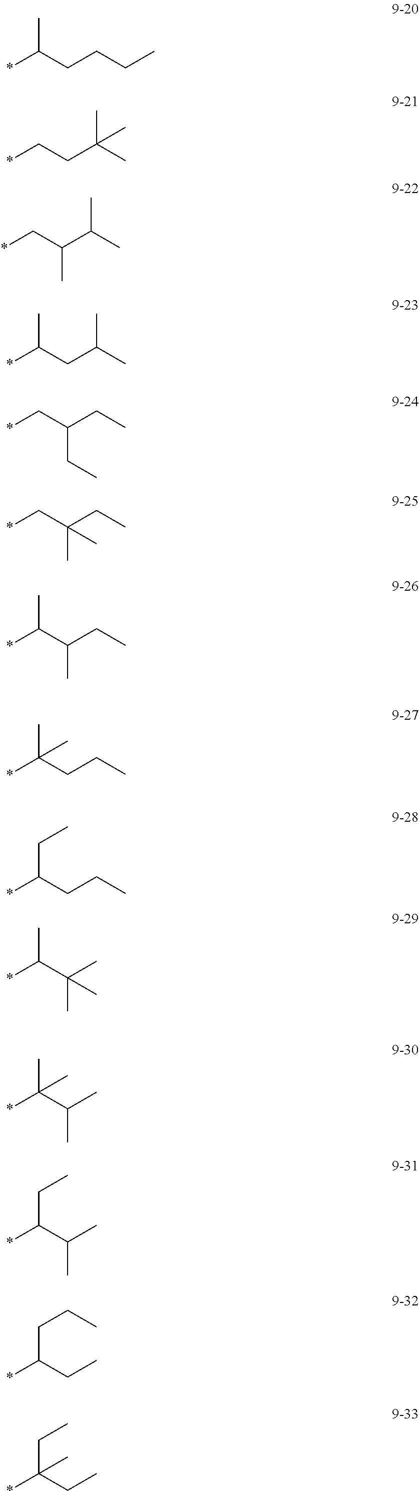

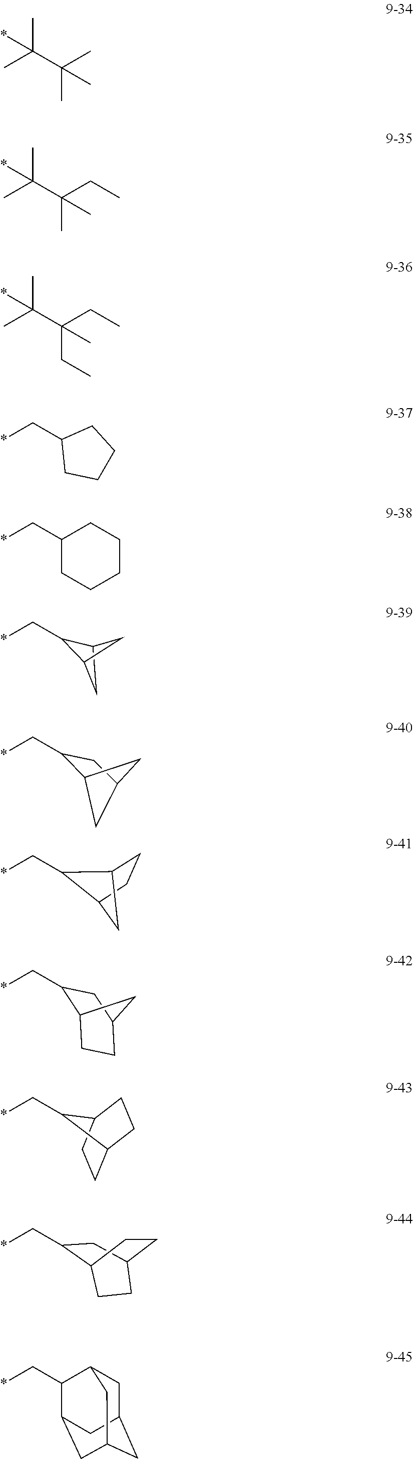

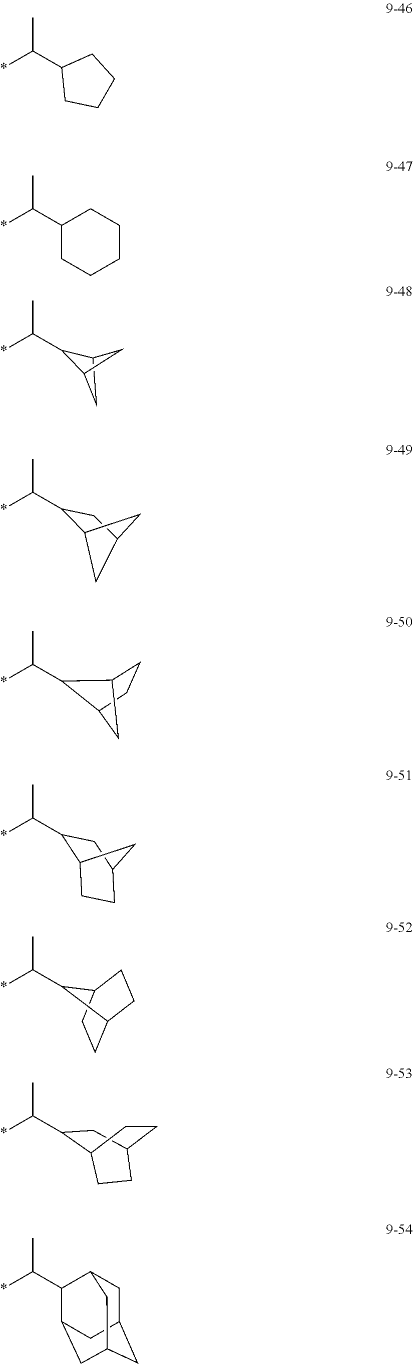

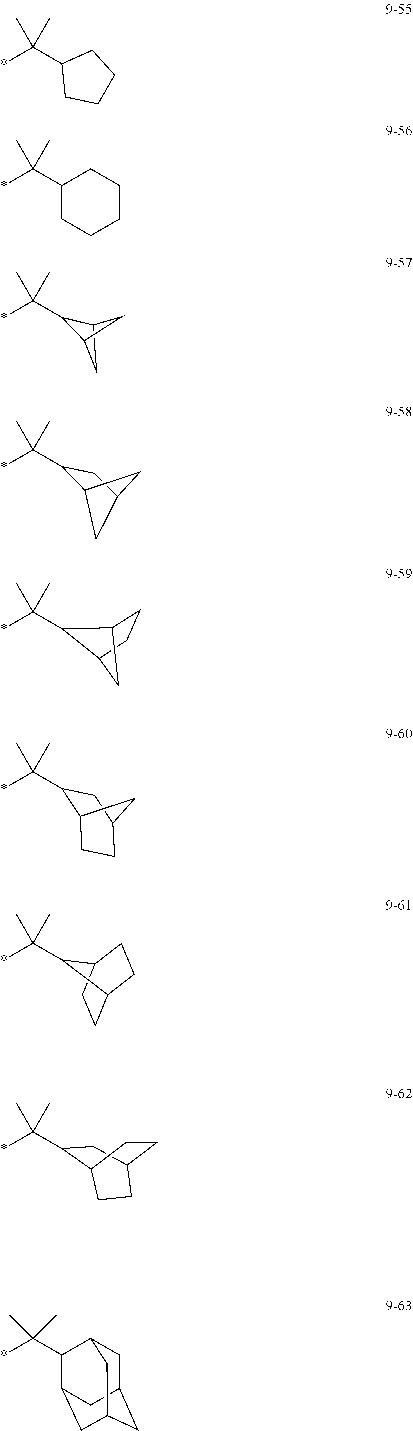

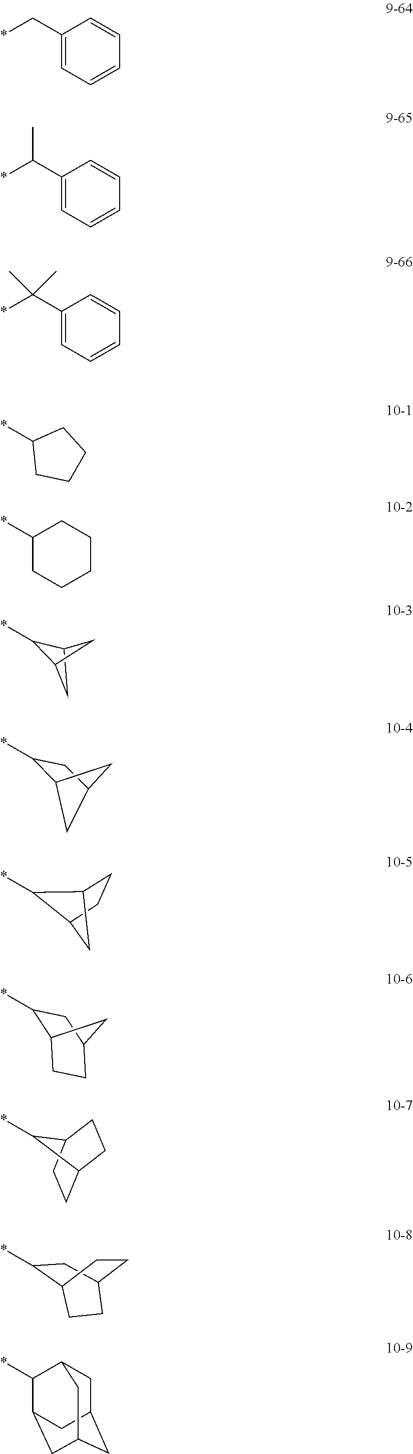

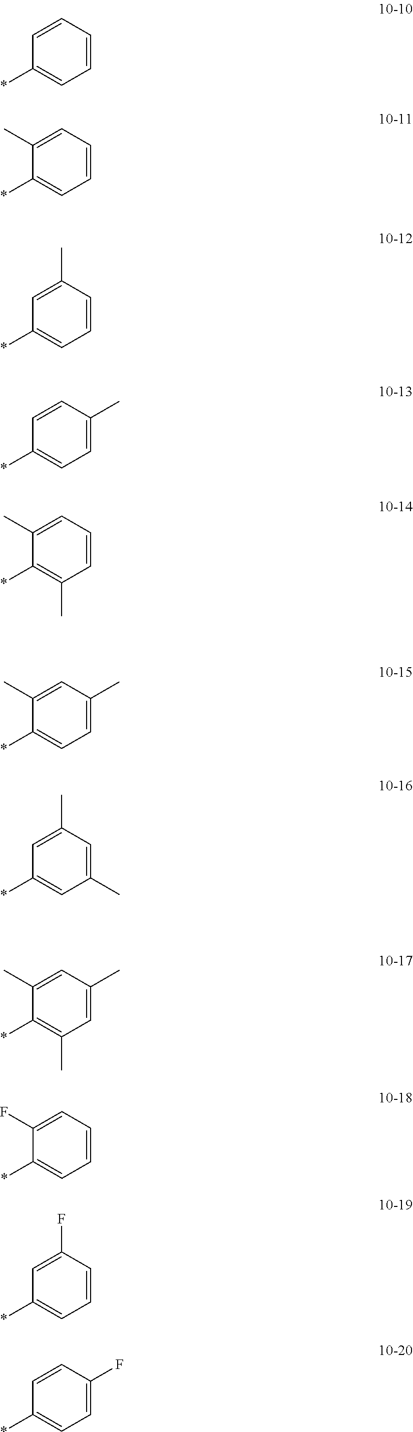

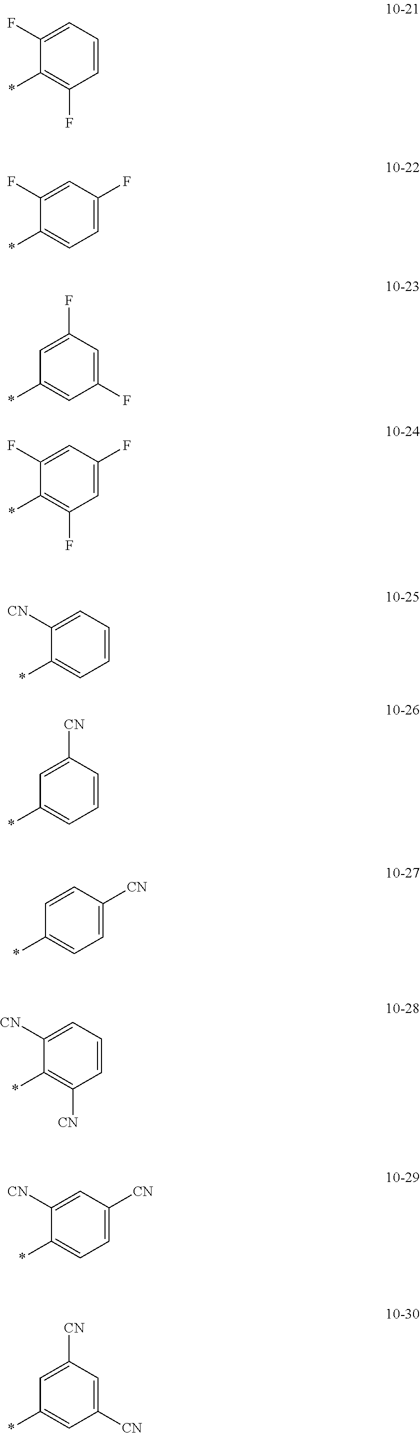

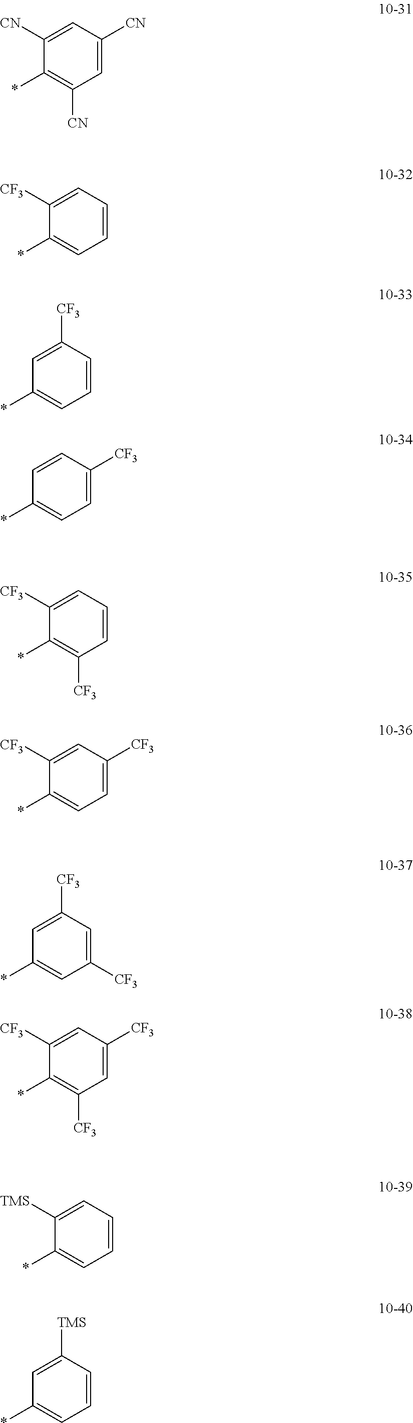

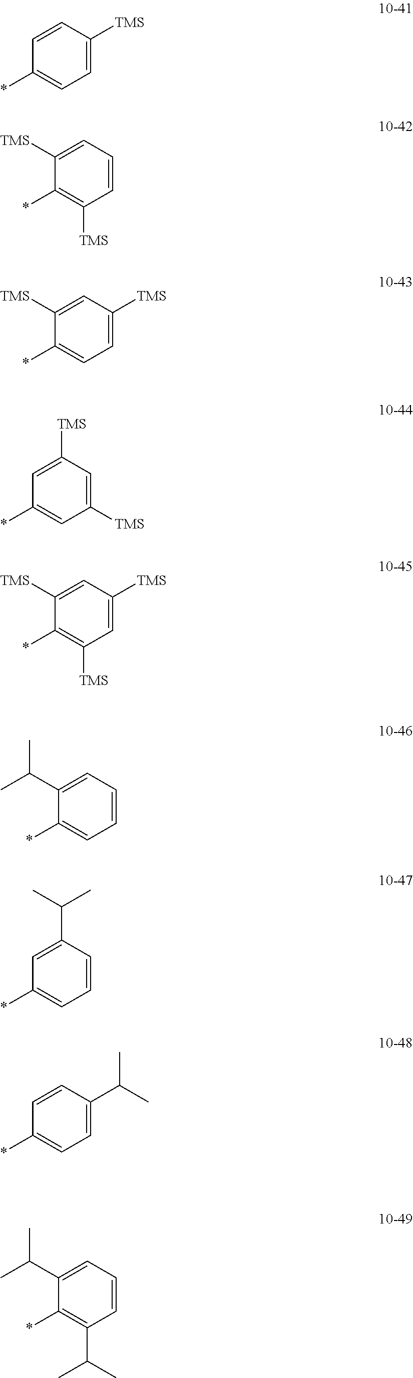

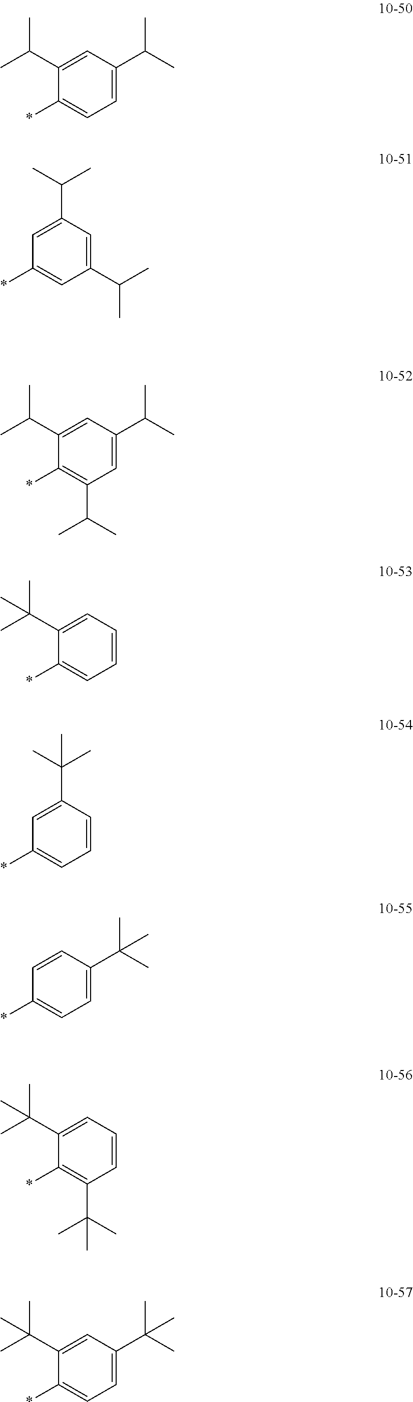

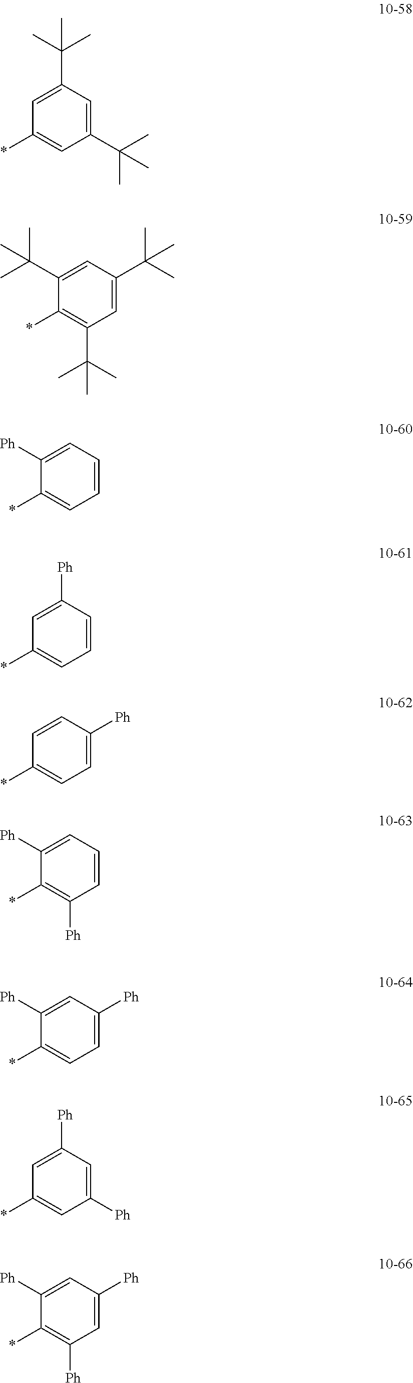

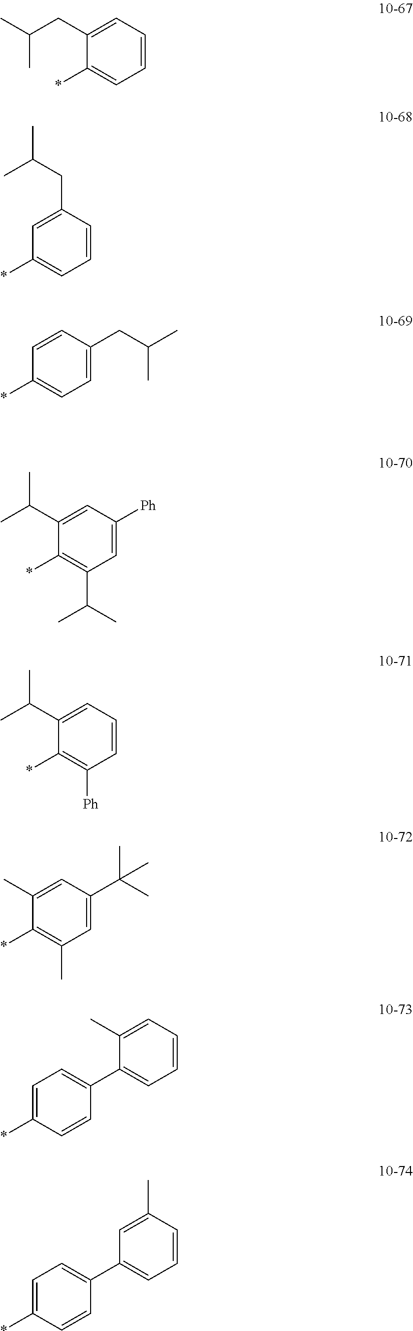

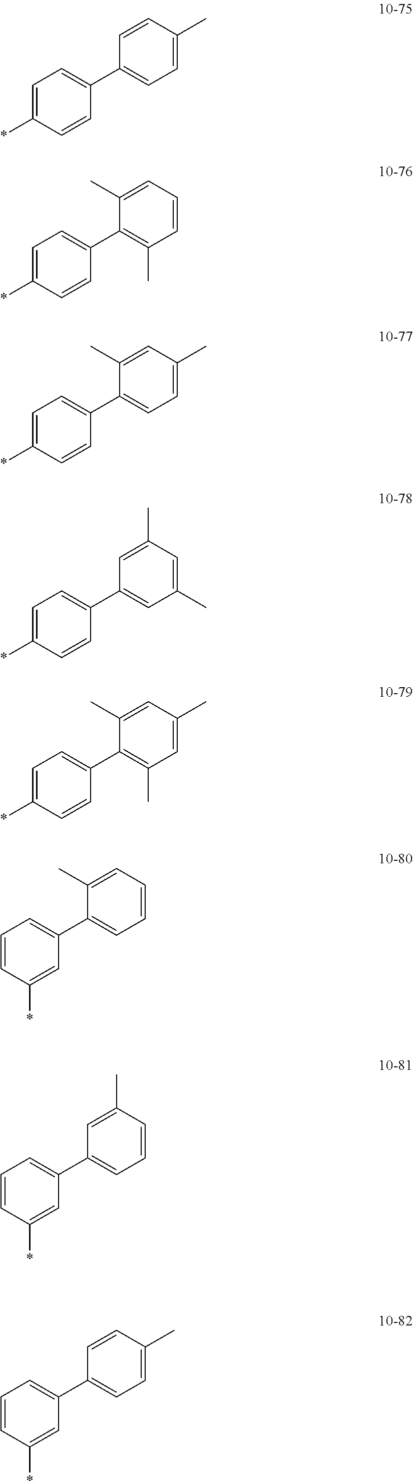

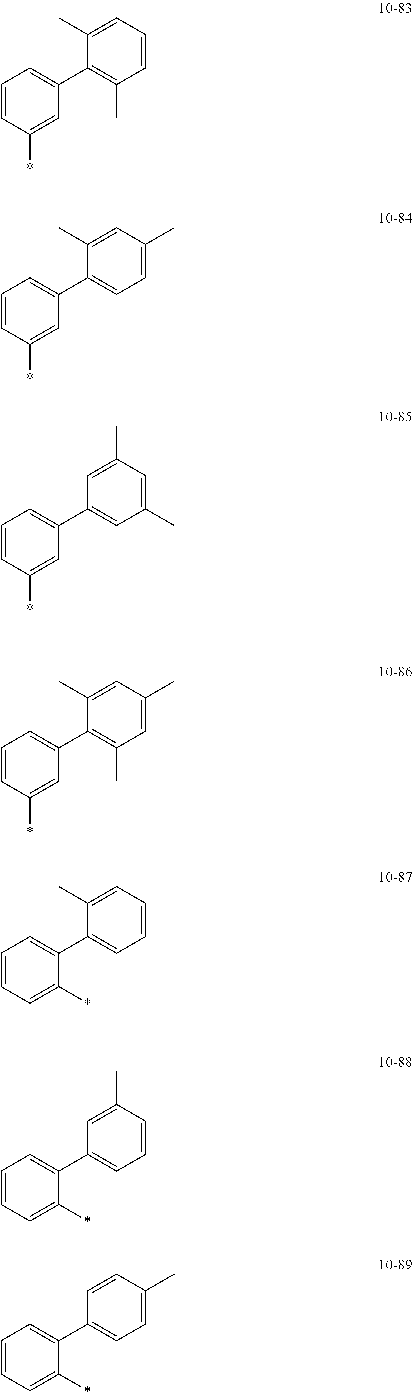

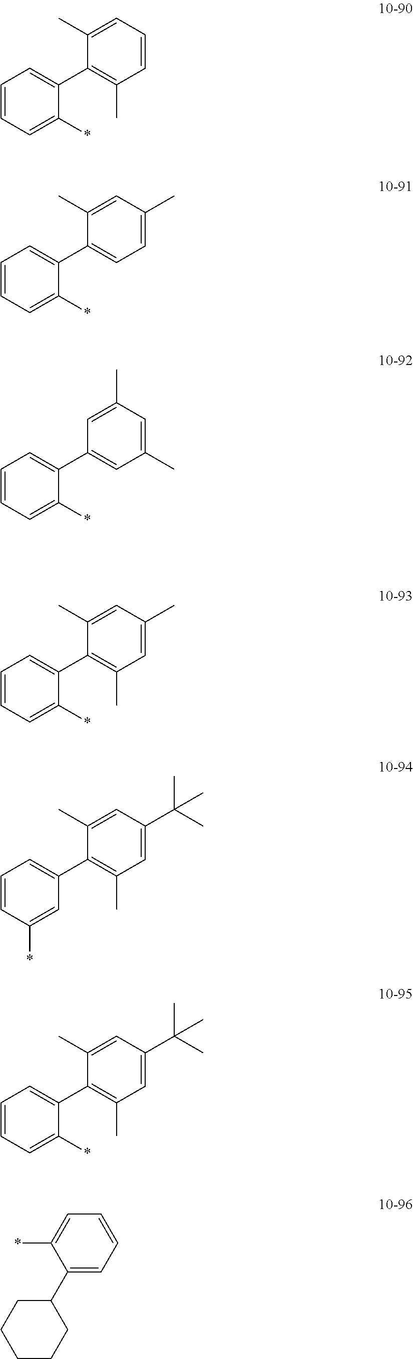

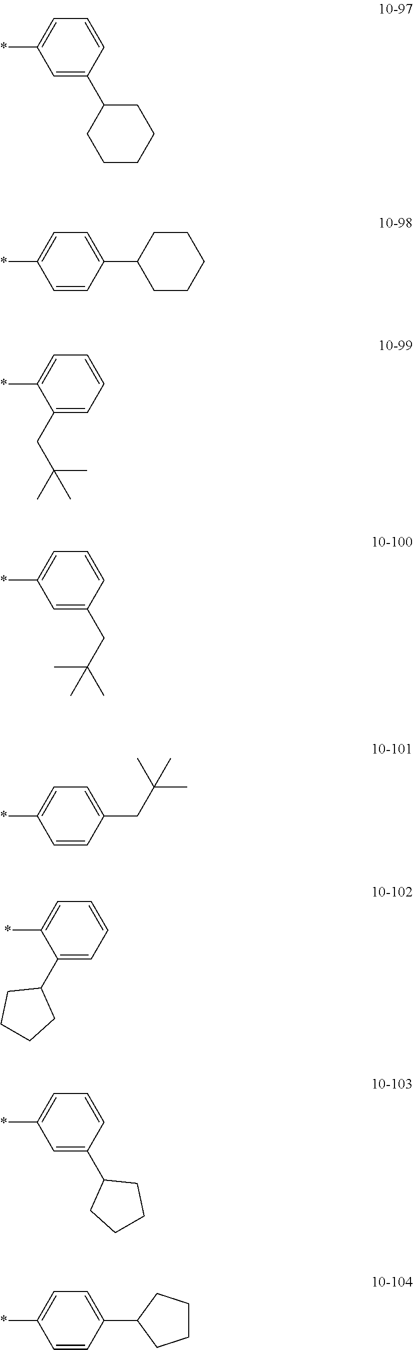

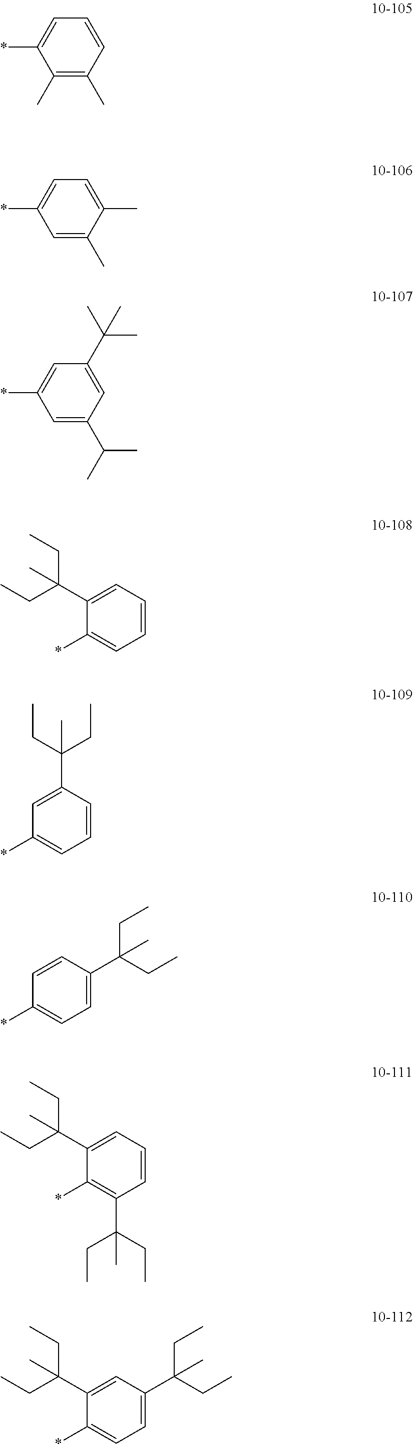

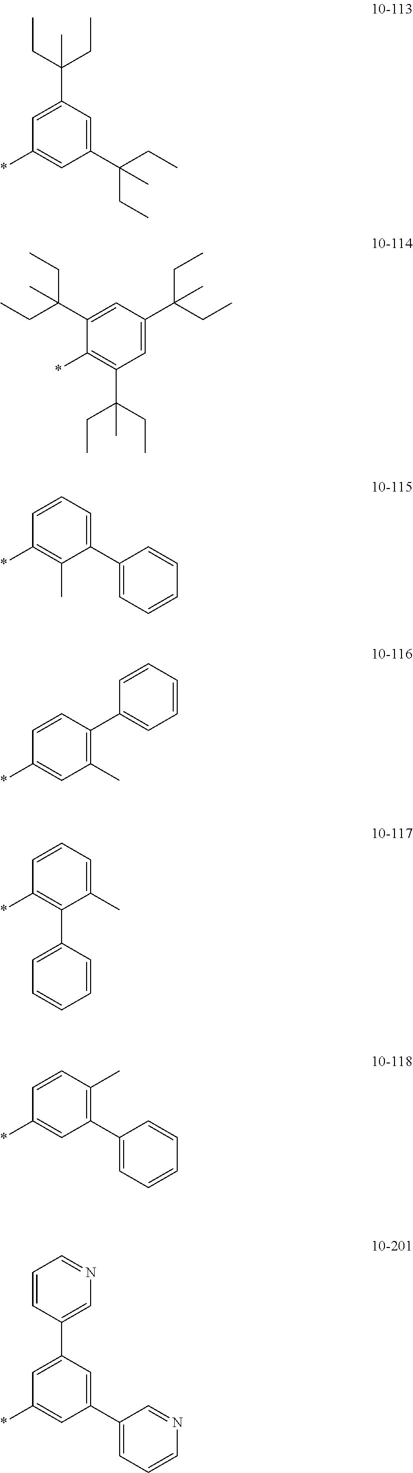

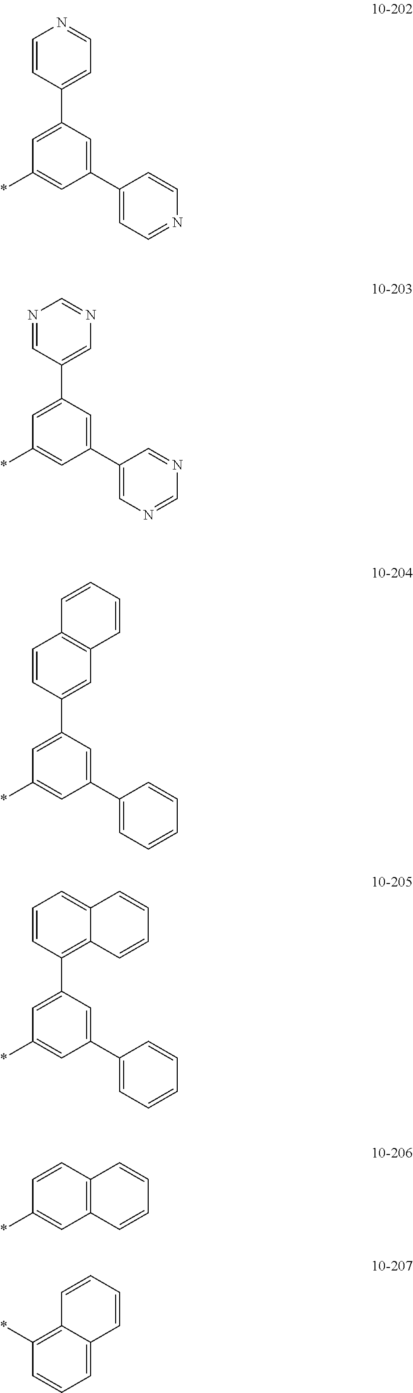 [SMILES: *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1 ; *c1cc(-c2ccccc2)cc(-c2cccc3ccccc23)c1 ; *c1ccc2ccccc2c1 ; *c1cccc2ccccc12]

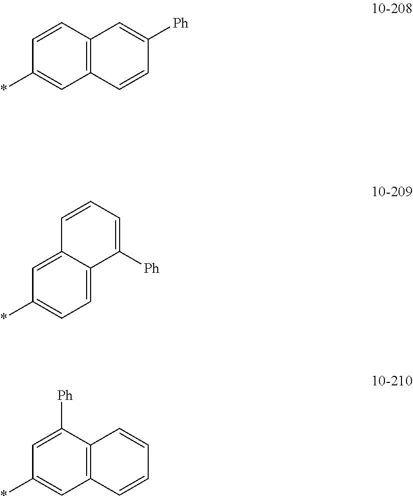 [SMILES: *c1ccc2cc(-c3ccccc3)ccc2c1 ; *c1ccc2c(-c3ccccc3)cccc2c1 ; *c1cc(-c2ccccc2)c2ccccc2c1]

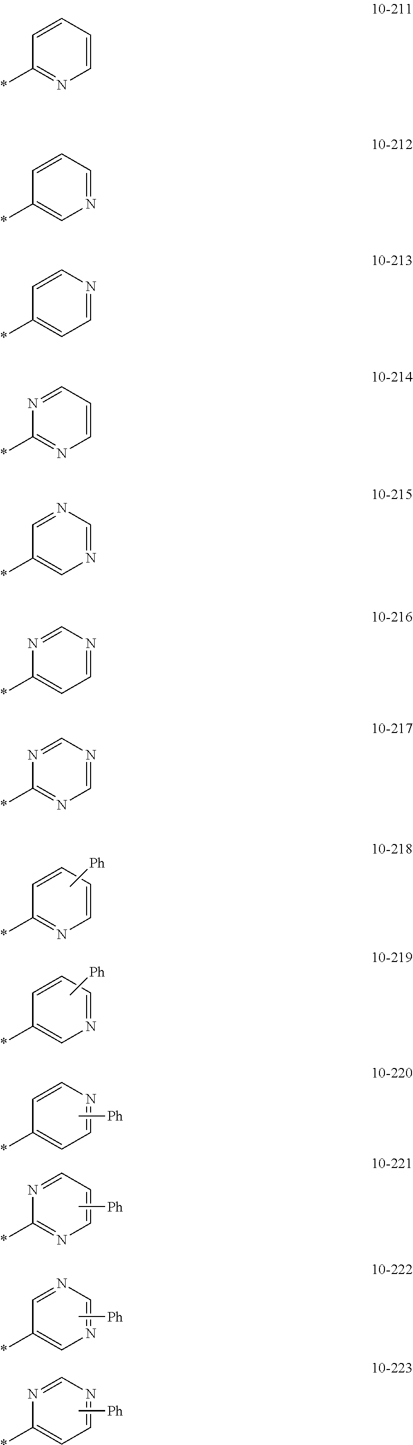

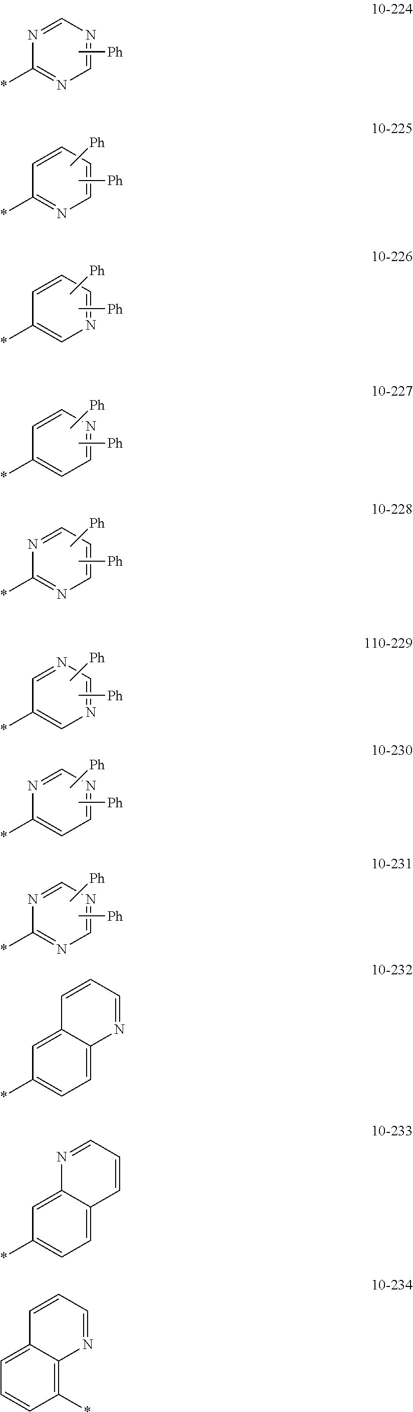

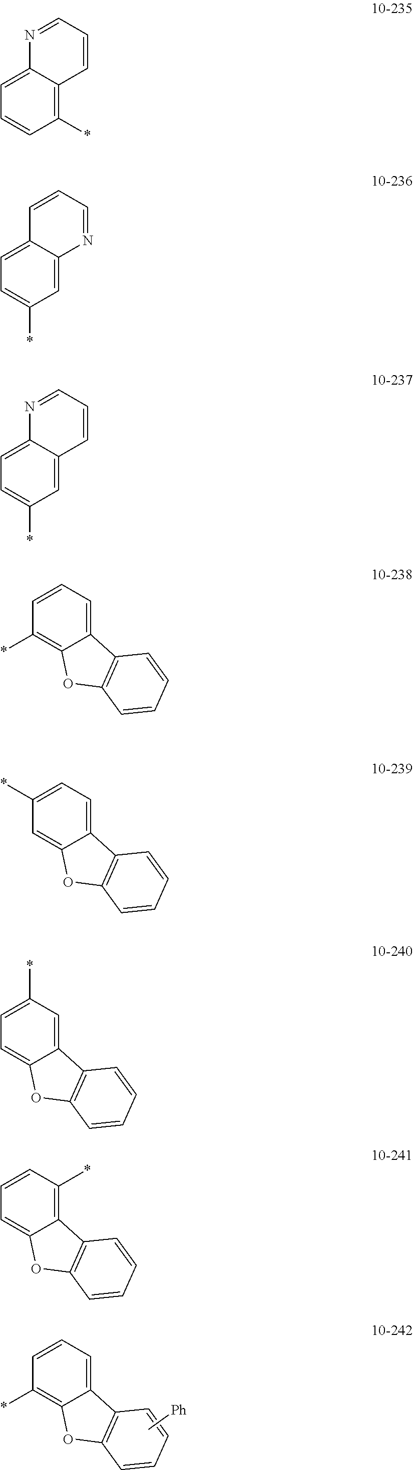

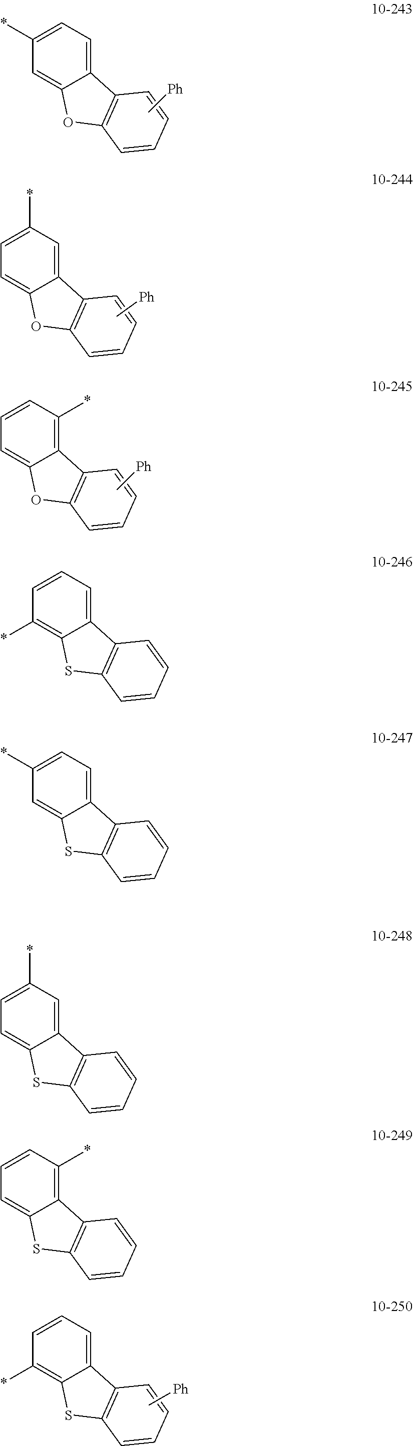

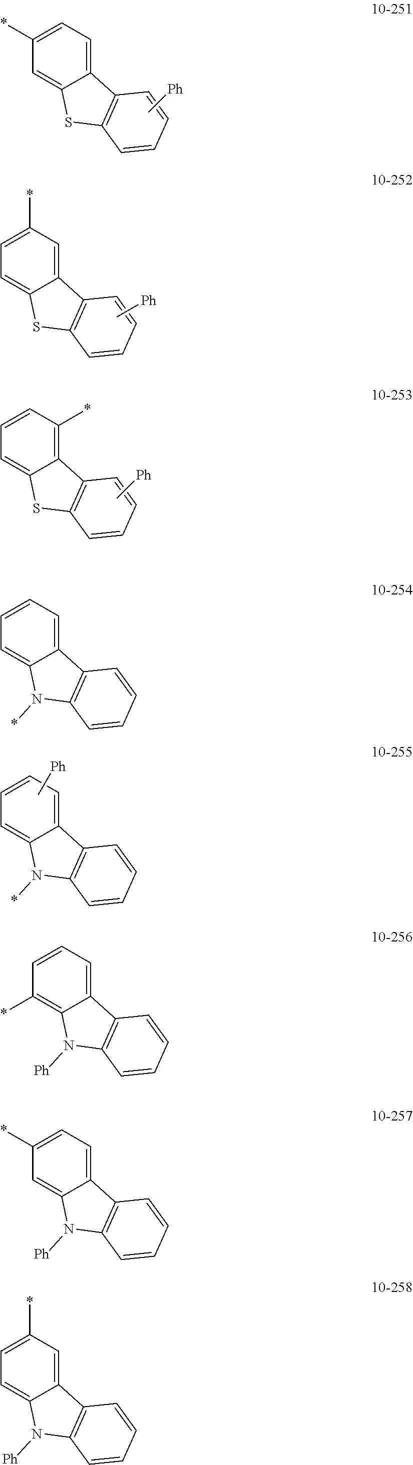

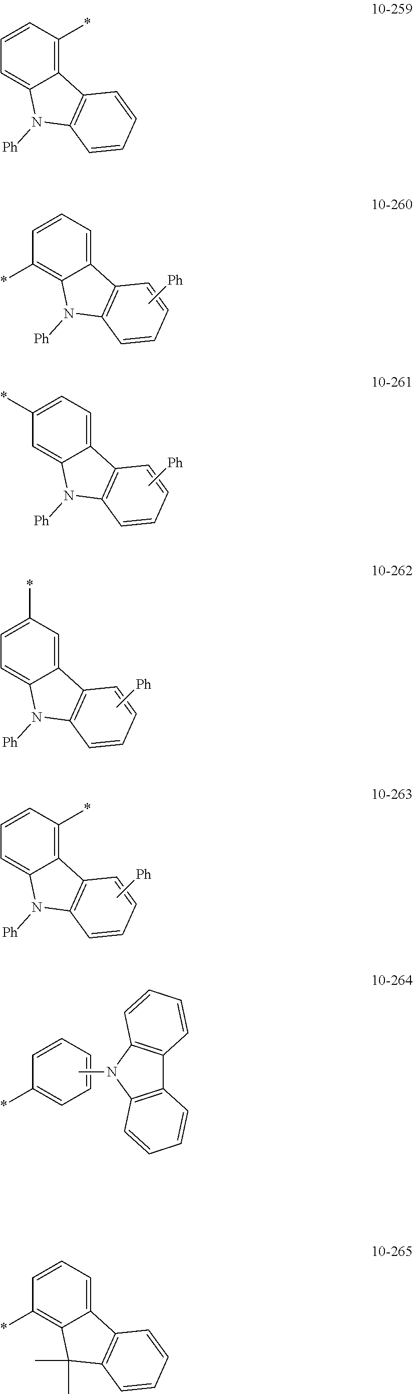

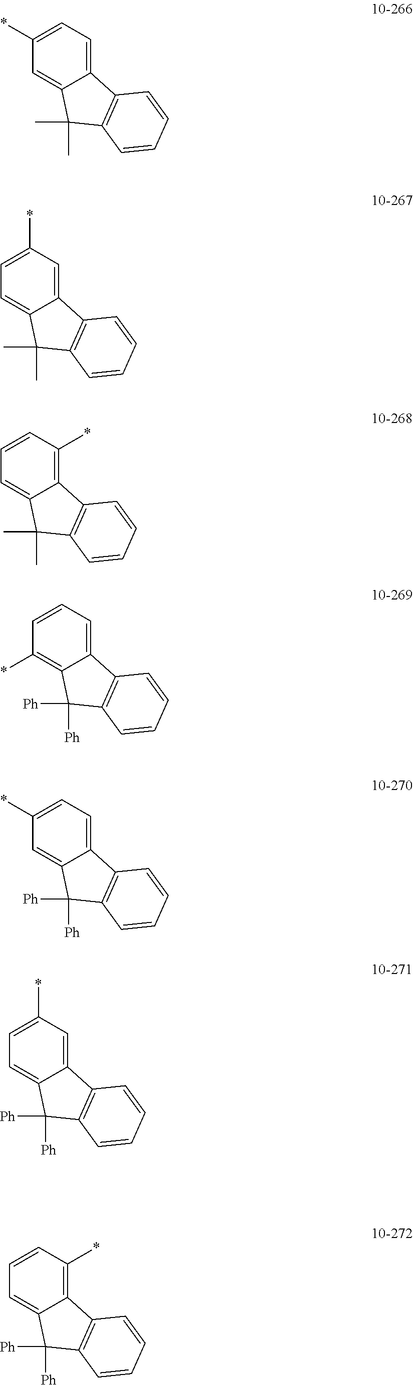

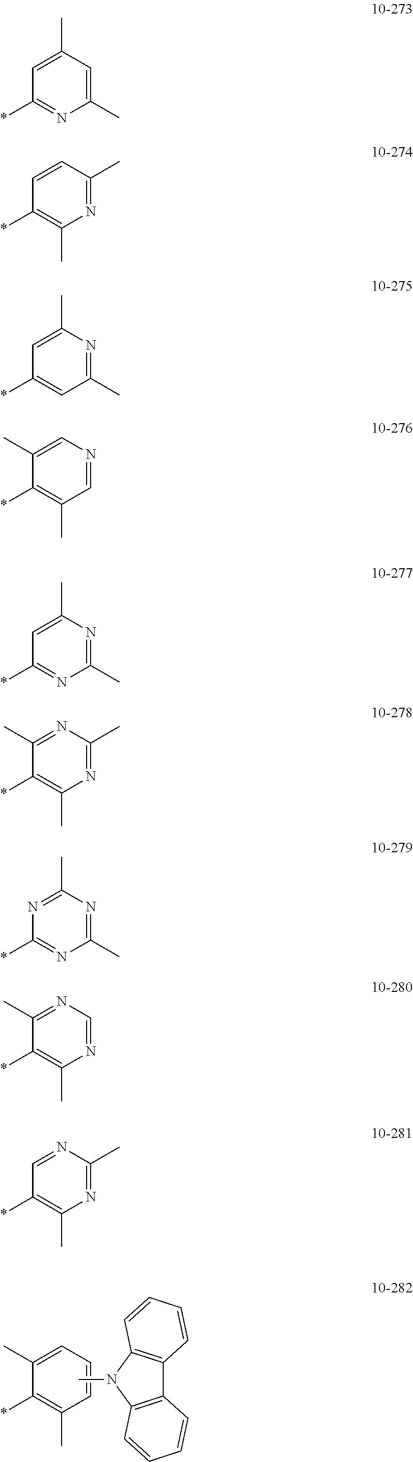

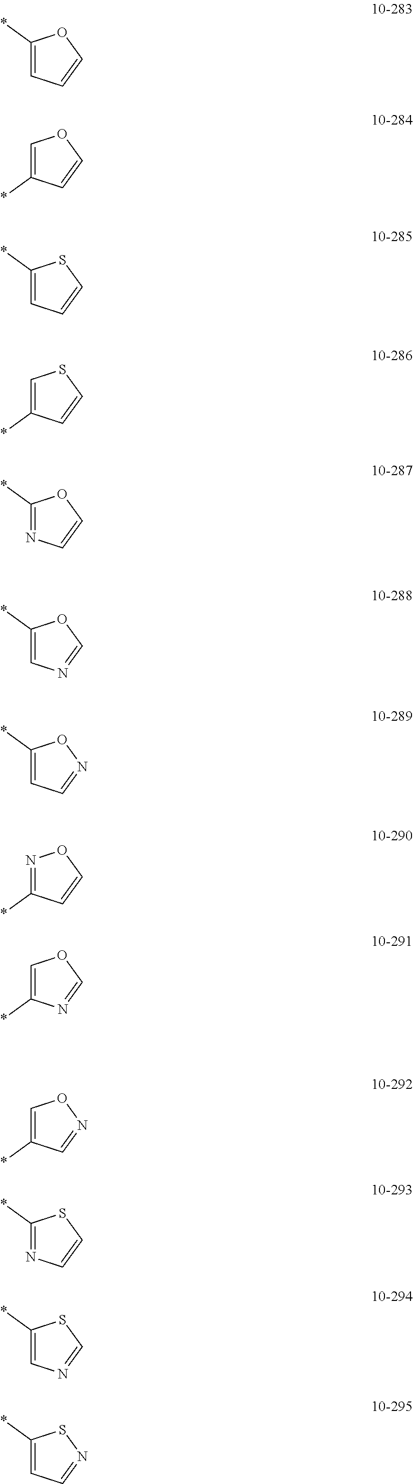

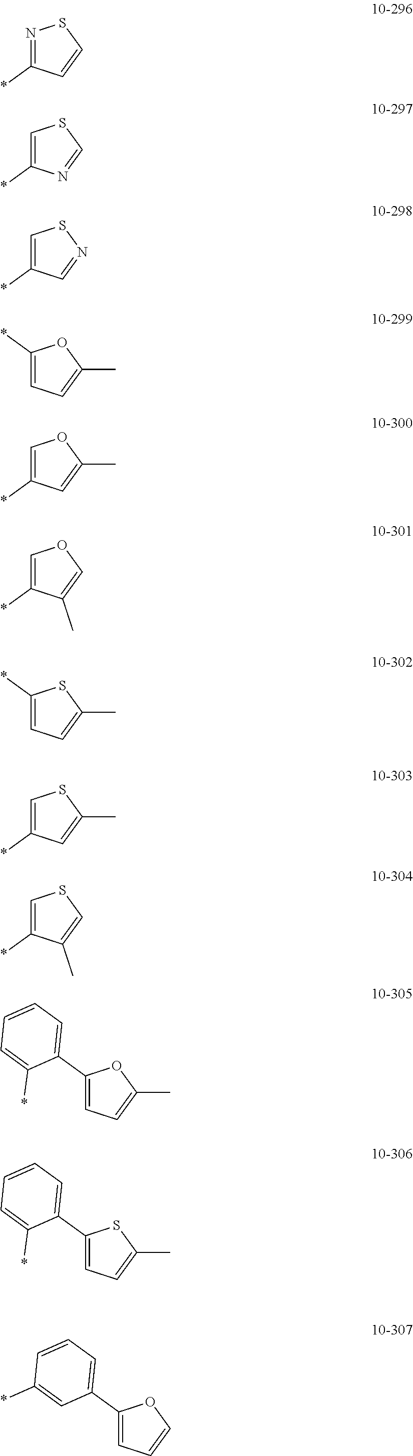

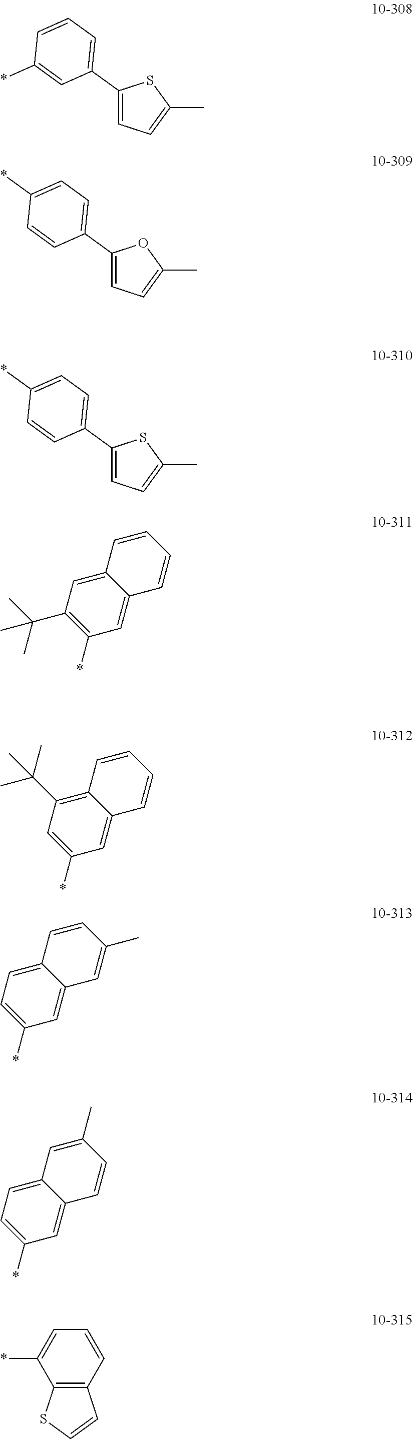

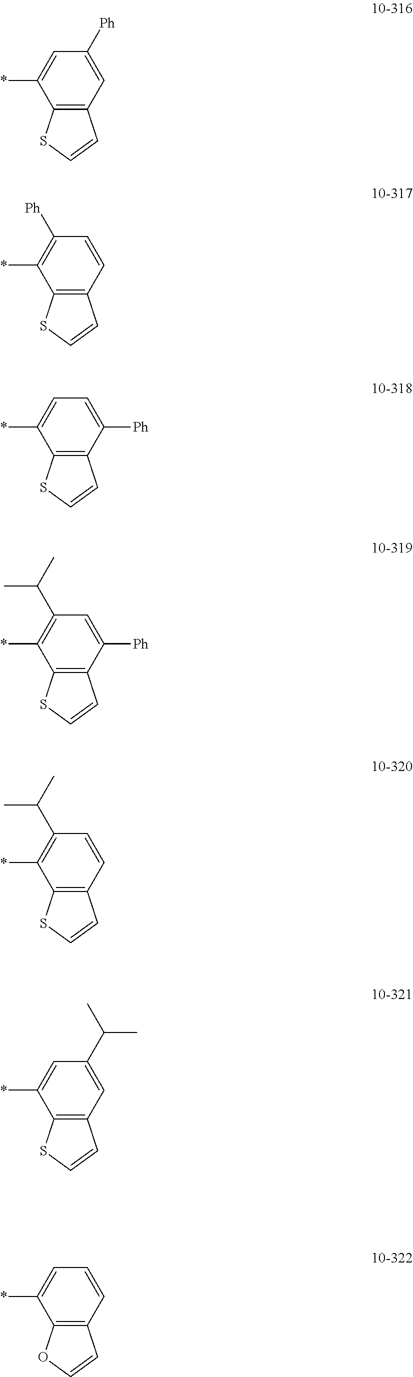

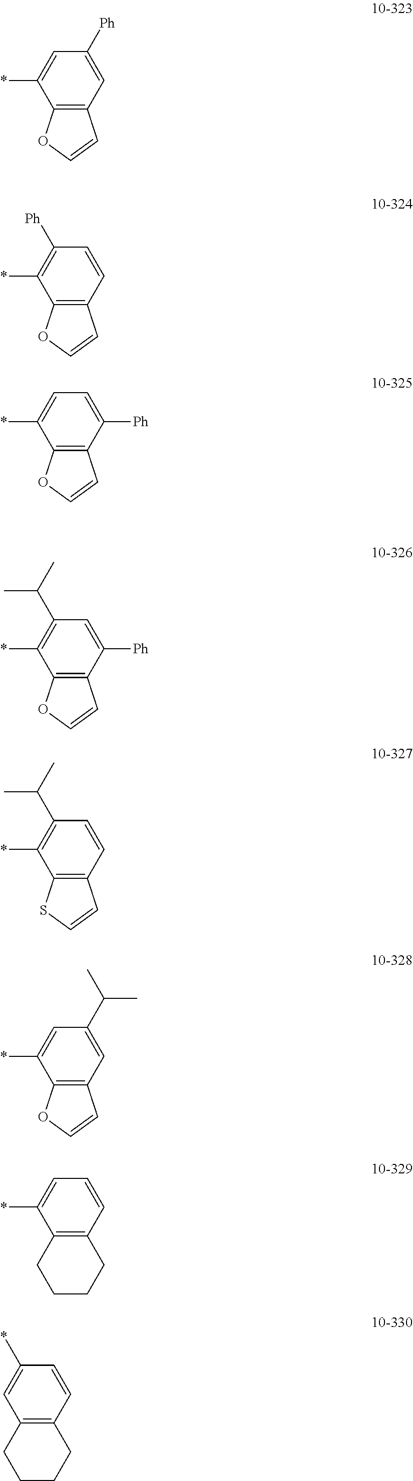

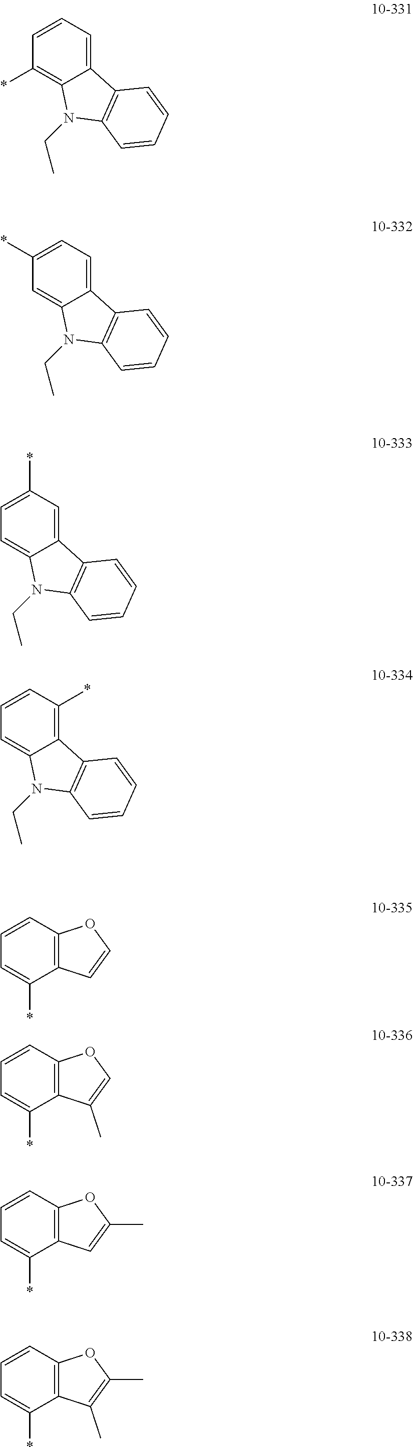

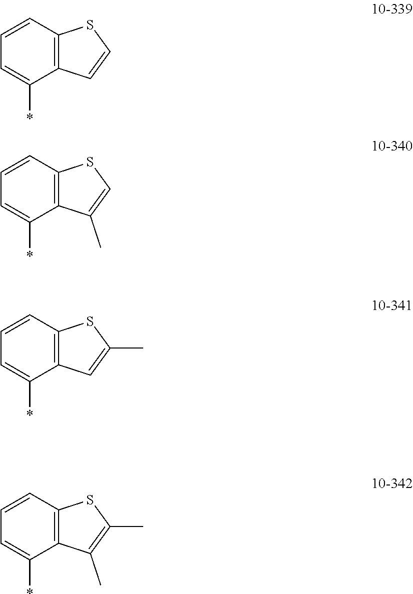

In Formulae 9-1 to 9-66, 10-1 to 10-118 and 10-201 to 10-342, * indicates a binding site to a neighboring atom, Ph indicates a phenyl group, and TMS indicates a trimethylsilyl group.

For example, Formula 9-33 may be a branched C₆ alkyl group (i.e., a tert-butyl group substituted with two methyl groups).

The “group represented by one of Formulae 9-1 to 9-66 in which at least one hydrogen is substituted with deuterium” may be, for example, a group represented by one of Formulae 9-501 to 9-514 or 9-601 to 9-638.

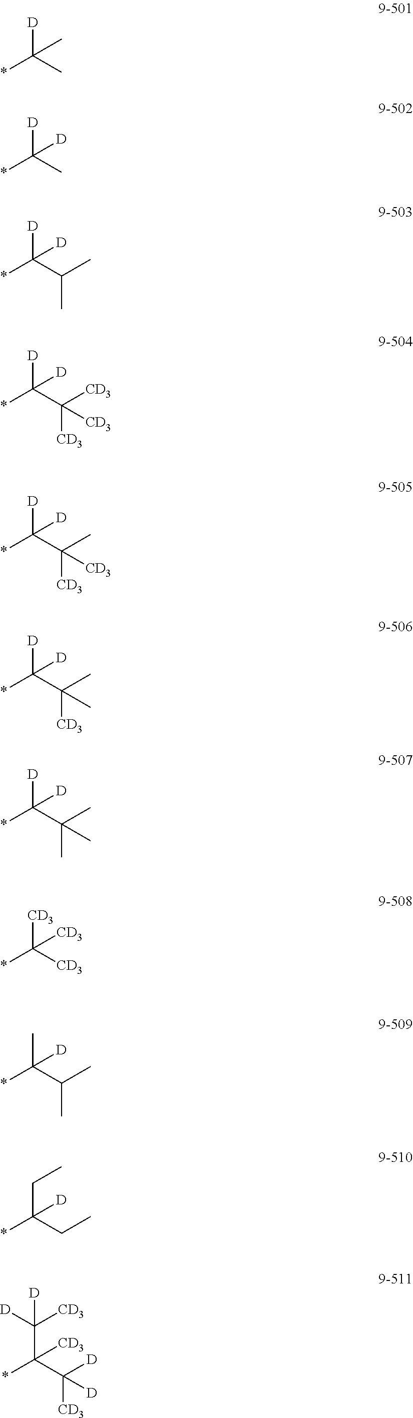

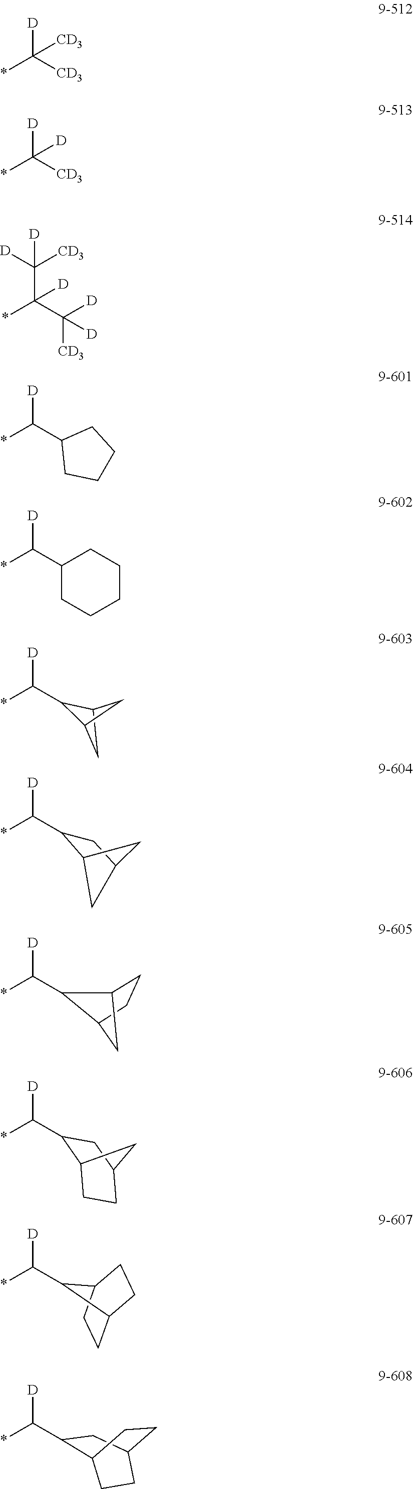

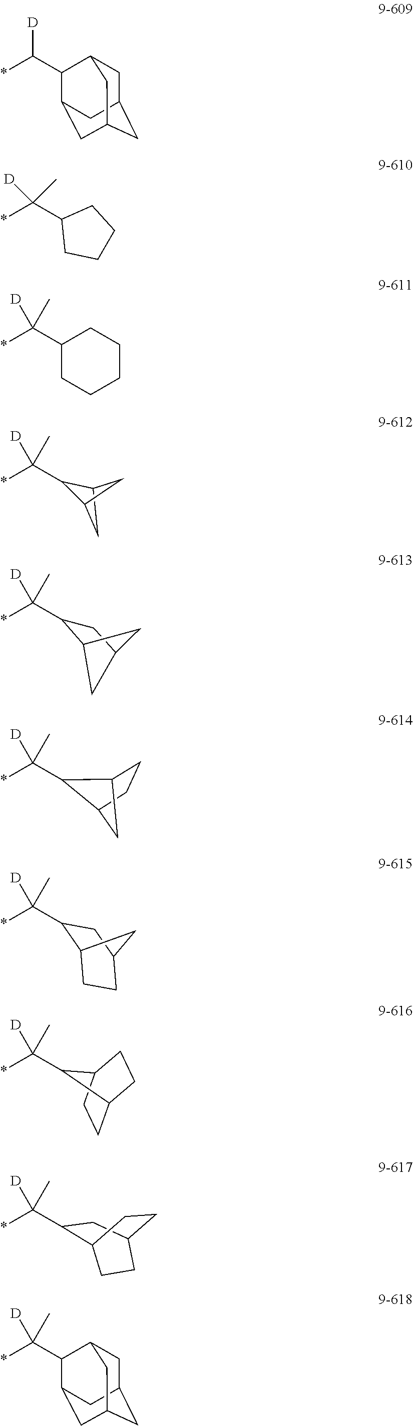

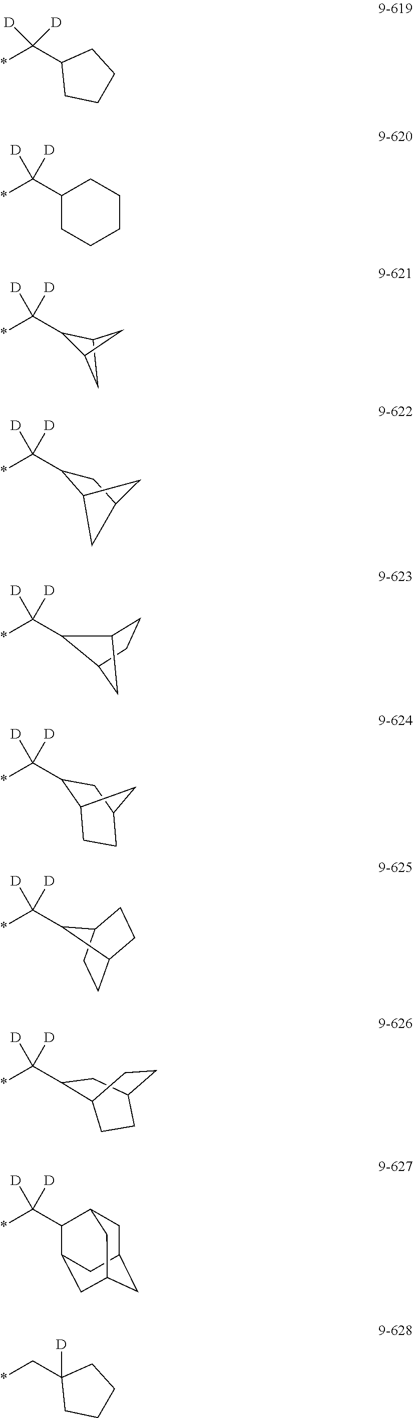

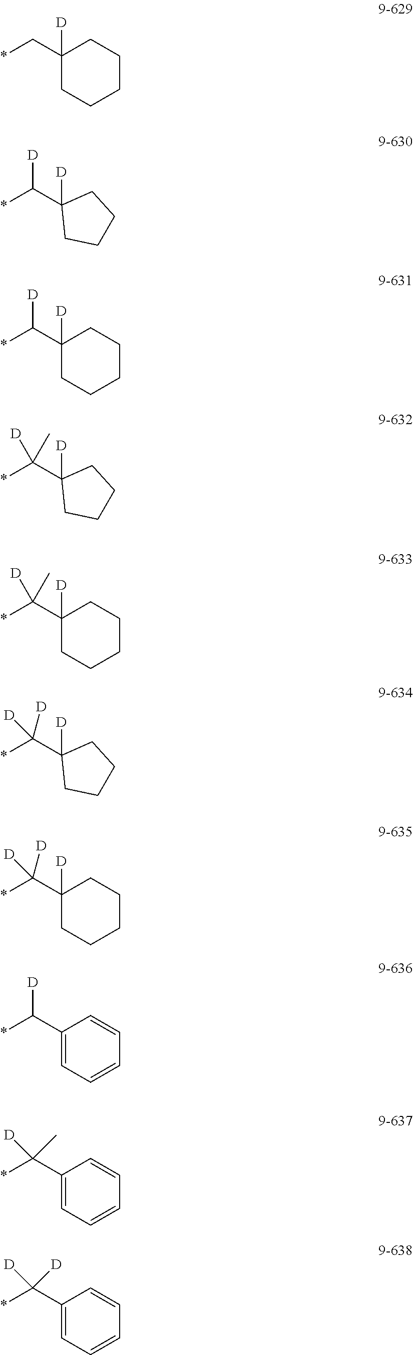

The “group represented by one of Formulae 10-1 to 10-118 in which at least one hydrogen is substituted with deuterium” may be, for example, a group represented by one of Formulae 10-501 to 10-552:

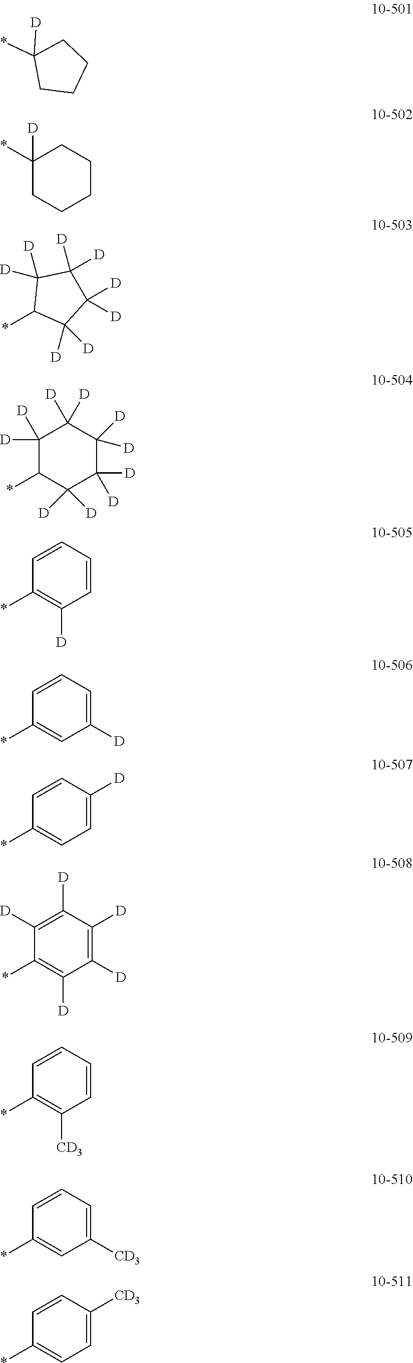

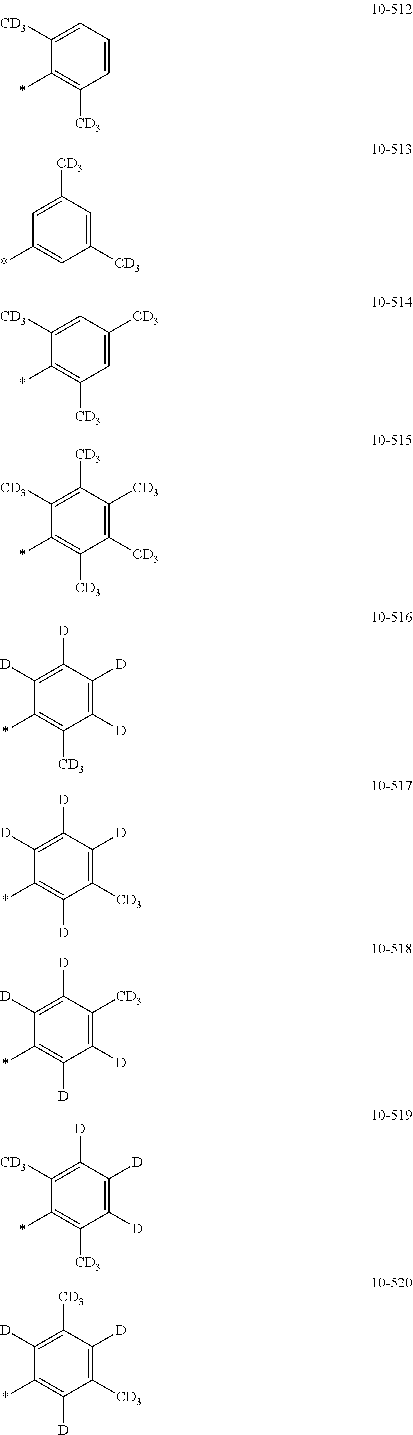

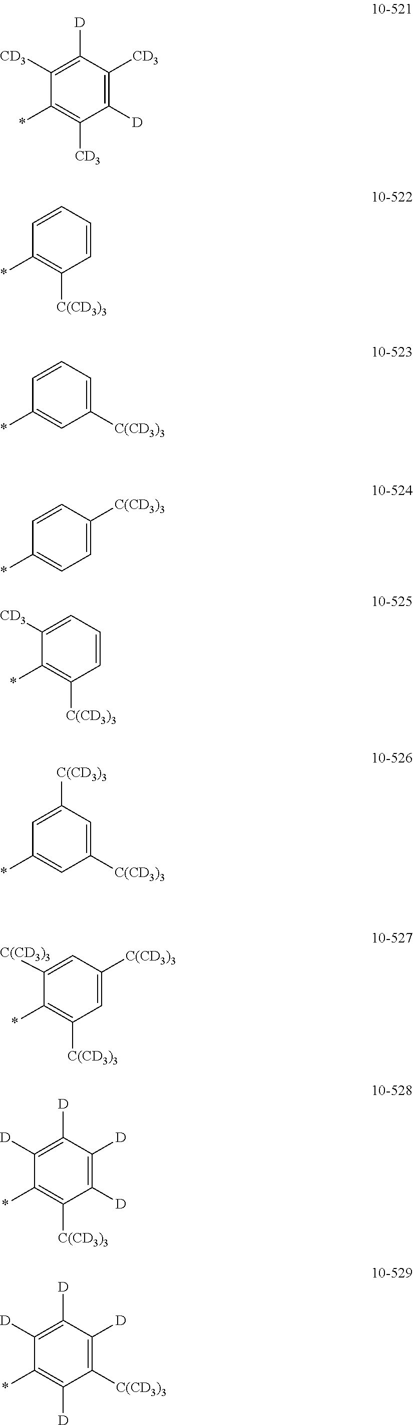

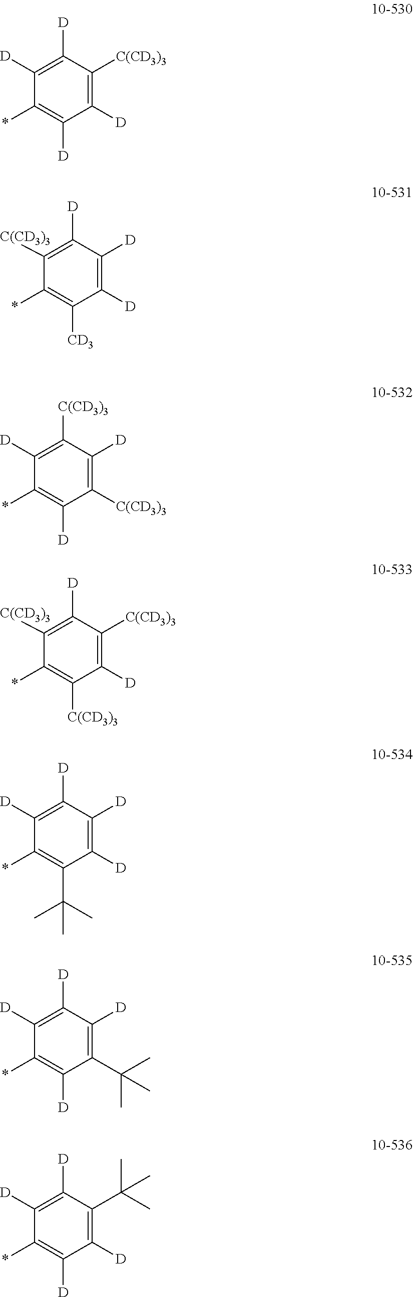

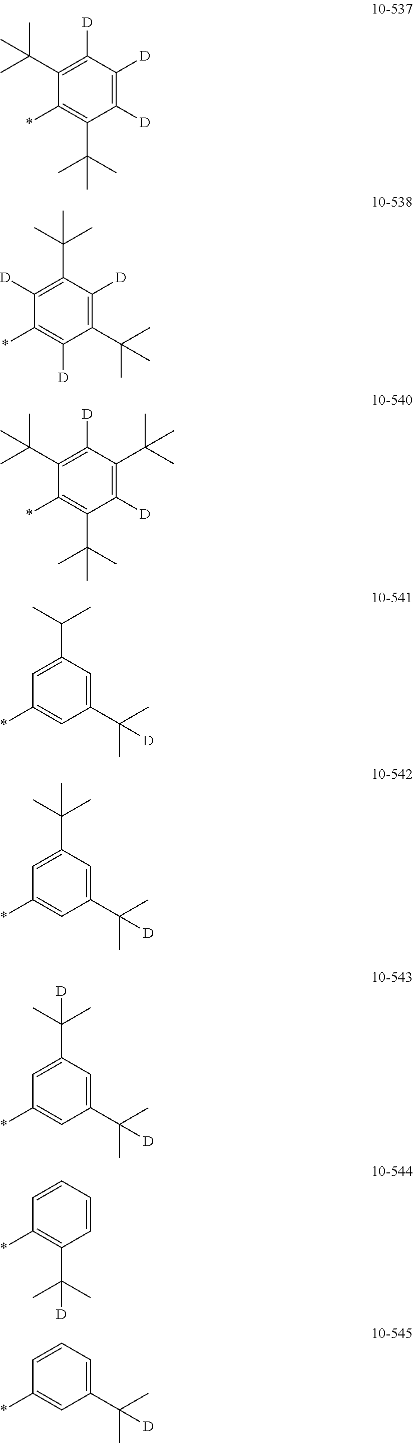

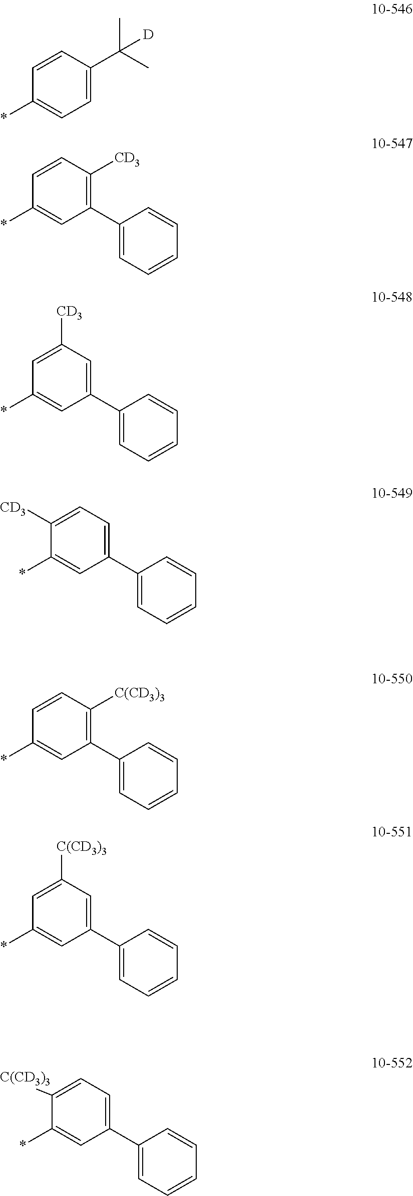

In an embodiment, in Formula 1A, A₅₂ may be a group represented by one of Formulae 9-1 to 9-36 in which all hydrogens are substituted with deuterium, but embodiments of the present disclosure are not limited thereto.

In Formula 1A, a1 to a4, a51, and a52 respectively indicate the number of groups *-[(L₁)_{b1}-(R₁)_{c1}], *-[(L₂)_{b2}-(R₂)_{c2}], *-[(L₃)_{b3}-(R₃)_{c3}], *-[(L₄)_{b4}-(R₄)_{c4}], A₅₁, and A₅₂, and may each independently be an integer from 0 to 10. When a1 is two or more, two or more groups *-[(L₁)_{b1}-(R₁)_{c1}] may be identical to or different from each other, when a2 is two or more, two or more groups *-[(L₂)_{b2}-(R₂)_{c2}] may be identical to or different from each other, when a3 is two or more, two or more groups *-[(L₃)_{b3}-(R₃)_{c3}] may be identical to or different from each other, when a4 is two or more, two or more groups *-[(L₄)_{b4}-(R₄)_{c4}] may be identical to or different from each other, when a51 is two or more, two or more groups A₅₁ may be identical to or different from each other, and when a52 is two or more, two or more groups A₅₂ may be identical to or different from each other, but embodiments of the present disclosure are not limited thereto.

For example, in Formula 1A, a1 to a4, a51, and a52 may each independently be 0, 1, 2, 3, 4, 5, or 6, but embodiments of the present disclosure are not limited thereto.

For example, in Formula 1A, a1 and a4 may each independently be 0, 1, 2, 3, or 4 and a2, a3, a51 and a52 may each independently be 0, 1, 2, or 3.

In Formula 1A, the sum of a51 and a52 may be 1 or more. That is, in Formula 1A, ring CY₅₁ is essentially substituted with at least one group represented by A₅₁; at least one group represented by A₅₂; or any combination thereof.

For example, the sum of a51 and a52 may be 1, 2, or 3. In an embodiment, the sum of a51 and a52 may be 1 or 2.

In Formula 1A, a53 indicates the number of groups represented by

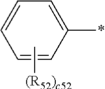

and may be an integer from 1 to 10. Since a53 in Formula 1A is not 0, ring CY₅₁ in Formula 1A is essentially substituted with a group represented by at least one

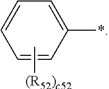

In an embodiment, in Formula 1A,

L₁ to L₃ may be a single bond, and

R₁ to R₃ may each independently be:

hydrogen, deuterium, —F, a cyano group, C₁-C₂₀ alkyl group, or a C₁-C₂₀ alkoxy group;

a C₁-C₂₀ alkyl group or a C₁-C₂₀ alkoxy group, each substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof; or a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group (for example, *—C(CD₃)₃), a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

In an embodiment, in Formula 1A, a3, and a4 may not be 0, and a group represented by *-(L₃)_{b3}-(R₃)_{c3}, and a group represented by *-(L₄)_{b4}-(R₄)_{c4} may not be hydrogen.

In an embodiment, in Formula 1A, a1, a3, and a4 may not be 0, and a group represented by *-(L₁)_{b1}-(R₁)_{c1}, a group represented by *-(L₃)_{b3}-(R₃)_{c3}, and a group represented by *-(L₄)_{b4}-(R₄)_{c4} may not be hydrogen.

In an embodiment, in Formula 1A, a1 may not be 0, a group represented by *-(L₁)_{b1}-(R₁)_{c1} may not be hydrogen, and a group represented by *-(L₁)_{b1}-(R₁)_{c1} in a number of a1 may include at least one deuterium.

In an embodiment, in Formula 1A, a1 may be 2, two groups represented by *-(L₁)_{b1}-(R₁)_{c1} may not be hydrogen, and two groups represented by *-(L₁)_{b1}-(R₁)_{c1} may be identical to each other.

In an embodiment, in Formula 1A, a1 may be 2, two groups represented by *-(L₁)_{b1}-(R₁)_{c1} may not be hydrogen, and two groups represented by *-(L₁)_{b1}-(R₁)_{c1} may be different from each other.

In an embodiment, in Formula 1A, a4 may not be 0, a group represented by *-(L₄)_{b4}-(R₄)_{c4} may not be hydrogen, and a group represented by *-(L₄)_{b4}-(R₄)_{c4} in a number of a4 may include at least one deuterium.

In an embodiment, in Formula 1A, a3 may not be 0, and at least one of the group represented by *-(L₃)_{b3}-(R₃)_{c3} in a number of a3 may satisfy Condition A and Condition B:

Condition A

L₃ is a single bond.

Condition B

R₃ is

hydrogen, deuterium, —F, a cyano group, C₁-C₂₀ alkyl group, or a C₁-C₂₀ alkoxy group;

a C₁-C₂₀ alkyl group or a C₁-C₂₀ alkoxy group, each substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof; or

a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

In an embodiment, in Condition B, R₃ may not be hydrogen.

In an embodiment, in Formula 1A, a3 may not be 0, and at least one of the group represented by *-(L₃)_{b3}-(R₃)_{c3} in a number of a3 may satisfy Condition A and Condition B(1):

Condition A

L₃ is a single bond.

Condition B(1)

R₃ is

a C₄-C₂₀ alkyl group unsubstituted or substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof; or a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

In an embodiment, in Formula 1A, a4 may not be 0, and at least one of the group represented by *-(L₄)_{b4}-(R₄)_{c4} in a number of a4 may satisfy Condition 1A, Condition 2A, or combination thereof:

Condition 1A

at least one of R₄ in a number of c4 is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

Condition 2A

L₄ is not a single bond.

In an embodiment, in Formula 1A, a4 may not be 0, and at least one of the group represented by *-(L₄)_{b4}-(R₄)_{c4} in a number of a4 may satisfy Condition 1(1)A, Condition 2(1)A, or a combination thereof:

Condition 1(1)A

at least one of R₄ in a number of c4 is a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

Condition 2(1)A

L₄ is a benzene group unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

In an embodiment, in Formula 1A, a4 may not be 0, and at least one of the group represented by *-(L₄)_{b4}-(R₄)_{c4} in a number of a4 may satisfy Condition 3A, Condition 4A, Condition 5A, or combination thereof:

Condition 3A

at least one of R₄ in a number of c4 is a substituted C₆-C₆₀ aryl group.

Condition 4A

L₄ is a C₅-C₃₀ carbocyclic group substituted with at least one R₁₀ₐ group,

Condition 5A

L₄ is a C₅-C₃₀ carbocyclic group that is unsubstituted or substituted with at least one R₁₀ₐ group and R₄ is not hydrogen.

In an embodiment, in Formula 1A, a4 may not be 0, and at least one of the group represented by *-(L₄)_{b4}-(R₄)_{c4} in a number of a4 may satisfy Condition 3(1)A, Condition 4(1)A, Condition 5(1)A, or combination thereof:

Condition 3(1)A

at least one of R₄ in a number of c4 is a phenyl group, a (C₁-C₂₀ alkyl)phenyl group, a biphenyl group, or a terphenyl group, each substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

Condition 4(1)A

L₄ is a benzene group substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

Condition 5(1)A

L₄ is a benzene group unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof, and

R₄ is

deuterium, —F, a cyano group, C₁-C₂₀ alkyl group, or a C₁-C₂₀ alkoxy group;

a C₁-C₂₀ alkyl group or a C₁-C₂₀ alkoxy group, each substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof; or

a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₂₀ alkyl group, a deuterium-containing C₂-C₂₀ alkyl group, a C₁-C₂₀ alkoxy group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a phenyl group, a (C₁-C₂₀ alkyl)phenyl group, a biphenyl group, a terphenyl group, or any combination thereof.

In an embodiment, in Formula 1A, a51 and a52 may each independently be 0, 1 or 2, the sum of a51 and a52 may be 1 or 2, and a53 may be 1 or 2.

* and *′ each indicate a binding site to a neighboring atom.

For example, a group represented by

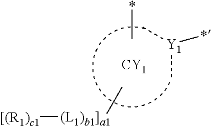

in Formula 1A may be a group represented by one of Formulae A₁ (1) to A₁ (30):

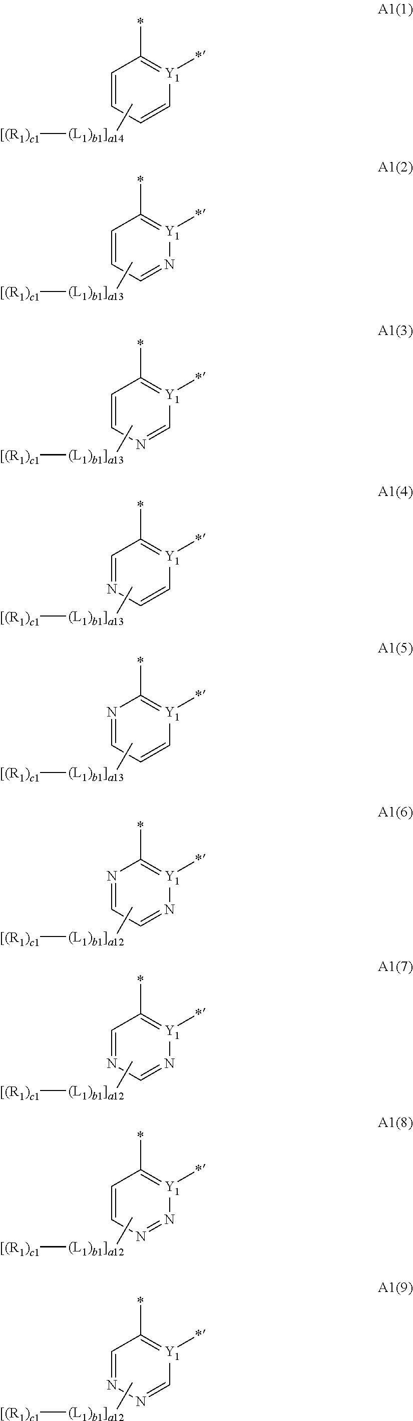

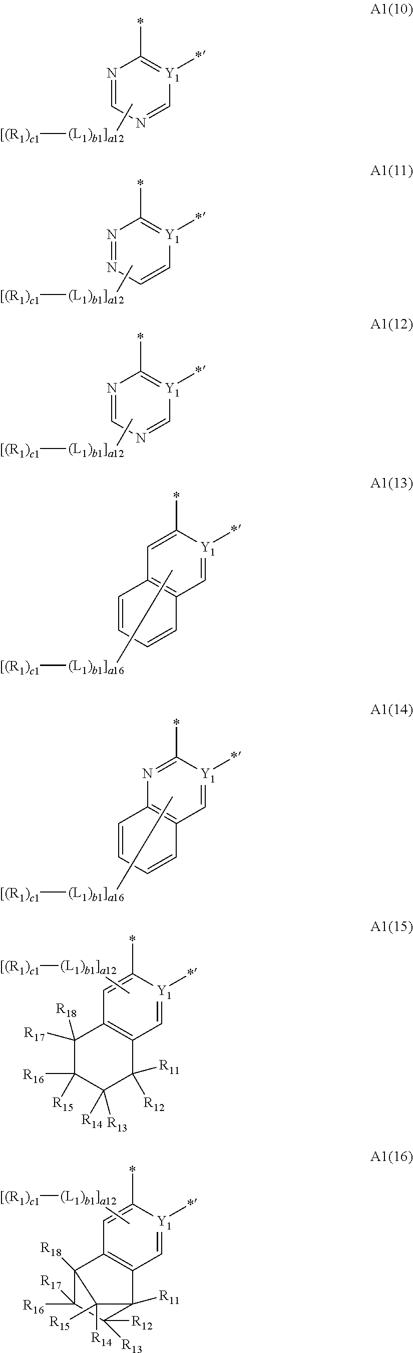

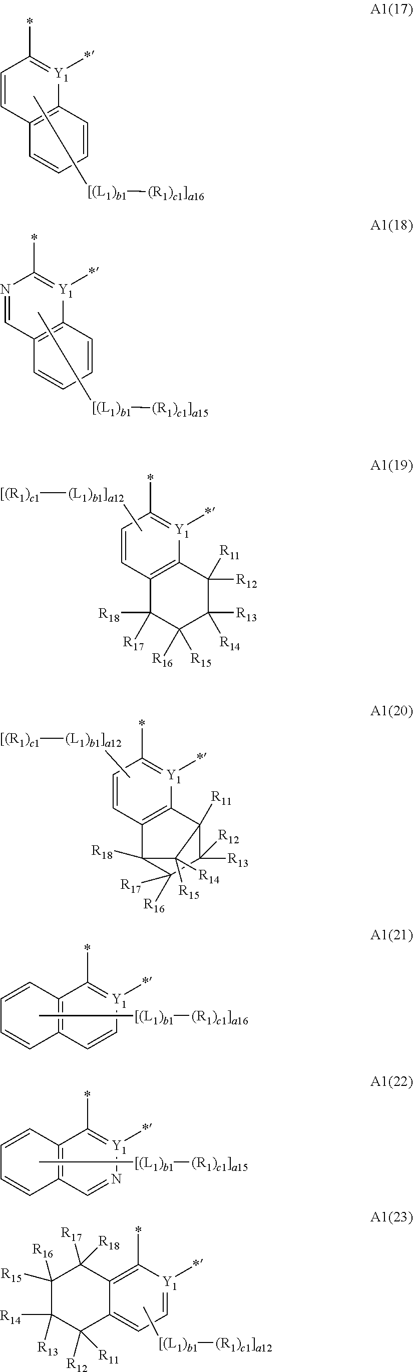

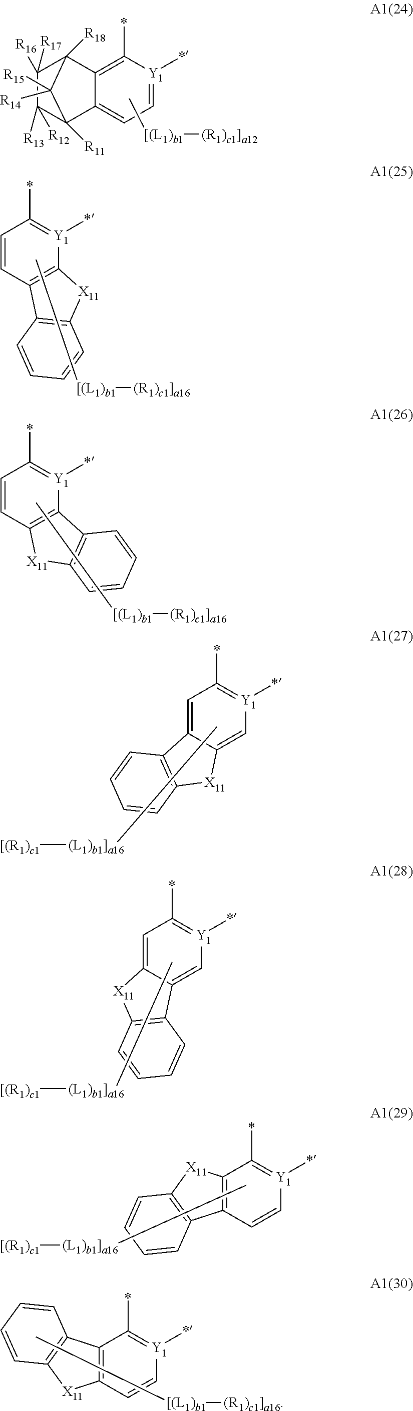

In Formulae A1(1) to A1(30),

Y₁, L₁, b1, R₁, and c1 may each independently be the same as described in Formula 1A,

X₁₁ may be O, S, N(R₁₁), C(R₁₁)(R₁₂), or Si(R₁₁)(R₁₂),

R₁₁ to R₁₈ may each independently be the same as described in connection with R₁ of Formula 1A

a12 may be an integer from 0 to 2,

a13 may be an integer from 0 to 3,

a14 may be an integer from 0 to 4,

a15 may be an integer from 0 to 5,

a16 may be an integer from 0 to 6,

*′ indicates a binding site to X₁ in Formula 1A, and

* indicates a binding site to Y₃ in Formula 1A.

The group represented by

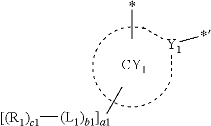

in Formula 1A may include deuterium, a deuterium-containing C₁-C₆₀ alkyl group unsubstituted or substituted with at least one C₃-C₁₀ cycloalkyl group, or any combination thereof. The number of deuterium atoms in the group represented by

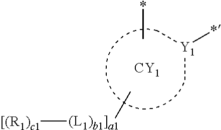

in Formula 1A may be from 1 to 20, for example, from 1 to 15, from 1 to 10, or from 1 to 5.

In an embodiment, a group represented by

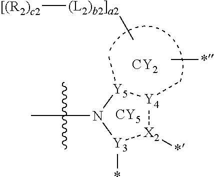

in Formula 1A may be a group represented by one of Formulae A2(1) to A2(4):

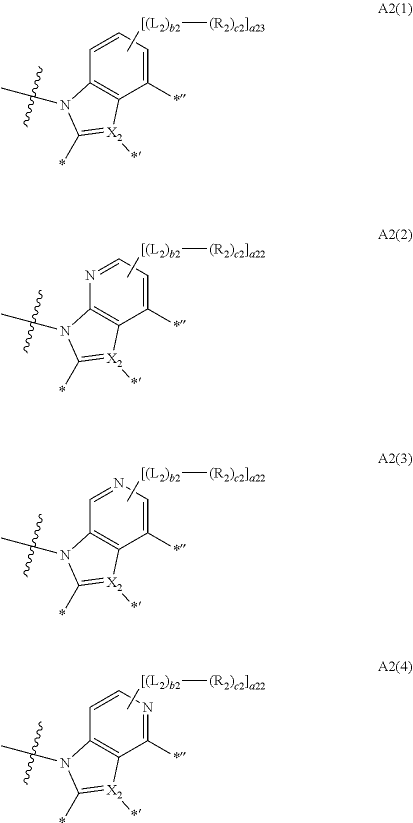

In Formulae A2(1) to A2(4),

X₂, L₂, b2, R₂, and c2 may each independently be the same as described in Formula 1A,

a22 may be an integer from 0 to 2,

a23 may be an integer from 0 to 3,

[symbol] indicates a binding site to L₅₁ in Formula 1A,

*″ indicates a binding site to ring CY₃ in Formula 1A,

*′ indicates a binding site to M in Formula 1A, and

* indicates a binding site to ring CY₁ in Formula 1A.

The group represented by

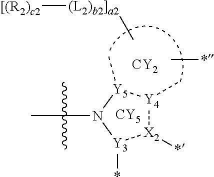

in Formula 1A may include deuterium, a deuterium-containing C₁-C₆₀ alkyl group unsubstituted or substituted with at least one C₃-C₁₀ cycloalkyl group, or any combination thereof. The number of deuterium atoms in the group represented by

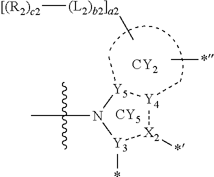

in Formula 1A may be from 1 to 20, for example, from 1 to 15, from 1 to 10, or from 1 to 5.

In an embodiment, a group represented by

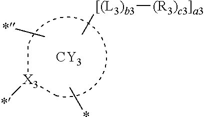

in Formula 1A may be a group represented by one of Formulae A3(1) to A3(17):

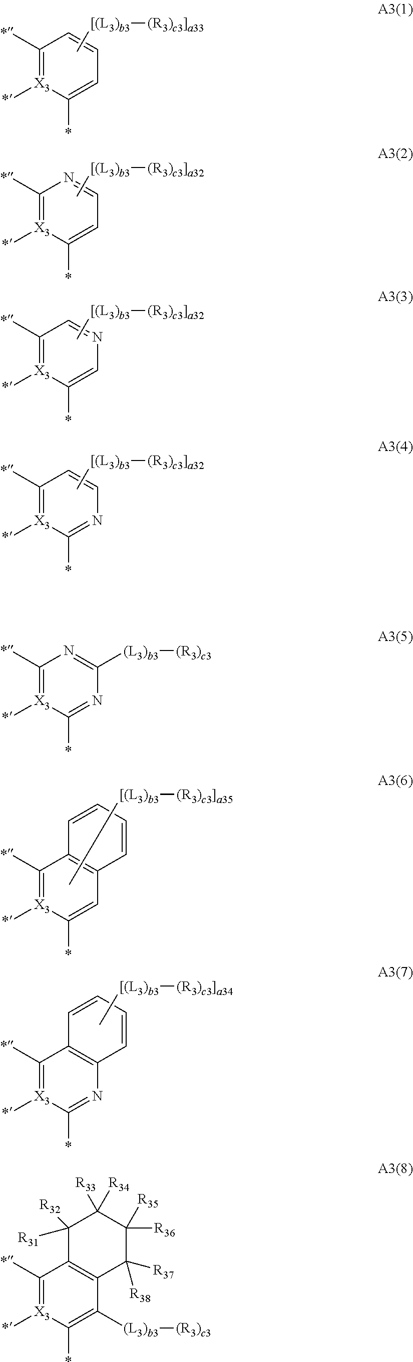

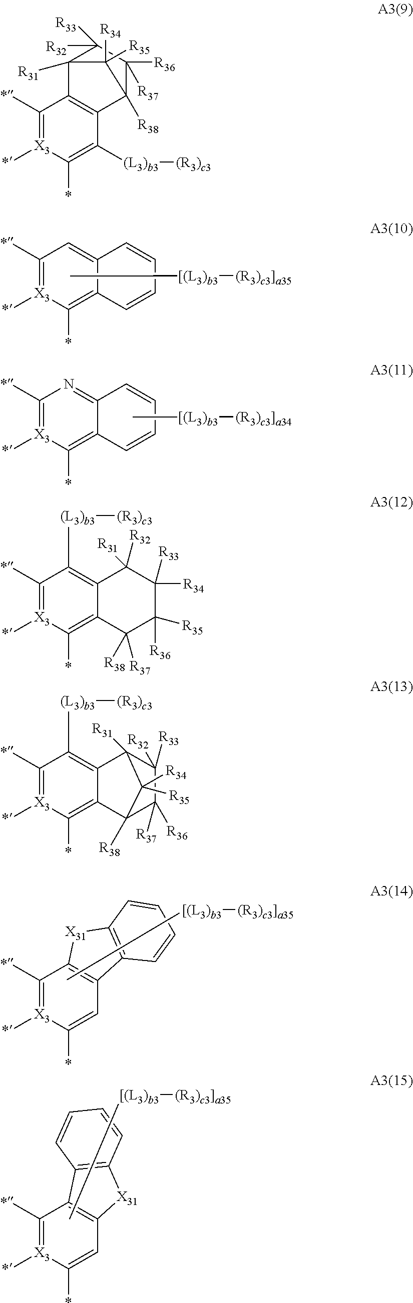

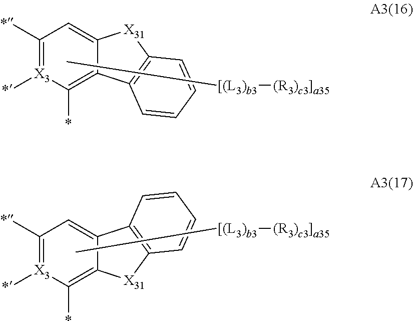

In Formulae A3(1) to A3(17),

X₃, L₃, b3, R₃, and c3 may each independently be the same as described in Formula 1A,

X₃₁ may be O, S, N(R₃₁), C(R₃₁)(R₃₂), or Si(R₃₁)(R₃₂),

R₃₁ to R₃₈ may each independently be the same as described in connection with R₃ of Formula 1A,

a32 may be an integer from 0 to 2,

a33 may be an integer from 0 to 3,

a34 may be an integer from 0 to 4,

a35 may be an integer from 0 to 5,

*″ indicates a binding site to ring CY₂ in Formula 1A,

*′ indicates a binding site to M in Formula 1A, and

* indicates a binding site to T₁ in Formula 1A.

The group represented by

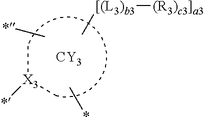

in Formula 1A may include deuterium, a deuterium-containing C₁-C₆₀ alkyl group unsubstituted or substituted with at least one C₃-C₁₀ cycloalkyl group, or any combination thereof. The number of deuterium atoms in the group represented by

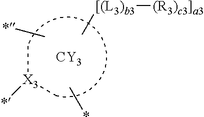

in Formula 1A may be from 1 to 20, for example, from 1 to 15, from 1 to 10, or from 1 to 5.

In an embodiment, a group represented by

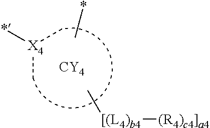

in Formula 1A may be a group represented by one of Formulae A4(1) to A4(45):

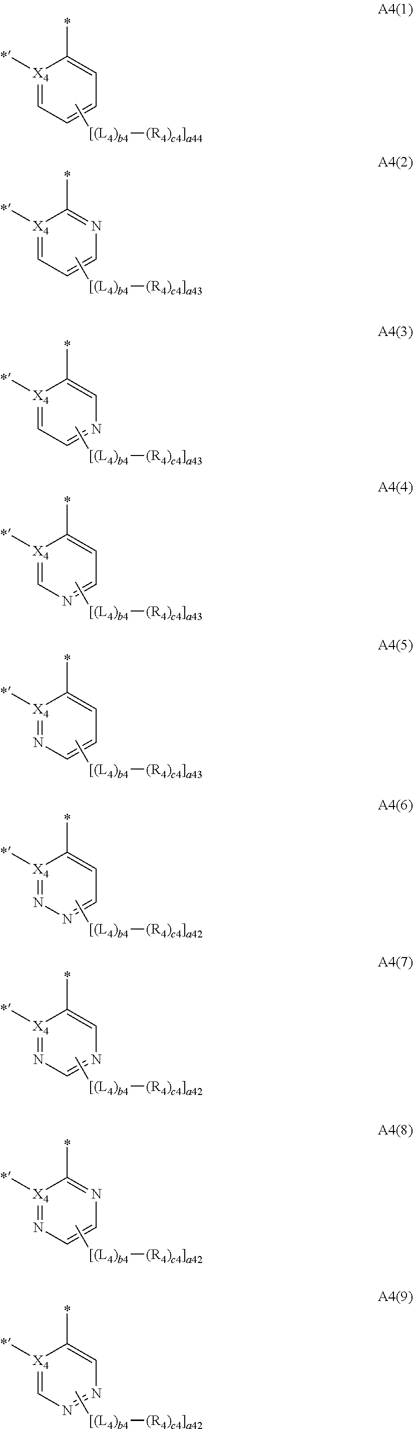

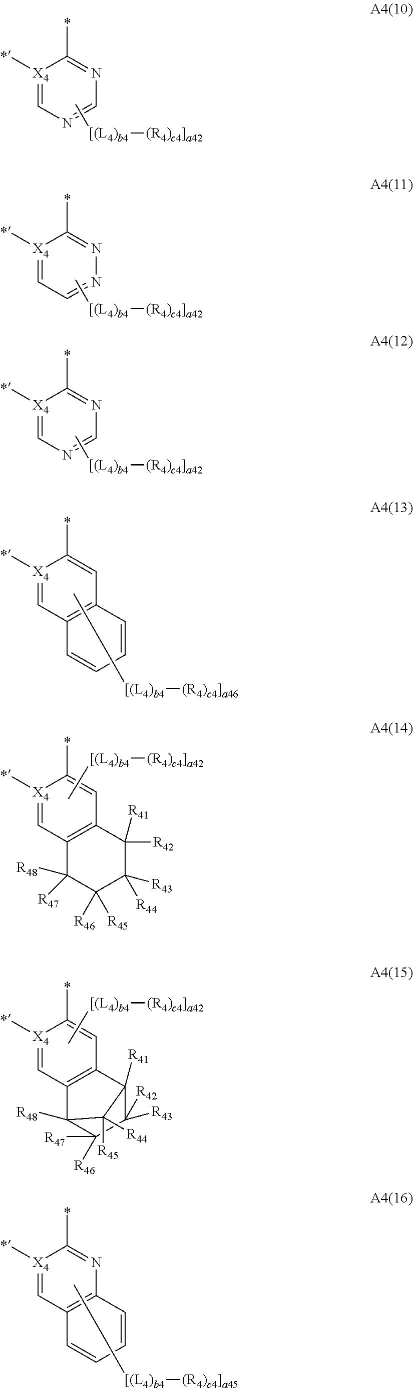

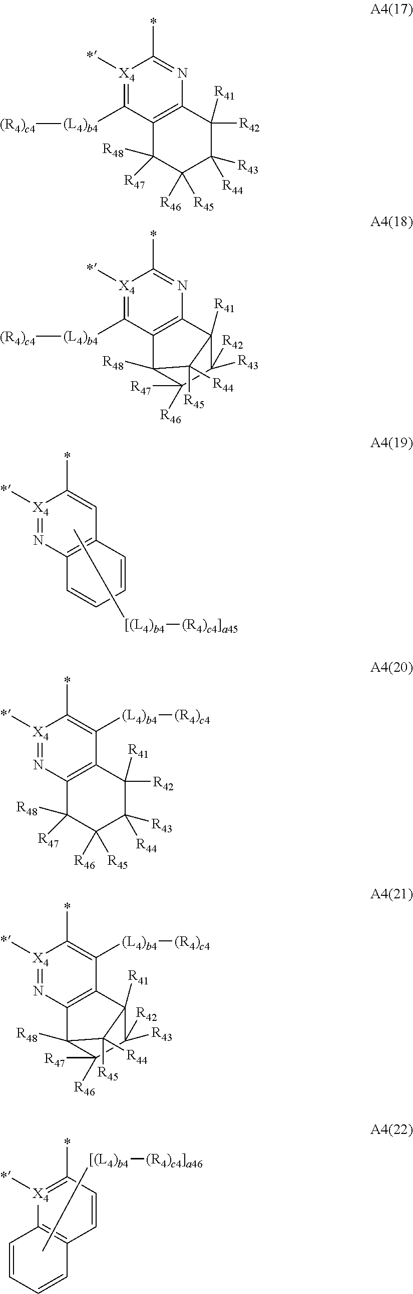

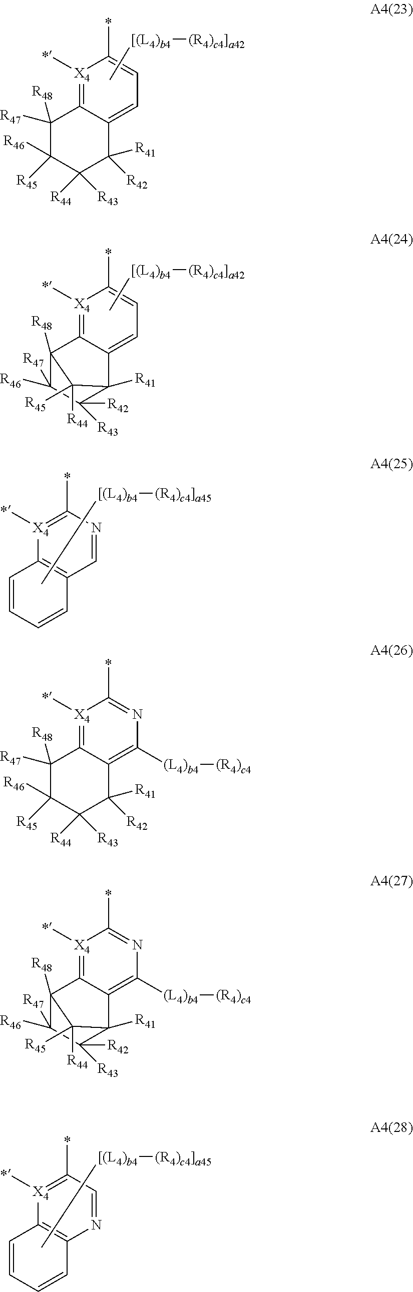

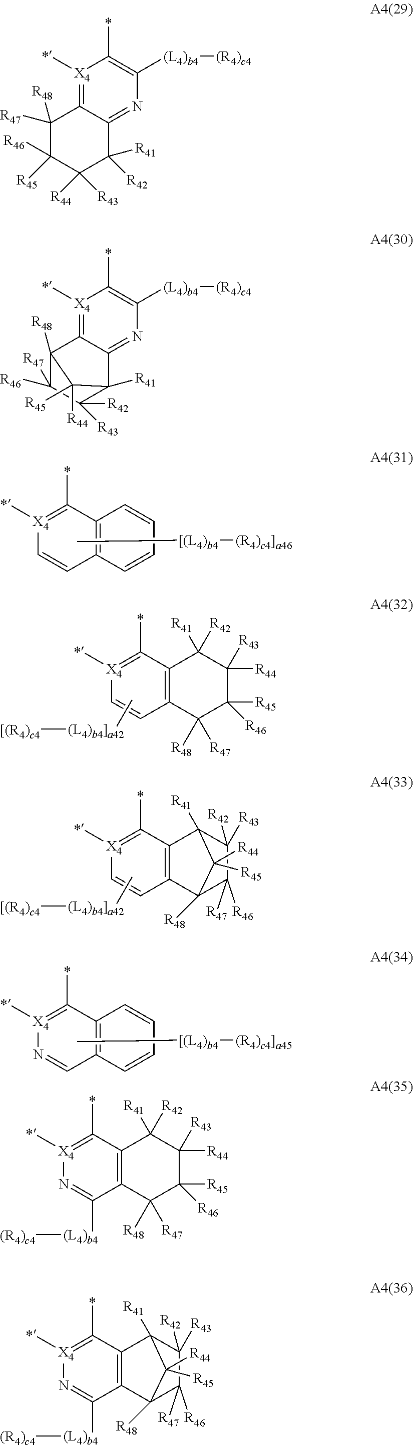

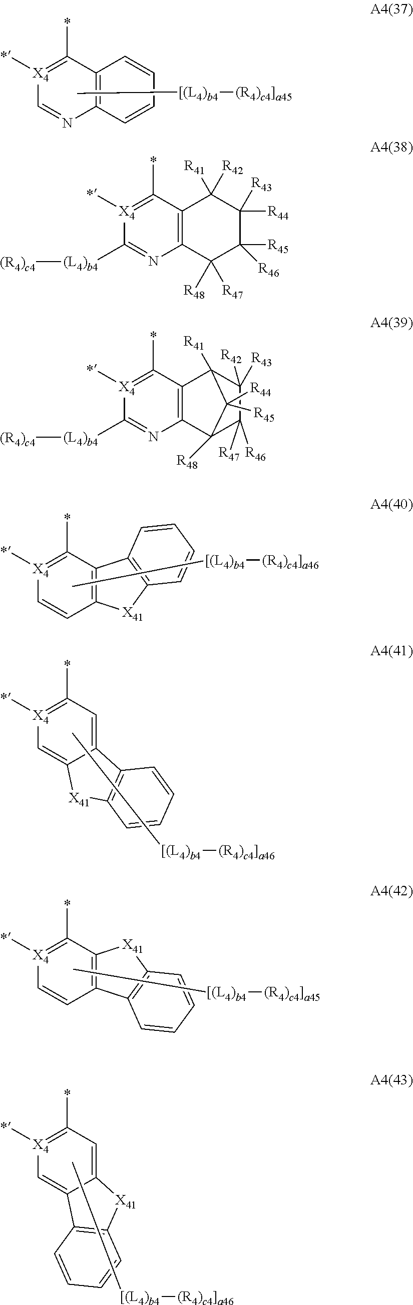

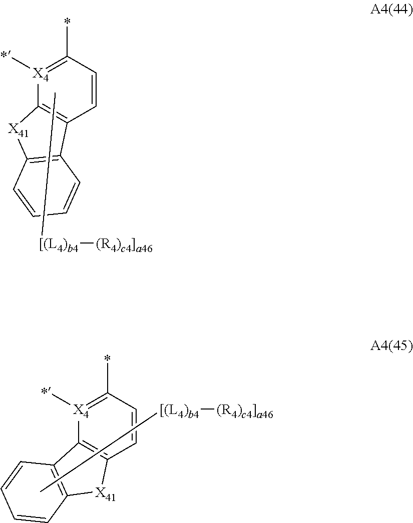

In Formulae A4(1) to A4(45),

X₄, L₄, b4, R₄, and c4 may each independently be the same as described in Formula 1A,

X₄₁ may be O, S, N(R₄₁), C(R₄₁)(R₄₂), or Si(R₄₁)(R₄₂),

R₄₁ to R₄₈ may each independently be the same as described in connection with R₄ of Formula 1A,

a42 may be an integer from 0 to 2,

a43 may be an integer from 0 to 3,

a44 may be an integer from 0 to 4,

a45 may be an integer from 0 to 5,

a46 may be an integer from 0 to 6,

*′ indicates a binding site to M in Formula 1A, and

* indicates a binding site to T₁ in Formula 1A.

The group represented by

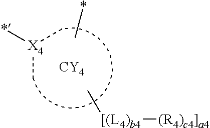

in Formula 1A may include deuterium, a deuterium-containing C₁-C₆₀ alkyl group unsubstituted or substituted with at least one C₃-C₁₀ cycloalkyl group, or any combination thereof. The number of deuterium atoms in the group represented by

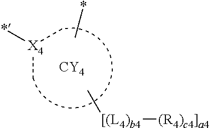

in Formula 1A may be from 1 to 20, for example, from 1 to 15, from 1 to 10, or from 1 to 5.

In an embodiment, in Formula 1A, a group represented by

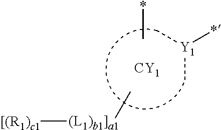

may be a group represented by one of Formulae CY1(1) to CY1(8), and/or

a group represented by

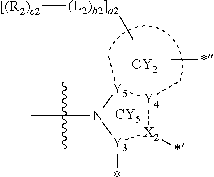

may be a group represented by one of Formulae CY2(1) to CY2(4), and/or

a group represented by

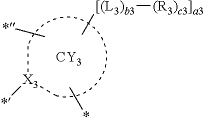

may be a group represented by one of Formulae CY3(1) to CY3(24), and/or

a group represented by

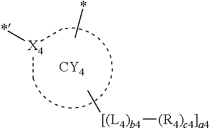

may be a group represented by one of Formulae CY4(1) to CY4(74), but embodiments of the present disclosure are not limited thereto:

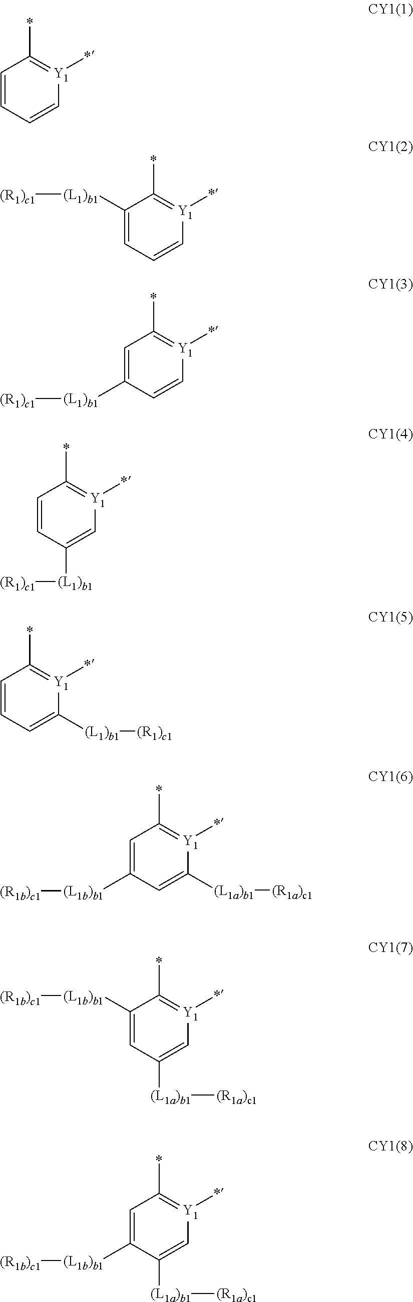

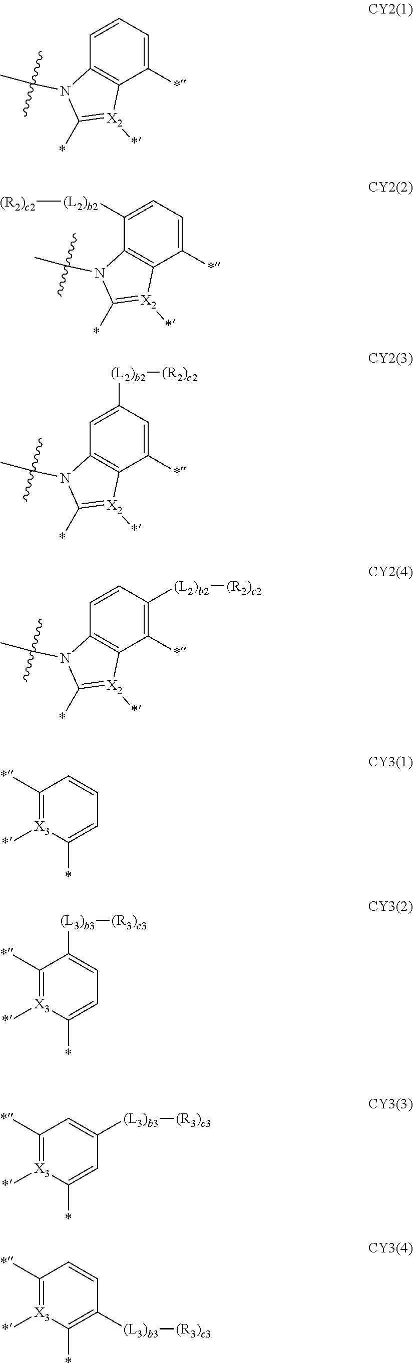

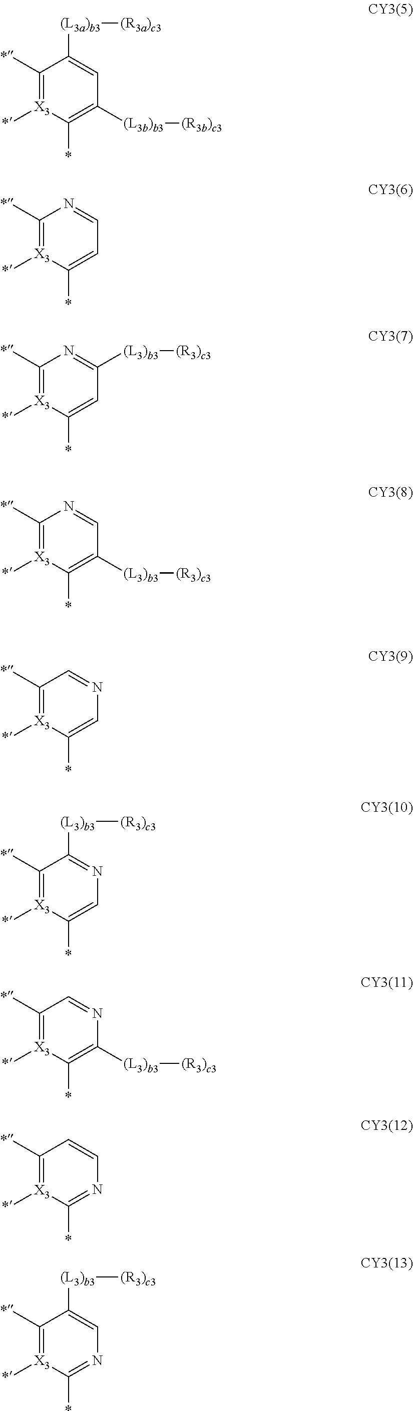

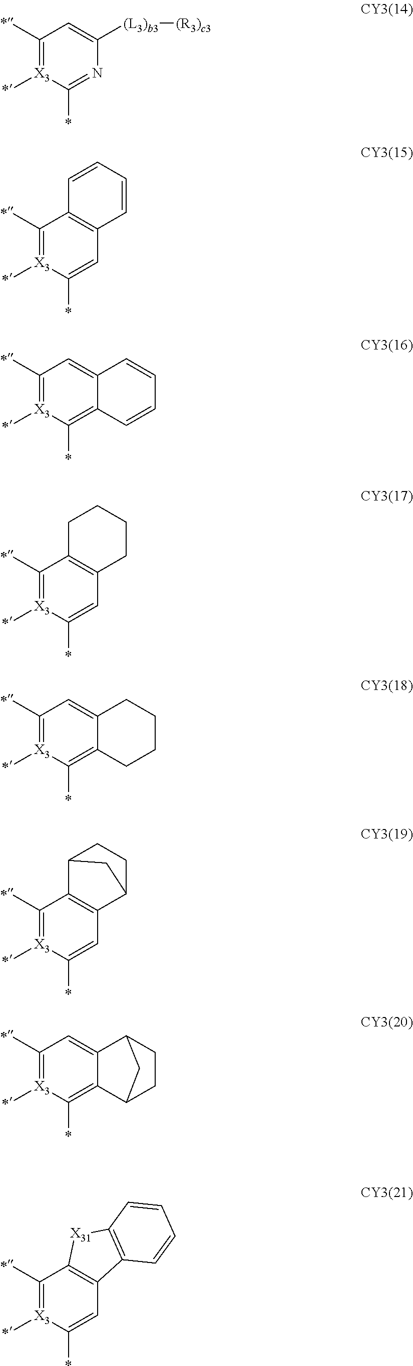

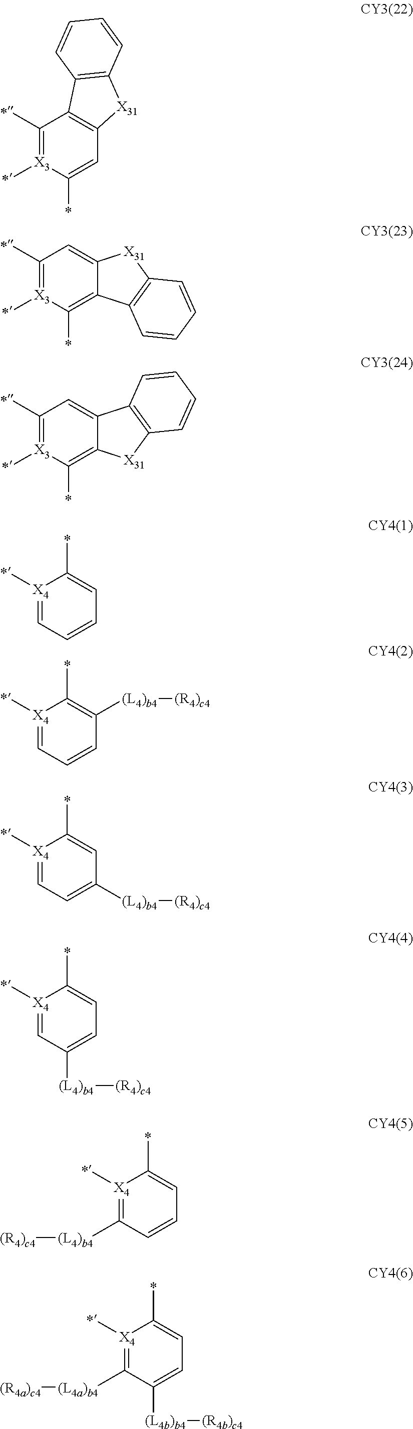

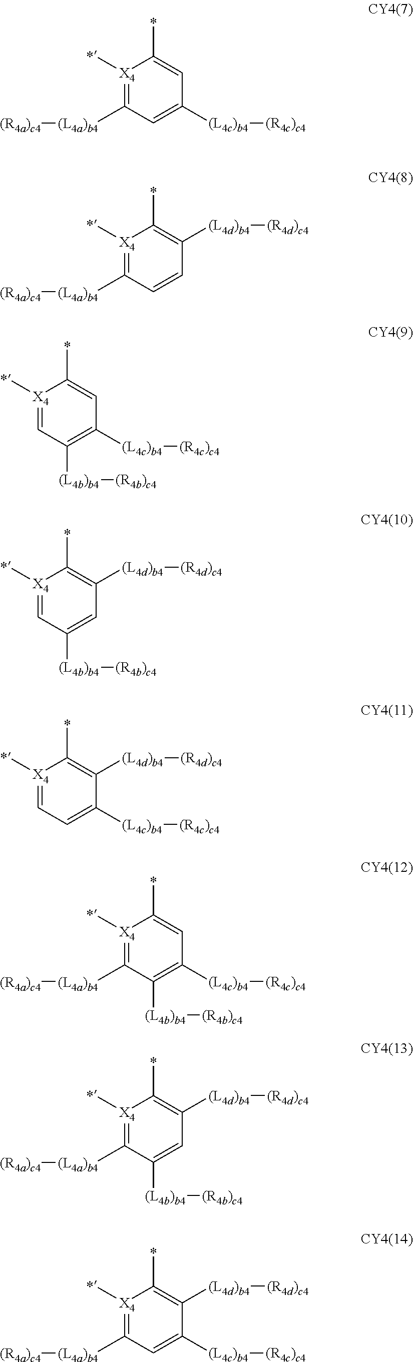

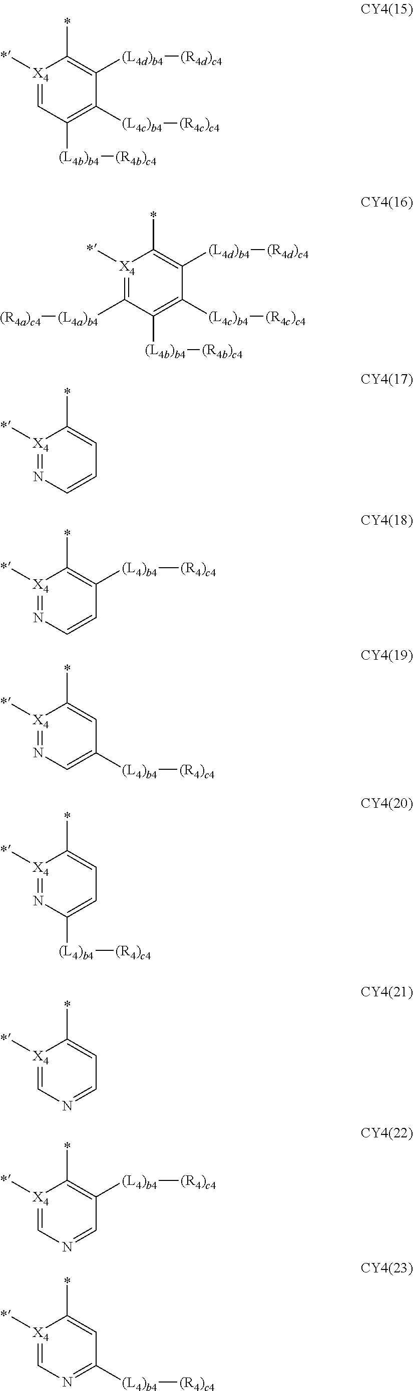

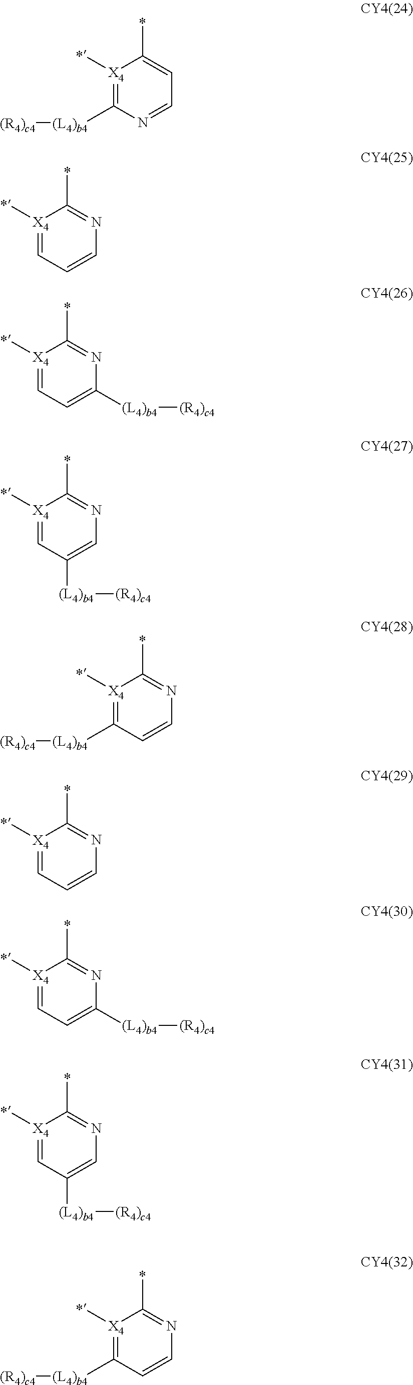

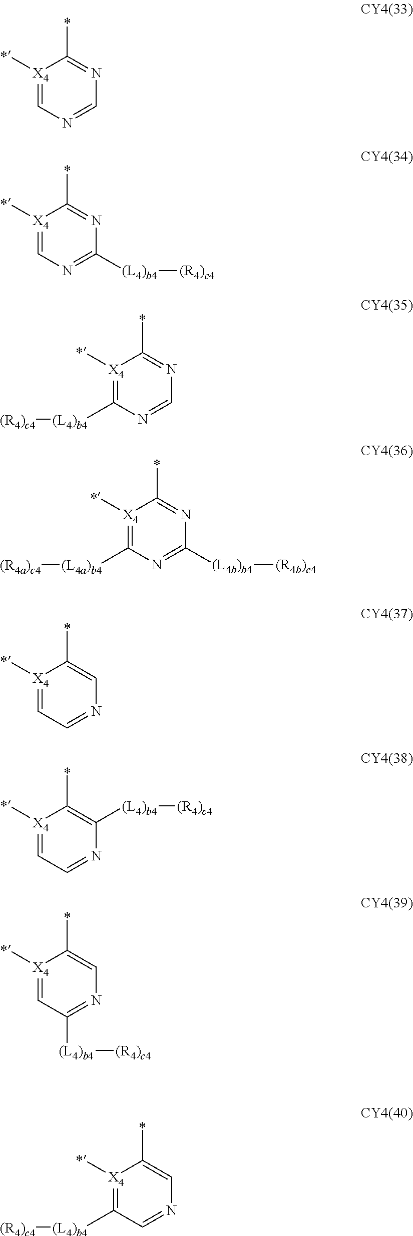

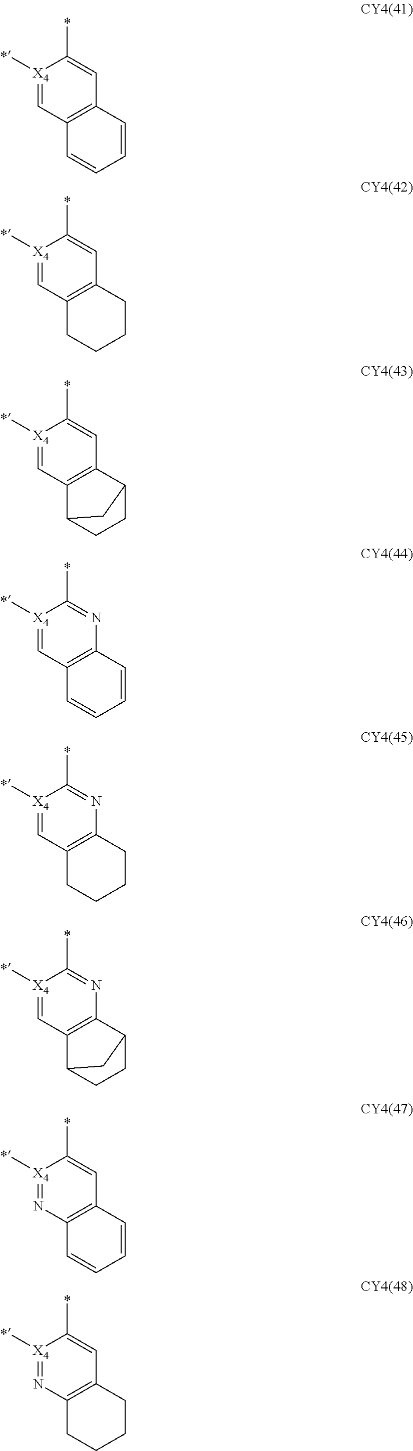

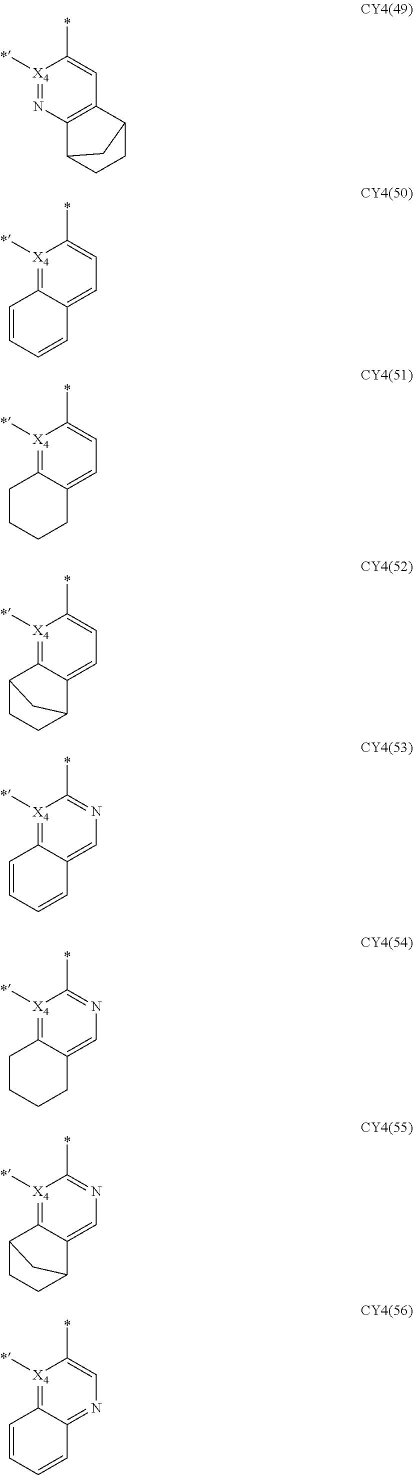

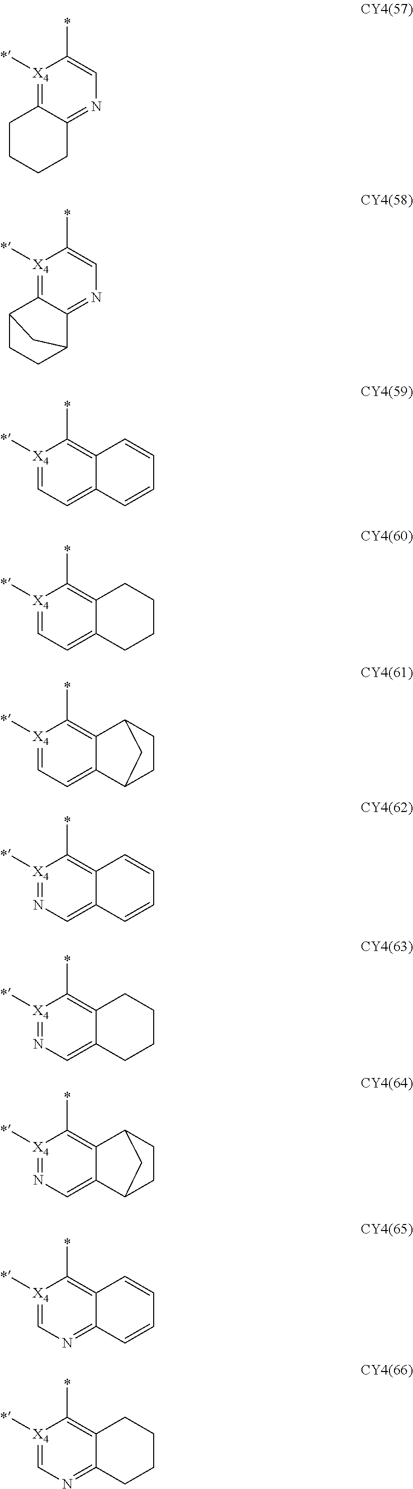

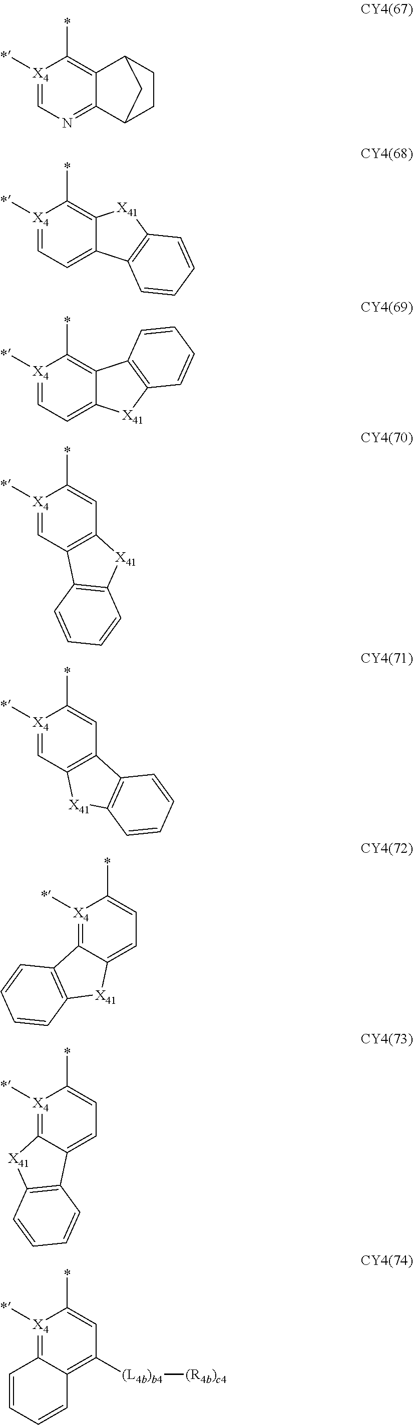

In Formulae CY1(1) to CY1(8), CY2(1) to CY2(4), CY3(1) to CY3(24), and CY4(1) to CY4(74),

X₂ to X₄, Y₁, L₁ to L₄, b1 to b4, R₁ to R₄, and c1 to c4 may each independently be the same as described in Formula 1A,

X₃₁ may be O, S, N(R₃₁), C(R₃₁)(R₃₂), or Si(R₃₁)(R₃₂),

X₄₁ may be O, S, N(R₄₁), C(R₄₁)(R₄₂), or Si(R₄₁)(R₄₂),

L₁ₐ and L_{1b} may each independently be the same as described in connection with L₁ of Formula 1A,

R₁ₐ and R_{1b} may each independently be the same as described in connection with R₁ of Formula 1A,

L₃ₐ and L₃b may each independently be the same as described in connection with L₃ of Formula 1A,

R₃ₐ, R_{3b}, R₃₁, and R₃₂ may each independently be the same as described in connection with R₃ of Formula 1A,

L₄ₐ to L_{4d} may each independently be the same as described in connection with L₄ of Formula 1A,

R₄ₐ to R_{4d}, R₄₁, and R₄₂ may each independently be the same as described in connection with R₄ of Formula 1A,

*-(L₁)_{b1}-(R₁)_{c1}, *-(L₁ₐ)_{b1}-(R₁ₐ)_{c1}, *-(L₁ₐ)_{b1}-(R_{1b})_{c1}, *-(L₂)_{b2}-(R₂)_{c2}, *-(L₃)_{b3}-(R₃)_{c3}, *-(L₃ₐ)_{b3}-(R₃ₐ)_{c3}, *-(L_{3b})_{b3}-(R_{3b})_{c3}, *-(L₄)_{b4}-(R₄)_{c4}, *-(L₄ₐ)_{b4}-(R₄ₐ)_{c4}, *-(L_{4b})_{b4}-(R_{4b})_{c4}, *- (L_{4c})_{b4}-(R_{4c})_{c4}, and *-(L_{4d})_{b4}-(R_{4d})_{c4} may not be hydrogen, and * indicates a binding site to a neighboring atom,

in Formulae CY1(1) to CY1(8), *′ indicates a binding site to X₁ in Formula 1A,

in Formulae CY2(1) to CY2(4), CY3(1) to CY3(24), and CY4(1) to CY4(74), *′ indicates a binding site to M in Formula 1A,

in Formulae CY1(1) to CY1(8), * indicates a binding site to Y₃ in Formula 1A,

in Formulae CY2(1) to CY2(4), * indicates a binding site to ring CY₁ in Formula 1A, and *″ indicates a binding site to ring CY₃ in Formula 1A,

in Formulae CY3(1) to CY3(24), *″ indicates a binding site to ring CY₂ in Formula 1A, and * indicates a binding site to T₁ in Formula 1A, and

in Formulae CY4(1) to CY4(74), * indicates a binding site to T₁ in Formula 1A.

In an embodiment, a group represented by

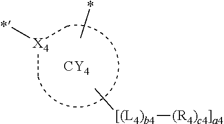

may be a group represented by Formula CY4-1 or CY4-2:

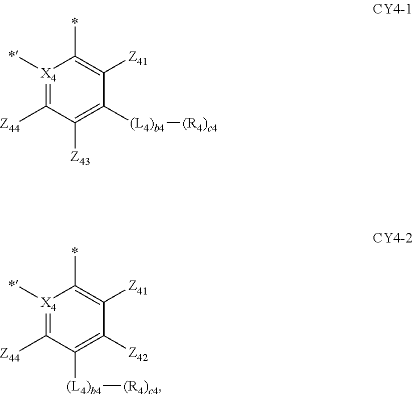

in Formulae CY4-1 and CY4-2,

X₄, L₄, b4, R₄, and c4 may each independently be the same as described in Formula 1A,

Z₄₁ to Z₄₄ may each independently be the same as described in connection with R₄ of Formula 1A,

*′ indicates a binding site to M in Formula 1A, and

* indicates a binding site to T₁ in Formula 1A.

For example, Formulae CY4-1 and CY4-2 may satisfy:

1) Condition 1A, Condition 2A, or any combination thereof (or, Condition 1(1)A, Condition 2(1)A, or any combination thereof), and/or

2) Condition 3A, Condition 4A, Condition 5A, or any combination thereof (or, Condition 3(1)A, Condition 4(1)A, Condition 5(1)A, or any combination thereof).

In an embodiment, in Formula 1A, a group represented by

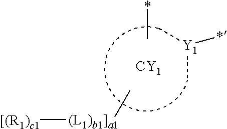

may be a group represented by Formula CY1(1) or CY1(6), and/or

a group represented by

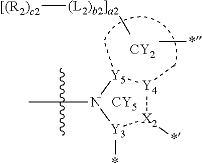

may be a group represented by Formula CY2(1), and/or

a group represented by

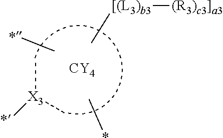

may be a group represented by Formula CY3(3), and/or

a group represented by

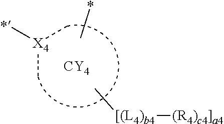

may be a group represented by Formula CY4(3), CY4(4) or CY4(16).

In an embodiment, a group represented by

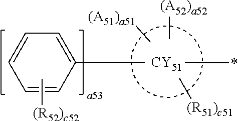

in Formula 1A may be a group represented by one of Formulae 51-1 to 51-32:

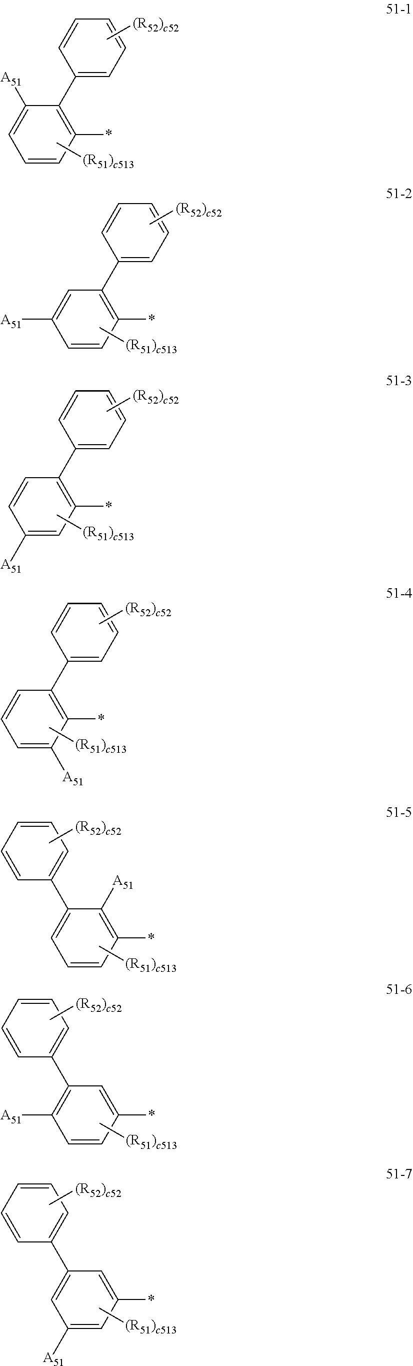

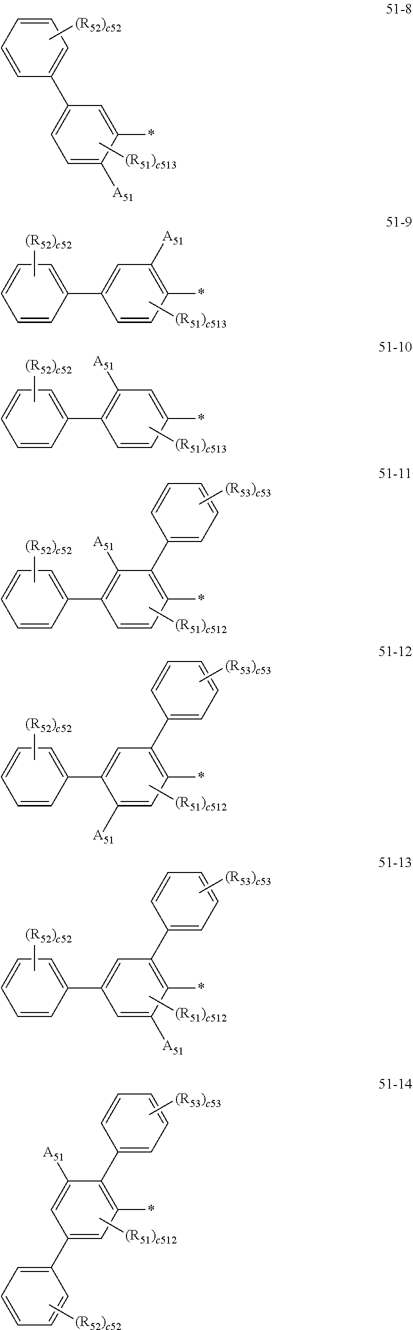

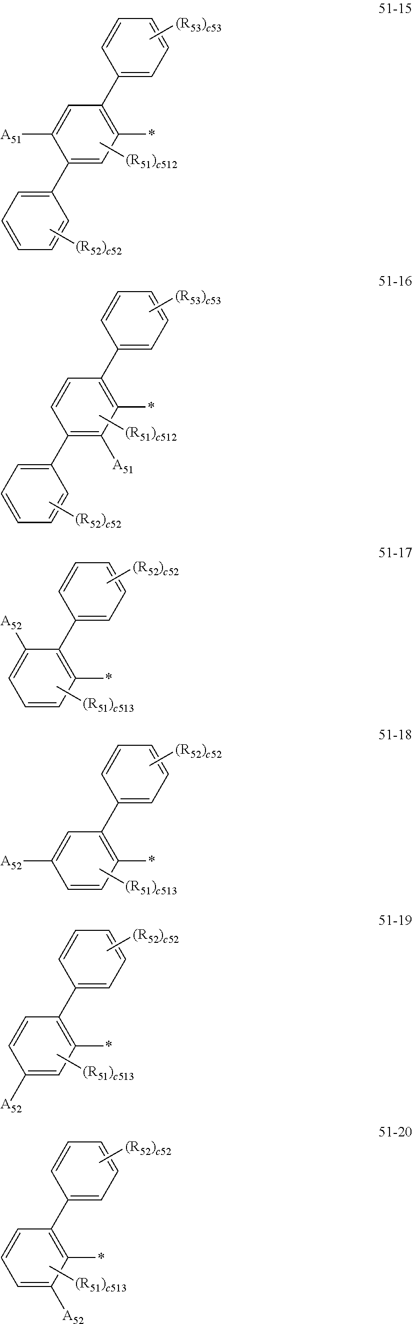

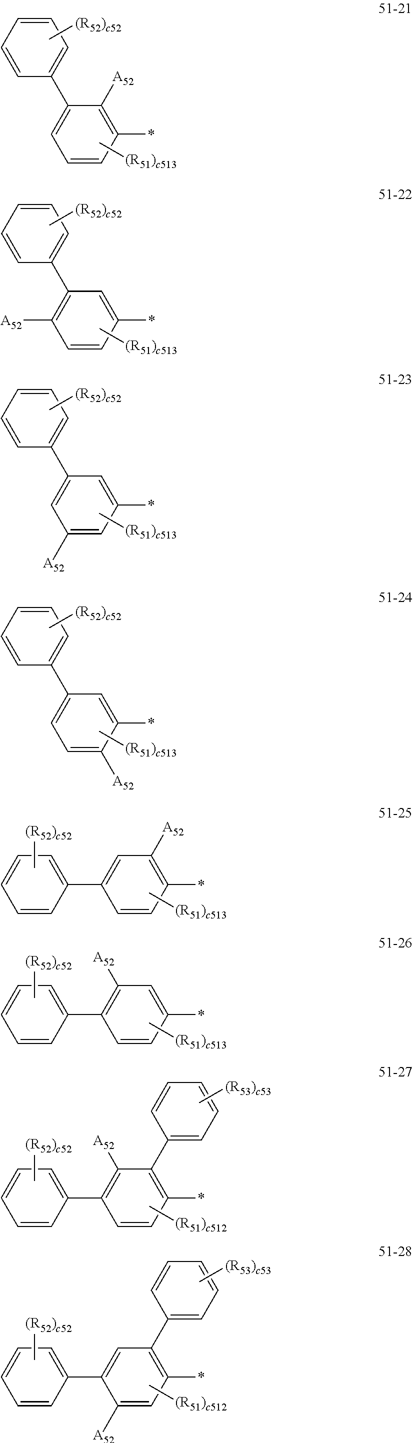

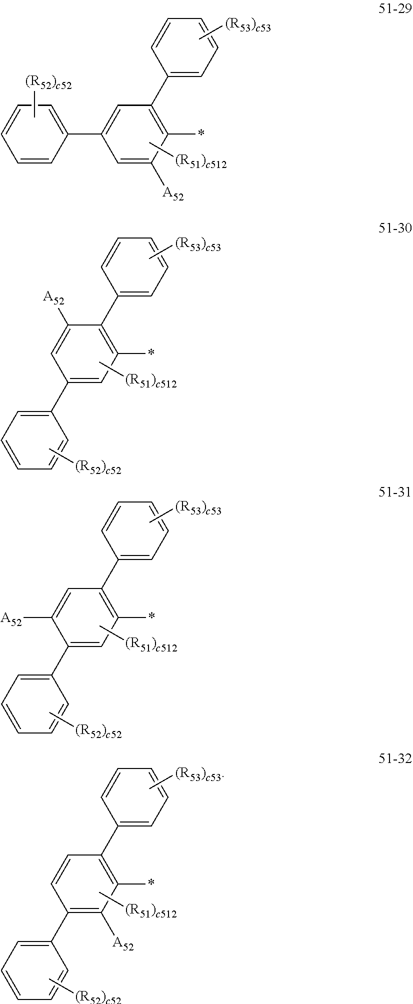

In Formulae 51-1 to 51-32, R₅₁, R₅₂, c52, A₅₁, and A₅₂ may each independently be the same as described in Formula 1A, R₅₃ and c53 may each independently be the same as described in connection with R₅₂ and c52 of Formula 1A, c512 is an integer of 0 to 2, c513 is an integer of 0 to 3, and * indicates a binding site to L₅₁.

In an embodiment, the organometallic compound may be represented by Formula 1-1A or 1-2A:

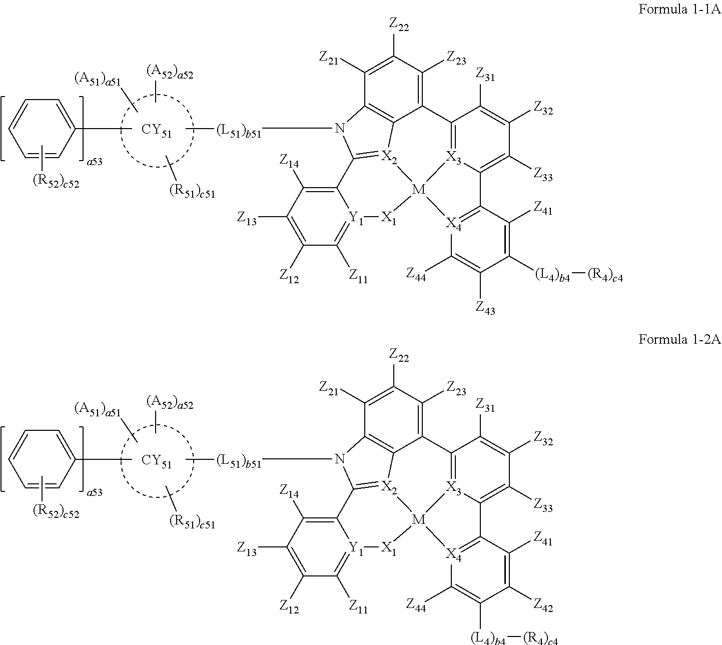

in Formulae 1-1A and 1-2A,

M, X₁ to X₄, Y₁, Y₃ to Y₅, L₄, L₅₁, b4, b51, R₅₁, R₅₂, c51, c52, A₅₁, A₅₂, a51, a52 and a53 may each independently be the same as described in Formula 1A,

Z₁₁ to Z₁₄ may each independently be the same as described in connection with R₁ of Formula 1A,

Z₂₁ to Z₂₃ may each independently be the same as described in connection with R₂ of Formula 1A,

Z₃₁ to Z₃₃ may each independently be the same as described in connection with R₃ of Formula 1A,

Z₄₁ to Z₄₄ may each independently be the same as described in connection with R₄ of Formula 1A,

two or more groups of Z₁₁ to Z₁₄ may be optionally linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group,

two or more groups of Z₂₁ to Z₂₃ may be optionally linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group,

two or more groups of Z₃₁ to Z₃₃ may be optionally linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group,

two or more groups of Z₄₁ to Z₄₄ may be optionally linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group, and

R₁₀ₐ is the same as described in connection with R₁ of Formula 1A.

Descriptions for Formula 1A can be applied for Formulae 1-1A and 1-2A.

For example,

1) Formulae 1-1A and 1-2A may satisfy Condition A, Condition B, or any combination thereof (or, Condition A, Condition B(1), or any combination thereof), and/or

2) Formulae 1-1A and 1-2A may satisfy Condition 1A, Condition 2A, or any combination thereof (or, Condition 1(1)A, Condition 2(1)A, or any combination thereof), and/or

3) Formulae 1-1A and 1-2A may satisfy Condition 3A, Condition 4A, Condition 5A, or any combination thereof (or, Condition 3(1)A, Condition 4(1)A, Condition 5(1)A, or any combination thereof), and/or

4) a group represented by

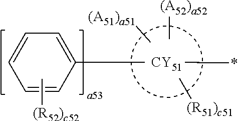

in Formulae 1-1A and 1-2A may be a group represented by one of Formulae 51-1 to 51-32.

In an embodiment, Z₁₂, Z₁₄, Z₂₁ to Z₂₃, Z₃₁, Z₃₃ and Z₄₁ to Z₄₄ in Formulae 1-1A and 1-2A may each independently be hydrogen, deuterium, —CH₃, or —CD₃.

In an embodiment, Z₁₂, Z₁₄, Z₂₁ to Z₂₃, Z₃₁, Z₃₃ and Z₄₁ to Z₄₄ in Formulae 1-1A and 1-2A may each independently be hydrogen, or deuterium.

In an embodiment, Z₁₁ and Z₁₃ in Formulae 1-1A and 1-2A may not be hydrogen and Z₁₁ and Z₁₃ may include a deuterium.

In an embodiment, Z₁₁ and Z₁₃ in Formulae 1-1A and 1-2A may not be hydrogen and Z₁₁ and Z₁₃ may be identical to each other.

In an embodiment, Z₁₁ and Z₁₃ in Formulae 1-1A and 1-2A may not be hydrogen and Z₁₁ and Z₁₃ may be different from each other.

In Formula 1A, i) two or more groups of a plurality of R₁ groups may optionally be linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group, ii) two or more groups of a plurality of R₂ groups may optionally be linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group, iii) two or more groups of a plurality of R₃ groups may optionally be linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group, iv) two or more groups of a plurality of R₄ groups may optionally be linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group, and v) two or more groups of R₁ to R₆ may optionally be linked to form a C₅-C₃₀ carbocyclic group that is unsubstituted or substituted with at least one R₁₀ₐ group or a C₂-C₃₀ heterocyclic group that is unsubstituted or substituted with at least one R₁₀ₐ group. An R₁₀ₐ group may be the same as described in connection with

* and *′ are each independently a binding site with a neighboring atom.

Description of Formula 1B

The organometallic compound may be represented by Formula 1B:

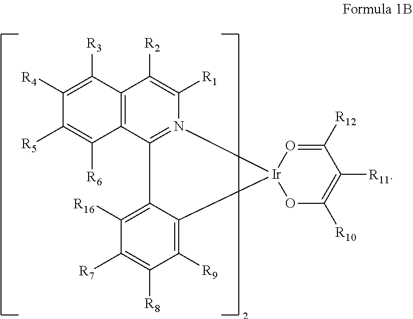

In Formula 1B, R₁ to R₁₂ and R₁₆ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), wherein Q₁ to Q₉ are each independently the same as described herein.

For example, R₁ to R₁₂ and R₁₆ may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, C₁-C₂₀ alkyl group, or a C₁-C₂₀ alkoxy group;

a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, a bicyclo[2.2.2]octyl group, a phenyl group, a biphenyl group, a terphenyl group, a naphthyl group, a pyridinyl group, a pyrimidinyl group, or any combination thereof;

a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, a bicyclo[2.2.2]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, a bicyclo[2.2.2]octyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₃)(Q₃₄)(Q₃₅), or any combination thereof; or

—N(Q₁)(Q₂), —Si(Q₃)(Q₄)(Q₅), —Ge(Q₃)(Q₄)(Q₅), —B(Q₆)(Q₇), —P(═O)(Q₈)(Q₉), and —P(Q₈)(Q₉).

In an embodiment, R₁ to R₉ and R₁₆ may each independently be hydrogen, deuterium, a substituted or unsubstituted C₁-C₆₀ alkyl group, a substituted or unsubstituted C₃-C₁₀ cycloalkyl group, or —Si(Q₃)(Q₄)(Q₅). Q₃ to Q₅ are the same as described in this disclosure.

In one or more embodiments, R₁ to R₁₂ and R₁₆ may each independently be:

hydrogen, deuterium, a methyl group, an ethyl group, an n-propyl group, an iso-propyl group, an n-butyl group, a sec-butyl group, an iso-butyl group, a tert-butyl group, an n-pentyl group, a tert-pentyl group, a neopentyl, an iso-pentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, a dibenzothiophenyl group, or —Si(Q₃)(Q₄)(Q₅);

a methyl group, an ethyl group, an n-propyl group, an iso-propyl group, an n-butyl group, a sec-butyl group, an iso-butyl group, a tert-butyl group, an n-pentyl group, a tert-pentyl group, a neopentyl group, an iso-pentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each substituted with at least one deuterium; or

a methoxy group, an ethoxy group, a propoxy group, a butoxy group, a pentoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, or a dibenzothiophenyl group, each substituted with deuterium, a C₁-C₁₀ alkyl group or any combination thereof, and

Q₃ to Q₅ are the same as described herein.

In one or more embodiments, R₁ to R₁₂ and R₁₆ may each independently be hydrogen, deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, or —Si(Q₃)(Q₄)(Q₅) (wherein Q₃ to Q₅ are the same as described herein). Above Formulae 9-1 to 9-66, 10-1 to 10-118 and 10-201 to 10-342 are the same as described in connection with Formula 1A.

At least one of R₁ to R₆ in Formula 1B may each independently be a group represented by Formula 2B:

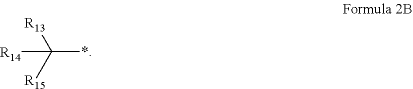

The number of carbon atoms included in Formula 2B may be 4 or more (for example, 4 to 20, 4 to 15 or 4 to 10),

R₁₃ in Formula 2B may be hydrogen, deuterium, a C₁-C₂₀ alkyl group, deuterium-containing C₁-C₂₀ alkyl group, a C₃-C₁₀ cycloalkyl group, or a deuterium-containing C₃-C₁₀ cycloalkyl group,

R₁₀ and R₁₅ in Formula 2B may each independently be a C₁-C₂₀ alkyl group, deuterium-containing C₁-C₂₀ alkyl group, a C₃-C₁₀ cycloalkyl group, or a deuterium-containing C₃-C₁₀ cycloalkyl group, and

* indicates a binding site to a neighboring atom.

In an embodiment, at least one of R₂ to R₅ in Formula 1B may be a group represented by Formula 2B.

In one or more embodiments, one of R₂ to R₅ in Formula 1B may be a group represented by Formula 2B, and R₁ to R₆ other than the group represented by Formula 2B may be hydrogen.

In one or more embodiments, in Formula 1B,

1) R₂ may be a group represented by Formula 2B and R₁ and R₃ to R₆ may be hydrogen,

2) R₃ may be a group represented by Formula 2B and R₁, R₂ and R₄ to R₆ may be hydrogen,

3) R₄ may be a group represented by Formula 2B and R₁ to R₃, R₅ and R₆ may be hydrogen,

4) R₅ may be a group represented by Formula 2B and R₁ to R₄ and R₆ may be hydrogen,

5) R₅ may be a group represented by Formula 2B, R₃ may be a substituted or unsubstituted C₁-C₆₀ alkyl group, or a substituted or unsubstituted C₃-C₁₀ cycloalkyl group, and R₁, R₂, R₄ and R₆ may be hydrogen,

6) R₄ may be a group represented by Formula 2B, R₂ may be a substituted or unsubstituted C₁-C₆₀ alkyl group, or a substituted or unsubstituted C₃-C₁₀ cycloalkyl group, and R₁, R₃, R₅ and R₆ may be hydrogen,

7) R₂ may be a group represented by Formula 2B, R₅ may be a substituted or unsubstituted C₁-C₆₀ alkyl group, or a substituted or unsubstituted C₃-C₁₀ cycloalkyl group, and R₁, R₃, R₄ and R₆ may be hydrogen,

8) R₄ may be a group represented by Formula 2B, R₅ may be a substituted or unsubstituted C₁-C₆₀ alkyl group, or a substituted or unsubstituted C₃-C₁₀ cycloalkyl group, and R₁, R₂, R₃ and R₆ may be hydrogen, or

9) R₄ may be a group represented by Formula 2B, R₃ may be a substituted or unsubstituted C₁-C₆₀ alkyl group, or a substituted or unsubstituted C₃-C₁₀ cycloalkyl group, and R₁, R₂, R₅ and R₆ may be hydrogen,

In one or more embodiments, R₇ and R₉ in Formula 1B may not be hydrogen.

In one or more embodiments, R₇ and R₉ in Formula 1B may not be hydrogen, and R₅ and R₁₆ may be hydrogen.

In one or more embodiments, R₁₆ in Formula 1B may be hydrogen.

In one or more embodiments, R₇ and R₉ in Formula 1B may not be hydrogen, and R₇ and R₉ may be identical to each other.

In one or more embodiments, R₇ and R₉ in Formula 1B may not be hydrogen, and R₇ and R₉ may be different from each other.

In one or more embodiments, R₇ and R₉ in Formula 1B may not be hydrogen, R₇ and R₉ may be different from each other, and the number of carbon atoms included in R₇ may be greater than that of carbon atoms included in R₉.

In one or more embodiments, R₇ and R₉ in Formula 1B may each independently be a substituted or unsubstituted C₁-C₆₀ alkyl group, a substituted or unsubstituted C₃-C₁₀ cycloalkyl group, or a substituted or unsubstituted C₆-C₆₀ aryl group.

In one or more embodiments, at least one of R₇ and R₉ in Formula 1B may each independently be a substituted or unsubstituted C₂-C₆₀ alkyl group, a substituted or unsubstituted C₃-C₁₀ cycloalkyl group, or a substituted or unsubstituted C₆-C₆₀ aryl group.

In one or more embodiments, R₁₃ in Formula 2B may be hydrogen or deuterium.

In one or more embodiments, R₁₃ in Formula 2B may be a C₁-C₂₀ alkyl group, a deuterium-containing C₁-C₂₀ alkyl group, a C₃-C₁₀ cycloalkyl group, or a deuterium-containing C₃-C₁₀ cycloalkyl group.

In one or more embodiments, R₁₄ and R₁₅ in Formula 2B may be different from each other.

In one or more embodiments, in Formula 2B,

R₁₃ may be hydrogen, deuterium, —CH₃, —CDH₂, —CD₂H, or —CD₃,
R₁₀ and R₁₅ may each independently be:

a methyl group, an ethyl group, an n-propyl group, an iso-propyl group, an n-butyl group, a sec-butyl group, an iso-butyl group, a tert-butyl group, an n-pentyl group, a tert-pentyl group, a neopentyl, an iso-pentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, or a bicyclo[2.2.2]octyl group; or

a methyl group, an ethyl group, an n-propyl group, an iso-propyl group, an n-butyl group, a sec-butyl group, an iso-butyl group, a tert-butyl group, an n-pentyl group, a tert-pentyl group, a neopentyl, an iso-pentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, bicyclo[1.1.1]pentyl, bicyclo[2.1.1]hexyl, bicyclo[2.2.1]heptyl, or a bicyclo[2.2.2]octyl group, each substituted with at least one deuterium.

In one or more embodiments, in Formula 2B, R₁₄ and R₁₅ may each independently be —CH₃, —CD₃, —CD₂H, —CDH₂, a group represented by any one of Formulae 9-1 to 9-36, a group represented by any one of Formulae 9-1 to 9-36 in which at least one hydrogen is substituted with deuterium, a group represented by any one of Formulae 10-1 to 10-9, or a group represented by any one of Formulae 10-1 to 10-9 in which at least one hydrogen is substituted with deuterium. Above Formulae 9-1 to 9-36 and 10-1 to 10-9 are the same as described in connection with Formula 1A.

In one or more embodiments, a case where all of R₁₃ to R₁₅ in Formula 2B are the same may be excluded.

In one or more embodiments, a case where all of R₁₃ to R₁₅ in Formula 2B are each independently a methyl group may be excluded.

At least one of R₁₀ and R₁₂ in Formula 1B may each independently be a group represented by Formula 3B:

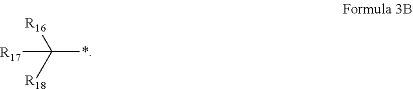

In Formula 3B, R₁₆ to R₁₈ may each independently be:

hydrogen, deuterium, a C₁-C₂₀ alkyl group, a C₃-C₁₀ cycloalkyl group, a C₆-C₆₀ aryl group, or a C₁-C₆₀ heteroaryl group; or

a C₁-C₂₀ alkyl group, a C₃-C₁₀ cycloalkyl group, a C₆-C₆₀ aryl group, or a C₁-C₆₀ heteroaryl group, each substituted with deuterium, a C₁-C₂₀ alkyl group, any combination thereof; and

* indicates a binding site to a neighboring atom.

For example, R₁₆ to R₁₈ in Formula 3B may each independently be hydrogen or deuterium.

In an embodiment, one or more of R₁₆ to R₁₈ in Formula 3B may be neither hydrogen nor deuterium. That is, Formula 3B may have two or less benzylic protons.

In one or more embodiments, two or more of R₁₆ to R₁₈ in Formula 3B may each independently be neither hydrogen nor deuterium. That is, Formula 3B may have one or no benzylic proton.

In an embodiment, in Formula 3B,

R₁₆ to R₁₈ may each independently be hydrogen or deuterium;

R₁₆ to R₁₈ may each independently be a methyl group or a deuterium-containing methyl group;

R₁₆ and R₁₇ may each independently be hydrogen or deuterium, and R₁₈ may be a methyl group or a deuterium-containing methyl group;

R₁₆ may be a methyl group or deuterium-containing methyl group, and R₁₇ and R₁₈ may each independently be a C₂-C₂₀ alkyl group or a deuterium-containing C₂-C₂₀ alkyl group;

R₁₆ and R₁₇ may each independently be hydrogen or deuterium, and R₁₈ may be

a C₂-C₂₀ alkyl group or a deuterium-containing C₂-C₂₀ alkyl group; or

R₁₆ and R₁₇ may each independently be a methyl group or a deuterium-containing methyl group, and R₁₈ may be a C₂-C₂₀ alkyl group or a deuterium-containing C₂-C₂₀ alkyl group.

“The C₂-C₂₀ alkyl group or the deuterium-containing C₂-C₂₀ alkyl group” may be an ethyl group, an n-propyl group, an iso-propyl group, an n-butyl group, a sec-butyl group, an iso-butyl group, a tert-butyl group, an n-pentyl group, a tert-pentyl group, a neopentyl, an iso-pentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, or a tert-decyl group, each unsubstituted or substituted with at least one deuterium.

In one or more embodiments, R₁₀ and R₁₂ in Formula 1B may be identical to each other.

In one or more embodiments, R₁₀ and R₁₂ in Formula 1B may be different from each other.

For example, in Formula 1B, R₁₀ may be an ethyl group, and R₁₂ may be a methyl group, an n-propyl group, or an iso-propyl group, but embodiments of the present disclosure are not limited thereto.

In one or more embodiments, at least one of R₁₀, R₁₂ and R₁₄ in Formulae 1B and 2B may each independently be a C₃-C₁₀ cycloalkyl group, or a deuterium-containing C₃-C₁₀ cycloalkyl group.

R₁ₐ may be the same as defined in connection with R₇ of Formula 1B.

In one or more embodiments, the organometallic compound represented by Formula 1B may satisfy at least one of <Condition 1B> to <Condition 6B>:

<Condition 1B>

At least one of R₁ to R₃, R₅ and R₆ in Formula 1B may not be hydrogen.

<Condition 2B>

At least one of R₇ and R₉ in Formula 1B may each independently be a group having two or more carbons.

<Condition 3B>

At least one of R₇ and R₉ in Formula 1B may each independently be a substituted or unsubstituted C₂-C₆₀ alkyl group, a substituted or unsubstituted C₃-C₁₀ cycloalkyl group, or a substituted or unsubstituted C₆-C₆₀ aryl group.

<Condition 4B>

At least one of R₁₀ and R₁₂ in Formula 1B may each independently be a group represented by Formula 3B and R₁₆ and R₁₈ in Formula 3B may not be hydrogen.

<Condition 5B>

At least one of R₁₀ and R₁₂ in Formula 1B may each independently be a group represented by Formula 3B and at least one of R₁₆ and R₁₈ in Formula 3B may each independently be a C₂-C₂₀ alkyl group, a C₃-C₁₀ cycloalkyl group or a C₆-C₆₀ aryl group; or a C₂-C₂₀ alkyl group, a C₃-C₁₀ cycloalkyl group or a C₆-C₆₀ aryl group, each substituted with deuterium, a C₁-C₂₀ alkyl group, or any combination thereof.

<Condition 6B>

At least one of R₁₀ and R₁₂ in Formula 1B may each independently be a substituted or unsubstituted C₃-C₁₀ cycloalkyl group.

In one or more embodiments, when R₄ in Formula 1B is a group represented by Formula 2B, R₁₃ in Formula 2B is hydrogen, R₁₄ in Formula 2B is a methyl group and R₁₅ in Formula 2 is a ethyl group, the organometallic compound represented by Formula 1B may satisfy at least one of <Condition 1B> to <Condition 6B>.

For example, in Formula 1B, at least two of R₁ to R₆ may optionally be linked to form a C₆-C₃₀ carbocyclic group unsubstituted or substituted with at least one R₁₀ₐ or a C₂-C₃₀ heterocyclic group unsubstituted or substituted with at least one R₁₀ₐ and at least two of R₇ to R₉ and R₁₆ may optionally be linked to form a C₆-C₃₀ carbocyclic group unsubstituted or substituted with at least one R₁₀ₐ or a C₂-C₃₀ heterocyclic group unsubstituted or substituted with at least one R₁₀ₐ. An R₁₀ₐ group may be the same as described in connection with R₁ in Formula 1A.

Description of Formula 1C

The organometallic compound may be represented by Formula 1C:

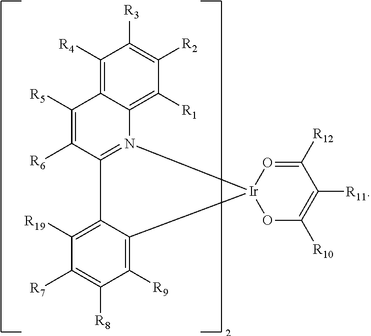

Descriptions for R₁ to R₁₂ and R₁₉ in Formula 1C are each respectively the same as descriptions for R₁ to R₁₂ and R₁₆ of Formula 1B.

In an embodiment, at least one of R₁ to R₆ in Formula 1C may each independently be a group represented by Formula 2C:

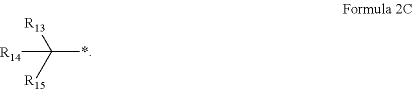

Descriptions for Formula 2C are the same as descriptions for Formula 2B.

In one or more embodiments, in Formula 1C,

1) R₂ may be a group represented by Formula 2C and R₁ and R₃ to R₆ may be hydrogen,

2) R₃ may be a group represented by Formula 2C and R₁, R₂ and R₄ to R₆ may be hydrogen,

3) R₄ may be a group represented by Formula 2C and R₁ to R₃, R₅ and R₆ may be hydrogen,

4) R₅ may be a group represented by Formula 2C and R₁ to R₄ and R₆ may be hydrogen,

5) R₄ may be a group represented by Formula 2C, R₅ may be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₂, R₃ and R₆ may be hydrogen,

6) R₅ may be a group represented by Formula 2C, R₃ may be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₂, R₄ and R₆ may be hydrogen,

7) R₂ may be a group represented by Formula 2C, R₅ may be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₃, R₄ and R₆ may be hydrogen,

8) R₄ may be a group represented by Formula 2C, R₆ may be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₂, R₃ and R₅ may be hydrogen,

9) R₃ may be a group represented by Formula 2C, R₅ may be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₂, R₄ and R₆ may be hydrogen, or

10) R₂ may be a group represented by Formula 2C, R₄ and R₅ may each independently be a substituted or unsubstituted C₁-C₆₀ alkyl group, a substituted or unsubstituted C₃-C₁₀ cycloalkyl group, a phenyl group, a biphenyl group, or —Si(Q₃)(Q₄)(Q₅) and R₁, R₃ and R₆ may be hydrogen.

In one or more embodiments, in Formula 1C,

1) R₇ and R₉ may not be hydrogen and R₈ and R₁₉ may be hydrogen,

2) R₇ and R₈ may not be hydrogen and R₉ and R₁₉ may be hydrogen,

3) R₇ to R₉ may not be hydrogen and R₁₉ may be hydrogen, or

4) R₇ may not be hydrogen and R₈, R₉ and R₁₉ may be hydrogen.

In one or more embodiments, in Formula 1C, at least one of R₁₀ and R₁₂ may each independently be a group represented by Formula 3C:

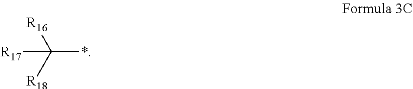

Descriptions for Formula 3C are the same as descriptions for Formula 3B.

In one or more embodiments, the organometallic compound represented by Formula 1C may satisfy at least one of <Condition 1B> to <Condition 6B> described in connection with Formula 1B.

Description of Formula 1D

The organometallic compound may be represented by Formula 1D:

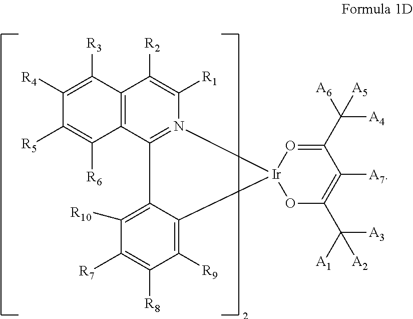

Descriptions for R₁ to R₁₀ and A₇ in Formula 1D are each respectively the same as descriptions for R₁ to R₉, R₁₆ and R₁₁ of Formula 1B, provided that, at least one of R₁ to R₁₀ may each independently be a substituted or unsubstituted C₂-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

A₁ to A₆ in Formula 1D may each independently be a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group.

Q₁ to Q₉ are the same as described herein.

In an embodiment, in Formula 1D,

R₁ to R₁₀ and A₇ may each independently be hydrogen, deuterium, a cyano group, a substituted or unsubstituted C₁-C₆₀ alkyl group, or a substituted or unsubstituted C₃-C₁₀ cycloalkyl group and/or at least one of R₁ to R₁₀ (for example, at least one of R₁ to R₆) may each independently be a substituted or unsubstituted C₂-C₆₀ alkyl group, or a substituted or unsubstituted C₃-C₁₀ cycloalkyl group, and/or

A₁ to A₆ may each independently be a substituted or unsubstituted C₁-C₆₀ alkyl group or a substituted or unsubstituted C₃-C₁₀ cycloalkyl group.

In one or more embodiments, at least one of R₁ to R₁₀ (for example, at least one of R₁ to R₆/in an embodiment, R₄) in Formula 1D may each independently be:

an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a methoxy group, an ethoxy group, a propoxy group, a butoxy group, a pentoxy group, a cyclopentyl group, a cyclohexyl group, a cydoheptyl group, a cyclooctyl group, an adamantyl group, a norbomyl group, a norbomenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, a dibenzothiophenyl group, or —Si(Q₃)(Q₄)(Q₅);

an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each substituted with deuterium, —F, a cyano group, or any combination thereof; or

a methoxy group, an ethoxy group, a propoxy group, a butoxy group, a pentoxy group, a cyclopentyl group, a cyclohexyl group, a cycloheptyl group, a cyclooctyl group, an adamantyl group, a norbomrnyl group, a norbomenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, or a dibenzothiophenyl group, each substituted with deuterium, —F, a cyano group, a C₁-C₁₀ alkyl group, or any combination thereof.

Q₃ to Q₅ are the same as described herein.

In one or more embodiments, A₁ to A₆ in Formula 1D may each independently be:

a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group or a dibenzothiophenyl group;

a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each substituted with deuterium, —F, a cyano group, or any combination thereof; or a methoxy group, an ethoxy group, a propoxy group, a butoxy group, a pentoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, or a dibenzothiophenyl group, each substituted with deuterium, —F, a cyano group, a C₁-C₁₀ alkyl group, or any combination thereof.

Q₃ to Q₅ are the same as described herein.

In one or more embodiments, in Formula 1D,

R₁ to R₁₀ and A₇ may each independently be hydrogen, deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, —Si(Q₃)(Q₄)(Q₅), or —Ge(Q₃)(Q₄)(Q₅) (wherein Q₃ to Q₅ are the same as described herein), and/or

at least one of R₁ to R₁₀ (for example, at least one of R₁ to R₆) may each independently be a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, —Si(Q₃)(Q₄)(Q₅), or —Ge(Q₃)(Q₄)(Q₅) (wherein Q₃ to Q₅ are the same as described herein), and/or

A₁ to A₆ may each independently be —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, or a group represented by any one of Formulae 10-201 to 10-342 in which at least one hydrogen is substituted with deuterium. Above Formulae 9-1 to 9-66, 10-1 to 10-118 and 10-201 to 10-342 are the same as described in connection with Formula 1A.

In one or more embodiments, in Formula 1D, at least one of R₁ to R₁₀ may be a group represented by Formula 2D:

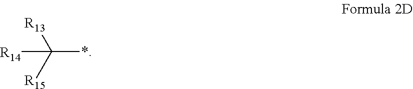

Descriptions for Formula 2D are the same as descriptions for Formula 2B.

In one or more embodiments, in Formula 2D,

R₁₃ may be hydrogen, deuterium, —CH₃, —CDH₂, —CD₂H, or —CD₃, and
R₁₀ and R₁₅ may each independently be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with at least one deuterium.

In one or more embodiments, in Formula 2D,

R₁₃ may be hydrogen, deuterium, —CH₃, —CDH₂, —CD₂H, or —CD₃,

R₁₄ may be —CH₃, —CDH₂, —CD₂H, or —CD₃, and

R₁₅ may be an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with at least one deuterium.

In an embodiment, at least one of R₁ to R₆ in Formula 1D may each independently be a group represented by Formula 2D.

For example, R₄ in Formula 1D may be a group represented by Formula 2D.

In an embodiment, R₁ to R₃, R₅, and R₆ in Formula 1D may each be hydrogen, and R₄ may be a group represented by Formula 2D.

In an embodiment, at least one of R₄, R₇, and R₉ in Formula 1D may not be each hydrogen.

In one or more embodiments, each of R₇ and R₉ in Formula 1D may not be hydrogen.

In one or more embodiments, in Formula 1D, each of R₇ and R₉ may not be hydrogen, and each of R₈ and R₁₀ may not be hydrogen.

In one or more embodiments, none of R₄, R₇, and R₉ in Formula 1D may be hydrogen.

In one or more embodiments, each of R₇ and R₉ in Formula 1D may not be hydrogen, and R₇ and R₉ may be identical to each other.

In one or more embodiments, each of R₇ and R₉ in Formula 1D may not be hydrogen, and R₇ and R₉ may be different from each other.

In one or more embodiments, in Formula 1D, each of R₇ and R₉ may not be hydrogen, R₇ and R₉ may be different from each other, and the number of carbon atoms included in R₇ may be greater than that of carbon atoms included in R₉.

In one or more embodiments, R₇ and R₉ in Formula 1 D may each independently be a substituted or unsubstituted C₁-C₆₀ alkyl group, a substituted or unsubstituted C₃-C₁₀ cycloalkyl group, or a substituted or unsubstituted C₆-C₆₀ aryl group.

In one or more embodiments, at least one of R₇ and R₉ in Formula 1 D may each independently be a substituted or unsubstituted C₂-C₆₀ alkyl group, a substituted or unsubstituted C₃-C₁₀ cycloalkyl group, or a substituted or unsubstituted C₆-C₆₀ aryl group.

In one or more embodiments, at least one of A₁ to A₆ in Formula 1 D may each independently be a substituted or unsubstituted C₂-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group.

For example, at least one of A₁ to A₆ in Formula 1 D may each independently be:

an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with deuterium, —F, a cyano group, any combination thereof; or

a methoxy group, an ethoxy group, a propoxy group, a butoxy group, a pentoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, or a dibenzothiophenyl group, each unsubstituted or substituted with deuterium, —F, a cyano group, a C₁-C₁₀ alkyl group, any combination thereof.

Q₃ to Q₅ are the same as described herein.

In an embodiment, at least one of A₁ to A₆ in Formula 1D may each independently be a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, or a group represented by any one of Formulae 10-201 to 10-342 in which at least one hydrogen is substituted with deuterium. Above Formulae 9-1 to 9-66, 10-1 to 10-118 and 10-201 to 10-342 are the same as described in connection with Formula 1A.

In one or more embodiments, A₇ may not be hydrogen.

In one or more embodiments, in Formula 1D, a group represented by *—C(A₁)(A₂)(A₃) and a group represented by *—C(A₄)(A₅)(A₆) may be identical to each other, and * indicates a binding site to a neighboring atom.

In one or more embodiments, in Formula 1D a group represented by *—C(A₁)(A₂)(A₃) and a group represented by *—C(A₄)(A₅)(A₆) may be different from each other, and * indicates a binding site to a neighboring atom.

In one or more embodiments, in Formula 1D,

A₁ an A₂ may be identical to each other, and A₁ and A₃ may be different from each other; and/or

A₄ and A₅ may be identical to each other, and A₄ and A₆ may be different from each other.

In Formula 1D, two or more of R₁ to R₁₀ may optionally be linked to form a C₅-C₆₀ carbocyclic group unsubstituted or substituted with at least one R₁ₐ or a C₁-C₆₀ heterocyclic group unsubstituted or substituted with at least one R₁ₐ, and two or more of A₁ to A₆ may optionally be linked to form a C₅-C₆₀ carbocyclic group unsubstituted or substituted with at least one R₁ₐ or a C₁-C₆₀ heterocyclic group unsubstituted or substituted with at least one R₁ₐ. Here, R₁ₐ is the same as defined in connection with R₇ of Formula 1D.

In an embodiment, two or more of A₁ to A₃ (for example, all of A₁ to A₃) in Formula 1D may be linked to form a C₅-C₆₀ carbocyclic group unsubstituted or substituted with at least one R₁ₐ or a C₁-C₆₀ heterocyclic group unsubstituted or substituted with at least one R₁ₐ, and/or two or more of A₄ to A₆ (for example, all of A₄ to A₆) in Formula 1D may be linked to form a C₅-C₆₀ carbocyclic group unsubstituted or substituted with at least one R₁ₐ or a C₁-C₆₀ heterocyclic group unsubstituted or substituted with at least one R₁ₐ.

In one or more embodiments, in Formula 1D, at least one of a group represented by *—C(A₁)(A₂)(A₃) and a group represented by *-(A₄)(A₅)(A₆) may each independently be a cyclopentane group, a cyclohexane group, a cycloheptane group, a cyclooctane group, an adamantane group, a norbornane group, a norbornene group, a cyclopentene group, a cyclohexene group, a cycloheptene group, a bicyclo[1.1.1]pentane group, a bicyclo[2.1.1]hexane group, a bicyclo[2.2.1]heptane group, a bicyclo[2.2.2]octane group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an isoindole group, an indole group, an indazole group, a purine group, a quinoline group, an isoquinoline group, a benzoquinoline group, a quinoxaline group, a quinazoline group, a cinnoline group, a carbazole group, a phenanthroline group, a benzimidazole group, a benzofuran group, a benzothiophene group, an isobenzothiophene group, a benzoxazole group, an isobenzoxazole group, a triazole group, a tetrazole group, an oxadiazole group, a triazine group, a tetrazine group, a dibenzofuran group, a dibenzothiophene group, a benzocarbazole group, a dibenzocarbazole group, an imidazopyridine group, or an imidazopyrimidine group, each unsubstituted or substituted with at least one R₁ₐ.

Description of Formula 1E

The organometallic compound may be represented by Formula 1E:

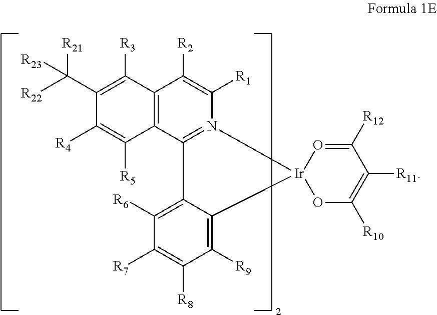

Descriptions for R₁ to R₁₂ and R₂₃ in Formula 1E are each respectively the same as descriptions for R₁, R₂, R₃, R₅, R₆, R₁₆, R₇, R₈, R₉, R₁₀, R₁₁ and R₁₂ of Formula 1B.

In Formula 1E, at least one of R₁ to R₅ (for example, one, two, three, four, or five of R₁ to R₅) may not be hydrogen. For example, at least one of R₁ to R₅ in Formula 1E (for example, one, two, three, four, or five of R₁ to R₅) may each independently be deuterium, —F, —Cl, —Br, —I, —SF₅, a hydroxyl group, a cyano group, a nitro group, an amino group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ arylalkyl group, a substituted or unsubstituted C₆-C₆₀ aryloxy group, a substituted or unsubstituted C₆-C₆₀ arylthio group, a substituted or unsubstituted heteroaryl group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

In an embodiment, in Formula 1E,

R₁ may not be hydrogen and R₂, R₃, R₄ and R₅ may each be independently be hydrogen or deuterium;

R₂ may not be hydrogen and R₁, R₃, R₄ and R₅ may each be independently hydrogen or deuterium;

R₃ may not be hydrogen and R₁, R₂, R₄ and R₅ may each be independently hydrogen or deuterium;

R₄ may not be hydrogen and R₁, R₂, R₃ and R₅ may each independently be hydrogen or deuterium; or

R₅ may not be hydrogen and R₁, R₂, R₃ and R₄ may each independently be hydrogen or deuterium.

In an embodiment, in Formula 1E, R₁ to R₁₂ and R₂₃ may each independently be:

hydrogen, deuterium, —F, a cyano group, or a C₁-C₂₀ alkyl group;

a C₁-C₂₀ alkyl group substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, or any combination thereof;

a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, or any combination thereof; or

—Si(Q₃)(Q₄)(Q₅), or —Ge(Q₃)(Q₄)(Q₅); and/or

at least one of R₁ to R₅ may each independently be:

deuterium, —F, a cyano group, or a C₁-C₂₀ alkyl group;

a C₁-C₂₀ alkyl group substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, or any combination thereof;

a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, or a terphenyl group, each unsubstituted or substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a (C₁-C₂₀ alkyl)phenyl group, a biphenyl group, a terphenyl group, or any combination thereof; or

—Si(Q₃)(Q₄)(Q₅), or —Ge(Q₃)(Q₄)(Q₅), wherein Q₃ to Q₅ may be each understood by referring to the detailed herein.

In Formula 1E, R₂₁ may be a C₂-C₂₀ alkyl group, a deuterium-containing C₂-C₂₀ alkyl group, a C₃-C₁₀ cycloalkyl group, or a deuterium-containing C₃-C₁₀ cycloalkyl group, and R₂₂ may be a C₁-C₂₀ alkyl group, a deuterium-containing C₁-C₂₀ alkyl group, a C₃-C₁₀ cycloalkyl group, or a deuterium-containing C₃-C₁₀ cycloalkyl group.

In an exemplary embodiment, R₂₁ in Formula 1E may be an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with at least one deuterium.

In an exemplary embodiment, R₂₂ in Formula 1E may be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with at least one deuterium.

In an embodiment, one of R₁ to R₅ in Formula 1E may be a substituted or unsubstituted C₁-C₆₀ alkyl group, a substituted or unsubstituted C₃-C₁₀ cycloalkyl group, —Si(Q₃)(Q₄)(Q₅), or —Ge(Q₃)(Q₄)(Q₅).

In an embodiment, in Formula 1E, R₆ and R₈ may each independently be hydrogen or deuterium, and R₇ and R₉ may each independently be a substituted or unsubstituted C₁-C₆₀ alkyl group, a substituted or unsubstituted C₃-C₁₀ cycloalkyl group, —Si(Q₃)(Q₄)(Q₅), or —Ge(Q₃)(Q₄)(Q₅).

In an embodiment, in Formula 1E, R₂₁ may be a C₃-C₁₀ cycloalkyl group or a deuterium-containing C₃-C₁₀ cycloalkyl group.

In an embodiment, in Formula 1E, R₂₁ may be a C₃-C₂₀ alkyl group, a deuterium-containing C₃-C₂₀ alkyl group, a C₃-C₁₀ cycloalkyl group, or a deuterium-containing C₃-C₁₀ cycloalkyl group.

In an embodiment, in Formula 1E, R₂₁ may be a branched C₃-C₂₀ alkyl group, a deuterium-containing branched C₃-C₂₀ alkyl group, a C₃-C₁₀ cycloalkyl group, or a deuterium-containing C₃-C₁₀ cycloalkyl group.

In an embodiment, in Formula 1E, R₂₂ may be a methyl group.

In an embodiment, in Formula 1E, R₂₂ may be a C₂-C₂₀ alkyl group, a deuterium-containing C₂-C₂₀ alkyl group, a C₃-C₁₀ cycloalkyl group, or a deuterium-containing C₃-C₁₀ cycloalkyl group.

In an embodiment, in Formula 1E, R₂₁ and R₂₂ may be identical to each other.

In an embodiment, in Formula 1E, R₂₁ and R₂₂ may be different from each other.

In an embodiment, in Formula 1E, R₂₃ may be hydrogen or deuterium.

In an embodiment, the organometallic compound represented by Formula 1E may satisfy Condition 3E, Condition 4E, or any combination thereof:

Condition 3E

R₁₀ in Formula 1E is represented by Formula 3E.

Condition 4E

R₁₂ in Formula 1E is represented by Formula 4E.

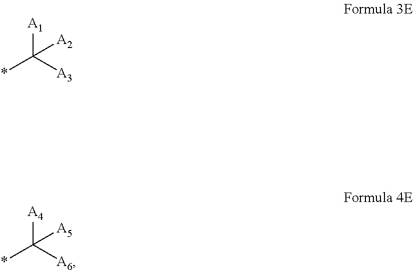

In Formulae 3E and 4E,

A₁ to A₆ may each independently be:

hydrogen or deuterium; or

a C₁-C₂₀ alkyl group, a C₃-C₁₀ cycloalkyl group, a C₆-C₆₀ aryl group, or a C₁-C₆₀ heteroaryl group, each unsubstituted or substituted with deuterium, a C₁-C₂₀ alkyl group, a C₃-C₁₀ cycloalkyl group, or any combination thereof; and

* indicates a binding site to a neighboring atom.

In an exemplary embodiment, Formula 3E may satisfy one of Condition 3-1E to Condition 3-5E and/or Formula 4E may satisfy one of Condition 4-1E to Condition 4-5E:

Condition 3-1E

A₁ to A₃ are not all hydrogen, simultaneously.

Condition 3-2E

A₁ to A₃ are each independently a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 3-3E

A₁ and A₂ are each independently a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₃ is a C₂-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 3-4E

A₁ is a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₂ and A₃ are each independently a C₂-C₂₀ alkyl group or a C₃-C₁₀ cycloalkyl group, each unsubstituted or substituted with deuterium, a C₁-C₂₀ alkyl group, a C₃-C₁₀ cycloalkyl group, or any combination thereof.

Condition 3-5E

A₁ is hydrogen or deuterium,

A₂ is a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₃ is a C₂-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 4-1E

A₄ to A₆ are not all hydrogen, simultaneously.

Condition 4-2E

A₄ to A₆ are each independently a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 4-3E

A₄ and A₅ are each independently a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₆ is a C₂-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 4-4E

A₄ is a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₅ and A₆ are each independently a C₂-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

Condition 4-5E

A₄ is hydrogen or deuterium,

A₅ is a C₁-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof, and

A₆ is a C₂-C₂₀ alkyl group, or a C₃-C₁₀ cycloalkyl group, each unsubstituted or substituted with deuterium, a C₁-C₂₀ alkyl group, a C₃-C₁₀ cycloalkyl group, or any combination thereof.

In an embodiment, R₁₀, R₁₂, or a combination thereof (for example, both R₁₀ and R₁₂) in Formula 1E may be a substituted or unsubstituted C₃-C₁₀ cycloalkyl group.

In an embodiment, R₁₀, R₁₂, or a combination thereof (for example, both R₁₀ and R₁₂) in Formula 1E may each independently be a cyclopentyl group, a cyclohexyl group, a cycloheptyl group, a cyclooctyl group, an adamantyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with deuterium, —F, —CD₃, —CD₂H, —CDH₂, —CF₃, —CF₂H, —CFH₂, a cyano group, a C₁-C₁₀ alkyl group, or any combination thereof.

In an embodiment, R₁₀ and R₁₂ in Formula 1E may be identical to each other.

In an embodiment, R₁₀ and R₁₂ in Formula 1E may be different from each other.

In an embodiment, R₁₁ in Formula 1E may be hydrogen, deuterium, or a methyl group.

In an embodiment, a case in which R₁₀ and R₁₂ in Formula 1E are each a methyl group and R₁₁ in Formula 1E is hydrogen is excluded from the scope of this disclosure.

In an embodiment, in Formulae 1E, 3E and 4E,

R₁ to R₁₂ and R₂₃ may each independently be hydrogen, deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, —Si(Q₃)(Q₄)(Q₅), or —Ge(Q₃)(Q₄)(Q₅) (wherein Q₃ to Q₅ are the same as described herein); and/or

at least one of R₁ to R₅ may each independently be deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, —Si(Q₃)(Q₄)(Q₅), or —Ge(Q₃)(Q₄)(Q₅) (wherein Q₃ to Q₅ are the same as described herein); and/or

R₂₁ may be a group represented by one of Formulae 9-1 to 9-36, a group represented by one of Formulae 9-1 to 9-36 in which at least one hydrogen is substituted with deuterium, a group represented by one of Formulae 10-1 to 10-9, or a group represented by one of Formulae 10-1 to 10-9 in which at least one hydrogen is substituted with deuterium; and/or

R₂₂ may be —CH₃, —CD₃, —CD₂H, —CDH₂, a group represented by one of Formulae 9-1 to 9-36, a group represented by one of Formulae 9-1 to 9-36 in which at least one hydrogen is substituted with deuterium, a group represented by one of Formulae 10-1 to 10-9, or a group represented by one of Formulae 10-1 to 10-9 in which at least one hydrogen is substituted with deuterium; and/or

A₁ to A₆ may each independently be hydrogen, deuterium, —CH₃, —CD₃, —CD₂H, —CDH₂, a group represented by one of Formulae 9-1 to 9-66, a group represented by one of Formulae 9-1 to 9-66 in which at least one hydrogen is substituted with deuterium, a group represented by one of Formulae 10-1 to 10-9, or a group represented by one of Formulae 10-1 to 10-9 in which at least one hydrogen is substituted with deuterium. Above Formulae 9-1 to 9-66, 10-1 to 10-118 and 10-201 to 10-342 are the same as described in connection with Formula 1A.

In Formula 1E, two or more of R₁ to R₉ may optionally be linked to each other to form a C₅-C₃₀ carbocyclic group unsubstituted or substituted with at least one R₁ₐ group or a C₂-C₃₀ heterocyclic group unsubstituted or substituted with at least one R₁ₐ group, and two or more of R₁₀ to R₁₂ may optionally be linked to each other to form a C₅-C₃₀ carbocyclic group unsubstituted or substituted with at least one R₁ₐ group or a C₂-C₃₀ heterocyclic group unsubstituted or substituted with at least one R₁ₐ group.

Descriptions for R₁ₐ are the same as descriptions for R₁ of Formula 1E.

Although the ligand L₂ in Formulae 1B to 1E is shown to have the structure

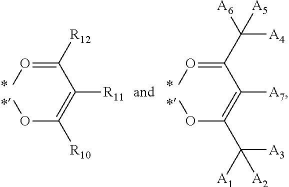

in some embodiments, the ligand L₂ may have a more general structure

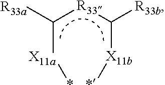

wherein

X₁₁ₐ and X_{11b} are each independently N, O, N(R₃₄), P(R₃₅)(R₃₆), or As(R₃₇)(R₃₈);

R₃₃″ is a single bond, a double bond, a substituted or unsubstituted C₁-C₅ alkylene group, or a substituted or unsubstituted C₂-C₅ alkenylene group;

R₃₃ₐ, R_{33b}, and R₃₄ to R₃₈ are each independently a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, or —Si(Q₄₁)(Q₄₂)(Q₄₃),

wherein Q₄₁ to Q₄₃ are each independently a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group; and

* and *′ each indicates a binding site to Ir in Formula 1E.

Description of Formula 1F

The organometallic compound may be represented by Formula 1F:

M(L₁)ₙ₁(L₂)ₙ₂. Formula 1F

M in Formula 1F may be a first-row transition metal, a second-row transition metal, or a third-row transition metal, of the Periodic Table of Elements,

L₁ in Formula 1F may be a ligand represented by Formula 2F,

n1 in Formula 1F may be 1, 2, or 3, wherein, when n1 is two or more, two or more L₁ may be identical to or different from each other,

L₂ in Formula 1F may be a monodentate ligand, a bidentate ligand, a tridentate ligand, or a tetradentate ligand,

n2 in Formula 1F may be 0, 1, 2, 3, or 4, wherein, when n2 is two or more, two or more L₂ may be identical to or different from each other, and

L₁ and L₂ in Formula 1F may be different from each other:

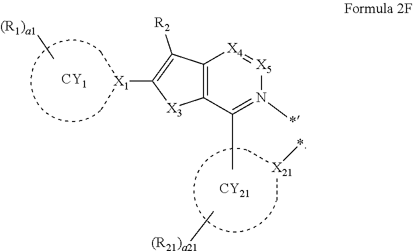

Formula 2F is the same as described below.

For example, n1 may be 1 or 2.

L₂ in Formula 1F may be a monodentate ligand, a bidentate ligand, a tridentate ligand, or a tetradentate ligand, and n2 in Formula 1F indicates the number of L₂ and may be 0, 1, 2, 3, or 4. When n2 is two or more, two or more L₂ may be identical to or different from each other. L₂ is the same as described below.

For example, n2 in Formula 1F may be 1 or 2.

L₁ and L₂ in Formula 1F may be different from each other.

In one embodiment, M may be Ir or Os, and the sum of n1 and n2 may be 3 or 4; or M may be Pt, and the sum of n1 and n2 may be 2.

In Formula 2F, X₁ may be C, N, Si, or P, and X₂₁ may be C or N.

For example, in Formula 2F, X₂₁ may be C.

In Formula 2F, ring CY₁ and ring CY₂₁ may each independently be a C₃-C₆₀ carbocyclic group or a C₁-C₆₀ heterocyclic group. Descriptions for ring CY₁ and ring CY₂₁ are the same as descriptions for CY₁ of Formula 1A.

In one or more embodiments, ring CY₁ may be a cyclopentane group, a cyclohexane group, a cycloheptane group, a cycloctane group, an adamantane group, a norbornane group, a norbornene group, a cyclopentene group, a cyclohexene group, a cycloheptene group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an isoindole group, an indole group, an indazole group, a purine group, a quinoline group, an isoquinoline group, a benzoquinoline group, a quinoxaline group, a quinazoline group, a cinnoline group, a carbazole group, a phenanthroline group, a benzimidazole group, a benzofuran group, a benzothiophene group, an isobenzothiazole group, a benzoxazole group, an isobenzoxazole group, a triazole group, a tetrazole group, an oxadiazole group, a triazine group, a dibenzofuran group, a dibenzothiophene group, a dibenzosilole group, a benzocarbazole group, a dibenzocarbazole group, an imidazopyridine group, or an imidazopyrimidine group, but embodiments of the present disclosure are not limited thereto.

In Formula 2F, X₃ may be O, S, Se, or N(R₃), X₄ may be N or C(R₄), and X₅ may be N or C(R₅).

In one embodiment, X₃ may be O or S, and X₅ may be C(R₅).

In one or more embodiments, X₃ may be O or S, and X₄ may be N.

In one or more embodiments, X₄ may be N, and X₅ may be C(R₅).

In one or more embodiments, X₄ may be C(R₄), and X₅ may be C(R₅).

In Formula 2F, descriptions for R₁ to R₅ and R₂₁ are each independently the same as descriptions for R₄ of Formula 1A.

In Formula 2F, a1 and a21 each indicate the number of R₁ and the number of R₂₁, respectively, and may each independently be an integer from 0 to 20 (for example, an integer from 0 to 10 or an integer from 0 to 5). When a1 is two or more, two or more R₁ may be identical to or different from each other, and when a21 is two or more, two or more R₂₁ may be identical to or different from each other.

In Formula 2F, ring CY₁ and R₂ are not linked to each other, and R₁ and R₂ are not linked to each other.

In one embodiment, a group represented by

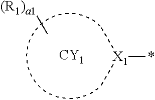

in Formula 2F may be a C₃-C₁₀ cycloalkenyl group, a C₂-C₁₀ heterocycloalkenyl group, a C₆-C₆₀ aryl group, a C₁-C₆₀ heteroaryl group, a monovalent non-aromatic condensed polycyclic group, or a monovalent non-aromatic condensed heteropolycyclic group, each unsubstituted or substituted with R₁ in the number of a1 .

In Formula 2F, R₁ and R₂ may each independently be:

hydrogen, deuterium, —F, —Cl, —Br, —I, a cyano group, or —SF₅; or

a C₁-C₆₀ alkyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₁-C₆₀ heteroaryl group, a monovalent non-aromatic condensed polycyclic group, or a monovalent non-aromatic condensed heteropolycyclic group, each unsubstituted or substituted with a deuterium, —F, —Cl, —Br, —I, —CD₃, —CD₂H, —CDH₂, —CF₃, —CF₂H, —CFH₂, a cyano group, a C₁-C₂₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a biphenyl group, a naphthyl group, a pyridinyl group, or a pyrimidinyl group, and

a1 may be an integer from 0 to 10.

In one or more embodiments, a group represented by

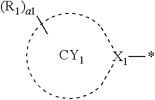

in Formula 2F may be a phenyl group, a biphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with an R₁ in the number of a1 ,

In Formula 2F, R₁ and R₂ may each independently be:

hydrogen, deuterium, —F, —Cl, —Br, —I, a cyano group, or —SF₅; or

a methyl group, an ethyl group, a propyl group, an n-butyl group, an isobutyl group, a sec-butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decanyl group, an isodecanyl group, a sec-decanyl group, a tert-decanyl group, a C₁-C₁₀ alkoxy, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a biphenyl group, a naphthyl group, a pyridinyl group, a pyrimidinyl group, a dibenzofuranyl group, or a dibenzothiophenyl group, each unsubstituted or substituted with a deuterium, —F, —Cl, —Br, —I, —CD₃, —CD₂H, —CDH₂, —CF₃, —CF₂H, —CFH₂, a cyano group, a C₁-C₂₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a biphenyl group, a naphthyl group, a pyridinyl group, a pyrimidinyl group, a dibenzofuranyl group, or a dibenzothiophenyl group, and a1 may be an integer from 0 to 5, but embodiments of the present disclosure are not limited thereto.

In one or more embodiments, a group represented by

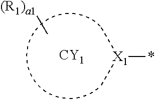

in Formula 2F may be a group represented by one of Formulae 10-13(1) to 10-13(18) or 10-13:

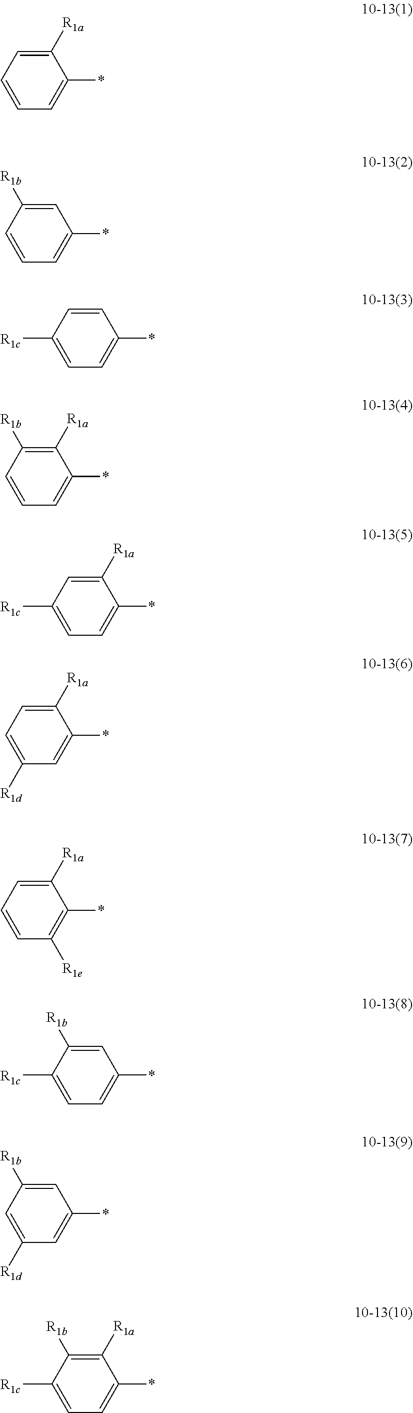

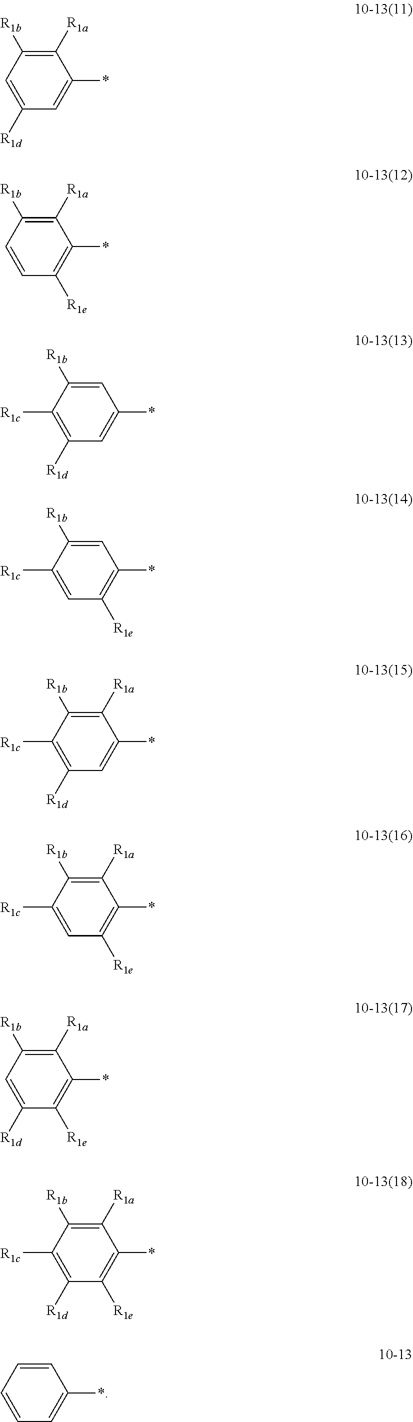

In Formulae 10-13(1) to 10-13(18) and 10-13, R₁ₐ to R₁ₑ may each independently the same as defined in connection with R₁ of Formula 1F wherein R₁ₐ to R₁ₑ may each independently not be hydrogen, and * indicates a binding site to a neighboring atom.

In one or more embodiments, in Formula 2F,

X₄ may be C(R₄), and

R₄ may be hydrogen, deuterium, —F, —Cl, —Br, —I, —SF₅, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, —N(Q₁)(Q₂), —Si(Q₃)(Q₄)(Q₅), —B(Q₆)(Q₇), or —P(═O)(Q₈)(Q₉).

In one or more embodiments, in Formula 2F,

X₄ may be C(R₄), and

R₄ may be a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In one or more embodiments, in Formula 2F, X₄ may be N.

For example, a group represented by

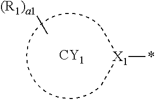

in Formula 2F may be a group represented by any one of Formulae 10-1 to 10-118, a group represented by any one of Formulae 10-1 to 10-118 in which at least one hydrogen is substituted with deuterium, a group represented by any one of Formulae 10-201 to 10-342, or a group represented by any one of Formulae 10-201 to 10-342 in which at least one hydrogen is substituted with deuterium, and/or R₁ to R₅ and R₂₁ may each independently be hydrogen, deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 10-1 to 10-118, a group represented by any one of Formulae 10-1 to 10-118 in which at least one hydrogen is substituted with deuterium, a group represented by any one of Formulae 10-201 to 10-342, a group represented by any one of Formulae 10-201 to 10-342 in which at least one hydrogen is substituted with deuterium, or —Si(Q₃)(Q₄)(Q₅) (wherein Q₃ to Q₅ are the same as described herein). Above Formulae 9-1 to 9-66, 10-1 to 10-118 and 10-201 to 10-342 are the same as described in connection with Formula 1A.

In Formula 2F, R₄ and R₅ may optionally be linked to form a C₅-C₃₀ carbocyclic group that is unsubstituted or substituted with R₁₀ₐ or a C₁-C₃₀ heterocyclic group that is unsubstituted or substituted with R₁₀ₐ, a plurality of neighboring R₂₁ may optionally be linked to form a C₅-C₃₀ carbocyclic group that is unsubstituted or substituted with R₁₀ₐ or a C₁-C₃₀ heterocyclic group that is unsubstituted or substituted with R₁₀ₐ, and R₁₀ₐ may be the same as defined in connection with R₂₁. The C₅-C₃₀ carbocyclic group and the C₁-C₃₀ heterocyclic group may each independently be the same as described elsewhere herein. Descriptions for R₁₀ₐ are the same as descriptions for R₂₁ of Formula 1F.

In Formula 2F, * and *′ each indicate a binding site to M in Formula 1F.

A group represented by

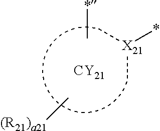

in Formula 2F may be a group represented by one of Formulae CY21-1 to CY21-31:

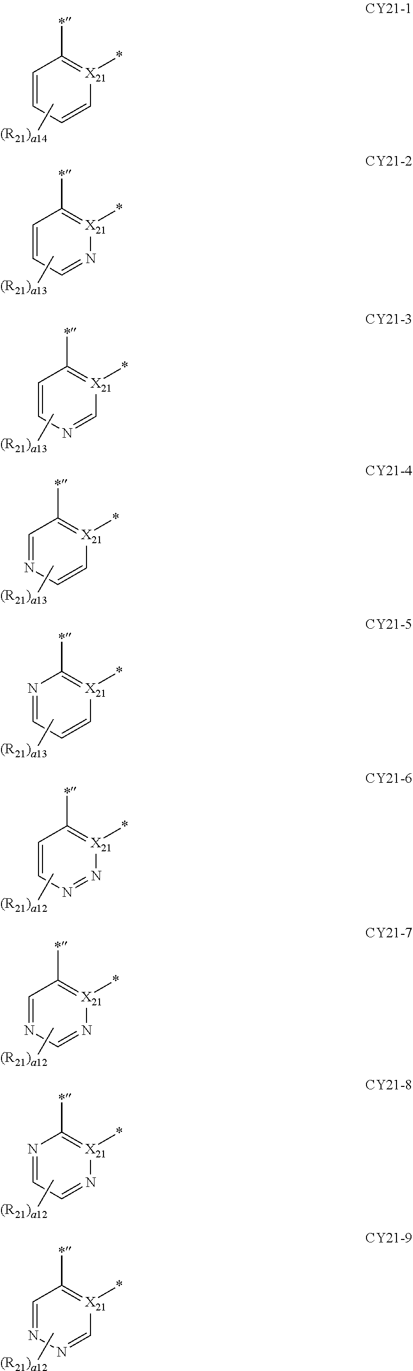

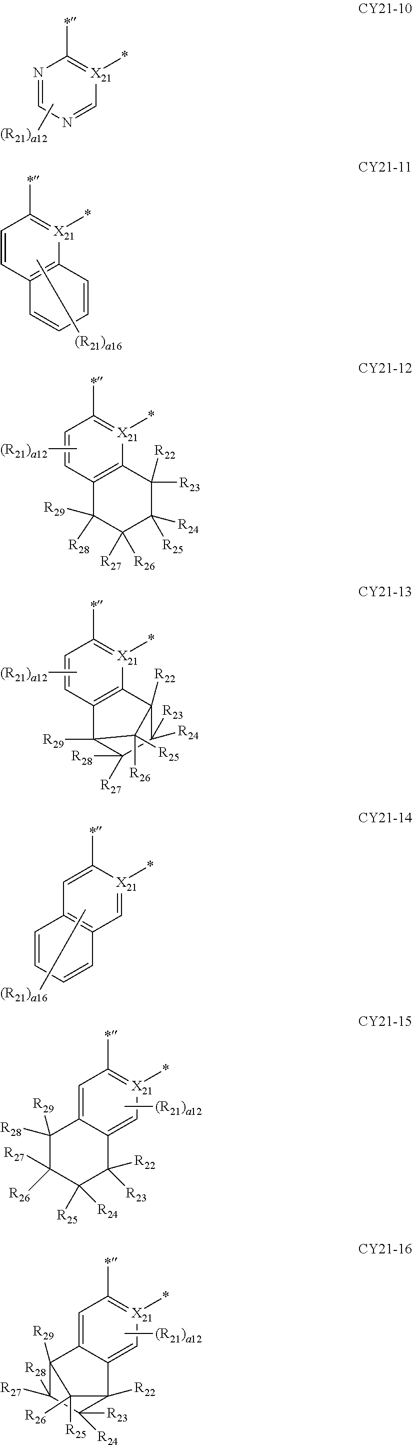

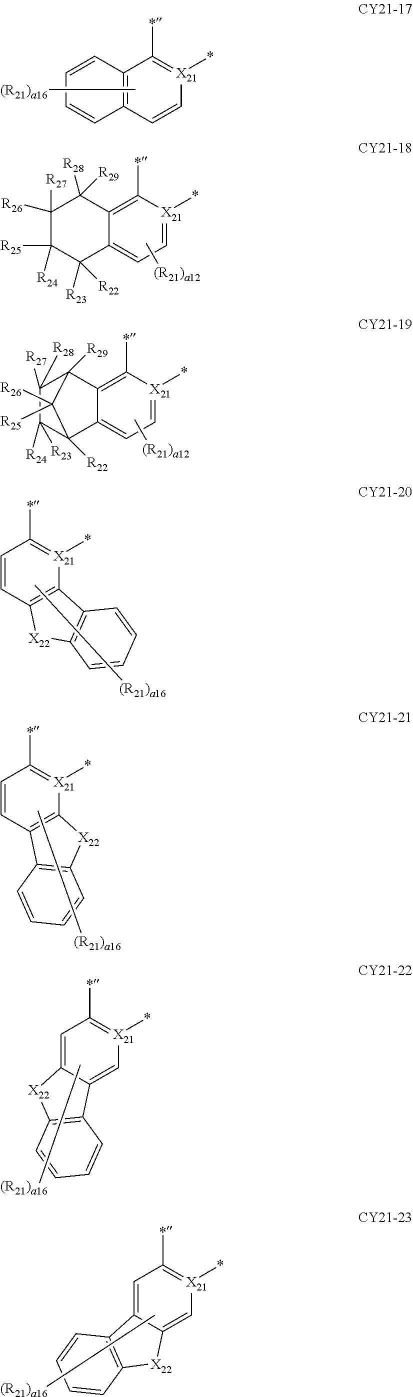

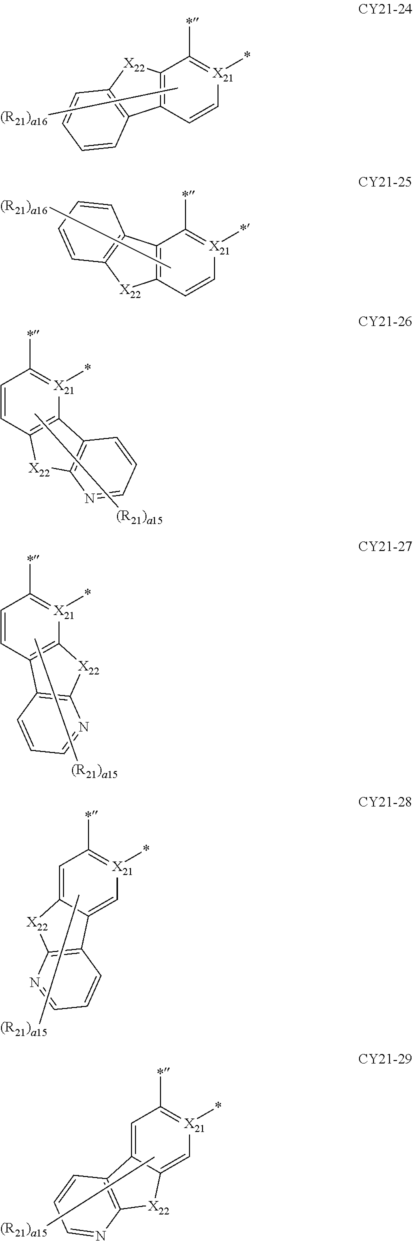

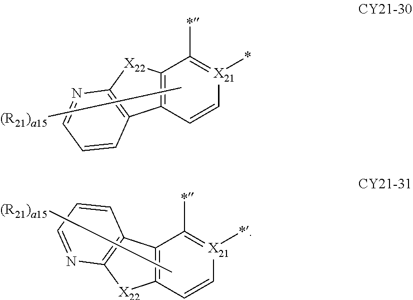

In Formulae CY21-1 to CY21-31,

X₂₁ and R₂₁ may each independently be the same as described in Formula 1F,

X₂₂ may be C(R₂₂)(R₂₃), N(R₂₂), O, S, or Si(R₂₂)(R₂₃),

R₂₂ to R₂₉ may each independently be the same as defined in connection with R₂₁ of Formula 1F,

a16 may be an integer from 0 to 6,

a15 may be an integer from 0 to 5,

a14 may be an integer from 0 to 4,

a13 may be an integer from 0 to 3,

a12 may be an integer from 0 to 2,

*″ indicates a binding site to a carbon atom of a neighboring 6-membered ring in Formula 2F, and

* indicates a binding site to M in Formula 1F.

In one embodiment, a group represented by

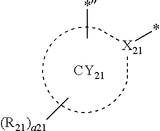

in Formula 2F may be a group represented by Formulae CY21(1) to CY21(56) or a group represented by Formulae CY21-20 to CY21-31:

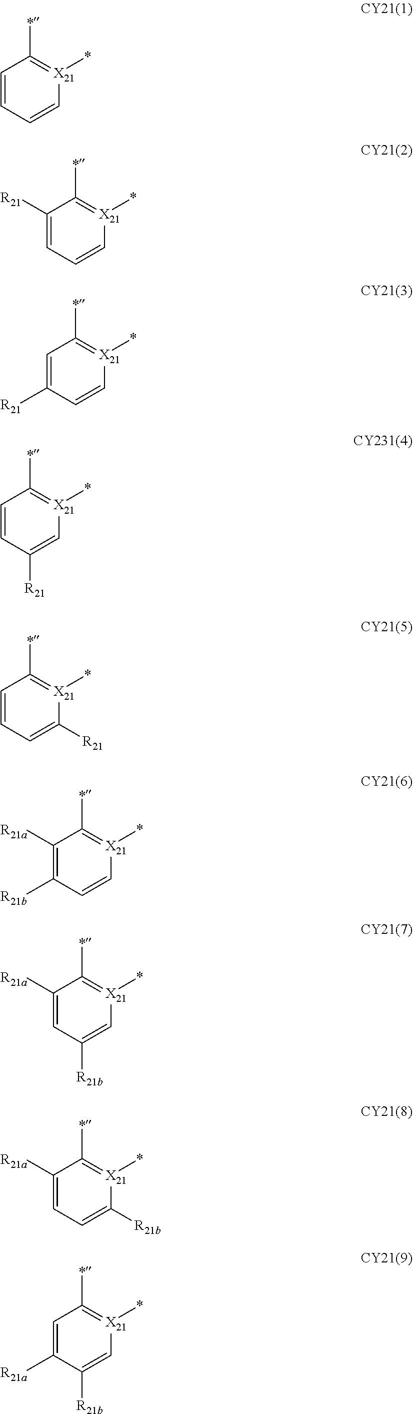

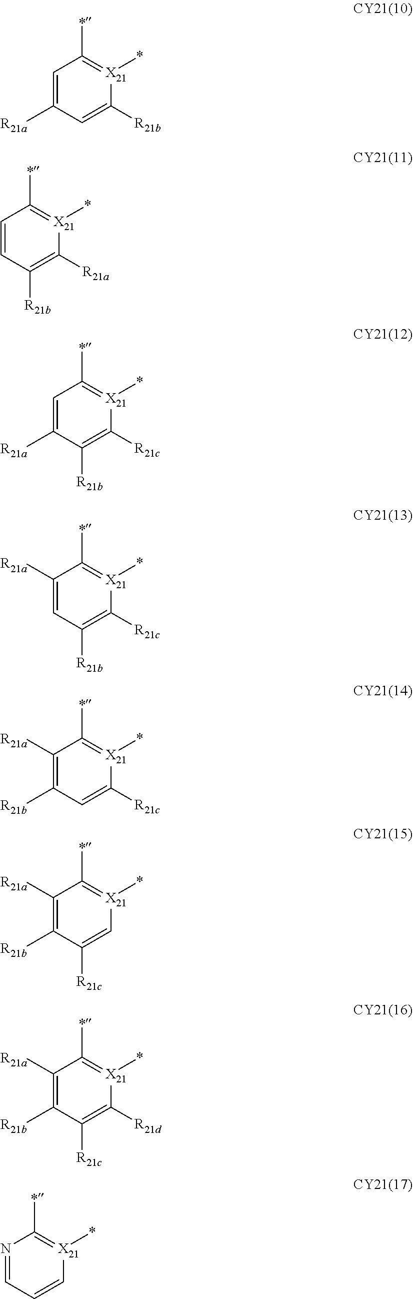

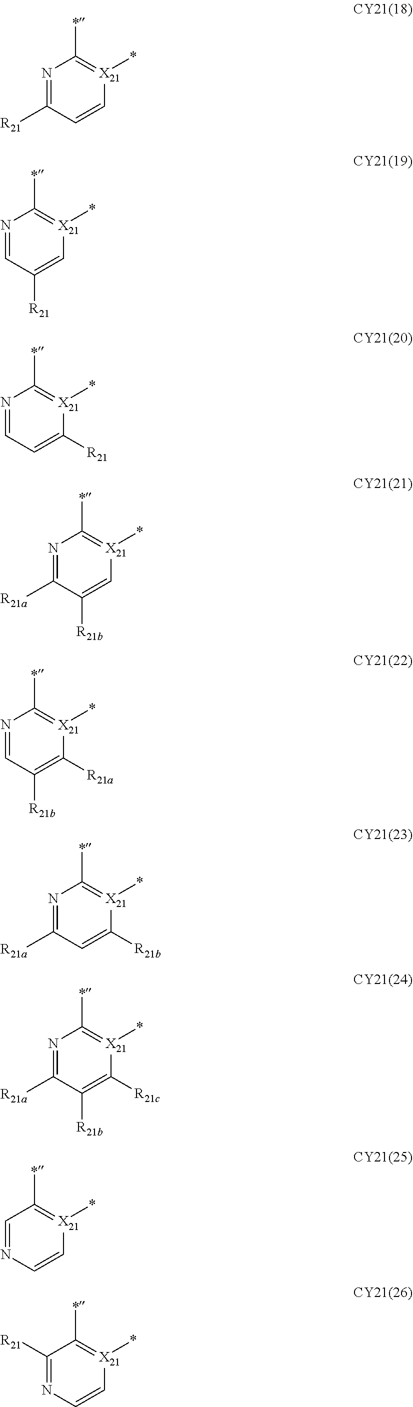

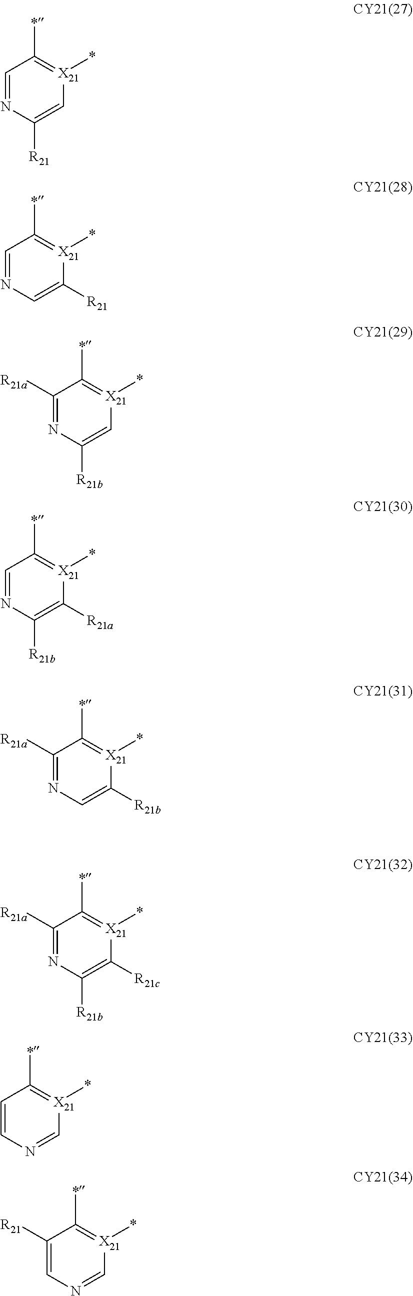

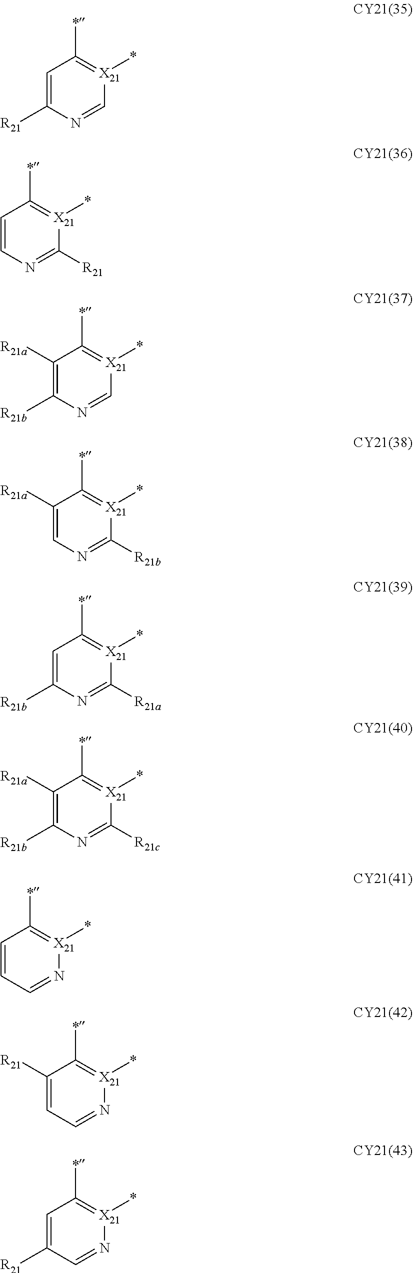

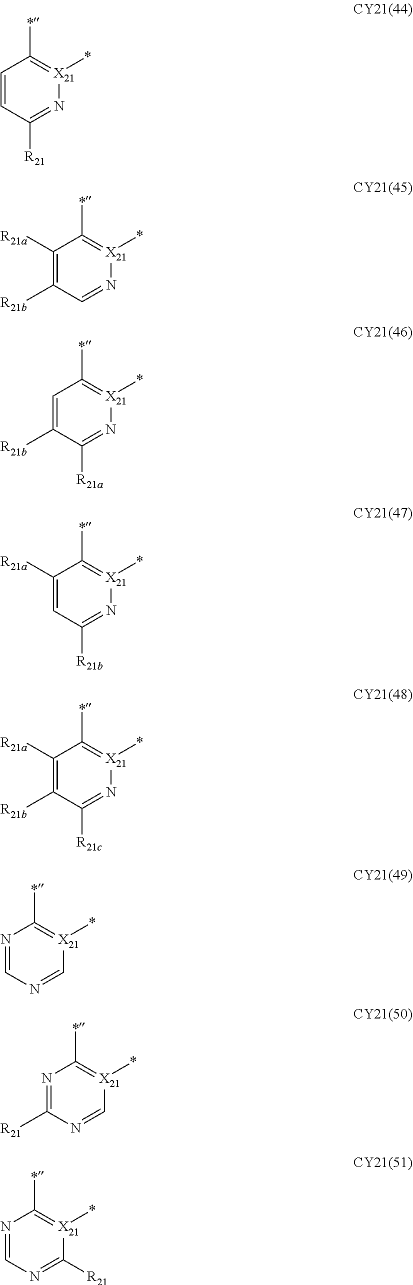

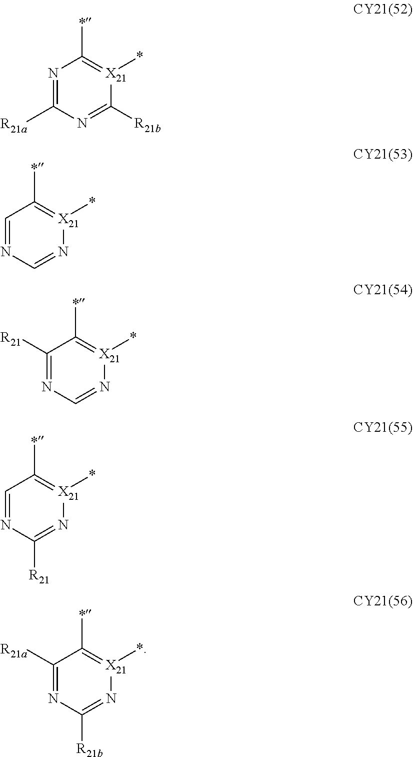

In Formulae CY21(1) to CY21(56),

X₂₁ and R₂₁ may each independently be the same as described in Formula 2F,

R₂₁ₐ to R_{21d} may each independently be the same as defined in connection with R₂₁ of Formula 2F, wherein R₂₁ and R₂₁ₐ to R_{21d} are each independently not hydrogen,

*″ indicates a binding site to a carbon atom of a neighboring 6-membered ring in Formula 2F, and

* indicates a binding site to M in Formula 1F.

In Formula 1F, descriptions for L₂ are the same as descriptions for L₂ of Formula 1H.

Description of Formula 1G

The organometallic compound may be represented by Formula 1G:

M(L₁)ₙ₁(L₂)ₙ₂. Formula 1G

In Formula 1G, descriptions for M, n1 and n2 are each independently the same as the descriptions for M, n1 and n2 of Formula 1F.

In Formula 1G, descriptions for L₂ are the same as the descriptions for L₂ of Formula 1H.

L₁ in Formula 1G may be a ligand represented by Formula 2G:

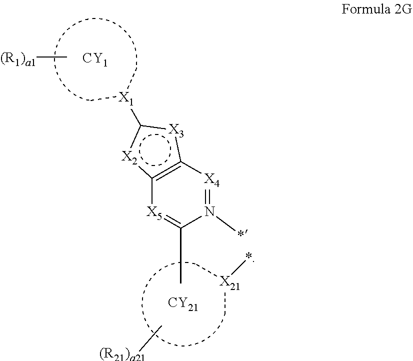

In Formula 2G, descriptions for X₁, X₂₁, ring CY₁, ring CY₂, X₄, X₅, R₁, R₄, R₅, R₂₁, a1 and a21 are each independently the same as X₁, X₂₁, ring CY₁, ring CY₂, X₄, X₅, R₁, R₄, R₅, R₂₁, a1 and a21 of Formula 2F.

In Formula 2G, X₂ and X₃ may each independently be O, S, Se, or C(R₂), and one of X₂ and X₃ may be O, S, or Se. Descriptions for R₂ are the same as the description for R₂₁ of Formula 2F.

For example, in Formula 2G, i) X₂ may each independently be O, S or Se and X₃ may be C(R₂); or ii) X₂ may be or C(R₂) and X₃ may each independently be O, S or Se.

* and *′ each indicate a binding site to M in Formula 1G.

In an embodiment, in Formula 1G, L₁ may be a ligand represented by Formula 2GA or 2 GB, but embodiments of the present disclosure are not limited thereto:

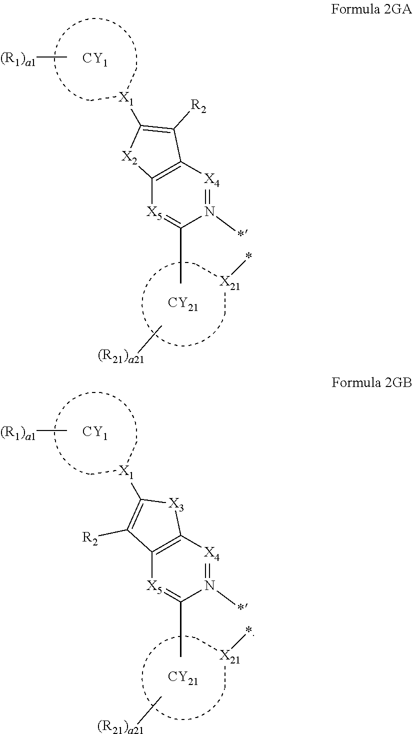

In Formulae 2GA and 2 GB, X₁, X₂₁, ring CY₁, ring CY₂₁, X₄, X₅, R₁, R₂, a1, a21, and *′ are each independently the same as described in Formula 1G, and X₂ and X₃ may be O, S, or Se.

Description of Formula 1H

The organometallic compound may be represented by Formula 1H:

M(L₁)ₙ₁(L₂)ₙ₂. Formula 1H

In Formula 1H, descriptions for M, n1 and n2 are each independently the same as the descriptions for M, n1 and n2 of Formula 1F.

L₁ in Formula 1H may be a ligand represented by Formula 2H:

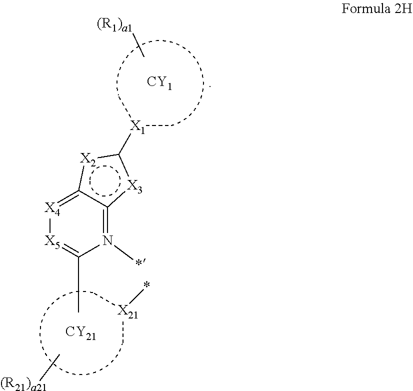

In Formula 2H, descriptions for X₁, X₂₁, ring CY₁, ring CY₂, X₄, X₅, R₁, R₄, R₅, R₂₁, a1 and a21 are each independently the same as the descriptions for X₁, X₂₁, ring CY₁, ring CY₂, X₄, X₅, R₁, R₄, R₅, R₂₁, a1 and a21 of Formula 2F.

In Formula 2H, X₂ and X₃ may each independently be O, S, Se, or C(R₂), and one X₂ and X₃ may be O, S, or Se. Descriptions for R₂ are the same as the descriptions for R₂₁ of Formula 2F.

For example, in Formula 2H, i) X₂ may each independently be O, S or Se and X₃ may be C(R₂); or ii) X₂ may be C(R₂) and X₃ may each independently be O, S or Se.

* and *′ each indicate a binding site to M in Formula 1H.

In an embodiment, L₁ in Formula 1H may be a ligand represented by Formula 2HA or 2HB, but embodiments of the present disclosure are not limited thereto:

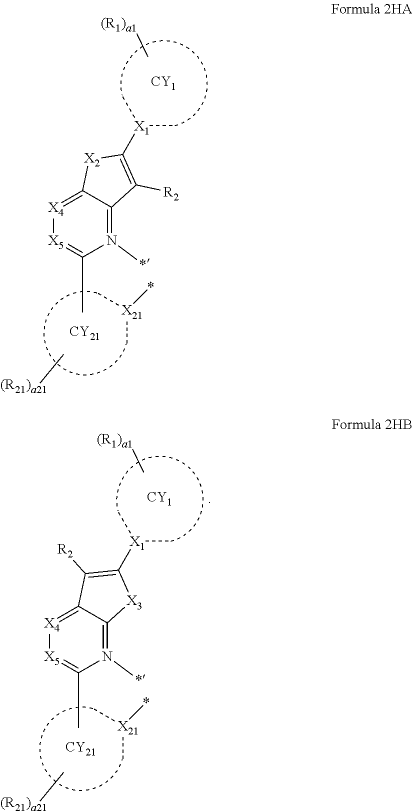

In Formulae 2HA and 2HB, X₁, X₂₁, ring CY₁, ring CY₂₁, X₄, X₅, R₁, R₂, a1, a21, and *′ are each independently the same as described in Formula 1H, and X₂ and X₃ may each independently be O, S, or Se.

In Formula 1H, L₂ may be a bidentate ligand linked to M of Formula 1H via O, S, N, C, P, Si, or As.

In an embodiment, L₂ in Formula 1H may be a bidentate ligand represented by Formula 3H:

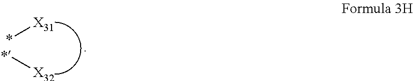

In Formula 3H,

X₃₁ and X₃₂ may each independently be O, S, N, C, P, Si, or As,

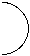

indicates an arbitrary atom group that links X₃₁ to X₃₂, and

* and *′ each indicate a binding site to M in Formula 1H.

For example, in Formula 3H, i) X₃₁ and X₃₂ may each independently be O; ii) X₃₁ may be O, and X₃₂ may be N, or iii) X₃₁ may be N, and X₃₂ may be C, but embodiments of the present disclosure are not limited thereto.

In one or more embodiments, in Formula 1H, L₂ may be a group represented by one of Formula 3HA to 3HF:

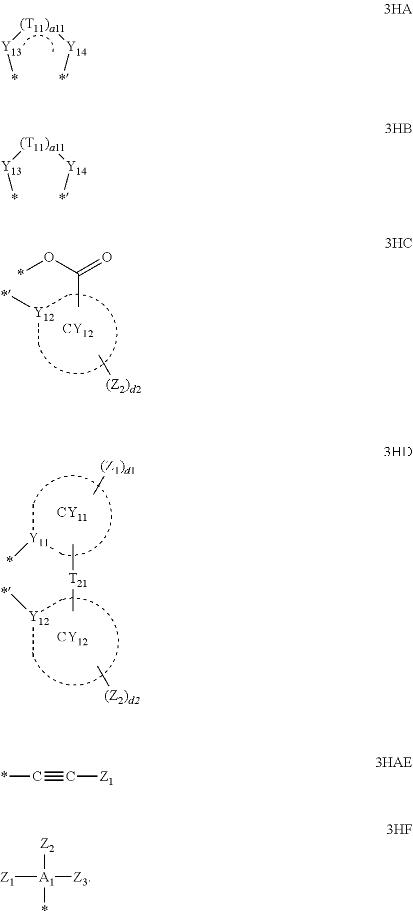

In Formulae 3HA to 3HF,

Y₁₃ may be O, N, N(Z₁), P(Z₁)(Z₂), or As(Z₁)(Z₂),

Y₁₄ may be O, N, N(Z₃), P(Z₃)(Z₄), or As(Z₃)(Z₄),

T₁₁ may each independently be a single bond, a double bond, *—C(Z₁₁)(Z₁₂)—*′, *—C(Z₁₁)═C(Z₁₂)—*′, *═C(Z₁₁)—*′, *—C(Z₁₁)=*′, *═C(Z₁₁)—C(Z₁₂)═C(Z₁₃)—*¹, *—C(Z₁₁)═C(Z₁₂)—C(Z₁₃)=*′, *—N(Z₁₁)—*′, or a C₅-C₃₀ carbocyclic group unsubstituted or substituted with at least one

a11 may be an integer from 1 to 10,

Y₁₁ and Y₁₂ may each independently be C or N,

T₂₁ may be a single bond, a double bond, O, S, C(Z₁₁)(Z₁₂), Si(Z₁₁)(Z₁₂), or ring CY₁₁ and ring CY₁₂ may each independently be a C₅-C₃₀ carbocyclic group or a C₁-C₃₀ heterocyclic group,

A₁ may be P or As,

Z₁ to Z₄ and Z₁₁ to Z₁₃ are each independently the same as described in connection with R₂₁ in Formula 1H,

d1 and d2 may each independently be an integer from 0 to 10, and

* and *′ each indicate a binding site to M in Formula 1H.

In Formulae 3HA to 3HF, the C₅-C₃₀ carbocyclic group and the C₁-C₃₀ heterocyclic group are each independently the same as described herein.

For example, a group represented by

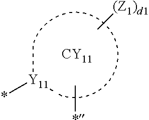

in Formula 3HD may be a group represented by one of Formulae CY11-1 to CY11-34, and/or

a group represented by

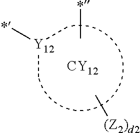

in Formulae 3HC and 3HD may be a group represented by one of Formulae CY12-1 to CY12-34:

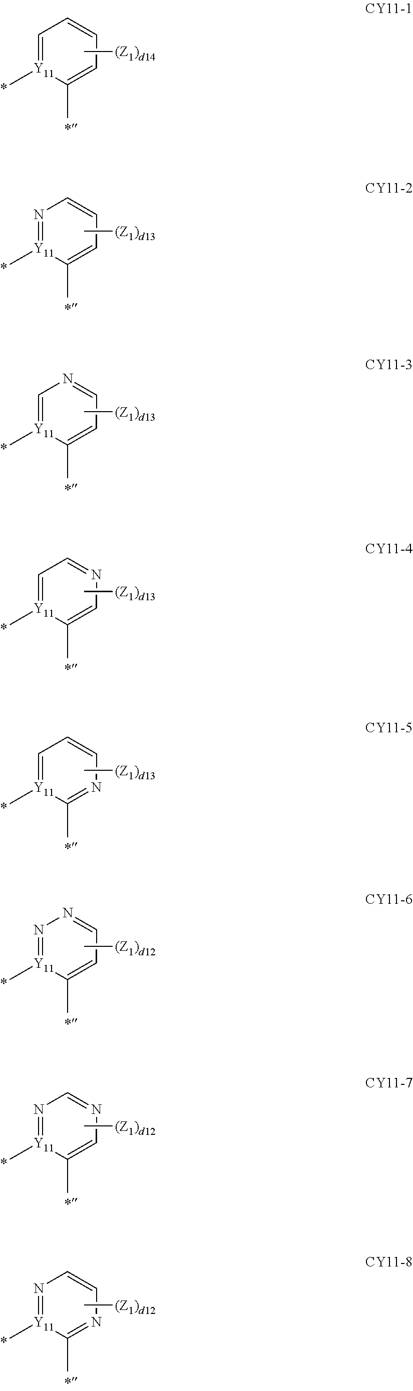

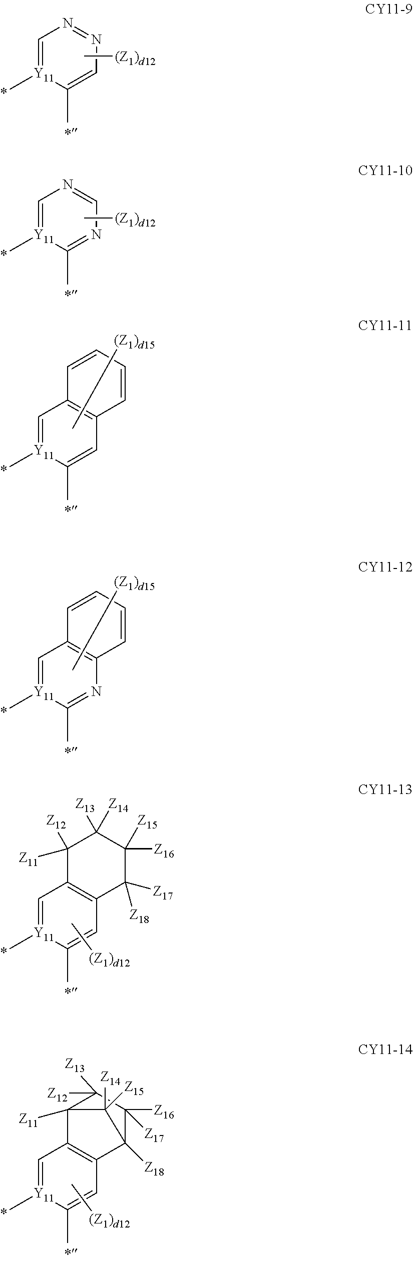

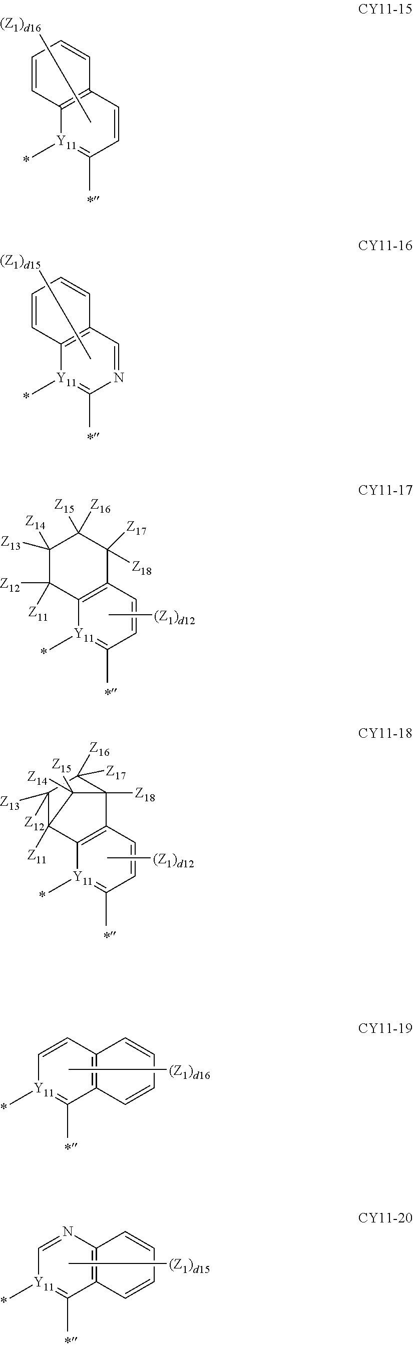

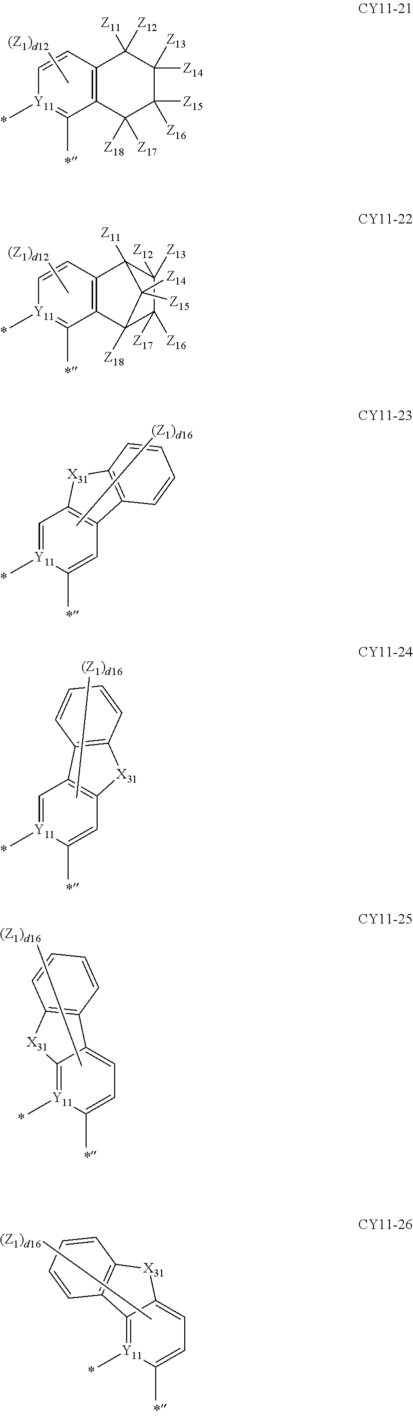

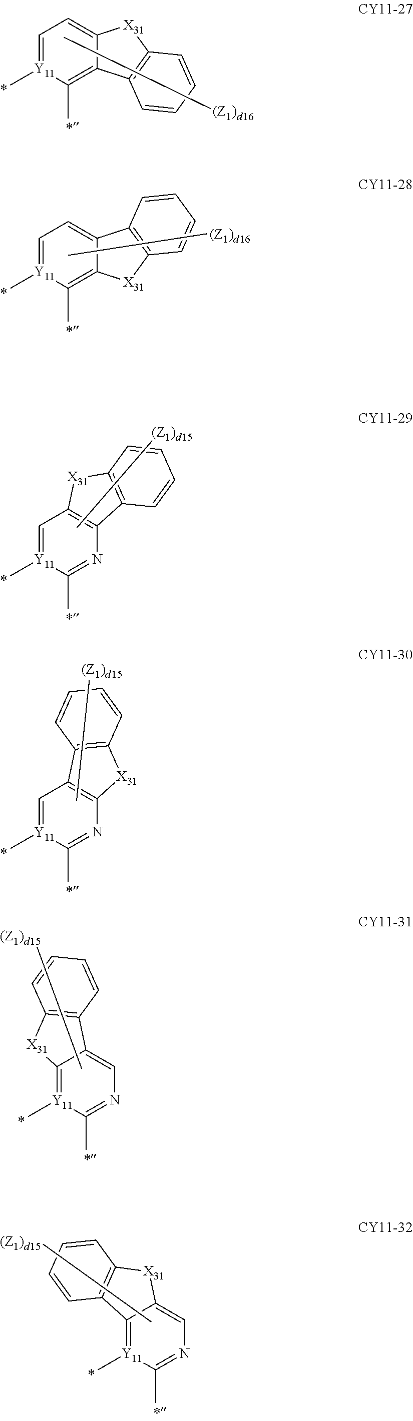

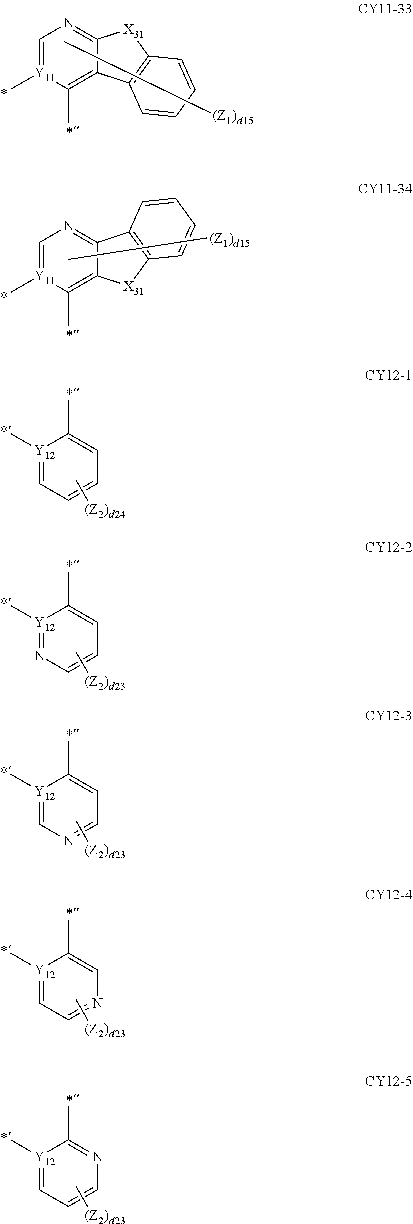

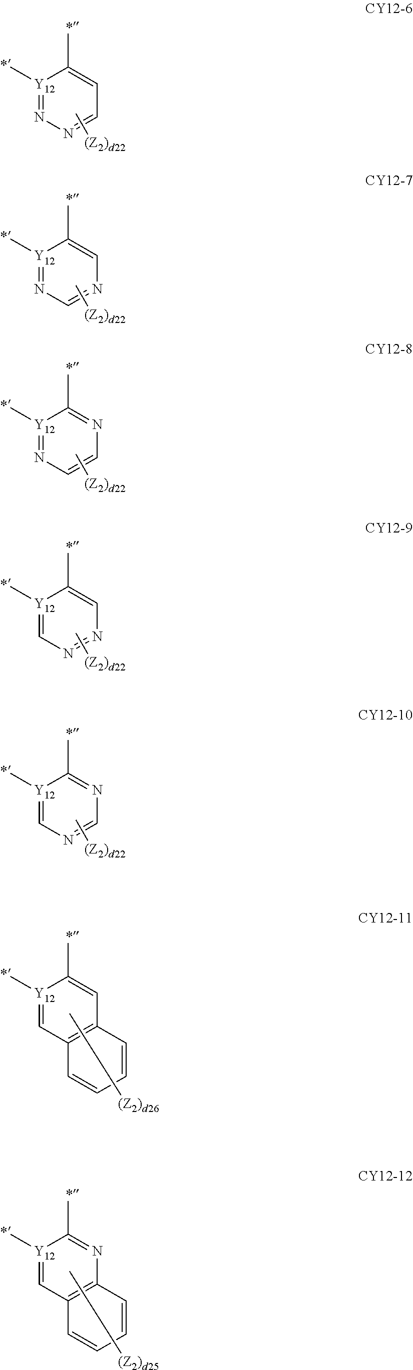

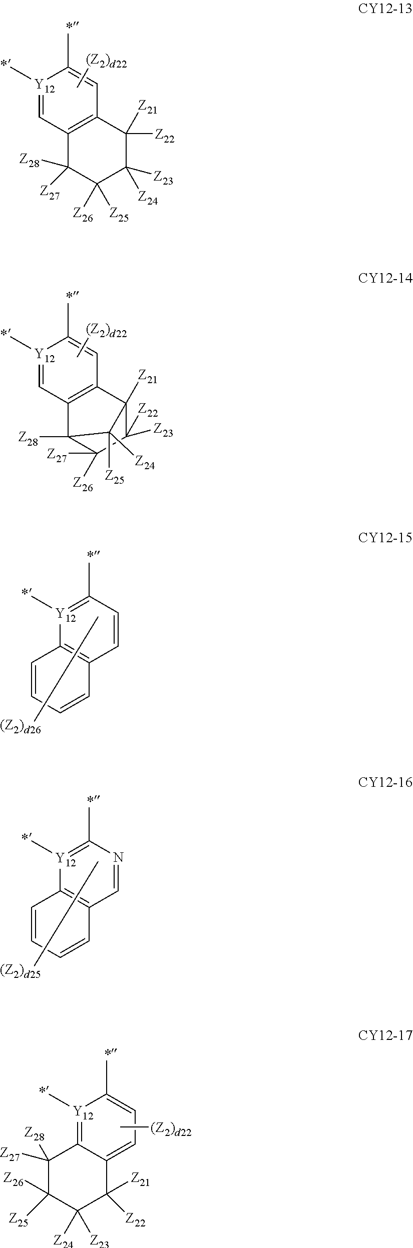

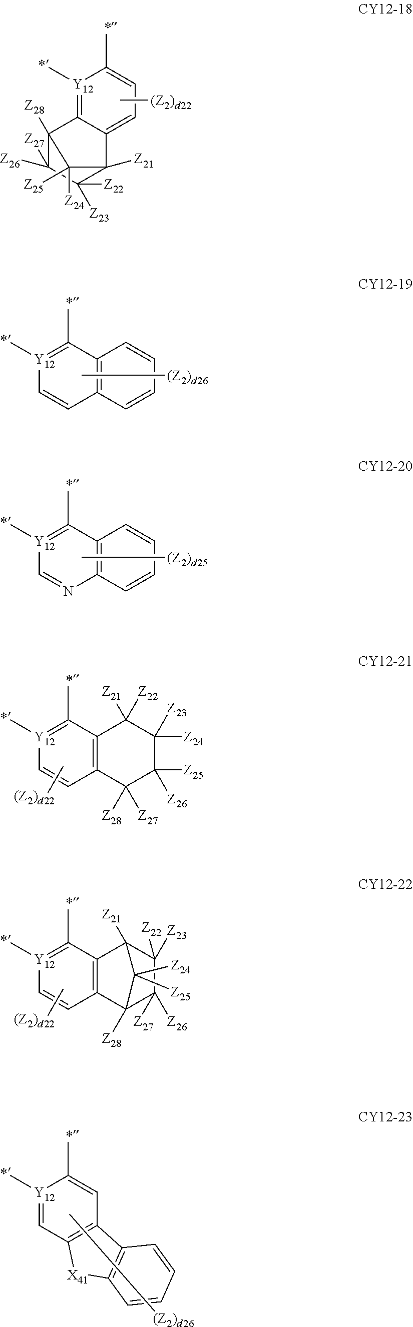

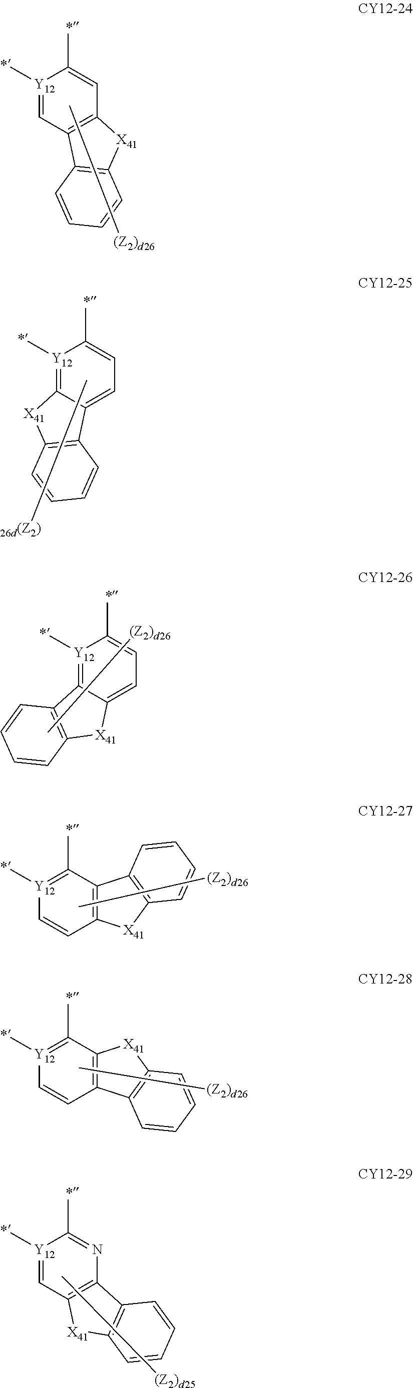

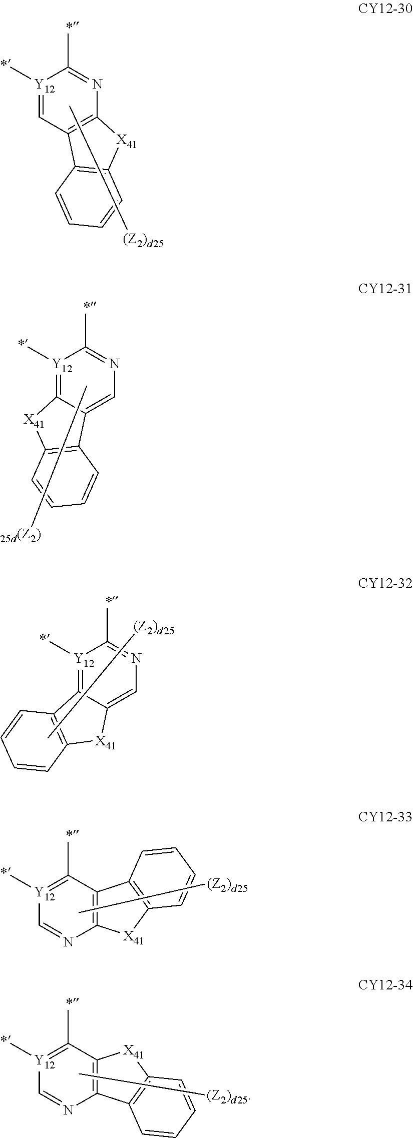

In Formulae CY11-1 to CY11-34 and CY12-1 to CY12-34,

X₃₁ may be O, S, C(Z₁₁)(Z₁₂), or Si(Z₁₁)(Z₁₂),

X₄₁ may be O, S, N(Z₂₁), C(Z₂₁)(Z₂₂), or Si(Z₂₁)(Z₂₂),

Y₁₁, Y₁₂, Z₁, and Z₂ are each independently the same as described in Formula 1H,

Z₁₁ to Z₁₈ and Z₂₁ to Z₂₈ are each independently the same as described in connection with R₂₁ in Formula 1H,

d12 and d22 may each independently be an integer from 0 to 2,

d13 and d23 may each independently be an integer from 0 to 3,

d14 and d24 may each independently be an integer from 0 to 4,

d15 and d25 may each independently be an integer from 0 to 5,

d16 and d26 may each independently be an integer from 0 to 6, and

in Formulae CY11-1 to CY11-34 and CY12-1 to CY12-34, * and *′ each indicate a binding site to M in Formula 1H, and *″ indicates a binding site to a neighboring atom in Formula 3HC or a binding site to T₂₁ in Formula 3HD.

In an embodiment, in Formula 1H, L₂ may be a group represented by one of Formulae 3-1(1) to 3-1(66) and 3-1(301) to 3-1(309), but embodiments of the present disclosure are not limited thereto:

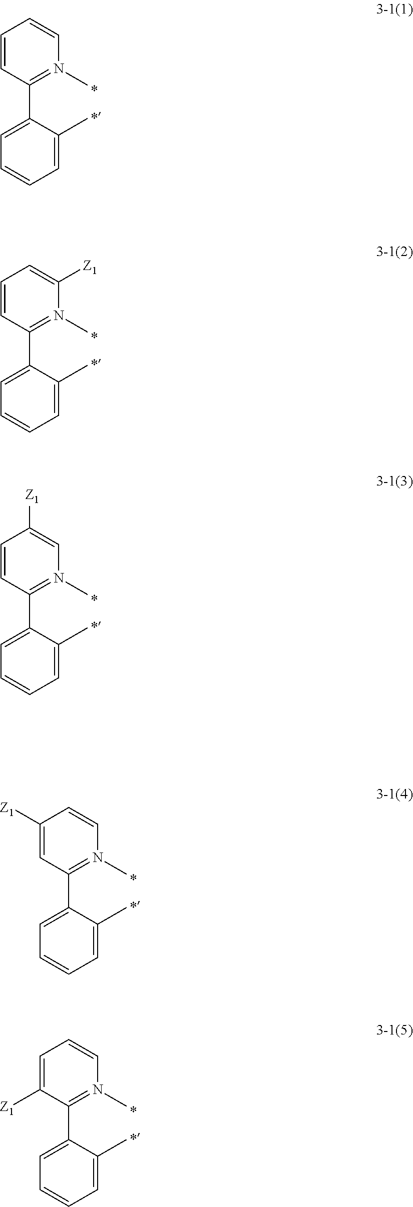

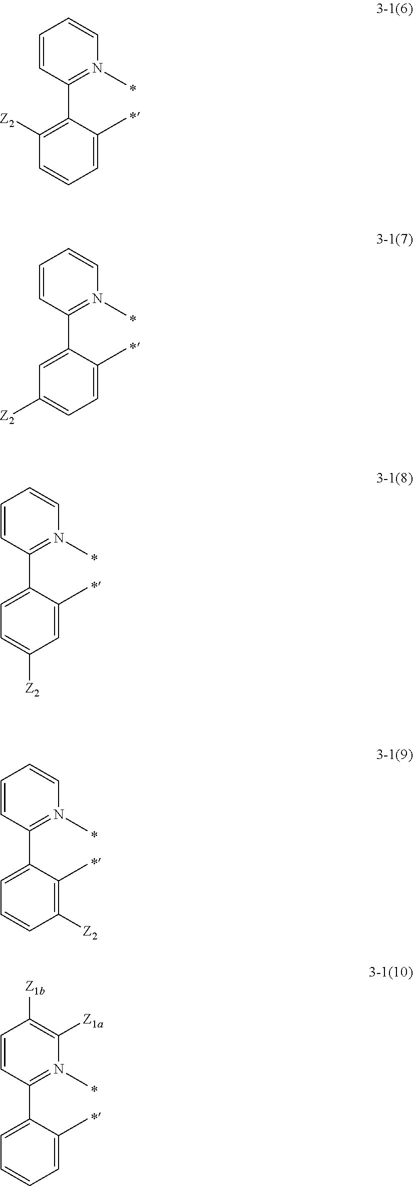

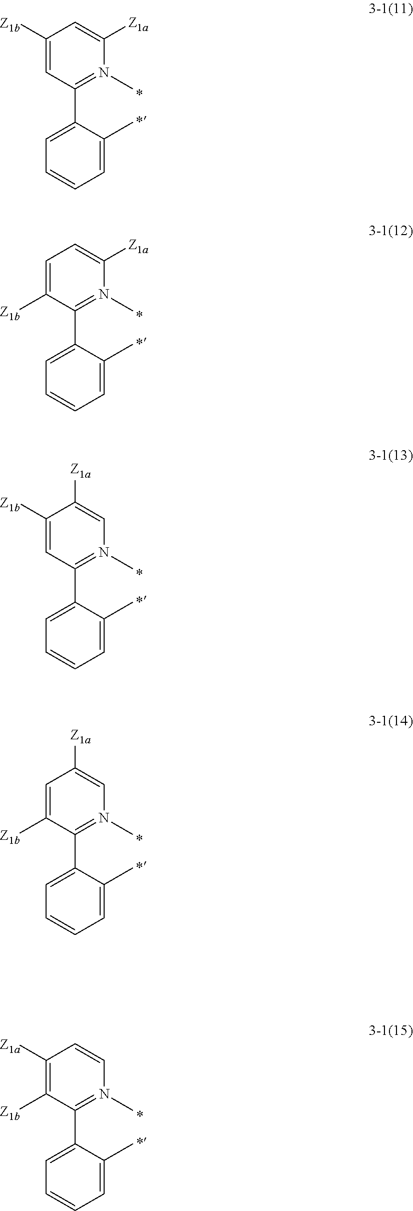

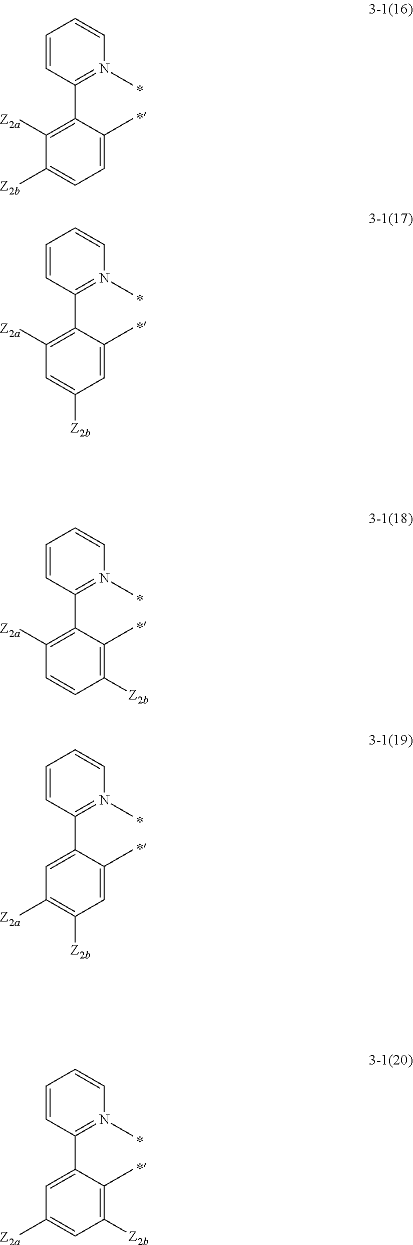

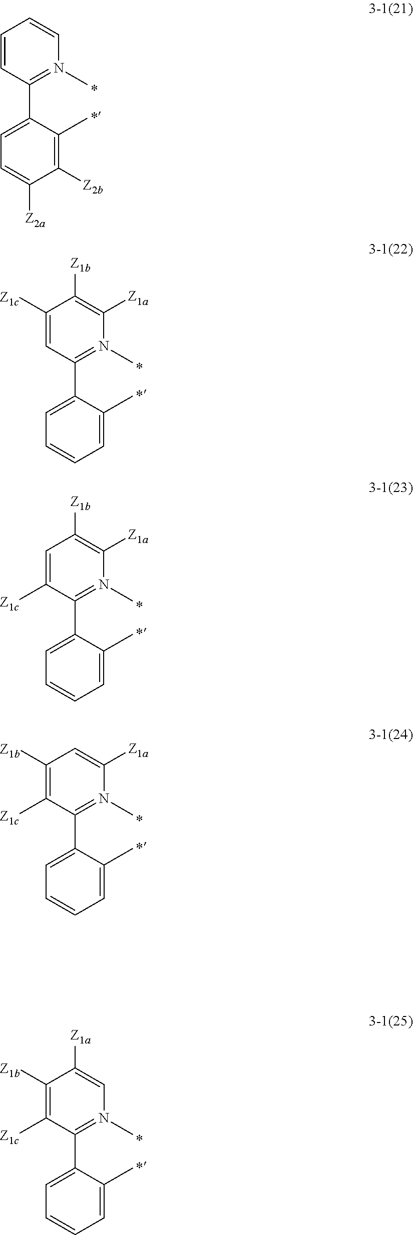

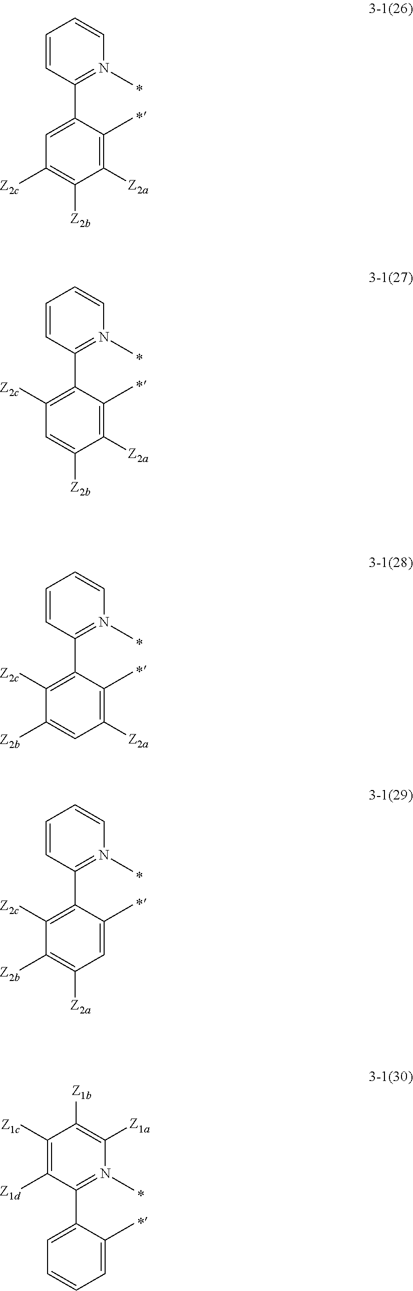

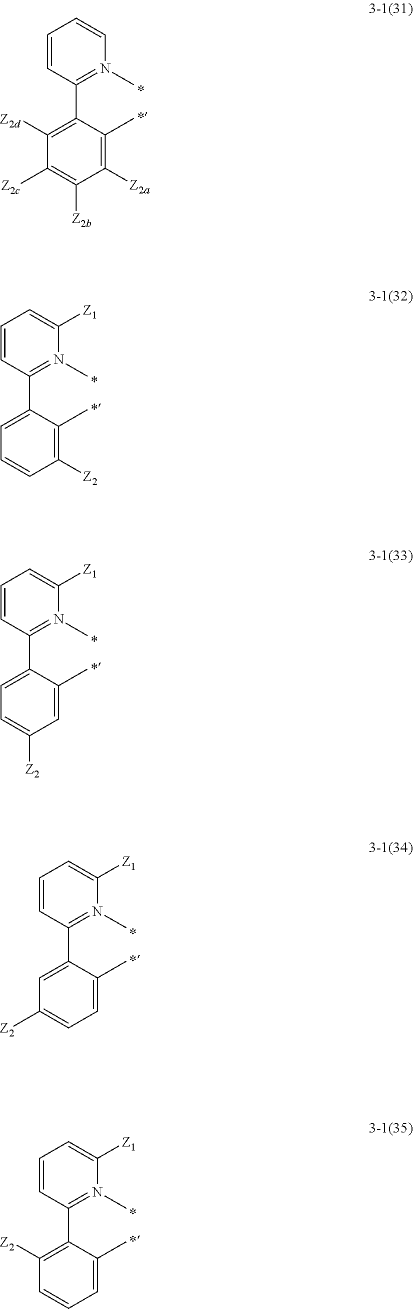

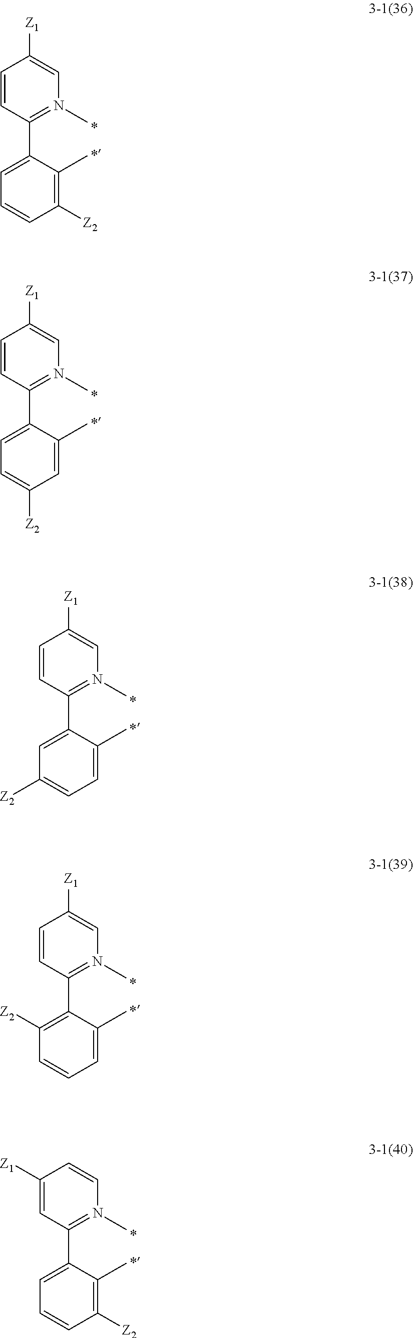

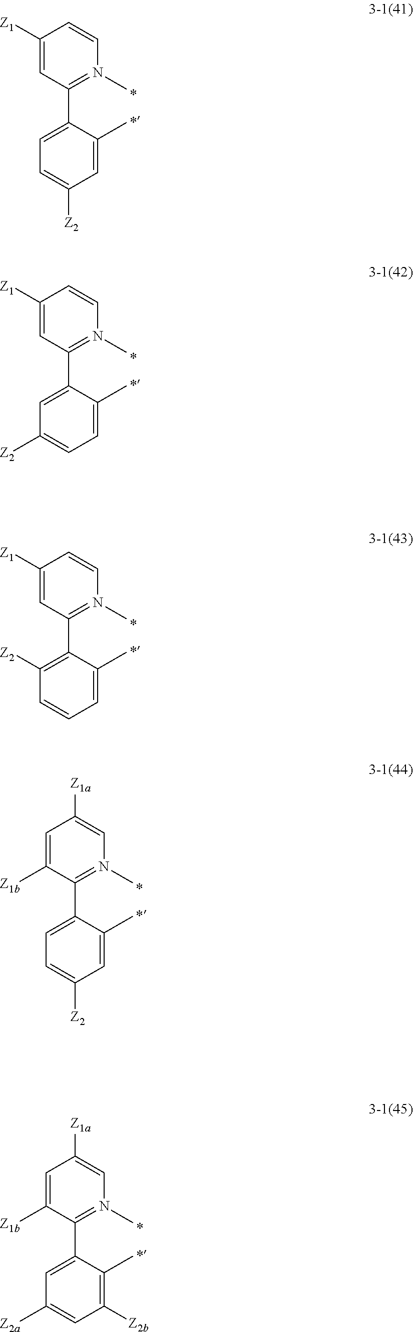

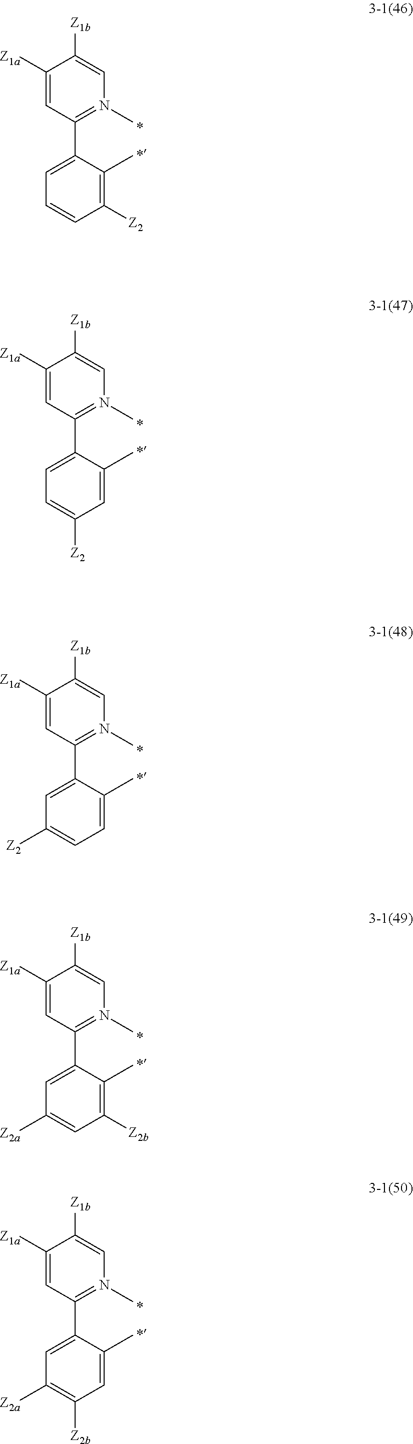

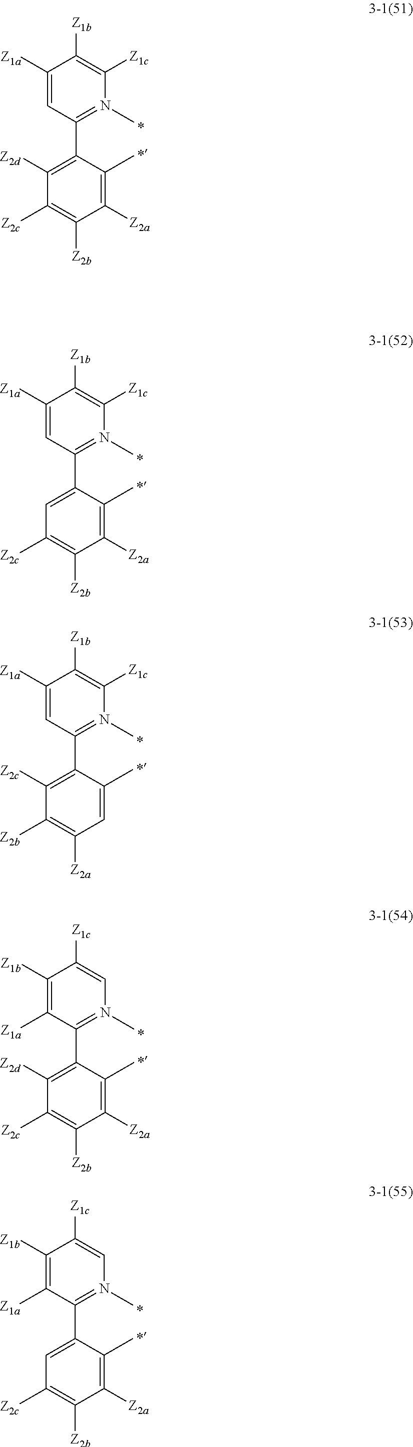

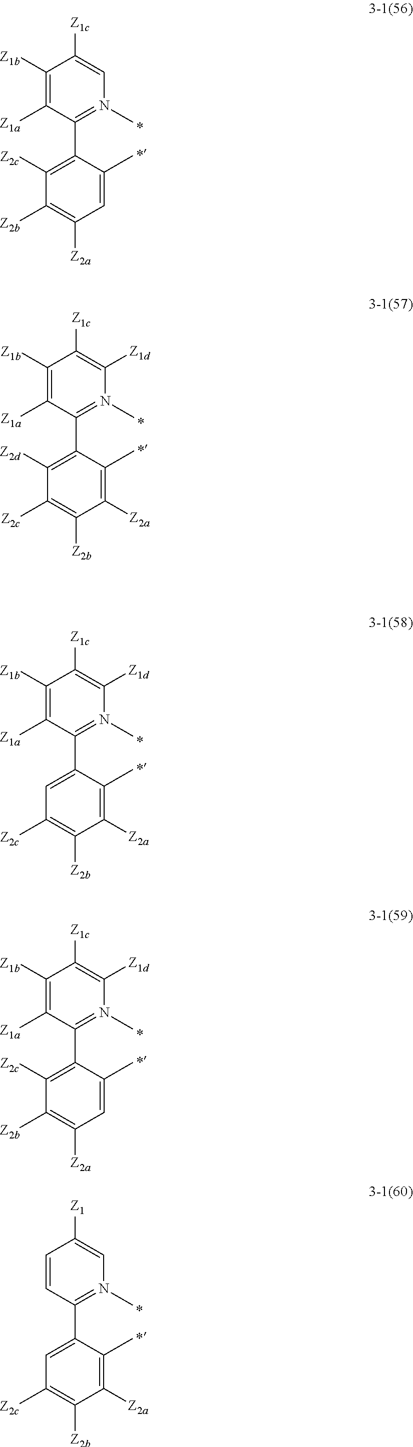

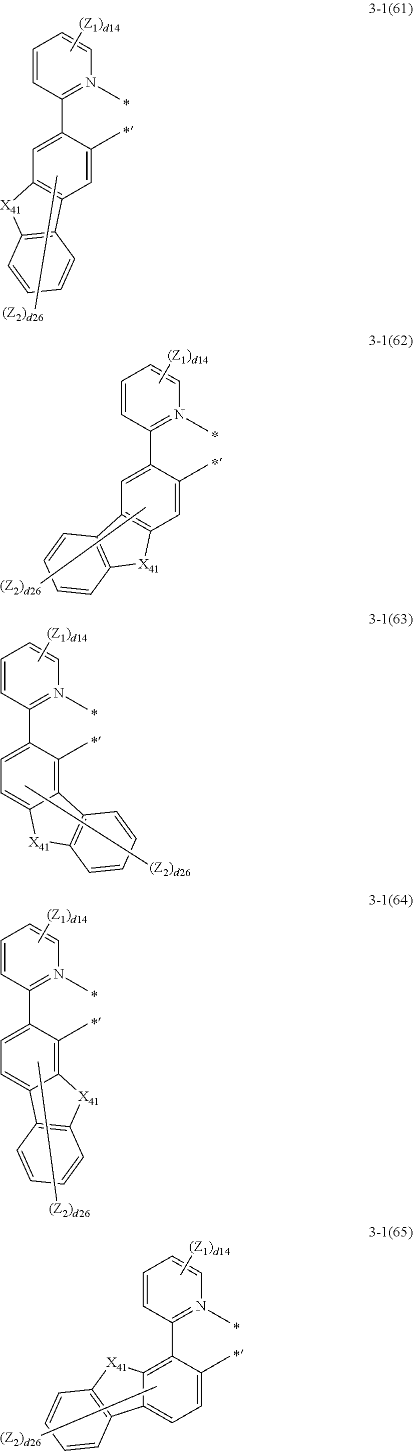

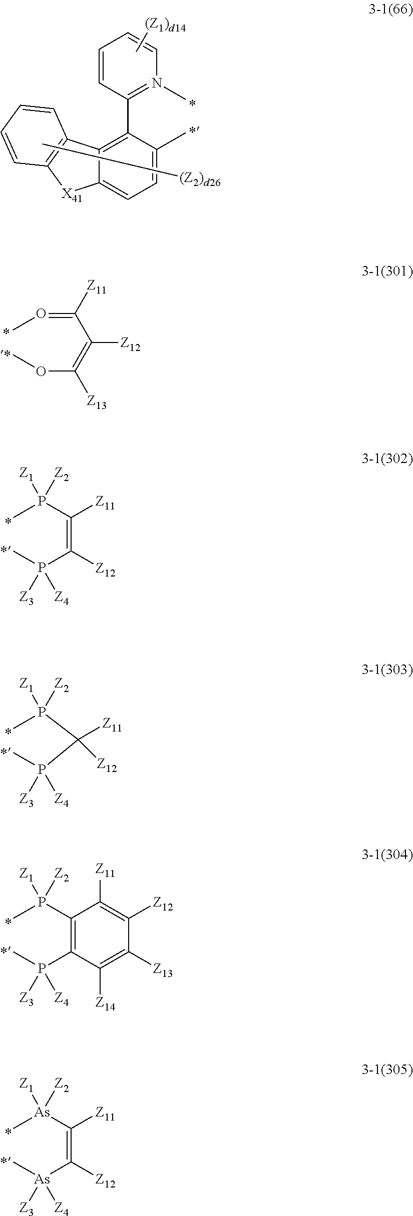

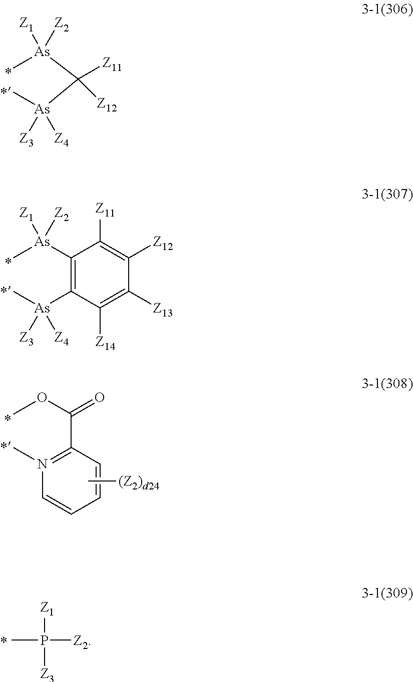

In Formulae 3-1(1) to 3-1(66) and 3-1(301) to 3-1(309),

X₄₁ may be O, S, N(Z₂₁), C(Z₂₁)(Z₂₂), or Si(Z₂₁)(Z₂₂),

Z₁ to Z₄, Z₁ₐ, Z_{1b}, Z_{1c}, Z_{1d}, Z₂ₐ, Z_{2b}, Z_{2c}, Z_{2d}, and Z₁₁ to Z₁₄ are each independently the same as described in connection with R₂₁ in Formula 1H,

d14 and d24 may each independently be an integer from 0 to 4,

d26 may be an integer from 0 to 6, and

* and *′ each indicate a binding site to M in Formula 1H.

Description of Formulae 1I to 1K

The organometallic compound may be represented by one of Formulae 1I to 1K:

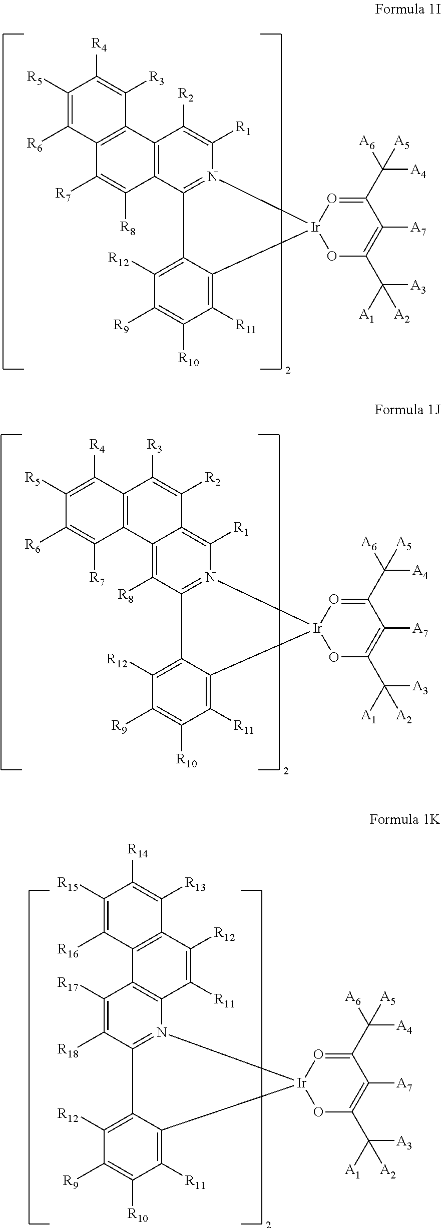

In Formulae 1I to 1K, R₁ to R₁₂ and A₇ may each independently be hydrogen, deuterium, —F, —Br, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), wherein Q₁ to Q₉ are each independently the same as described herein.

In an embodiment, R₁ to R₁₂ and A₇ of Formulae 1I to 1K may each independently be,

hydrogen, deuterium, —F, or a cyano group; or

a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, or a dibenzothiophenyl group, each unsubstituted or substituted with deuterium, —F, a cyano group, a C₁-C₂₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a phenyl group, a biphenyl group, a terphenyl group, a naphthyl group, a pyridinyl group, a pyrimidinyl group, a carbazolyl group, a fluorenyl group, a dibenzosilolyl group, a dibenzofuranyl group, a dibenzothiophenyl group, or any combination thereof.

At least one of R₁ to R₁₂ of Formulae 1I to 1K (for example, one or two of R₁ to R₁₂) may each independently be —F or a fluorinated C₁-C₆₀ alkyl group.

In an embodiment, at least one of R₁ to R₈ of Formulae 1I to 1K (for example, one or two of R₁ to R₈) may each independently be —F or a fluorinated C₁-C₂₀ alkyl group.

In an embodiment, at least one of R₁ to R₁₂ of Formulae 1I to 1K may each independently be:

—F; or

a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each substituted with at least one —F.

In an embodiment, at least one of R₂ to R₈ of Formulae 1I to 1K (for example, one or two of R₂ to R₈) may each independently be —F or a fluorinated C₁-C₆₀ alkyl group.

In an embodiment, at least one of R₄ to R₈ of Formulae 1I to 1K (for example, one or two of R₄ to R₈) may each independently be —F or a fluorinated C₁-C₆₀ alkyl group.

In an embodiment, in Formulae 1I to 1K,

i) R₂ may be —F or a fluorinated C₁-C₆₀ alkyl group and R₁ and R₃ to R₈ may be hydrogen;

ii) R₃ may be —F or a fluorinated C₁-C₆₀ alkyl group and R₁, R₂ and R₄ to R₈ may be hydrogen;

iii) R₄ may be —F or a fluorinated C₁-C₆₀ alkyl group and R₁ to R₃ and R₅ to R₈ may be hydrogen;

iv) R₅ may be —F or a fluorinated C₁-C₆₀ alkyl group and R₁ to R₄ and R₆ to R₈ may be hydrogen;

v) R₆ may be —F or a fluorinated C₁-C₆₀ alkyl group and R₁ to R₅, R₇ and R₈ may be hydrogen;

vi) R₇ may be —F or a fluorinated C₁-C₆₀ alkyl group and R₁ to R₆ and R₈ may be hydrogen;

vii) R₈ may be —F or a fluorinated C₁-C₆₀ alkyl group and R₁ to R₇ may be hydrogen; or

R₄ may be —F or a fluorinated C₁-C₆₀ alkyl group, R₅ may be a C₁-C₆₀ alkyl group and R₁ to R₃ and R₆ to R₈ may be hydrogen.

In one or more embodiments, in Formulae 1I to 1K, R₉ and R₁₁ may not be hydrogen.

In one or more embodiments, in Formulae 1I to 1K, R₉ and R₁₁ may not be hydrogen, and R₁₀ and R₁₂ may be hydrogen.

In one or more embodiments, in Formulae 1I to 1K, R₉ and R₁₁ may be identical to each other.

In one or more embodiments, in Formulae 1I to 1K, R₉ and R₁₁ may be different from each other.

In one or more embodiments, in Formulae 1I to 1K, R₉ and R₁₁ may be different from each other, and the number of carbon atoms included in R₉ may be different from the number of carbon atoms included in R₁₁.

In one or more embodiments, in Formulae 1I to 1K, R₉ and R₁₁ may each independently be a substituted or unsubstituted C₁-C₆₀ alkyl group, or a substituted or unsubstituted C₃-C₁₀ cycloalkyl group.

In one or more embodiments, in Formulae 1I to 1K,

R₁ to R₁₂ and A₇ may each independently be hydrogen, deuterium, —F, a cyano group, a nitro group, —SF₅, —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, a group represented by any one of Formulae 9-1 to 9-66 in which at least one hydrogen is substituted with —F, a group represented by any one of Formulae 10-1 to 10-118, a group represented by any one of Formulae 10-1 to 10-118 in which at least one hydrogen is substituted with deuterium, a group represented by any one of Formulae 10-1 to 10-118 in which at least one hydrogen is substituted with —F, a group represented by any one of Formulae 10-201 to 10-342, a group represented by any one of Formulae 10-201 to 10-342 in which at least one hydrogen is substituted with deuterium, a group represented by any one of Formulae 10-201 to 10-342 in which at least one hydrogen is substituted with —F, or —Si(Q₃)(Q₄)(Q₅) (wherein Q₃ to Q₅ are the same as described herein), and/or

at least one of R₁ to R₁₂ may each independently be —F, —CF₃, —CF₂H, —CFH₂, or a group represented by any one of Formulae 9-1 to 9-66 in which at least one hydrogen is substituted with —F.

Above Formulae 9-1 to 9-66, 10-1 to 10-118 and 10-201 to 10-342 are the same as described in connection with Formula 1A.

In Formulae 1I to 1K, A₁ to A₆ may each independently be hydrogen, deuterium, —F, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, or a substituted or unsubstituted monovalent non-aromatic condensed heteropolycyclic group.

Formulae 1I to 1K may satisfy Condition 1I, Condition 2I, or any combination thereof:

Condition 1I

At least one of A₁ and A₄ includes at least two carbon atoms.

Condition 2I

A₁ to A₆ include at least one carbon atom.

In one or more embodiments, Formulae 1I to 1K may satisfy Condition 1(1)I, Condition 2(1)I, or any combination thereof:

Condition 1 (1)I

At least one of A₁ and A₄ may each independently be an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with deuterium, —F, a cyano group, a C₁-C₂₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, or any combination thereof.

Condition 2(1)I

A₁ to A₆ may each independently be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, or a bicyclo[2.2.2]octyl group, each unsubstituted or substituted with deuterium, —F, a cyano group, a C₁-C₂₀ alkyl group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, or any combination thereof.

In one or more embodiments, Formulae 1I to 1K may satisfy Condition 1(2)I, Condition 2(2)I, or any combination thereof:

Condition 1(2)I

At least one of A₁ and A₄ may each independently be a group represented by any one of Formulae 9-1 to 9-66, a group represented by any one of Formulae 9-1 to 9-66 in which at least one hydrogen is substituted with deuterium, or a group represented by any one of Formulae 9-1 to 9-66 in which at least one hydrogen is substituted with —F.

Condition 2(2)I

A₁ to A₆ may each independently be —CH₃, —CD₃, —CD₂H, —CDH₂, —CF₃, —CF₂H, —CFH₂, a group represented by any one of Formulae 9-1 to 9-66, a group represented by any one of Formulae 9-1 to 9-66 in which at least one hydrogen is substituted with deuterium, or a group represented by any one of Formulae 9-1 to 9-66 in which at least one hydrogen is substituted with —F.

Above Formulae 9-1 to 9-66 are the same as described in connection with Formula 1A.

In one or more embodiments, A₇ in Formulae 1I to 1K may not be hydrogen.

In one or more embodiments, A₇ in Formulae 1I to 1K may be hydrogen, a substituted or unsubstituted C₁-C₆₀ alkyl group, a substituted or unsubstituted C₃-C₁₀ cycloalkyl group, a phenyl group or a biphenyl group.

In one or more embodiments, in Formulae 1I to 1K, a group represented by *—C(A₁)(A₂)(A₃) and a group represented by *—C(A₄)(A₅)(A₆) may be identical to each other, and * indicates a binding site to a neighboring atom.

In one or more embodiments, in Formulae 1I to 1K a group represented by *—C(A₁)(A₂)(A₃) and a group represented by *—C(A₄)(A₅)(A₆) may be different from each other, and * indicates a binding site to a neighboring atom.

In Formulae 1I to 1K, 1) two or more of R₁ to R₁₂ may optionally be linked to form a C₅-C₃₀ carbocyclic group unsubstituted or substituted with at least one R₁ₐ or a C₁-C₃₀ heterocyclic group unsubstituted or substituted with at least one R₁ₐ, and/or 2) two or more of A₁ to A₇ may optionally be linked to form a C₅-C₃₀ carbocyclic group unsubstituted or substituted with at least one R₁ₐ or a C₁-C₃₀ heterocyclic group unsubstituted or substituted with at least one R₁ₐ. Here, R₁ₐ is the same as defined in connection with R₇ of Formula 1I.

In an embodiment, i) two or more of A₁ to A₃ (for example, all of A₁ to A₃) in Formulae 1I to 1K may be linked to form a C₅-C₃₀ carbocyclic group unsubstituted or substituted with at least one R₁ₐ or a C₁-C₃₀ heterocyclic group unsubstituted or substituted with at least one R₁ₐ (that is, a group represented by *—C(A₁)(A₂)(A₃) may be a C₅-C₃₀ carbocyclic group unsubstituted or substituted with at least one R₁ₐ or a C₁-C₃₀ heterocyclic group unsubstituted or substituted with at least one R₁ₐ), and/or ii) two or more of A₄ to A₆ (for example, all of A₄ to A₆) in Formulae 1I to 1K may be linked to form a C₅-C₃₀ carbocyclic group unsubstituted or substituted with at least one R₁ₐ or a C₁-C₃₀ heterocyclic group unsubstituted or substituted with at least one R₁ₐ (that is, a group represented by *—C(A₄)(A₅)(A₆) may be a C₅-C₃₀ carbocyclic group unsubstituted or substituted with at least one R₁ₐ or a C₁-C₃₀ heterocyclic group unsubstituted or substituted with at least one R₁ₐ).

As described above, since the organometallic compound satisfies Condition 1 related to the PMI diagram and a radiative decay rate of 2.5×10⁵ s⁻¹ or more at the “same time”, internal quantum emission efficiency and optical orientation may be improved to provide excellent external quantum emission efficiency. Therefore, an electronic device, for example, an organic light-emitting device, which includes the organometallic compound, may have excellent quantum emission efficiency and excellent roll-off ratio, simultaneously.

Synthesis methods of the organometallic compound may be understood by one of ordinary skill in the art in view of the following embodiments.

The organometallic compound is suitable for use in an organic layer of an organic light-emitting device, for example, for use as a dopant in an emission layer of the organic layer. Thus, another aspect provides an organic light-emitting device that includes: a first electrode; a second electrode; and an organic layer that is disposed between the first electrode and the second electrode, the organic layer includes an emission layer, and the organic layer includes at least one organometallic compound described above.

The organic light-emitting device may have, due to the inclusion of an organic layer including the organometallic compound, excellent quantum emission efficiency and roll-off ratio, simultaneously.

The organometallic compound may be used between a pair of electrodes of an organic light-emitting device. For example, the organometallic compound may be included in the emission layer. In this regard, the organometallic compound may act as a dopant, and the emission layer may further include a host (that is, an amount of the organometallic compound is smaller than an amount of the host).

In one or more embodiments, the emission layer may include a host and a dopant, and the dopant may include the organometallic compound. The dopant may be a red or green phosphorescent dopant.

The expression “(an organic layer) includes at least one organometallic compounds” as used herein may include an embodiment in which “(an organic layer) includes identical organometallic compounds represented by Formula 1A” and an embodiment in which “(an organic layer) includes two or more different organometallic compounds represented by Formula 1A.”

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In an embodiment, in the organic light-emitting device, the first electrode may be an anode, the second electrode may be a cathode, and the organic layer may further include a hole transport region disposed between the first electrode and the emission layer and an electron transport region disposed between the emission layer and the second electrode, wherein the hole transport region may include a hole injection layer, a hole transport layer, an electron blocking layer, or any combination thereof, and wherein the electron transport region may include a hole blocking layer, an electron transport layer, an electron injection layer, or any combination thereof.

The term “organic layer” as used herein refers to a single layer or a plurality of layers between the first electrode and the second electrode of the organic light-emitting device. The “organic layer” may include, in addition to an organic compound, an organometallic complex including metal.

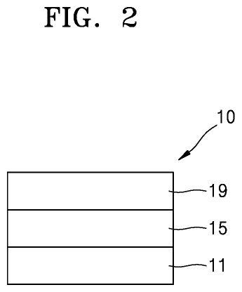

FIG. 2 is a schematic view of an organic light-emitting device 10 according to an embodiment. Hereinafter, the structure of an organic light-emitting device according to an embodiment and a method of manufacturing an organic light-emitting device according to an embodiment will be described in connection with FIG. 2. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be a material having a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), and zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include a hole injection layer, a hole transport layer, an electron blocking layer, a buffer layer, or any combination thereof.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

A hole injection layer may be formed on the first electrode 11 by using one or more suitable methods vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. For example, the deposition conditions may include a deposition temperature of about 100 to about 500° C., a vacuum pressure of about 10⁻⁸ torr to about 10⁻³ torr, and a deposition rate of about 0.01 Angstroms per second (Å/sec) to about 100 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include m-MTDATA, TDATA, 2-TNATA, NPB, 13-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), polyaniline/poly(4-styrene sulfonate) (PANI/PSS), a compound represented by Formula 201 below, a compound represented by Formula 202 below, or any combination thereof:

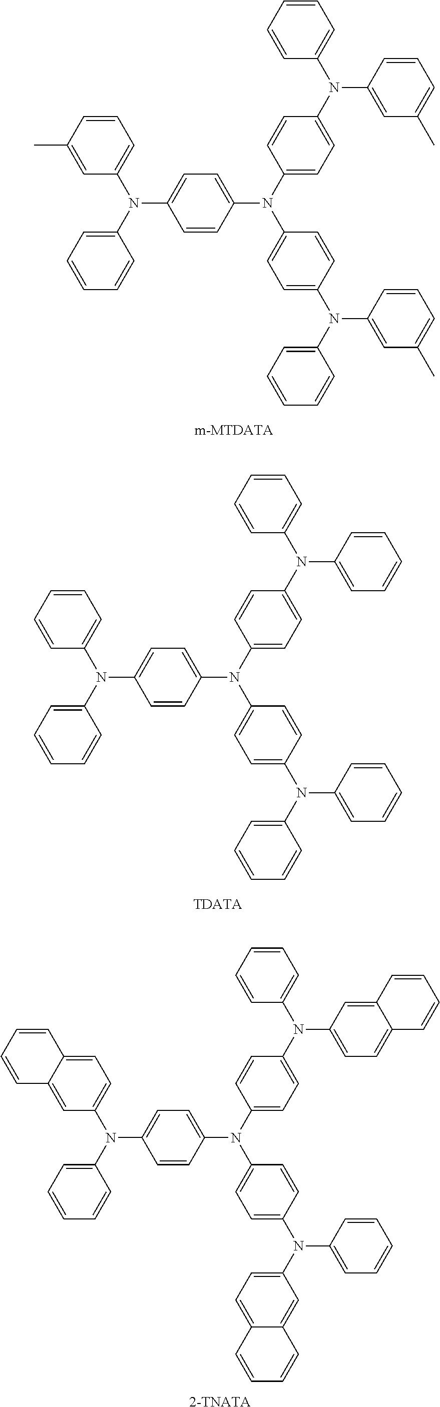

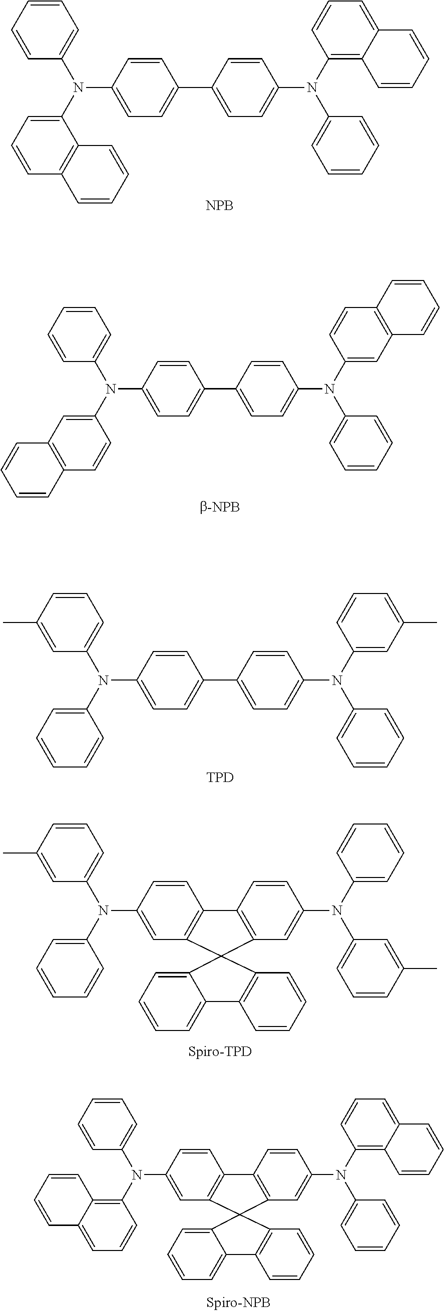

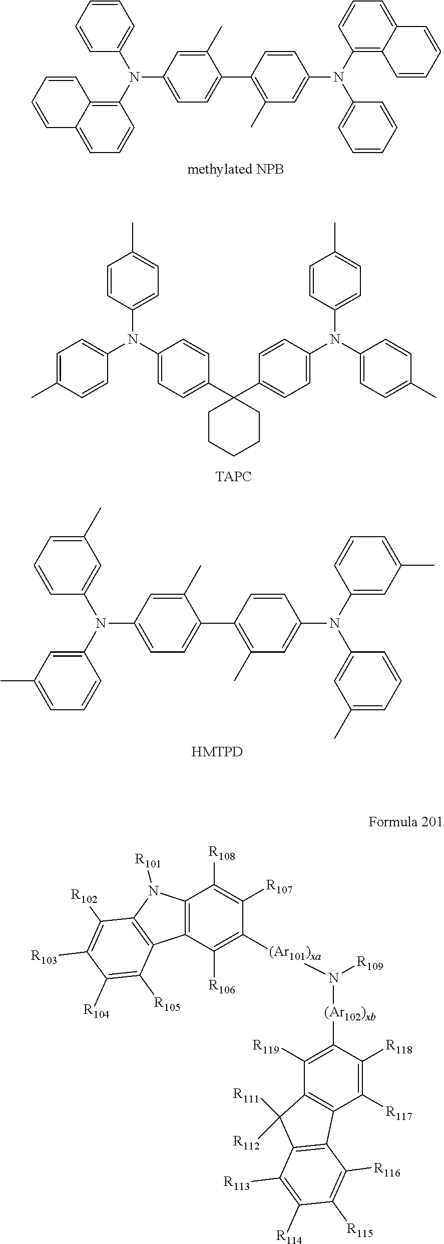

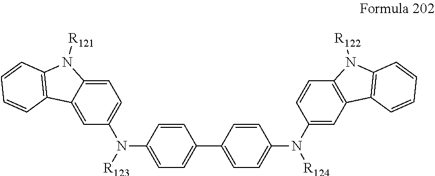

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₂-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, or any combination thereof.

In Formula 201, xa and xb may each independently be an integer from 0 to 5, or may be 0, 1, or 2. For example, xa is 1 and xb is 0, but xa and xb are not limited thereto.

In Formulae 201 and 202, R₁₀₁ to R₁₀₈, R₁₁₁ to R₁₁₉, and R₁₂₁ to R₁₂₄ may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);

a C₁-C₁₀ alkyl group or a C₁-C₁₀ alkoxy group, each substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or any combination thereof;

a phenyl group, a naphthyl group, an anthracenyl group, a fluorenyl group, or a pyrenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or any combination thereof,

but embodiments of the present disclosure are not limited thereto.

In Formula 201, R₁₉₉ may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or any combination thereof.

In an embodiment, the compound represented by Formula 201 may be represented by Formula 201A, but embodiments of the present disclosure are not limited thereto:

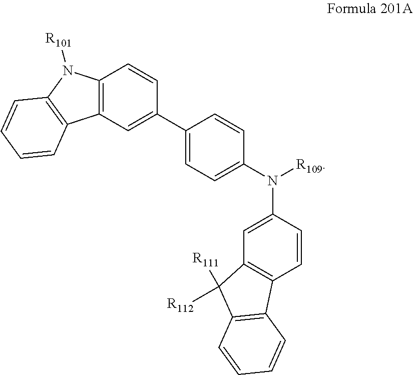

In Formula 201A, R₁₀₁, R₁₁₁, R₁₁₂, and R₁₀₉ are each independently the same as described above.

For example, the hole transport region may include at least one of Compounds HT1 to HT21, but are not limited thereto:

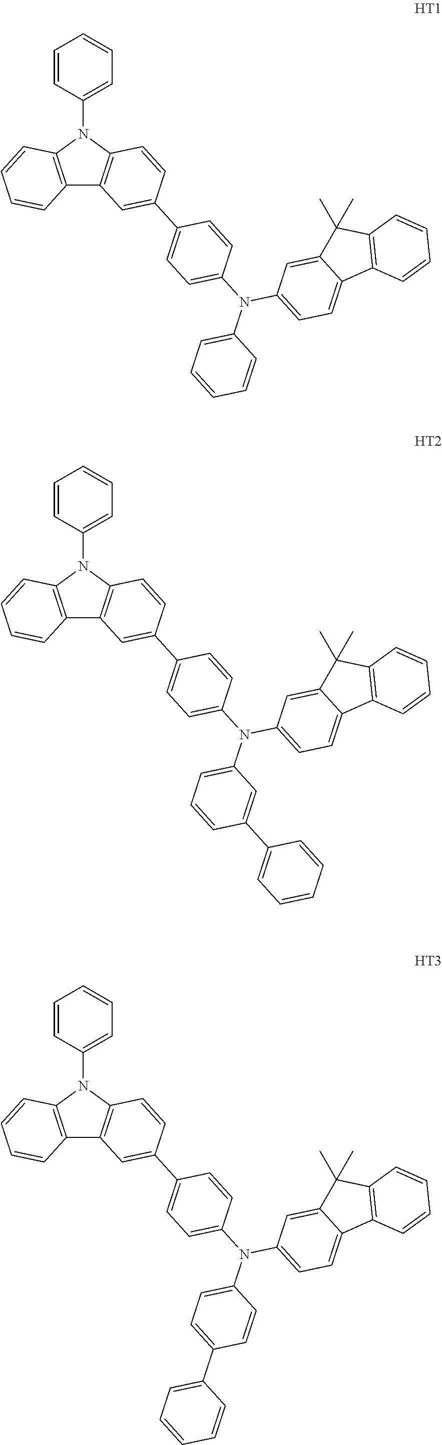 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

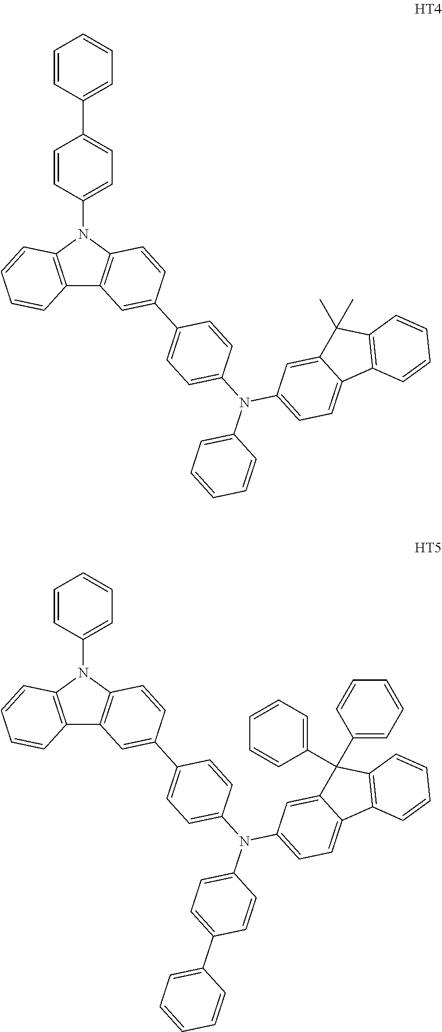 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

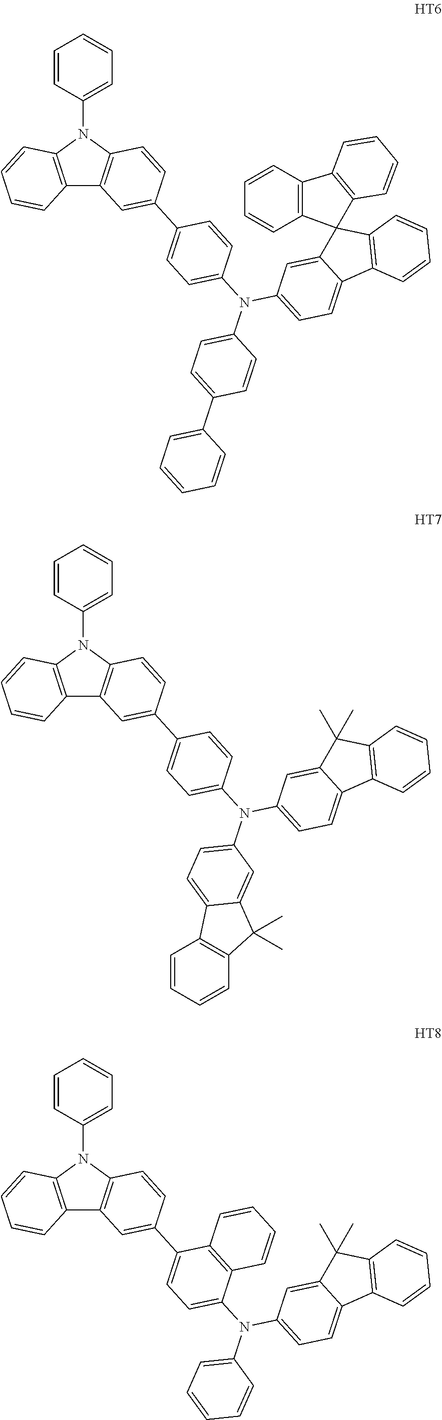 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

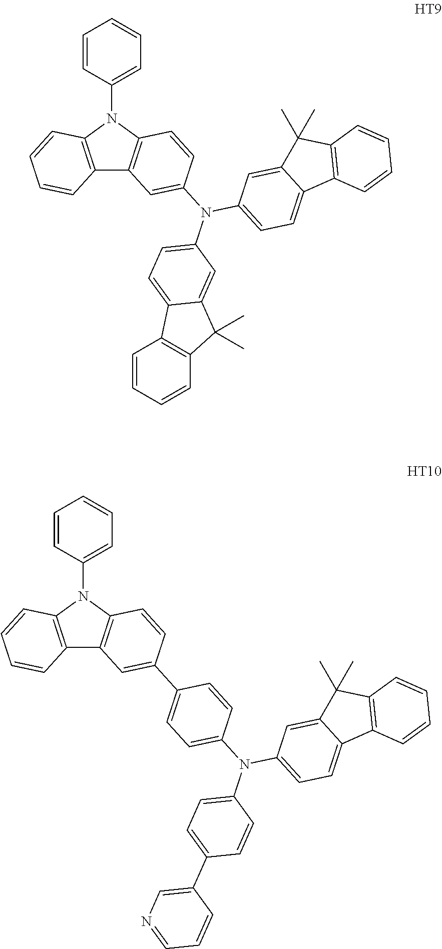 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

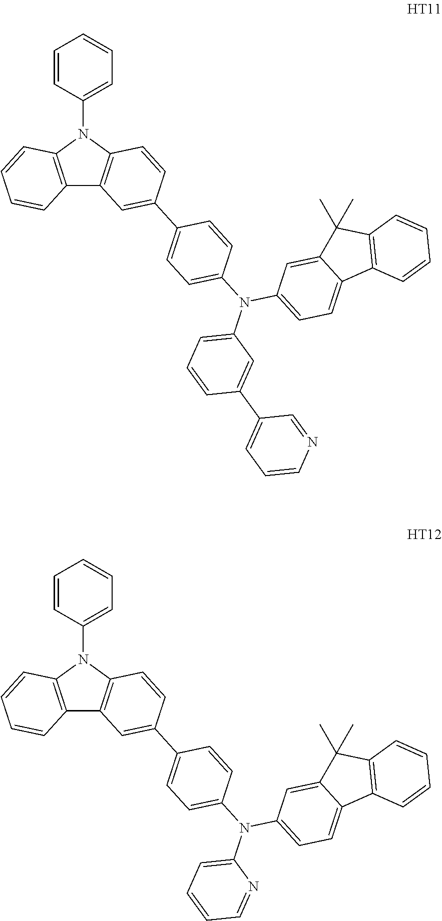 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

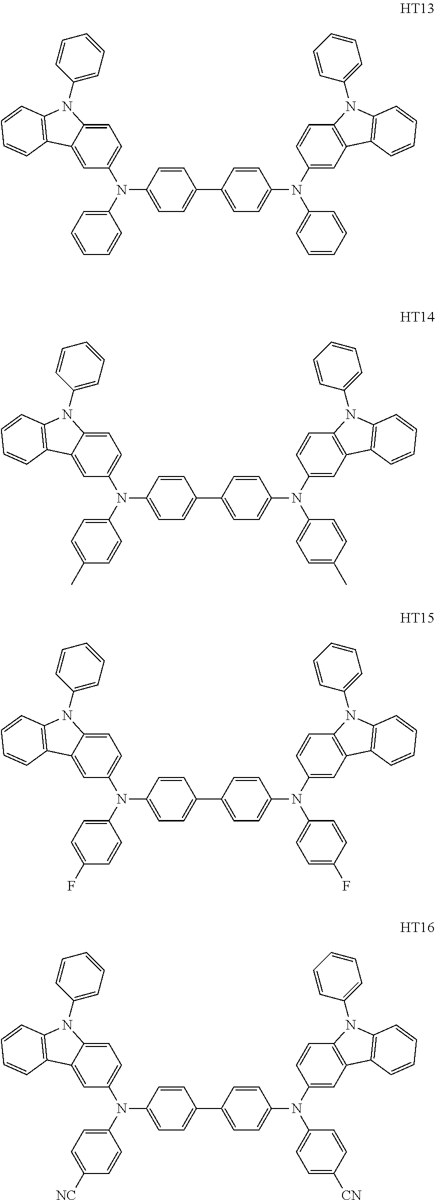 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

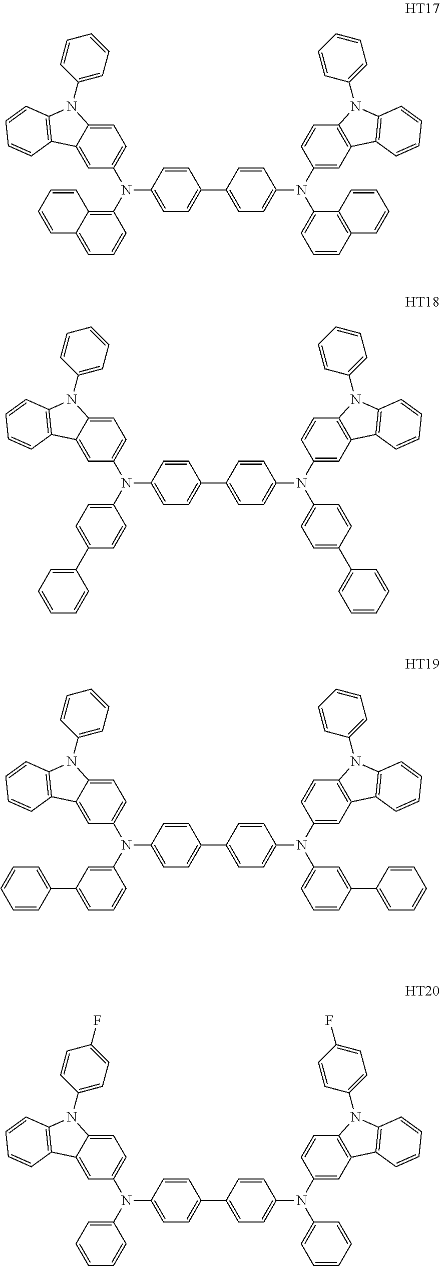 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

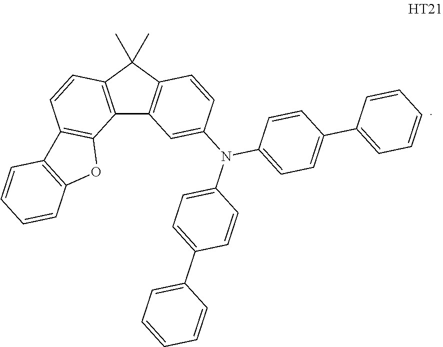 [SMILES: CC1(C)c2ccc(N(c3ccc(-c4ccccc4)cc3)c3ccc(-c4ccccc4)cc3)cc2-c2c1ccc1c2oc2ccccc21]

A thickness of the hole transport region may be in a range of about 100 Angstroms (Å) to about 10,000 Å, for example, about 100 Å to about 1,000 Å. When the hole transport region includes at least one of a hole injection layer and a hole transport layer, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1,500 Å. While not wishing to be bound by theory, it is understood that when the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one a quinone derivative, a metal oxide, a cyano group-containing compound, or any combination thereof, but embodiments of the present disclosure are not limited thereto. Non-limiting examples of the p-dopant are a quinone derivative, such as tetracyanoquinodimethane (TCNQ), 2,3,5,6-tetrafluoro-tetracyano-1,4-benzoquinodimethane (F4-TCNQ), or F6-TCNNQ; a metal oxide, such as a tungsten oxide or a molybdenum oxide; a cyano group-containing compound, such as Compound HT-D1; or any combination thereof but are not limited thereto:

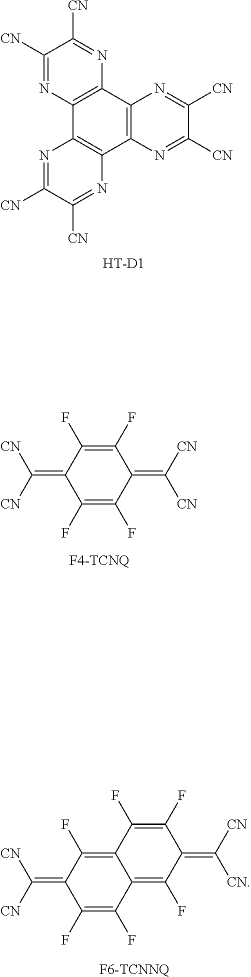

The hole transport region may include a buffer layer.

Also, the buffer layer may compensate for an optical resonance distance according to a wavelength of light emitted from the emission layer, and thus, efficiency of a formed organic light-emitting device may be improved.

Meanwhile, when the hole transport region includes an electron blocking layer, a material for the electron blocking layer may be materials for the hole transport region described above and materials for a host to be explained later. However, the material for the electron blocking layer is not limited thereto. For example, when the hole transport region includes an electron blocking layer, a material for the electron blocking layer may be mCP, Compound H21, or any combination thereof.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

The emission layer may include a host and a dopant, and the dopant may include the organometallic compound satisfying both Condition 1 and the radiative decay rate described herein.

The host may include at least one TPBi, TBADN, ADN (also referred to as “DNA”), CBP, CDBP, TCP, mCP, Compound H50, Compound H51, Compound H52, or any combination thereof:

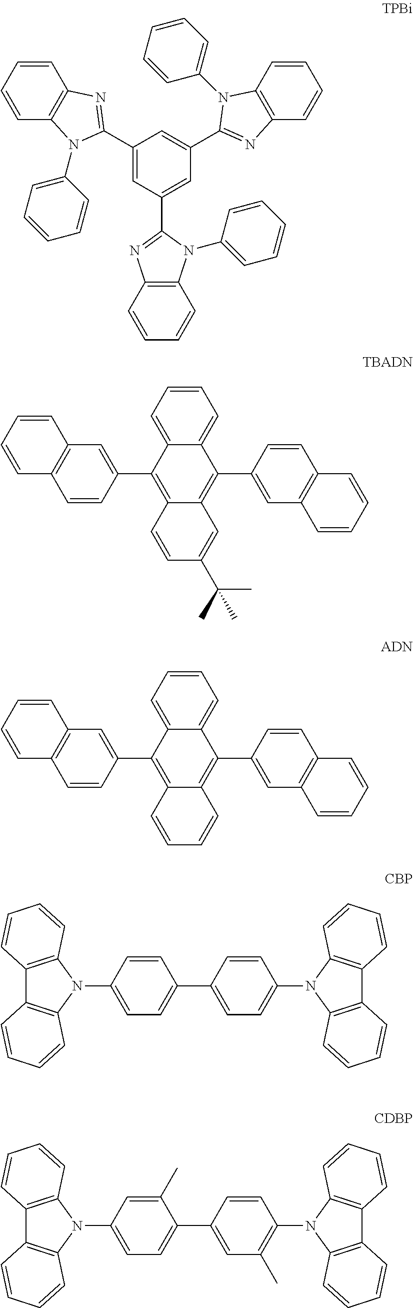

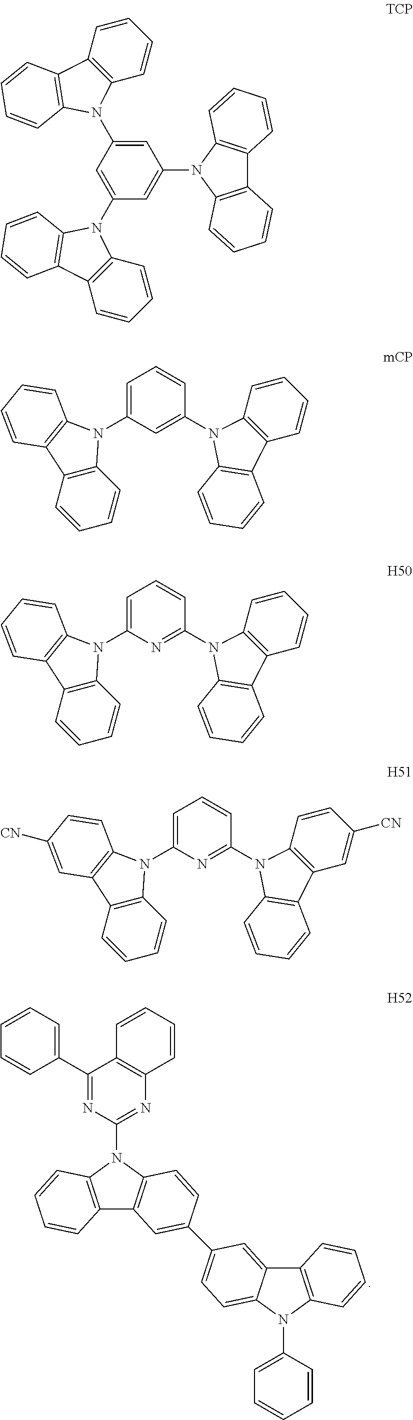

In one or more embodiments, the host may include a carbazole group, a fluorene group, a spiro-bifluorene group, a dibenzofuran group, a dibenzothiophene group, a dibenzosilole group, an indenocarbazole group, an indolocarbazole group, a benzofurocarbazole group, a benzothienocarbazole group, an acridine group, a dihydroacridine group, a triindolobenzene group, an azadibenzofuran group, an azadibenzothiophene group, an azacarbazole group, an azafluorene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a phenazine group, a cinnoline group, a cyano group, a phosphine oxide group, a sulfoxide group, or any combination thereof.

In one or more embodiments, the host may include a hole-transporting host and an electron-transporting host, wherein the hole-transporting host and the electron-transporting host may be different from each other.

For example, the electron-transporting host may include at least one electron-transporting moiety,

the hole-transporting host may not include an electron-transporting moiety nor an amine-containing group, and

the electron-transporting moiety may be a cyano group, a π electron-depleted nitrogen-containing cyclic group, groups represented by the following formulae, or any combination thereof, but embodiments of the present disclosure are not limited thereto:

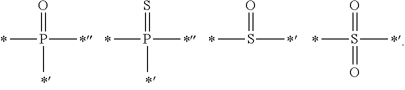

In the formulae above, *, *′, and *″ each indicate a binding site to a neighboring atom.

When the organic light-emitting device is a full-color organic light-emitting device, the emission layer may be patterned into a red emission layer, a green emission layer, and/or a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight based on 100 parts by weight of the host, but embodiments of the present disclosure are not limited thereto.

The dopant may include the organometallic compound described herein. For example, the dopant may be a red, green, or blue phosphorescent dopant.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Then, an electron transport region may be disposed on the emission layer.

The electron transport region may include a hole blocking layer, an electron transport layer, an electron injection layer, or any combination thereof.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, BCP, BPhen, BAlq, or any combination thereof, but embodiments of the present disclosure are not limited thereto:

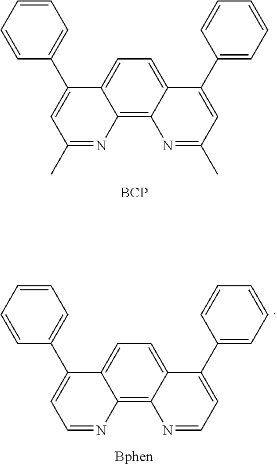

Alternatively, the electron blocking layer may include a host, a material for an electron transport layer, a material for an electron injection layer, or any combination thereof.

A thickness of the hole blocking layer may be in a range of about 20 Å to about 1,000 Å, for example, about 30 Å to about 600 Å. While not wishing to be bound by theory, it is understood that when the thickness of the hole blocking layer is within these ranges, the hole blocking layer may have improved hole blocking ability without a substantial increase in driving voltage.

The electron transport layer may include BCP, BPhen, TPBi, Alq3, BAlq, TAZ, NTAZ, or any combination thereof:

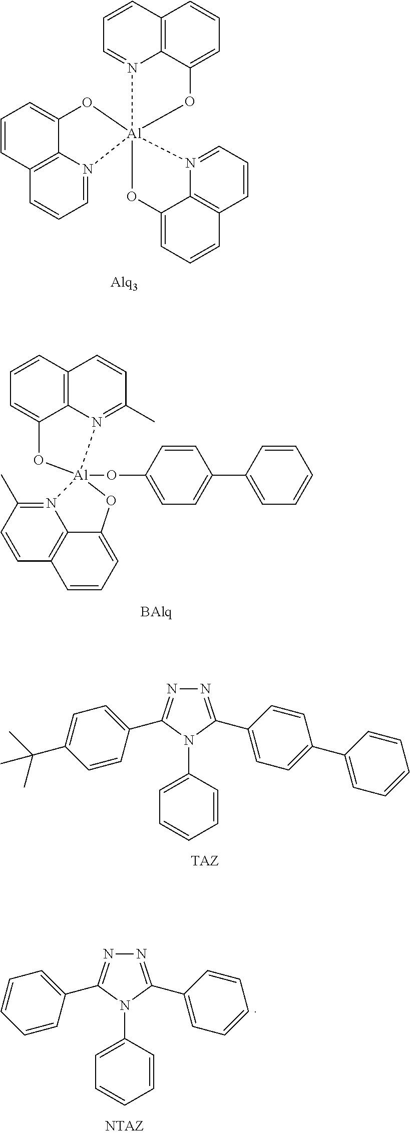

In one or more embodiments, the electron transport layer may include at least one of ET1 to ET25, but are not limited thereto:

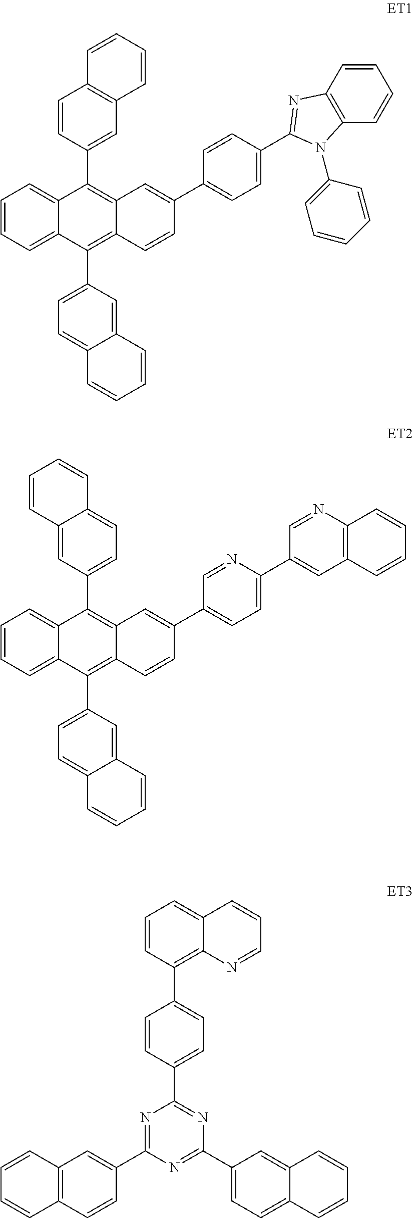 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

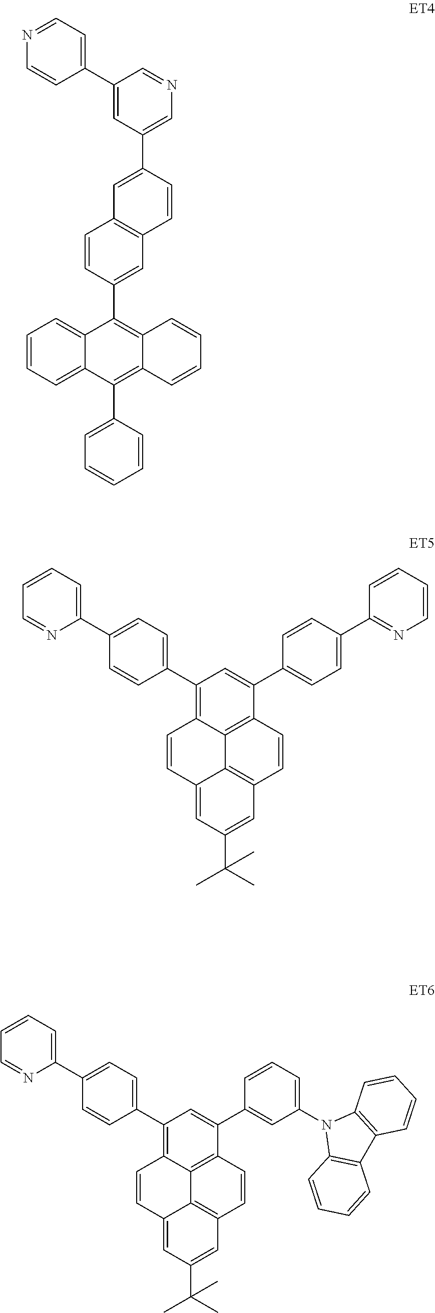 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

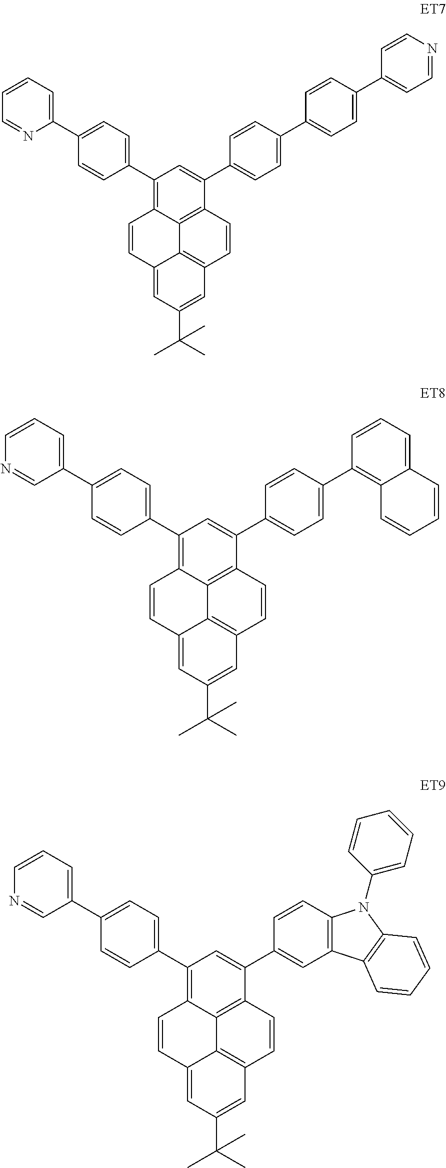 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

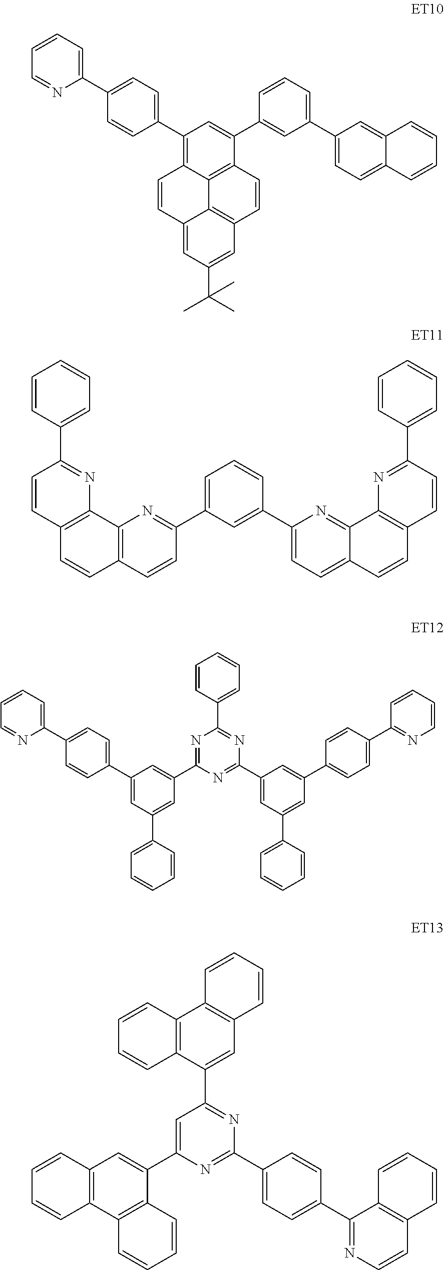 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

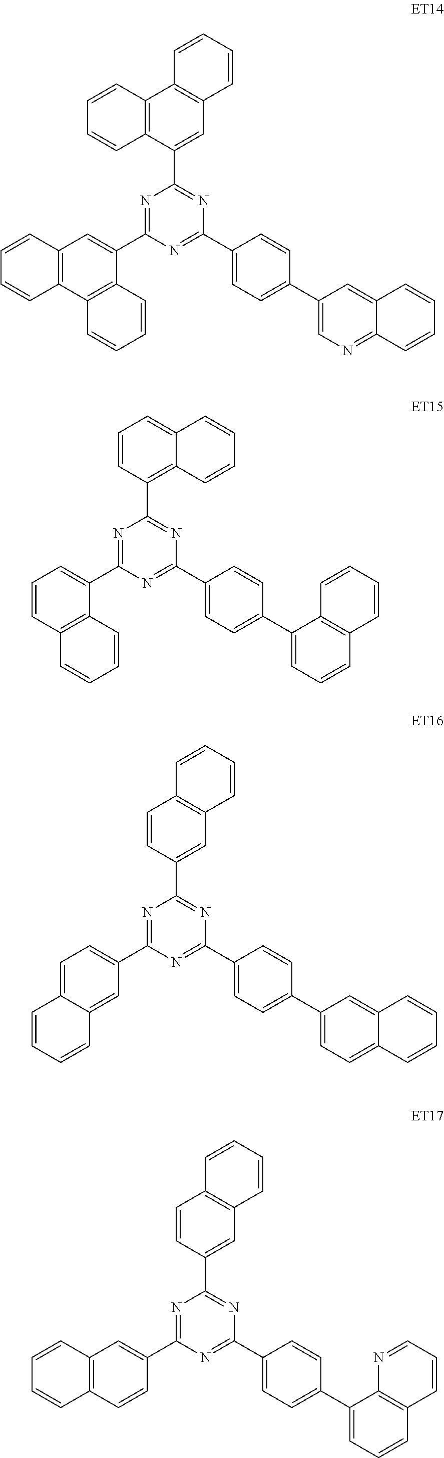 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

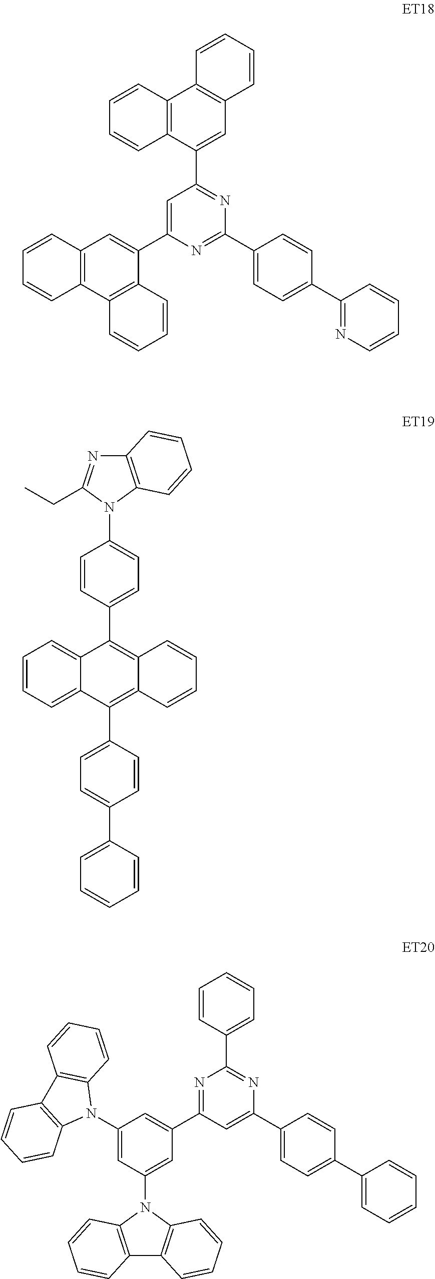 [SMILES: c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

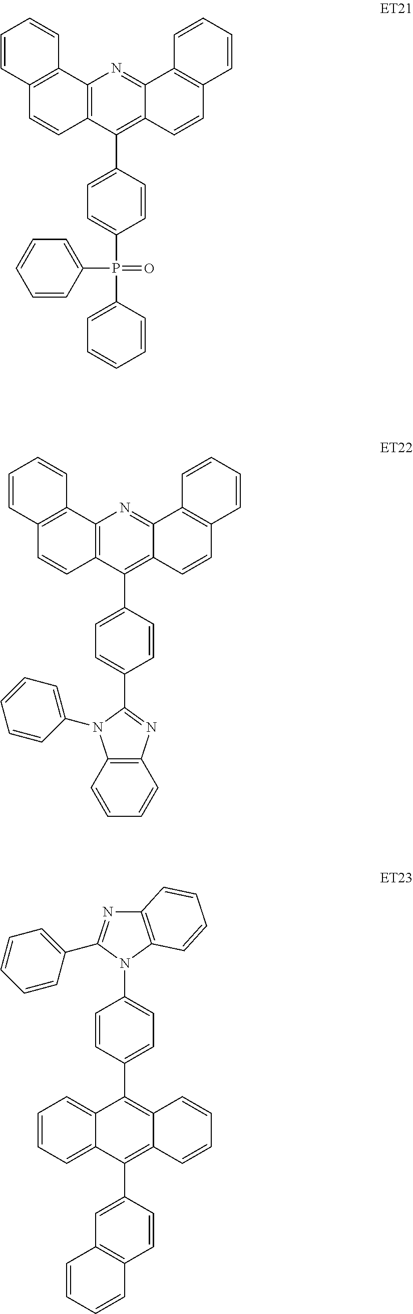 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

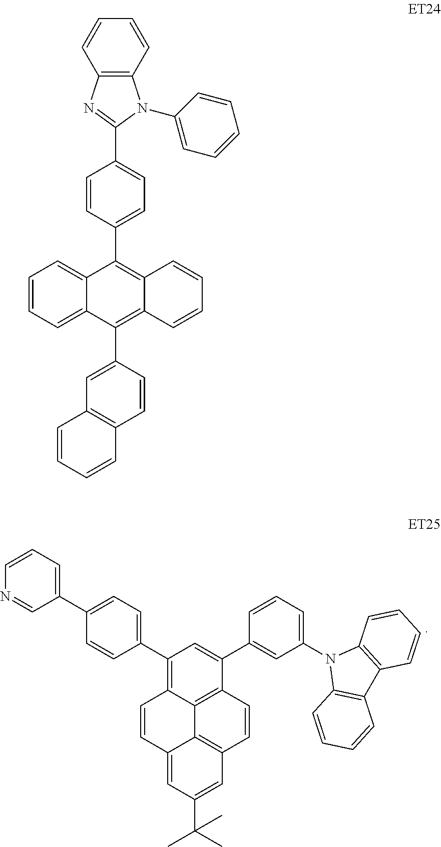 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a L₁ complex. The L₁ complex may include, for example, Compound ET-D1 or ET-D2:

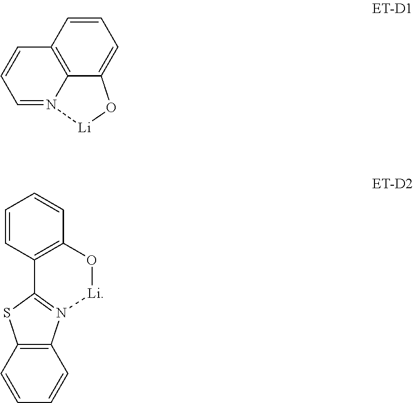

The electron transport region may include an electron injection layer that promotes flow of electrons from the second electrode 19 thereinto.

The electron injection layer may include LiF, NaCl, CsF, Li₂O, BaO, or any combination thereof.

A thickness of the electron injection layer may be in a range of about 1 Å to about 100 Å, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be metal, an alloy, an electrically conductive compound, or any combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device 20 has been described with reference to FIG. 2, but embodiments of the present disclosure are not limited thereto.

In an embodiment, the organic light-emitting device may satisfy at least one of Condition 10, Condition 11, Condition 12, Condition 13 and Condition 14:

### Condition 10

The organic light-emitting device may further comprise the hole transport region disposed between the first electrode and the emission layer and the hole transport region may comprise the p-dopant.

### Condition 11

The organic light-emitting device may further comprise the hole transport region disposed between the first electrode and the emission layer and the hole transport region may not comprise m-MTDATA.

### Condition 12

The organic light-emitting device may further comprise the hole transport region disposed between the first electrode and the emission layer and the hole transport region may not comprise NPB.

### Condition 13

The organic light-emitting device may further comprise the hole transport region disposed between the first electrode and the emission layer and the hole transport region may not comprise 2-TNATA.

### Condition 14

The organic light-emitting device may further comprise the electron transport region disposed between the emission layer and the second electrode and the electron transport region may not comprise Alq3.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, and an iso-propyloxy group.

The term “C₂-C₆₀ alkenyl group” as used herein refers to a hydrocarbon group formed by including at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by including at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom of N, O, P, Si Se, Ge, or S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₂-C₁₀ heterocycloalkenyl group” as used herein refers to a monovalent monocyclic group that has at least one heteroatom of N, O, P, Si, Se, Ge, or S as a ring-forming atom, 2 to 10 carbon atoms, and at least one carbon-carbon double bond in its ring. Examples of the C₂-C₁₀ heterocycloalkenyl group are a 2,3-dihydrofuranyl group, and a 2,3-dihydrothiophenyl group. The term “C₂-C₁₀ heterocycloalkenylene group” as used herein refers to a divalent group having the same structure as the C₂-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₇-C₆₀ alkylaryl group” as used herein refers to a C₆-C₅₉ aryl group substituted with at least one C₁-C₅₄ alkyl group.

The term “C₁-C₆₀ heteroaryl group” as used herein refers to a monovalent group having a heterocyclic aromatic system that has at least one heteroatom N, O, P, Si, Se, Ge, or S as a ring-forming atom, and 1 to 60 carbon atoms. The term “C₁-C₆₀ heteroarylene group” as used herein refers to a divalent group having a heterocyclic aromatic system that has at least one heteroatom N, O, P, Si, Se, Ge, or S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₂-C₆₀ alkyl heteroaryl group” as used herein refers to a C₁-C₅₉ heteroaryl group substituted with at least one C₁-C₅₉ alkyl group.

The term “C₆-C₆₀ aryloxy group” as used herein indicates —OA₁₀₂ (wherein A₁₀₂ is the C₆-C₆₀ aryl group), a C₆-C₆₀ arylthio group as used herein indicates —SA₁₀₃ (wherein A₁₀₃ is the C₆-C₆₀ aryl group), and the term “C₇-C₆₀ arylalkyl group” as used herein indicates -A₁₀₄A₁₀₅ (wherein A₁₀₅ is the C₆-C₅₉ aryl group and A₁₀₄ is the C₁-C₅₄ alkylene group).

The term “C₁-C₆₀ heteroaryloxy group” as used herein refers to —OA₁₀₆ (wherein A₁₀₆ is the C₁-C₆₀ heteroaryl group), the term “C₁-C₆₀ heteroarylthio group” as used herein indicates —SA₁₀₇ (wherein A₁₀₇ is the C₁-C₆₀ heteroaryl group), and the term “C₂-C₆₀ heteroarylalkyl group” as used herein refers to -A₁₀₈A₁₀₉ (A₁₀₉ is a C₁-C₅₉ heteroaryl group, and A₁₀₈ is a C₁-C₅₉ alkylene group).

The terms “(C₁-C₂₀ alkyl)cyclopentyl group,” “(C₁-C₂₀ alkyl)cyclohexyl group,” “(C₁-C₂₀ alkyl)cycloheptyl group,” “(C₁-C₂₀ alkyl)cyclooctyl group, and “(C₁-C₂₀ alkyl)bicyclo[1.1.1]pentyl group,” “(C₁-C₂₀ alkyl)bicyclo[2.1.1]hexyl group,” “(C₁-C₂₀ alkyl)bicyclo[2.2.1]heptyl group,” and “(C₁-C₂₀ alkyl)bicyclo[2.2.2]octyl group” “(C₁-C₂₀ alkyl)adamantyl group,” refer to −A₁₁₀A₁₁₁ (A₁₁₀ is a C₁-C₂₀ alkylene group, and A₁₁₁ is the respective cycloalkyl group).

The terms “(C₁-C₂₀ alkyl)norbornenyl group,” ‘(C₁-C₂₀ alkyl)cyclopentenyl group,” “(C₁-C₂₀ alkyl)cyclohexenyl group,” and “(C₁-C₂₀ alkyl)cycloheptenyl group,” refer to -A₁₁₂A₁₁₃ (A₁₁₂ is a C₁-C₂₀ alkylene group, and A₁₁₃ is the respective cycloalkenyl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom of N, O, P, Si, Se, Ge, or S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group.

The term “C₁-C₃₀ heterocyclic group” as used herein refers to a saturated or unsaturated cyclic group having, as a ring-forming atom, at least one heteroatom of N, O, Si, P, Se, Ge, or S other than 1 to 30 carbon atoms. The C₁-C₃₀ heterocyclic group may be a monocyclic group or a polycyclic group.

Non-limiting examples of the C₁-C₆₀ alkyl group, C₁-C₂₀ alkyl group and/or C₁-C₁₀ alkyl group include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or any combination thereof, and the like, but embodiments of the present disclosure are not limited thereto.

Non-limiting examples of the C₁-C₆₀ alkoxy group, C₁-C₂₀ alkoxy group and/or C₁-C₁₀ alkoxy group include a methoxy group, an ethoxy group, a propoxy group or a butoxy group, and the like, but embodiments of the present disclosure are not limited thereto.

Non-limiting examples of the C₃-C₁₀ cycloalkyl group include a cyclopropyl group, a cyclobutyl group, a cyclopentyl group, a cyclohexyl group, a cycloheptyl group, a cyclooctyl group, an adamantyl group, a bicyclo[1.1.1]pentyl group, a bicyclo[2.1.1]hexyl group, a bicyclo[2.2.1]heptyl group, a bicyclo[2.2.2]octyl group, and the like, but embodiments of the present disclosure are not limited thereto.

The deuterium-containing C₁-C₆₀ alkyl group (or, the deuterium-containing C₁-C₂₀ alkyl group, the deuterium-containing C₂-C₂₀ alkyl group, etc.) means a C₁-C₆₀ alkyl group substituted with a deuterium (or, a C₁-C₂₀ alkyl group substituted with at least one deuterium, a C₂-C₂₀ alkyl group substituted with a deuterium, etc.). For example, a deuterium-containing C₁ alkyl group (that is, a deuterium-containing methyl group) includes—CD₃, —CD₂H and —CDH₂.

The deuterium-containing C₁-C₆₀ alkyl group (or, the deuterium-containing C₁-C₂₀ alkyl group, the deuterium-containing C₂-C₂₀ alkyl group, etc.) may be additionally substituted with at least one C₃-C₁₀ cycloalkyl group. For example, Formula 9-619 is a group corresponding to —CD₂H, in which “—H” is substituted with a cyclopentyl group.

The fluorinated C₁-C₆₀ alkyl group means a C₁-C₆₀ alkyl group substituted with at least one —F. For example, a fluorinated methyl group includes —CF₃, —CF₂H and —CFH₂.

At least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, and the substituted monovalent non-aromatic condensed heteropolycyclic group may be:

a deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or

any combination thereof. For example, a CH₂CN group is a C₁ group substituted with a cyano group.

Q₁ to Q₉, Q₁₁ to Q₁₉, Q₂₁ to Q₂₉, and Q₃₁ to Q₃₉ in this disclosure may each independently be hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₂-C₁₀ heterocycloalkyl group; a C₃-C₁₀ cycloalkenyl group; a C₂-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₇-C₆₀ arylalkyl group; a C₁-C₆₀ heteroaryl group; a C₁-C₆₀ heteroaryloxy group; a C₁-C₆₀ heteroarylthio group; a C₂-C₆₀ heteroarylalkyl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉, and Q₃₁ to Q₃₉ in this disclosure may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or an n-propyl group, an iso-propyl group, an n-butyl group, a sec-butyl group, an iso-butyl group, a tert-butyl group, an n-pentyl group, a tert-pentyl group, a neo-pentyl group, an iso-pentyl group, a sec-pentyl group, a 3-pentyl group, a sec-iso-pentyl group, a phenyl group, a biphenyl group or a naphthyl group, each unsubstituted or substituted with deuterium, a C₁-C₁₀ alkyl group, a phenyl group, or any combination thereof.

For example, a C₅-C₃₀ carbocyclic group (that is unsubstituted or substituted with an R₁₀ₐ group) and a C₂-C₃₀ heterocyclic group (that is unsubstituted or substituted with an R₁₀ₐ group) may each independently be a cyclopentane group, a silole group, an azasilole group, a diazasilole group, a triazasilole group, an adamantane group, a norbornene group, a bicyclo[1.1.1]pentane group, a bicyclo[2.1.1]hexane group, a bicyclo[2.2.1]heptane group, a bicyclo[2.2.2]octane group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene-5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with an R₁ₐ group, but embodiments of the present disclosure are not limited thereto.

Hereinafter, a compound and an organic light-emitting device according to embodiments are described in detail with reference to Synthesis Example and Examples. However, the organic light-emitting device is not limited thereto. The expression “‘A’ is used instead of ‘B’” used in describing Synthesis Examples means that a molar equivalent of “A” was identical to a molar equivalent of “B”.

### EXAMPLES

### Synthesis Example of Compound Pt-1

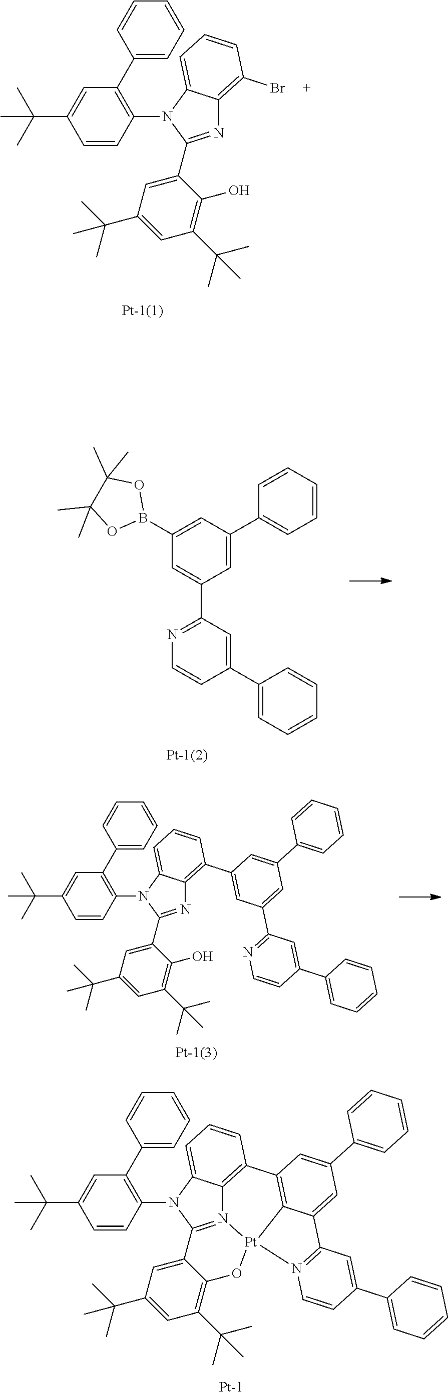

Synthesis of Intermediate Pt-1(3)

Compound Pt-1(1) (2.5 grams (g), 4.0 millimoles, mmol), Compound Pt-1(2) (1.6 g, 3.7 mmol), tetrakis(triphenylphosphine)palladium(0) (0.3 g, 0.3 mmol), and potassium carbonate (1.5 g, 11.0 mmol) were mixed with 60 milliliters (mL) of tetrahydrofuran (THF) and 20 mL of distilled water, and the reaction mixture was stirred for 12 hours under reflux. The reaction solution was cooled to room temperature, and the organic layer was extracted by using methylene chloride (MC). The obtained organic layer was dried by using anhydrous magnesium sulfate (MgSO₄) and filtered to obtain a filtrate. The residue obtained therefrom under reduced pressure was purified by column chromatography with a mixture of ethyl acetate (EA) and hexane as an eluent to obtain 2.5 g (yield: 83%) of Intermediate Pt-1(3).

Synthesis of Compound Pt-1

Intermediate Pt-1(3) (1.6 g, 2.0 mmol) and K₂PtCl₄(1.0 g, 2.4 mmol) were mixed with 20 mL of acetic acid, and the reaction mixture was stirred for 18 hours under reflux. The reaction mixture was cooled, the solid obtained therefrom was filtered, and the crude product was purified by column chromatography with a mixture of MC and hexane as an eluent to obtain 1.1 g (yield: 53%) of Compound Pt-1. The obtained compound was identified by Mass Spectroscopy (MS) and HPLC analysis.

HRMS (MALDI) calcd for C₆₀H₅₅N₃OPt: m/z 1028.3993, Found: 1028.3987.

### Synthesis Example of Compound Pt-2

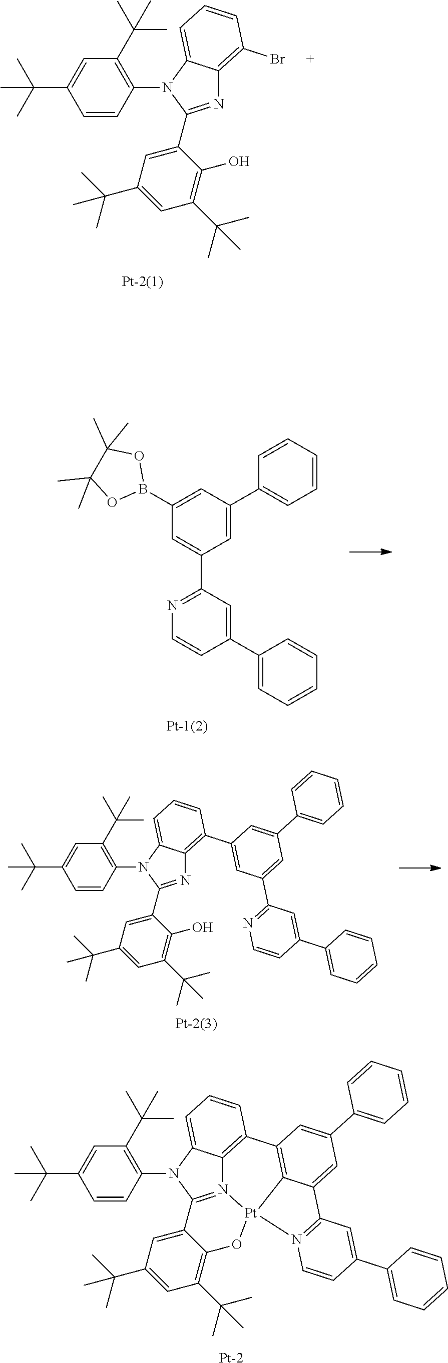

Synthesis of Intermediate Pt-2(3)

2.3 g (yield: 77%) of Intermediate Pt-2(3) was obtained in the same manner as Synthesis of Intermediate Pt-1(3), except that Intermediate Pt-2(1) was used instead of Compound Pt-1(1).

Synthesis of Compound Pt-2

0.95 g (yield: 48%) of Compound Pt-2 was obtained in the same manner as Synthesis of Compound Pt-1, except that Intermediate Pt-2(3) was used instead of Intermediate Pt-1(3). The obtained compound was identified by MS and HPLC analysis.

HRMS (MALDI) calcd for C₆₀H₅₅N₃OPt: m/z 1028.3993, Found: 1028.4001.

### Synthesis Example of Compound Ir-1

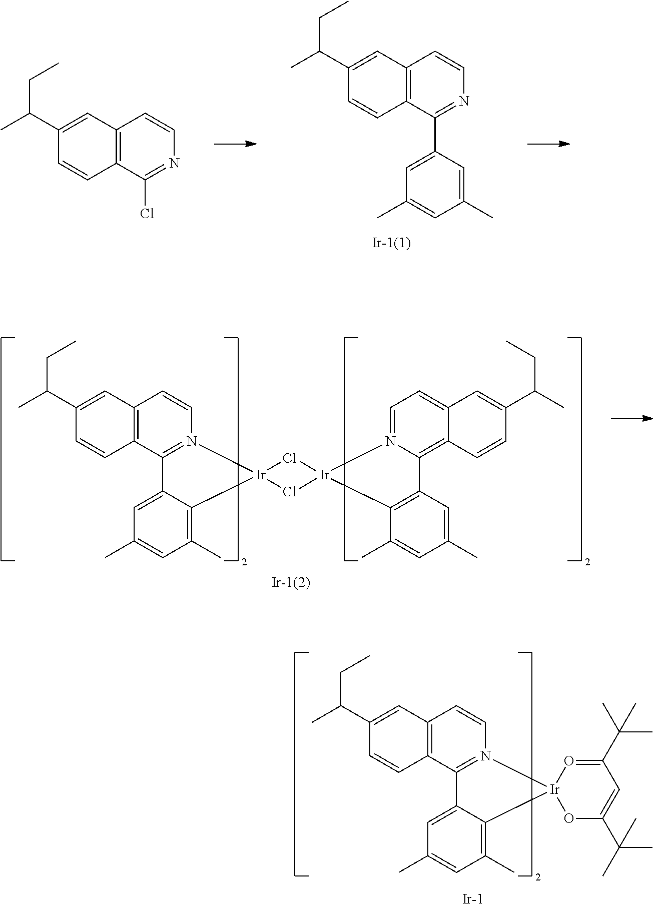

Synthesis of Intermediate Ir-1(1)

1-chloro-6-(sec-butyl)isoquinoline (4.56 grams (g), 20.76 millimoles, mmol), (3,5-dimethylphenyl)boronic acid (4.67 g, 31.14 mmol), Pd(PPh₃)₄ (1.92 g, 1.66 mmol), and K₂CO₃ (7.17 g, 51.90 mmol) were mixed with 60 milliliters (mL) of tetrahydrofuran (THF) and 30 mL of distilled water, and the mixed solution was stirred under reflux for 18 hours. After the temperature was lowered to room temperature, methylene chloride (MC) was used to extract the organic layer, and then, anhydrous magnesium sulfate (MgSO₄) was added to dry the organic layer. The resulting solution was filtered, and the filtrate was evaporated to produce a residue. The residue was then purified by column chromatography with EA:Hexane=1:10 (v/v) as an eluent, thereby obtaining Intermediate Ir-1(1) (5.60 g, yield of 93%).

MALDI-TOFMS (m/z): C₂₁H₂₃N (M+) 289.

Synthesis of Intermediate Ir-1(2)

Intermediate Ir-1(1) (5.58 g, 19.3 mmol) and iridium chloride hydrate (3.02 g) were mixed with 45 mL of 2-ethoxyethanol and 15 mL of distilled water, and the mixed solution was stirred under reflux for 24 hours. After a reaction was complete, the temperature was lowered to room temperature. The resulting solids produced from the reaction were separated by filtration and thoroughly washed with water/methanol/hexane sequentially to obtain a solid product. The solid product was dried in a vacuum oven, thereby obtaining Intermediate Ir-1(2) (3.9 g, yield of 50.3%).

Synthesis of Compound Ir-1

Intermediate Ir-1(2) (1.30 g, 0.81 mmol), 2,2,6,6-tetramethylheptane-3,5-dione (1.49 g, 8.14 mmol), and Na₂CO₃ (0.83 g, 8.14 mmol) were mixed with 15 mL of 2-ethoxyethanol, and the mixed solution was stirred under reflux for 24 hours. After a reaction was complete, the resulting solids produced from the reaction were separated by filtration and thoroughly washed using ethanol and hexane to obtain residues. The residues were purified by column chromatography with dichloromethane:n-hexane=1:1 (v/v) as an eluent, thereby obtaining Compound Ir-1 (0.78 g, yield of 50.6%). Then, Compound Ir-1 was identified by MS and HPLC.

HRMS(MALDI) calcd for C₅₃H₆₃IrN₂O₂: m/z 952.4519, Found: 952.4517.

### Synthesis Example of Compound Ir-2

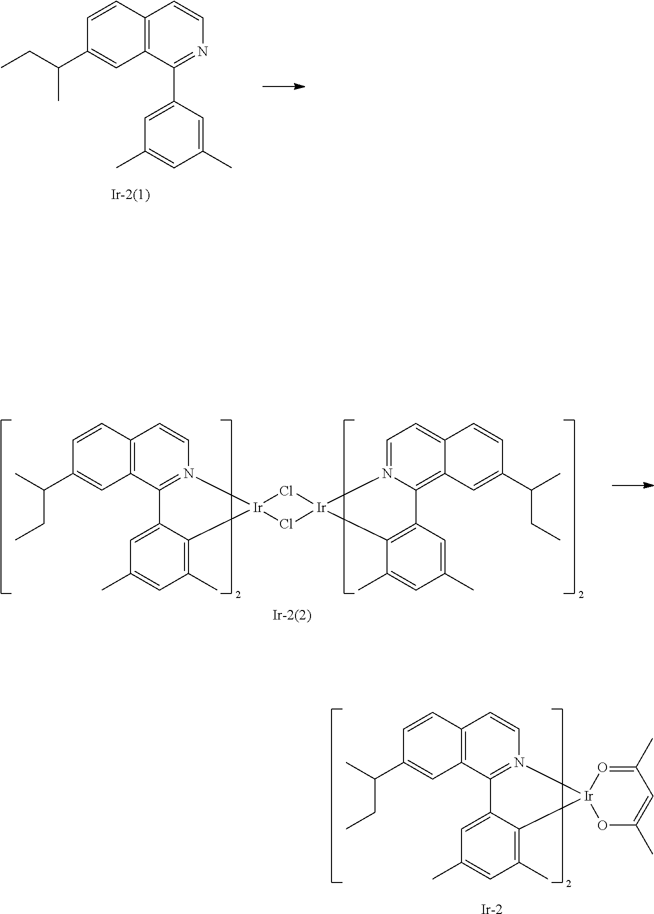

Synthesis of Intermediate Ir-2(2)

2.1 g (yield: 70%) of Intermediate Ir-2(2) was obtained in the same manner as Synthesis of Intermediate Ir-1(2), except that Compound Ir-2(1) was used instead of Intermediate Ir-1(1).

Synthesis of Compound Ir-2

0.8 g (yield: 40%) of Compound Ir-2 was obtained in the same manner as Synthesis of Compound Ir-1, except that Intermediate Ir-2(2) and pentane-2,4-dione were used instead of Intermediate Ir-1(2) and 2,2,6,6-tetramethylheptane-3,5-dione, respectively.

HRMS (MALDI) calcd for C₄₇H₅₁IrN₂O₂: m/z 868.3580, Found: 868.3498.

### Synthesis Example of Compound Ir-3

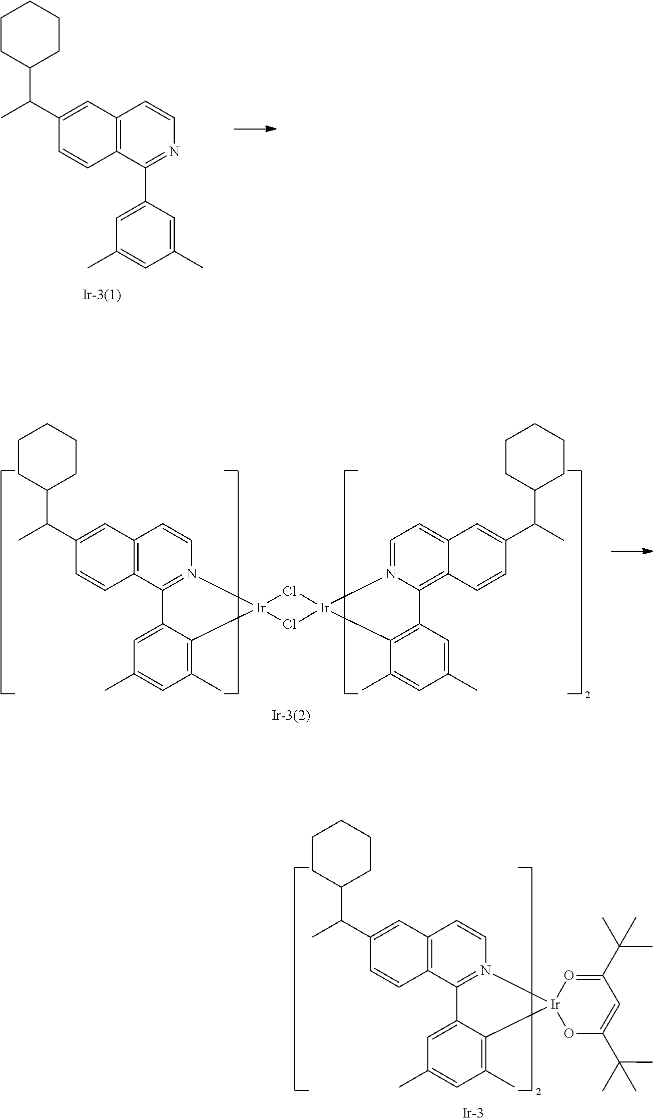

Synthesis of Intermediate Ir-3(2)

1.6 g (yield: 53%) of Intermediate Ir-3(2) was obtained in the same manner as Synthesis of Intermediate Ir-1(2), except that Compound Ir-3(1) was used instead of Intermediate Ir-1(1).

Synthesis of Compound Ir-3

0.95 g (yield: 48%) of Compound Ir-3 was obtained in the same manner as Synthesis of Compound Ir-1, except that Intermediate Ir-3(2) was used instead of Intermediate Ir-1(2). The obtained compound was identified by MS and HPLC analysis.

HRMS (MALDI) calcd for C₅₃H₆₃IrN₂O₂: m/z 952.4519, Found: 952.4512.

### Synthesis Example of Compound Ir-4

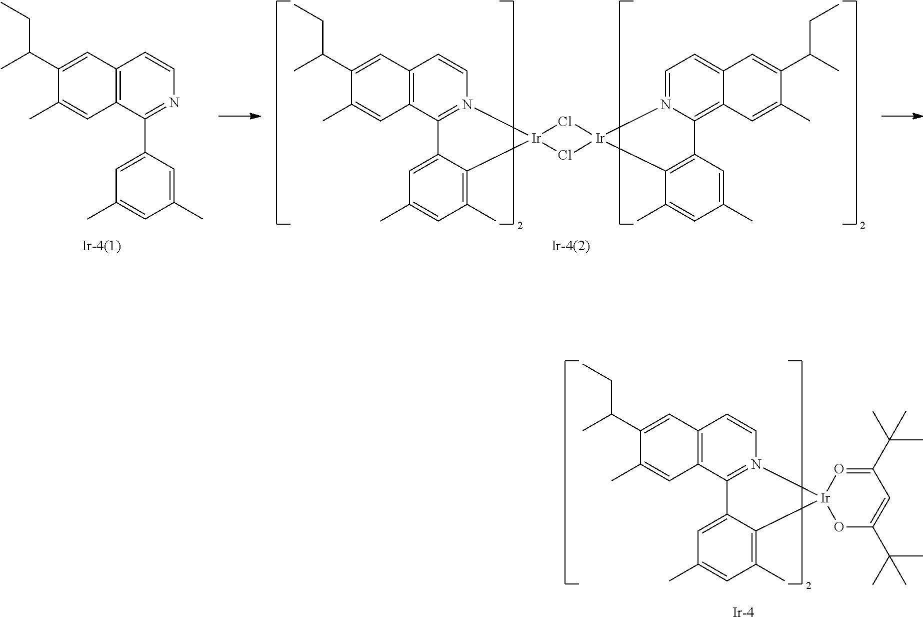

Synthesis of Intermediate Ir-4(2)

1.4 g (yield: 47%) of Intermediate Ir-4(2) was obtained in the same manner as Synthesis of Intermediate Ir-1(2), except that Compound Ir-4(1) was used instead of Intermediate Ir-1(1).

Synthesis of Compound Ir-4

1.1 g (yield: 55%) of Compound Ir-4 was obtained in the same manner as Synthesis of Compound Ir-1, except that Intermediate Ir-4(2) was used instead of Intermediate Ir-1(2). The obtained compound was identified by MS and HPLC analysis.

HRMS (MALDI) calcd for C₅₅H₆₇IrN₂O₂: m/z 980.4832, Found: 980.4839.

### Synthesis Example of Compound Ir-5

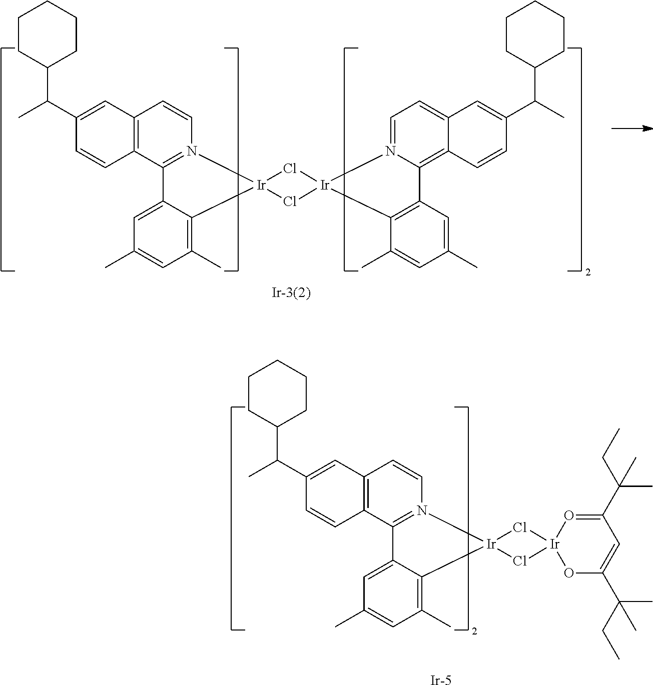

0.8 g (yield: 40%) of Compound Ir-5 was obtained in the same manner as Synthesis of Compound Ir-3, except that 3,3,7,7-tetramethylnonane-4,6-dione was used instead of 2,2,6,6-tetramethylheptane-3,5-dione. The obtained compound was identified by MS and HPLC analysis.

HRMS (MALDI) calcd for C₆₃H₇₉IrN₂O₂: m/z 1088.5771, Found: 1088.5761.

### Synthesis Example of Compound Ir-6

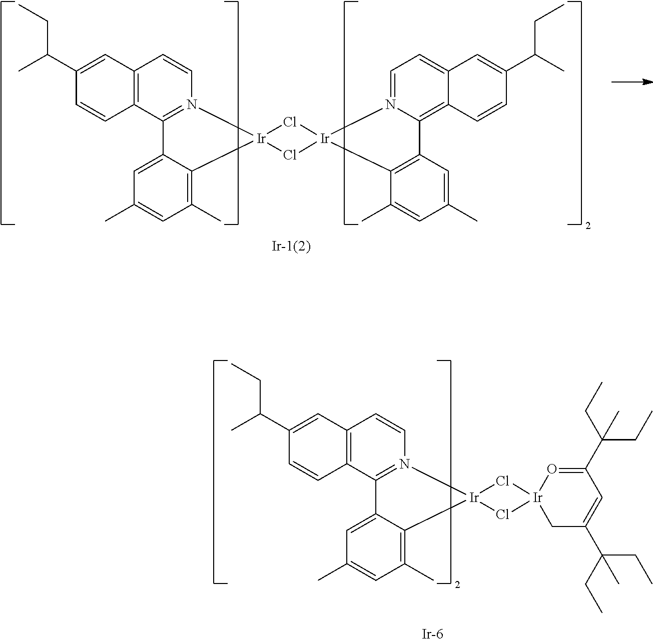

0.8 g (yield: 40%) of Compound Ir-6 was obtained in the same manner as Synthesis of Compound Ir-1, except that 3,7-diethyl-3,7-dimethylnonane-4,6-dione was used instead of 2,2,6,6-tetramethylheptane-3,5-dione. The obtained compound was identified by MS and HPLC analysis.

HRMS (MALDI) calcd for C₅₇H₇₁IrN₂O₂: m/z 1008.5145, Found: 1008.5150.

### Synthesis Example of Compound Ir-7

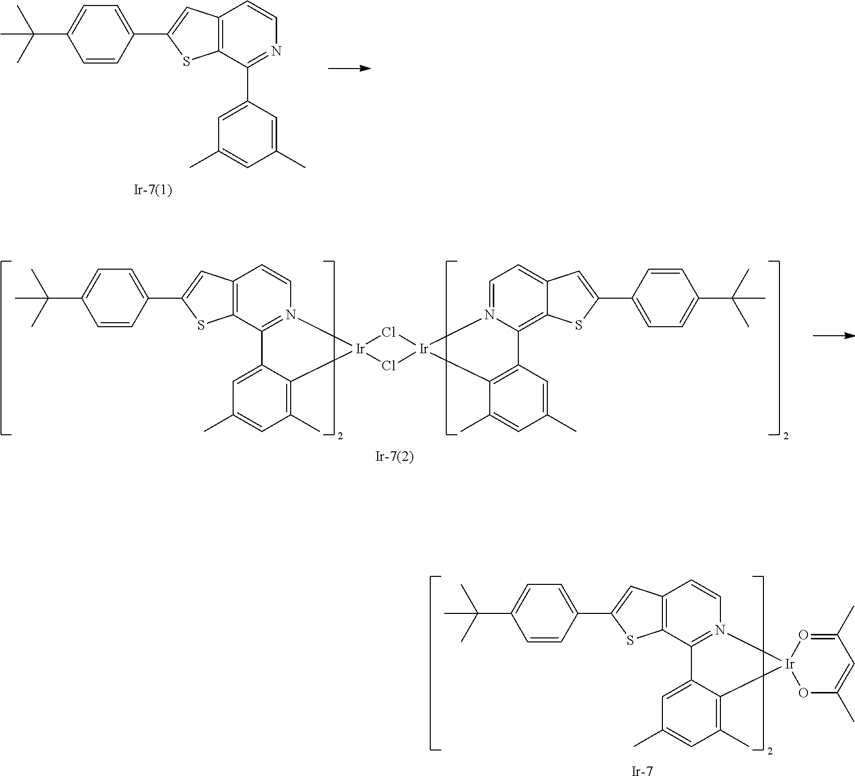

Synthesis of Intermediate Ir-7(2)

2.2 g (yield: 73%) of Intermediate Ir-7(2) was obtained in the same manner as Synthesis of Intermediate Ir-1(2), except that Compound Ir-7(1) was used instead of Intermediate Ir-1(1).

Synthesis of Compound Ir-7

0.7 g (yield: 35%) of Compound Ir-7 was obtained in the same manner as Synthesis of Compound Ir-1, except that Intermediate Ir-7(2) and pentane-2,4-dione were used instead of Intermediate Ir-1(2) and 2,2,6,6-tetramethylheptane-3,5-dione, respectively. The obtained compound was identified by MS and HPLC analysis.

HRMS (MALDI) calcd for C₅₅H₅₅IrN₂O₂S₂: m/z 1032.3334, Found: 1032.3339.

### Synthesis Example of Compound Ir-8

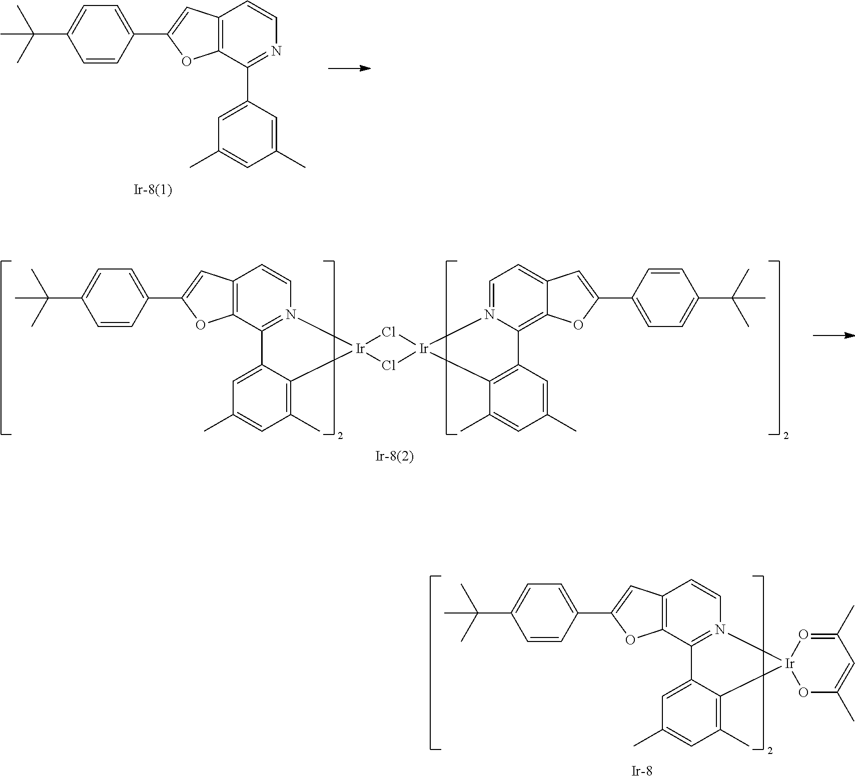

Synthesis of Intermediate Ir-8(2)

1.9 g (yield: 63%) of Intermediate Ir-8(2) was synthesized in the same manner as Synthesis of Intermediate Ir-1(2), except that Compound Ir-8(1) was used instead of Intermediate Ir-1(1).

Synthesis of Compound Ir-8

0.8 g (yield: 40%) of Compound Ir-8 was obtained in the same manner as Synthesis of Compound Ir-1, except that Intermediate Ir-8(2) and pentane-2,4-dione were used instead of Intermediate Ir-1(2) and 2,2,6,6-tetramethylheptane-3,5-dione, respectively. The obtained compound was identified by MS and HPLC analysis.

HRMS (MALDI) calcd for C₅₅H₅₅IrN₂O₄: m/z 1000.3791, Found: 1000.3799.

### Synthesis Example of Compound Ir-9

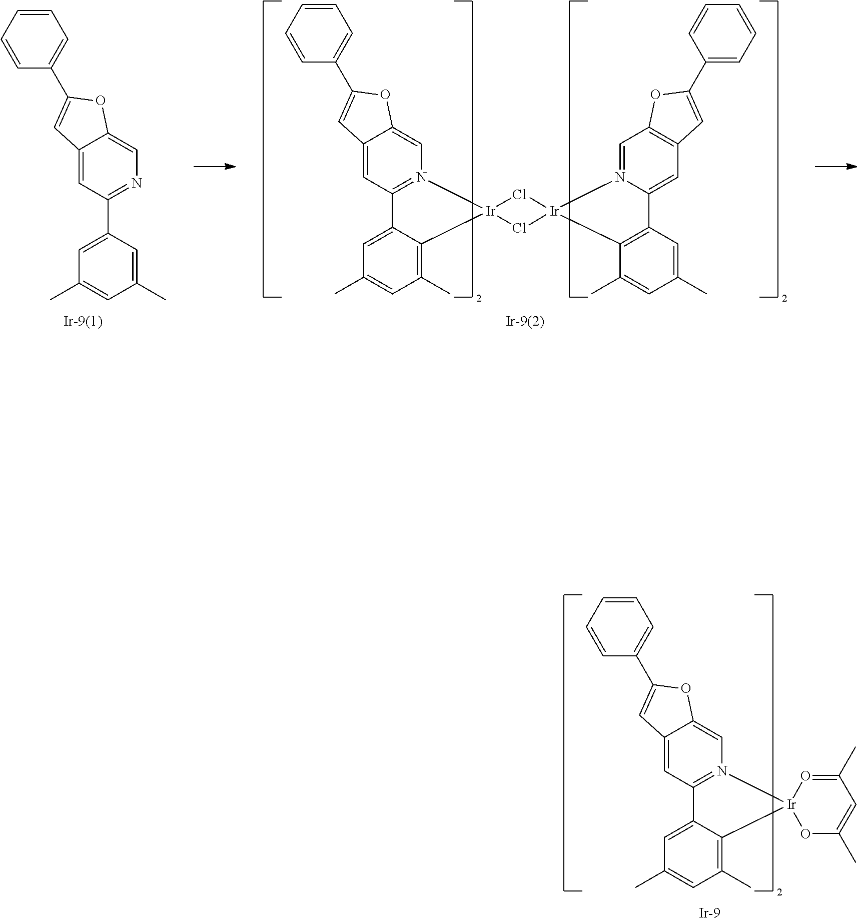

Synthesis of Intermediate Ir-9(2)

1.5 g (yield: 50%) of Intermediate Ir-9(2) was obtained in the same manner as Synthesis of Intermediate Ir-1(2), except that Compound Ir-9(1) was used instead of Intermediate Ir-1(1).

Synthesis of Compound Ir-9

0.5 g (yield: 25%) of Compound Ir-9 was obtained in the same manner as Synthesis of Compound Ir-1, except that Intermediate Ir-9(2) and pentane-2,4-dione were used instead of Intermediate Ir-1(2) and 2,2,6,6-tetramethylheptane-3,5-dione, respectively. The obtained compound was identified by MS and HPLC analysis.

HRMS (MALDI) calcd for C₄₇H₃₉IrN₂O₄: m/z 888.2539, Found: 888.2530.

### Synthesis Example of Compound Ir-10

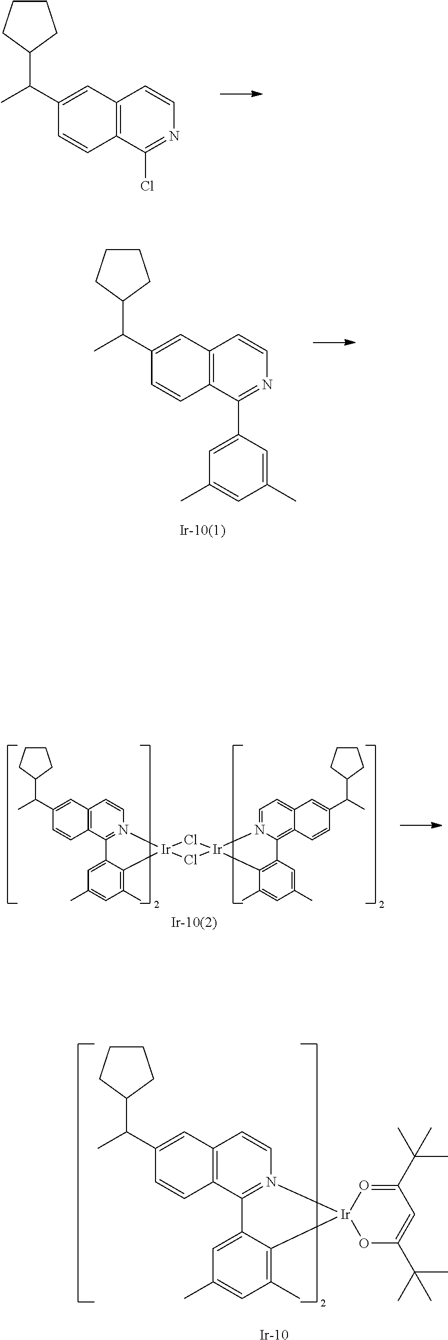

Synthesis of Intermediate Ir-10(1)

Intermediate Ir-10(1) (5.95 g, yield of 87%) was synthesized in the same manner as in the synthesis of Intermediate Ir-1(1), except that 1-chloro-6-(1-cyclopentyl-ethyl)isoquinoline (5.39 g, 20.76 mmol) was used instead of 1-chloro-6-(sec-butyl)isoquinoline.

HRMS(MALDI) calcd for C₂₄H₂₉N: m/z 331.2300, Found: 331.2311.

Synthesis of Intermediate Ir-10(2)

Intermediate Ir-10(2) was synthesized in the same manner as in the synthesis of Intermediate Ir-1(2), except that Intermediate Ir-10(1) was used instead of Intermediate Ir-1(1).

Synthesis of Compound Ir-10

Compound Ir-10 (0.68 g, yield of 41%) was synthesized in the same manner as in the synthesis of Compound Ir-1, except that Intermediate Ir-10(2) was used instead of Intermediate Ir-1(2).

HRMS(MALDI) calcd for C₅₉H₇₁IrN₂O₂: m/z 1032.5145, Found: 1032.5151.

### Synthesis Example of Compound Ir-11

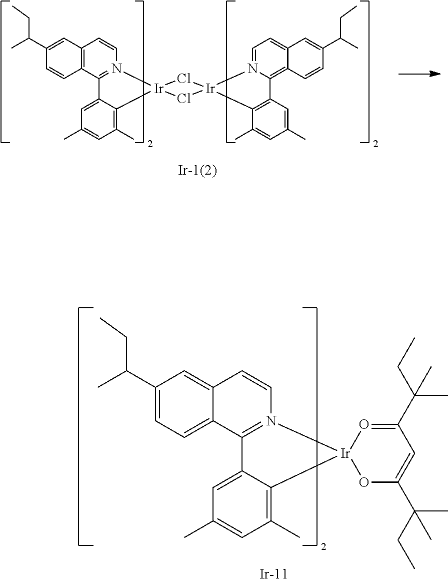

Intermediate Ir-1(2) (1.56 g, 0.97 mmol), 3,3,7,7-tetramethylnonane-4,6-dione (2.06 g, 9.69 mmol), Na₂CO₃ (1.02 g, 9.69 mmol), and 2-ethoxyethanol (20 mL) were mixed together, and the mixed solution was stirred for 24 hours. The mixture obtained therefrom was filtered, and the filtered solid was thoroughly washed by using ethanol and hexane, and purified by using column chromatography under conditions of dichloromethane:n-hexane=1:1(v/v), thereby obtaining 1.40 g (yield: 74%) of Compound Ir-11.

HRMS(MALDI) calcd for C₅₅H₆₇IrN₂O₂: m/z 980.37, Found: 980.39.

### Synthesis Example of Compound Ir-12

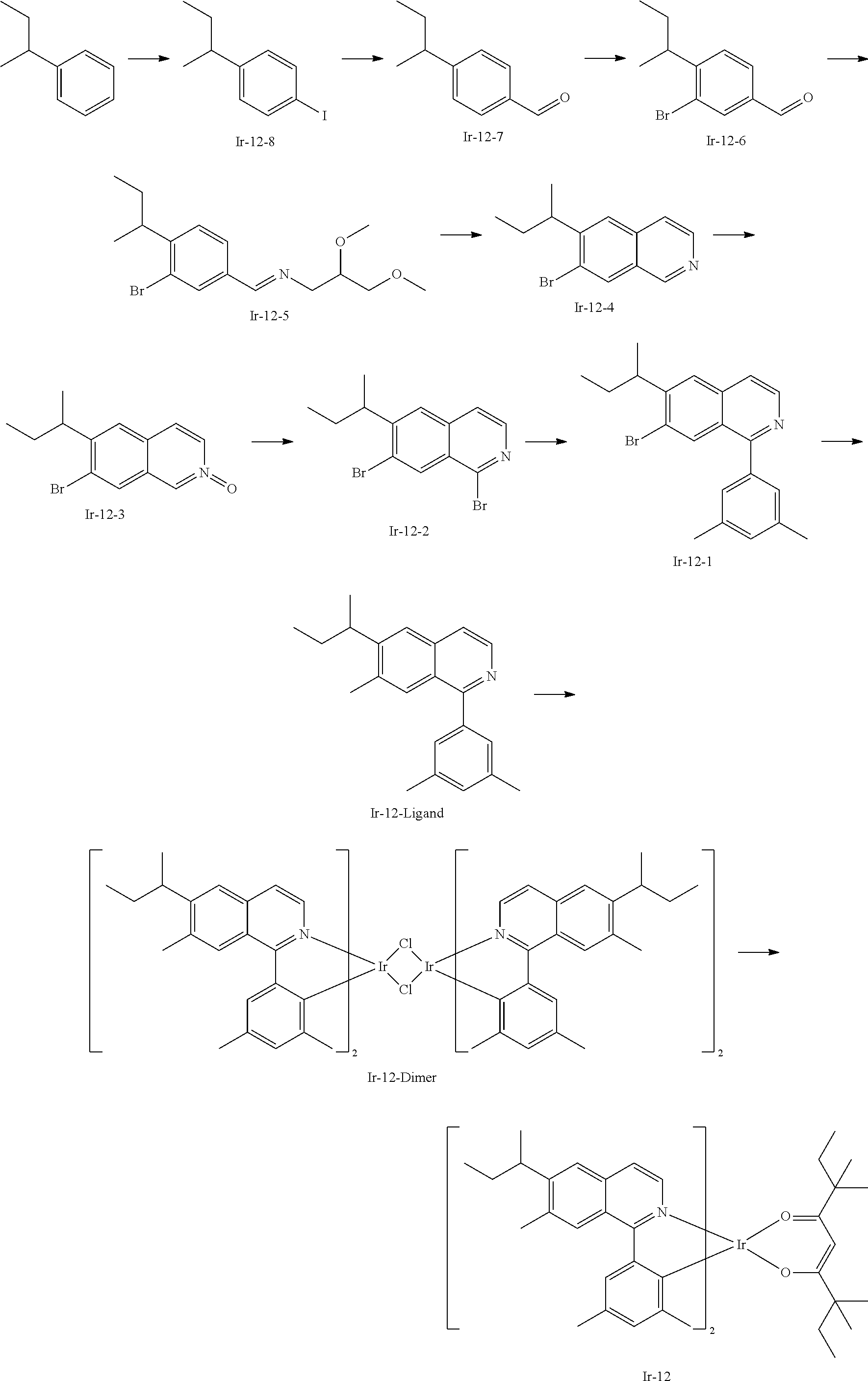

Synthesis of Intermediate Ir-12-8

72 ml (461.3 mmol) of sec-butylbenzene was mixed with 450 ml of acetonitrile, and 88.0 g (346.0 mmol) of iodine and 122.6 g (346.0 mmol) of Selectfluor (1-chloromethyl-4-fluoro-1,4-diazabicyclo[2.2.2]octane bis(tetrafluoroborate)) were added thereto. The mixture was then stirred at a temperature of 60° C. for 4 hours. After the completion of the reaction, the reaction mixture was mixed with dichloromethane, and an extraction process was performed thereon using saturated sodium thiosulfate aqueous solution. An organic layer obtained therefrom was then dried with magnesium sulfate, and subjected to distillation under reduced pressure. The resulting product was purified by liquid chromatography, thereby obtaining 75.0 g (yield: 63%) of Intermediate Ir-12-8.

LC-MS m/z=261(M+H

Synthesis of Intermediate Ir-12-7

148 g (512.9 mmol) of Intermediate Ir-12-8 was mixed with 500 ml of tetrahydrofuran, and 205 ml (205 mmol) of 1.0 M isopropylmagnesium chloride solution was slowly added thereto. The mixture was then stirred at a temperature of 0° C. After 10 minutes, 256 ml (410 mmol) of a 1.6 M n-butyl lithium (BuLi) solution was slowly added thereto, and then, the mixed solution was stirred for 1 hour. Afterwards, 51 ml (666.7 mmol) of DMF was slowly added thereto dropwise at a temperature of −10° C., and the resulting solution was stirred at room temperature for 1 hour. After the completion of the reaction, an extraction process was performed on the reaction mixture by using ethyl acetate and an aqueous hydrochloric acid solution. An organic layer obtained therefrom was dried with magnesium sulfate, and subjected to distillation under reduced pressure. The resulting product was purified by liquid chromatography, thereby obtaining 83.2 g (yield: 100%) of Intermediate Ir-12-7.

LC-MS m/z=163(M+H)⁺

Synthesis of Intermediate Ir-12-6

44 g (326.6 mmol) of AlCl₃ was added to 100 ml of dichloromethane, and the mixture was heated at a temperature of 40° C. 30 g (186.6 mmol) of Intermediate Ir-12-7 mixed with 6 ml of dichloromethane was slowly added thereto, and the resulting mixture was then stirred for 30 minutes. 10 ml (205.3 mmol) of bromine was added thereto for 1 hour. After the completion of the reaction, the reaction mixture was slowly added to iced water, and an organic layer obtained therefrom was then dried with magnesium sulfate, and subjected to distillation under reduced pressure. The resulting product was purified by liquid chromatography, thereby obtaining 27 g (yield: 60%) of Intermediate Ir-12-6.

LC-MS m/z=241(M+H

Synthesis of Intermediate Ir-12-5

27 g (112.7 mmol) of Intermediate Ir-12-6 was mixed with 100 ml of chloroform, and 18 ml (169 mmol) of aminoacetaldehyde dimethyl acetal was slowly added thereto at room temperature. After 1 hour, the mixture was heated at a temperature of 100° C. to remove a solvent therefrom. The resulting reaction mixture was then cooled to room temperature, and without a separate purification process, Intermediate Ir-12-5 was obtained.

Synthesis of Intermediate Ir-12-4

37 g (113.6 mmol) of Intermediate Ir-12-5 was mixed with 100 ml of chloroform, and 11 ml (113.6 mmol) of ethyl chloroformate and 16 ml (136.3 mmol) of trimethyl phosphite were slowly added dropwise thereto at a temperature of 0° C. sequentially in the stated order. The reaction mixture obtained therefrom was then stirred at room temperature for 48 hours, and 454 ml (454 mmol) of 1.0 M TiCl₄ was slowly added dropwise thereto at a temperature of 0° C. The resulting mixture was then heated under reflux for about 48 hours. After the completion of the reaction, the reaction mixture was cooled to room temperature, and then, added to iced water. A water layer obtained therefrom was washed using dichloromethane, and added to 256 g (908.5 mmol) of tartrate solution. The mixed solution was neutralized with saturated NaHCO₃solution, and an extraction process was performed thereon using dichloromethane. An organic layer obtained therefrom was purified by liquid chromatography, thereby obtaining 11 g (yield: 38%) of Intermediate Ir-12-4.

LC-MS m/z=264(M+H)⁺

Synthesis of Intermediate Ir-12-3

11 g (43.2 mmol) of Intermediate Ir-12-4 was mixed with 90 ml of dichloromethane, and 15 g (86.4 mmol) of mCPBA was slowly added dropwise thereto at a temperature of 0° C. The reaction mixture was stirred for about 18 hours at room temperature, and then, an extraction process was performed thereon using 6 N KOH solution. An organic layer obtained therefrom was dried with magnesium sulfate, and without a separate purification process, 12 g (yield: 100%) of Intermediate Ir-12-3 was obtained.

Synthesis of Intermediate Ir-12-2

12 g (43.2 mmol) of Intermediate Ir-12-3 was mixed with 90 ml of dichloromethane, and 15 g (52 mmol) of POBr₃ was slowly added dropwise thereto at a temperature of 0° C. Then, 1.7 ml (22 mmol) of DMF was slowly added thereto, and the mixture was stirred for about 18 hours at room temperature. After the completion of the reaction, the reaction solution was neutralized with a saturated NaHCO₃ solution, and an extraction process was performed thereon using dichloromethane. An organic layer obtained therefrom was dried with magnesium sulfate, and purified by liquid chromatography, thereby obtaining 3.8 g (yield: 26%) of Intermediate Ir-12-2.

LC-MS m/z=342(M+H)⁺

Synthesis of Intermediate Ir-12-1

3.8 g (10.9 mmol) of Intermediate Ir-12-2 was mixed with 40 ml of toluene and 8 ml of EtOH, and 1.5 g (9.8 mmol) of 3,5-dimethylphenyl boronic acid, 0.6 g (0.5 mmol) of a Pd(PPh₃)₄, and 8 ml of 2.0 N Na₂CO₃ solution were added thereto. The mixture was then heated under reflux at a temperature of 85° C. for 18 hours. After the completion of the reaction, an extraction process was performed thereon using 50 ml of ethyl acetate. An organic layer obtained therefrom was dried with magnesium sulfate, and purified by liquid chromatography, thereby obtaining 3.6 g (yield: 90%) of Intermediate Ir-12-1.

LC-MS m/z=368(M+H)⁺

Synthesis of Intermediate Ir-12-Ligand

4.1 mmol of Intermediate Ir-12-1 was mixed with 80 ml of THF. 2.1 g (8.2 mmol) of DABAL-Me3 (triethylenediaminine bis(trimethylaluminum)), 0.4 g (0.4 mmol) of a Pd(PPh₃)₄, and 0.4 g (0.4 mmol) of Xphos (2-dicyclohexylphosphino-2″,4″,6″-triisopropylbiphenyl) were added thereto, the mixture was heated under reflux at a temperature of 80° C. for 18 hours. After the completion of the reaction, the reaction mixture was neutralized with HCl, and then, an extraction process was performed thereon using 100 ml of ethyl acetate. An organic layer obtained therefrom was then dried with magnesium sulfate, and then, subjected to distillation under reduced pressure. The resulting product was purified by liquid chromatography, thereby obtaining 0.9 g (yield: 90%) of Intermediate Ir-12-Ligand.

LC-MS m/z=304(M+H)⁺

Synthesis of Ir-12-Dimer

2.96 mmol of Intermediate Ir-12-Ligand and 0.5 g (1.41 mmol) of iridium chloride were mixed with 45 mL of 2-ethoxyethanol and 15 mL of distilled water, and the resulting solution was stirred under reflux for 24 hours. When the reaction was complete, the temperature was lowered to room temperature. A solid produced therefrom was separated by filtration, and then, sufficiently washed using water/methanol/hexane in the stated order. The resulting solid was dried in a vacuum oven, thereby obtaining Ir-12-Dimer (yield: 77%).

Synthesis of Compound Ir-12

0.57 mmol of Ir-12-Dimer, 1.43 mmol of 3,3,7,7-tetramethylnonane-4,6-dione, and 0.18 g (1.71 mmol) of Na₂CO₃ were mixed with 15 mL of 2-ethoxyethanol, and the mixed solution was stirred for 24 hours. When the reaction was complete, a solid obtained by filtering the reaction mixture was washed sufficiently with ethanol and hexane, and then, was subjected to column chromatography under conditions of dichloromethane: n-hexane=1:1(v/v), thereby obtaining Compound Ir-12 (yield: 45%). The synthesized compound was identified by LCMS.

LC-MS m/z=1009(M+H)⁺

### Synthesis Example of Compound Ir-13

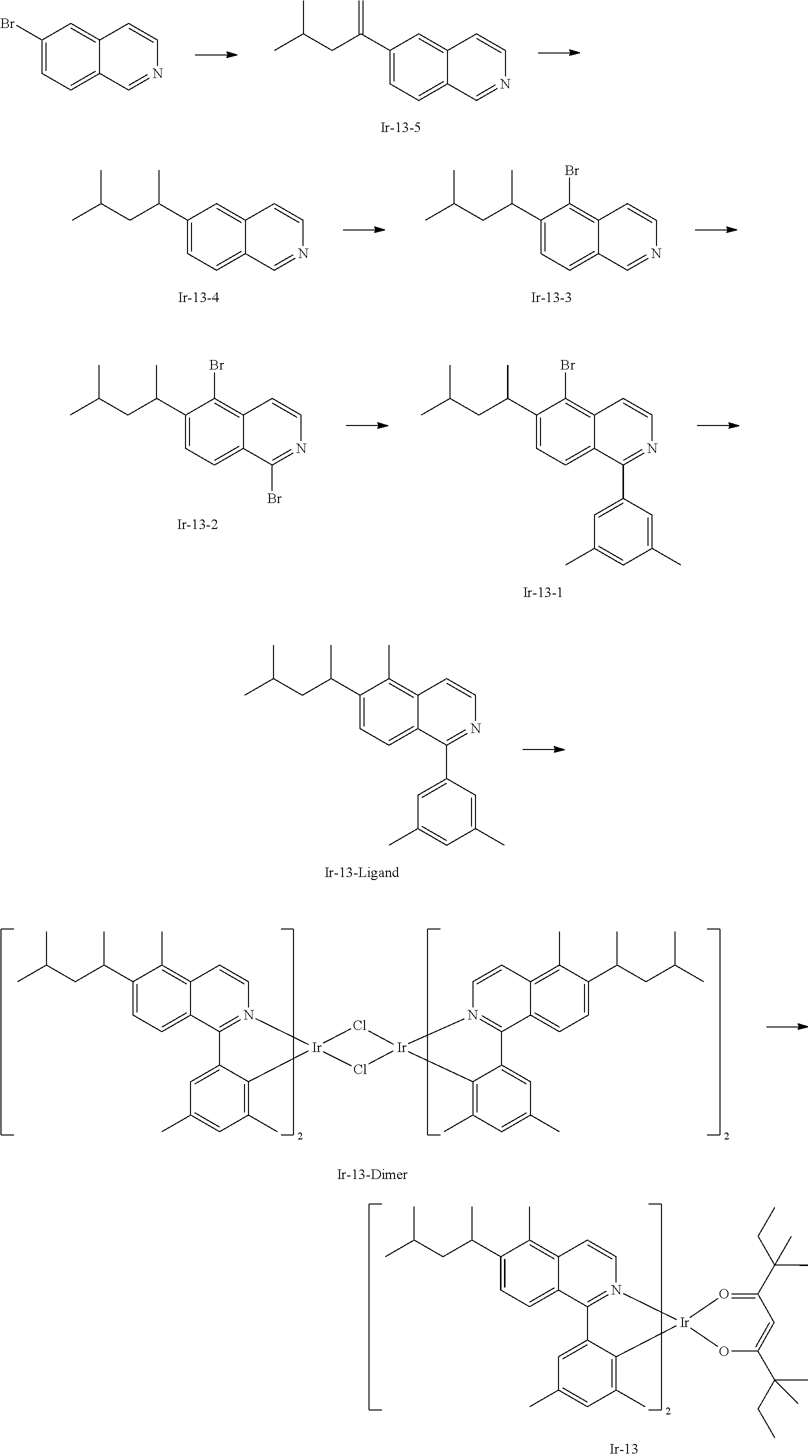

Synthesis of Intermediate Ir-13-5

20 g (96.1 mmol) of 6-bromoisoquinoline was mixed with 120 ml of tetrahydrofuran, and 11 g (9.6 mmol) of Pd(PPh₃)₄, 18 g (144.2 mmol) of (4-methylpent-1-en-2-yl)boronic acid, 33.2 g (240.5 mmol) of K₂CO₃, and 30 ml of water were added thereto. The mixture was then heated under reflux at a temperature of 80° C. for about 18 hours. After the completion of the reaction, an extraction process was performed thereon using ethyl acetate. An organic layer obtained therefrom was dried with magnesium sulfate, and purified by liquid chromatography, thereby obtaining 16 g (yield: 80%) of Intermediate Ir-13-5.

LC-MS m/z=212(M+H)⁺

Synthesis of Intermediate Ir-13-4

55.3 mmol of Intermediate Ir-13-5 was mixed with 200 ml of methanol, and 1.0 g (10 wt %) of a Pd(PPh₃)₄ was added thereto. By injecting hydrogen thereto, the mixed solution was stirred for 18 hours. After the completion of the reaction, the reaction mixture was passed through a celite pad, and then, concentrated under reduced pressure. The resulting product was purified by liquid chromatography, thereby obtaining Intermediate Ir-13-4 (yield: 95%).

LC-MS m/z=214(M+H)⁺

Synthesis of Intermediate Ir-13-3

5.8 g (43.2 mmol) of AlCl₃ was mixed with 120 ml of chloroform, and the mixture was stirred at a temperature of 55° C. for 30 minutes. Then, 4.6 g (21.6 mmol) of Intermediate Ir-13-4 mixed with a small amount of chloroform was slowing added dropwise thereto, and the resulting mixture was stirred at a temperature of 55° C. for 1 hour. Subsequently, 1.2 ml (32.4 mmol) of bromine mixed with 30 ml of chloroform was slowly added dropwise thereto, and the resulting mixture was stirred for 3 hours. After the completion of the reaction, an extraction process was performed thereon using iced water and saturated sodium thiosulfate aqueous solution. An organic layer obtained therefrom was dried with magnesium sulfate, and purified by liquid chromatography, thereby obtaining 2.3 g (yield: 40%) of Intermediate Ir-13-3.

LC-MS m/z=292(M+H)⁺

Synthesis of Intermediate Ir-13-2

1.7 g (yield: 70%) of Intermediate Ir-13-2 was synthesized in the same manner as in the synthesis of Intermediate Ir-12-2, except that Intermediate Ir-13-3 was used instead of Intermediate Ir-12-3.

LC-MS m/z=370(M+H)⁺

Synthesis of Intermediate Ir-13-1

Intermediate Ir-13-1 was synthesized in the same manner as in the synthesis of Intermediate Ir-12-1, except that Intermediate Ir-13-2 was used instead of Intermediate Ir-12-2.

LC-MS m/z=396(M+H)⁺

Synthesis of Intermediate Ir-13-Ligand

0.8 g (yield: 85%) of Intermediate Ir-13-Ligand was synthesized in the same manner as in the synthesis of Intermediate Ir-12-Ligand, except that Intermediate Ir-13-1 was used instead of Intermediate Ir-12-1. The synthesized compound was identified by LCMS.

LC-MS m/z=332(M+H)⁺

Synthesis of Ir-13-Dimer

Ir-13-Dimer was synthesized in the same manner as in the synthesis of Ir-12-Dimer, except that Intermediate Ir-13-Ligand was used instead of Intermediate Ir-12-Ligand.

Synthesis of Compound Ir-13

0.5 g (yield: 46%) of Compound Ir-13 was synthesized in the same manner as in the synthesis of Compound Ir-12, except that Ir-13-Dimer was used instead of Ir-12-Dimer. The synthesized compound was identified by LCMS.

LC-MS m/z=1065(M+H)⁺

### Synthesis Example of Compound Ir-14

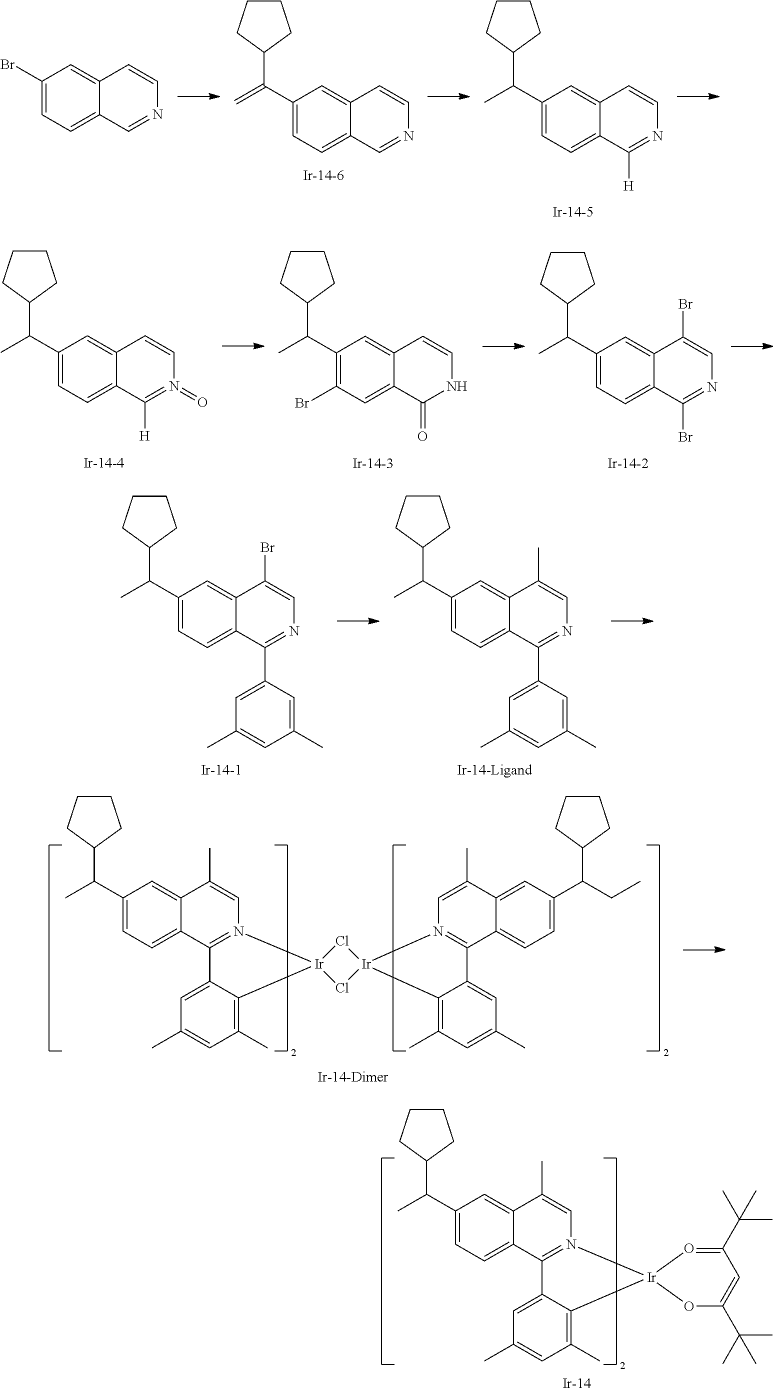

Synthesis of Intermediate Ir-14-6

44 g (181.4 mmol) of 6-bromoisoquinoline was mixed with 400 ml of tetrahydrofuran (THF) and 100 ml of water, 181.4 mmol of 2-(1-cyclopentylvinyl)-4,4,5,5-tetramethyl-1,3,2-dioxaborolane, 14.7 g (12.7 mmol) of a Pd(PPh₃)₄, and 63.0 g (453.0 mmol) of K₂CO₃ were added thereto, and the mixture was heated under reflux at a temperature of 80° C. for 18 hours. After the completion of the reaction, the reaction mixture was concentrated under reduced pressure, and an extraction process was performed thereon using 200 ml of ethyl acetate. An organic layer obtained therefrom was then dried with magnesium sulfate, and then, subjected to distillation under reduced pressure. The resulting product was purified by liquid chromatography, thereby obtaining 18.0 g (yield: 46%) of Intermediate Ir-14-6.

Synthesis of Intermediate Ir-14-5

55.3 mmol of Intermediate Ir-14-6 was mixed with 200 ml of methanol, and 1.0 g (10 wt %) of a Pd(PPh₃)₄ was added thereto. By injecting hydrogen thereto, the mixed solution was stirred for 18 hours. After the completion of the reaction, the reaction mixture was passed through a celite pad, and then, concentrated under reduced pressure. The resulting product was purified by liquid chromatography, thereby obtaining Intermediate Ir-14-5.

Synthesis of Intermediate Ir-14-4

50.0 mmol of Intermediate Ir-14-5 was mixed with 60 ml of CH₂Cl₂, and 100.0 mmol of 3-chlorobenzoic acid (mCPBA) was slowly added thereto dropwise at a temperature of 0° C. . The resulting product was stirred for one day. After the completion of the reaction, an extraction process was performed on the reaction mixture by using 6N KOH, and an organic layer obtained therefrom was dried with magnesium sulfate. The resulting product was purified by liquid chromatography, thereby obtaining Intermediate Ir-14-4.

Synthesis of Intermediate Ir-14-3

47.2 mmol of Intermediate Ir-14-4 was mixed with acetic anhydride, and the mixed solution was heated under reflux. After the completion of the reaction, an extraction process was performed on the reaction mixture by using saturated sodium bicarbonate aqueous solution. An organic layer obtained therefrom was dried with magnesium sulfate, and then, was subjected to distillation under reduced pressure. The resulting product was purified by liquid chromatography, thereby obtaining Intermediate Ir-14-3.

Synthesis of Intermediate Ir-14-2

34.8 mmol of Intermediate Ir-14-3 was mixed with 350 ml of CH₂Cl₂, and 24 g (87.4 mmol) of POBr₃ was slowly added thereto dropwise at a temperature of 0° C. Then, 5.0 ml of DMF was added thereto, and the resulting solution was stirred for 24 h at room temperature. After the completion of the reaction, an extraction process was performed on the reaction mixture by using saturated sodium bicarbonate aqueous solution. An organic layer obtained therefrom was dried with magnesium sulfate, and then, was subjected to distillation under reduced pressure. The resulting product was purified by liquid chromatography, thereby obtaining Intermediate Ir-14-2.

Synthesis of Intermediate Ir-14-1

Intermediate Ir-14-1 was synthesized in the same manner as in the synthesis of Intermediate Ir-12-1, except that Intermediate Ir-14-2 was used instead of Intermediate Ir-12-2.

Synthesis of Intermediate Ir-14-Ligand

Intermediate Ir-14-Ligand was synthesized in the same manner as in the synthesis of Intermediate Ir-12-Ligand, except that Intermediate Ir-14-1 was used instead of Intermediate Ir-12-1.

LC-MS m/z=344(M+H)⁺

Synthesis of Ir-14-Dimer

Ir-14-Dimer was synthesized in the same manner as in the synthesis of Ir-12-Dimer, except that Intermediate Ir-14-Ligand was used instead of Intermediate Ir-12-Ligand.

Synthesis of Compound Ir-14

1.5 g (0.82 mmol) of Ir-14-Dimer, 0.38 g (2.05 mmol) of 2,2,6,6-tetramethylheptane-3,5-dione, and 0.34 g (2.46 mmol) of K₂CO₃ were mixed with 30 ml of 2-ethoxyethanol, and the mixture was stirred for 48 hours. When the reaction proceeded, a solid obtained by filtering the reaction mixture was sufficiently washed with methanol and hexane, and then, was subjected to column chromatography under conditions of dichloromethane: n-hexane=1:2(v/v), thereby obtaining 0.8 g (yield: 46%) of Compound Ir-14. The synthesized compound was identified by LCMS.

LC-MS m/z=1061(M+H)⁺

### Synthesis Example of Compound Ir-15

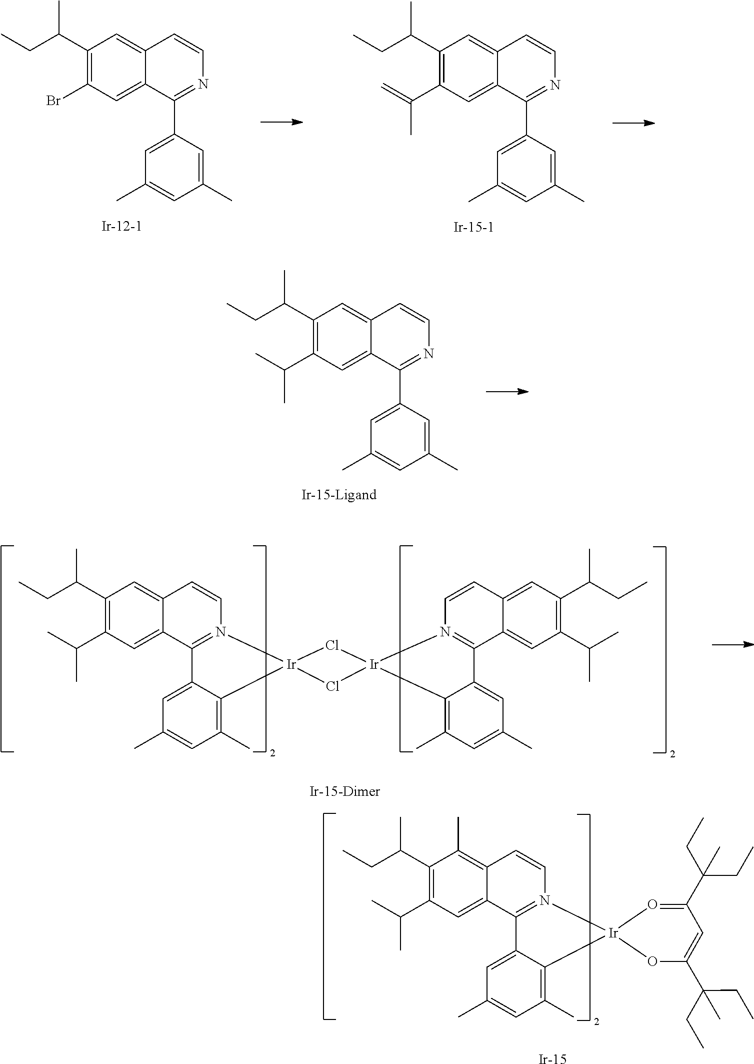

Synthesis of Intermediate Ir-15-1

1.52 g (4.12 mmol) of Intermediate Ir-12-1 was mixed with 400 ml of THF and 60 ml of water, and 1.0 g (6.2 mmol) of 4,4,5,5-tetramethyl-2-(prop-1-en-2-yl)-1,3,2-dioxaborolane, 0.3 g (0.3 mmol) of Pd(PPh₃)₄, and 1.4 g (10.3 mmol) of K₂CO₃ were added thereto. The mixture was then heated under reflux at a temperature of 80° C. for 18 hours. After the completion of the reaction, the reaction mixture was concentrated under reduced pressure, and an extraction process was performed thereon using 30 ml of ethyl acetate. An organic layer obtained therefrom was then dried with magnesium sulfate, and then, subjected to distillation under reduced pressure. The resulting product was purified by liquid chromatography, thereby obtaining 1.1 g (yield: 81%) of Intermediate Ir-15-1.

LC-MS m/z=330(M+H)⁺

Synthesis of Intermediate Ir-15-Ligand

1.0 g (3.0 mmol) of Intermediate Ir-15-1 was mixed with 50 ml of MeOH, and 19.0 g (30.0 mmol) of ammonium formate and 0.15 g of Pd/C were added thereto. The mixture was then heated under reflux at a temperature of 70° C. for 6 hours. After the completion of the reaction, the reaction mixture was filtered through a celite pad, and then, concentrated under reduced pressure. The resulting product was purified by liquid chromatography, thereby obtaining 0.9 g (yield: 95%) of Intermediate Ir-15-Ligand.

LC-MS m/z=332(M+H)⁺

Synthesis of Ir-15-Dimer

Ir-15-Dimer was synthesized in the same manner as in the synthesis of Ir-12-Dimer, except that Intermediate Ir-15-Ligand was used instead of Intermediate Ir-12-Ligand.

Synthesis of Compound Ir-15

0.6 g (yield: 47%) of Compound Ir-15 was synthesized in the same manner as in the synthesis of Compound Ir-12, except that Ir-15-Dimer and 3,7-diethyl-3,7-dimethylnonane-4,6-dione were used instead of Ir-12-Dimer and 3,3,7,7-tetramethylnonane-4,6-dione, respectively.

LC-MS m/z=1093(M+H)⁺

### Synthesis Example of Compound Ir-16

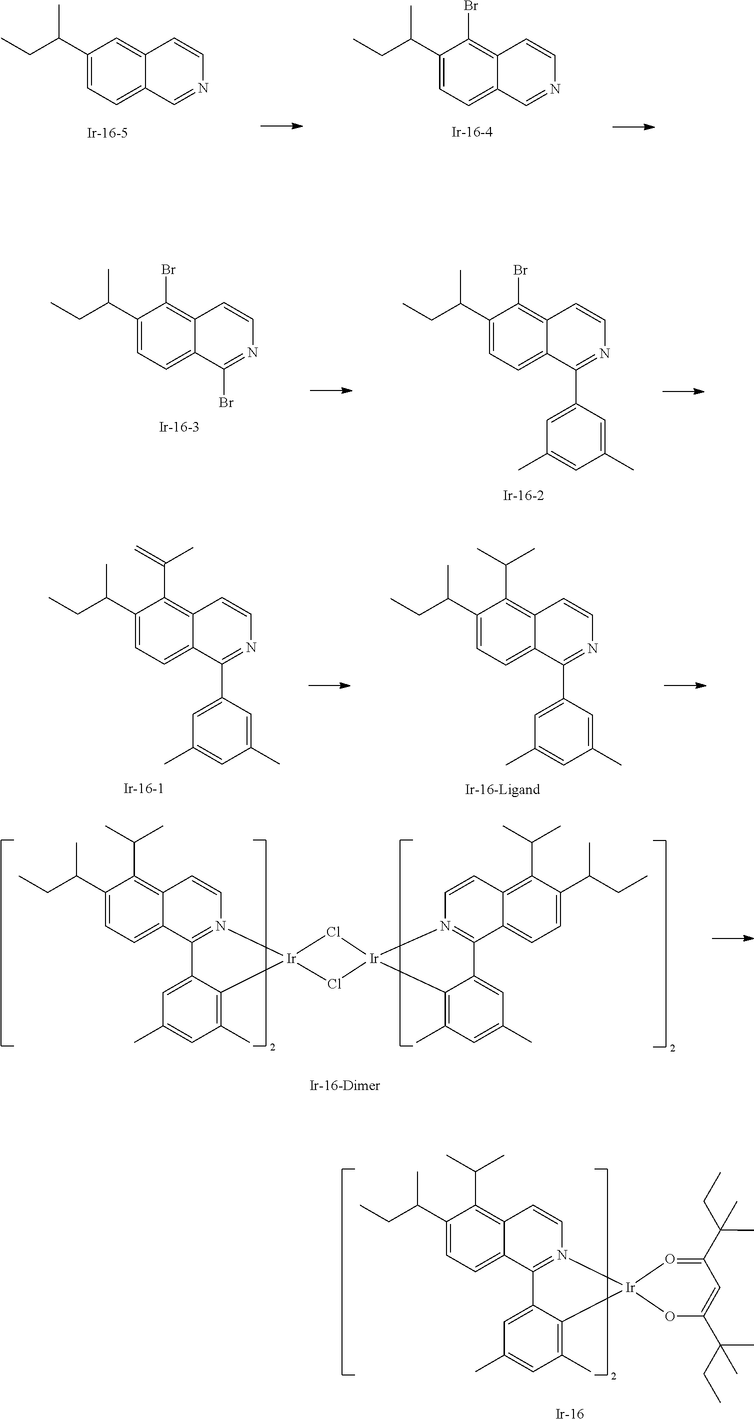

Synthesis of Intermediate Ir-16-4

Intermediate Ir-16-4 was synthesized in the same manner as in the synthesis of Intermediate Ir-13-3, except that Compound Ir-16-5 was used instead of Intermediate Ir-13-4.

Synthesis of Intermediate Ir-16-3

Intermediate Ir-16-3 was synthesized in the same manner as in the synthesis of Intermediate Ir-13-2, except that Intermediate Ir-16-4 was used instead of Intermediate Ir-13-3.

Synthesis of Intermediate Ir-16-2

Intermediate Ir-16-2 was synthesized in the same manner as in the synthesis of Intermediate Ir-13-1, except that Intermediate Ir-16-3 was used instead of Intermediate Ir-13-2.

LC-MS m/z=369(M+H)⁺

Synthesis of Intermediate Ir-16-1

Intermediate Ir-16-1 was synthesized in the same manner as in the synthesis of Intermediate Ir-12-1, except that Intermediate Ir-16-2 was used instead of Intermediate Ir-12-2.

LC-MS m/z=330(M+H)⁺

Synthesis of Intermediate Ir-16-Ligand

Intermediate Ir-16-Ligand was synthesized in the same manner as in the synthesis of Intermediate Ir-15-Ligand, except that Intermediate Ir-16-1 was used instead of Intermediate Ir-15-1.

LC-MS m/z=332(M+H)⁺

Synthesis of Ir-16-Dimer

Ir-16-Dimer was synthesized in the same manner as in the synthesis of Ir-12-Dimer, except that Intermediate Ir-16-Ligand was used instead of Intermediate Ir-12-Ligand

Synthesis of Compound Ir-16

0.9 g (yield: 46%) of Compound Ir-16 was synthesized in the same manner as in the synthesis of Compound Ir-12, except that Ir-16-Dimer was used instead of Ir-12-Dimer.

LC-MS m/z=1065(M+H)⁺

### Synthesis Example of Compound Ir-17

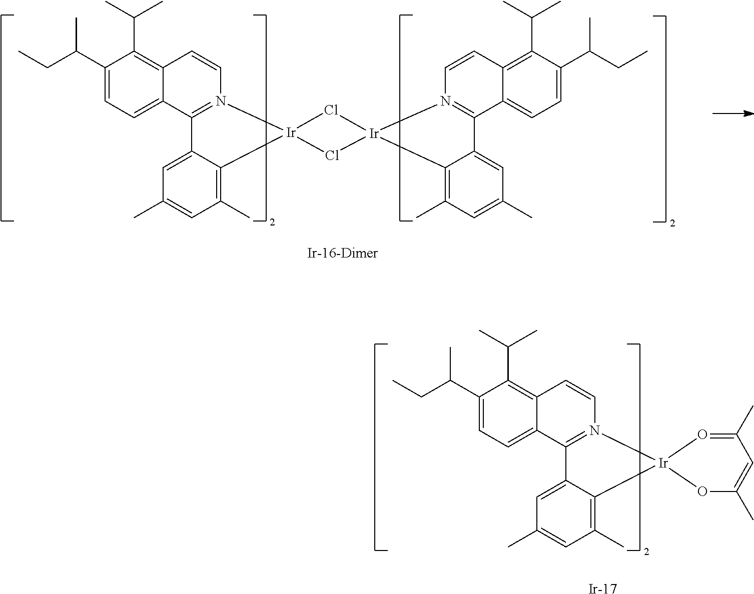

0.7 g (yield: 45%) of Compound Ir-17 was synthesized in the same manner as in the synthesis of Compound Ir-16, except that pentane-2,4-dione was used instead of 3,3,7,7-tetramethylnonane-4,6-dione.

LC-MS m/z=953(M+H)⁺

### Synthesis Example of Compound Ir-18

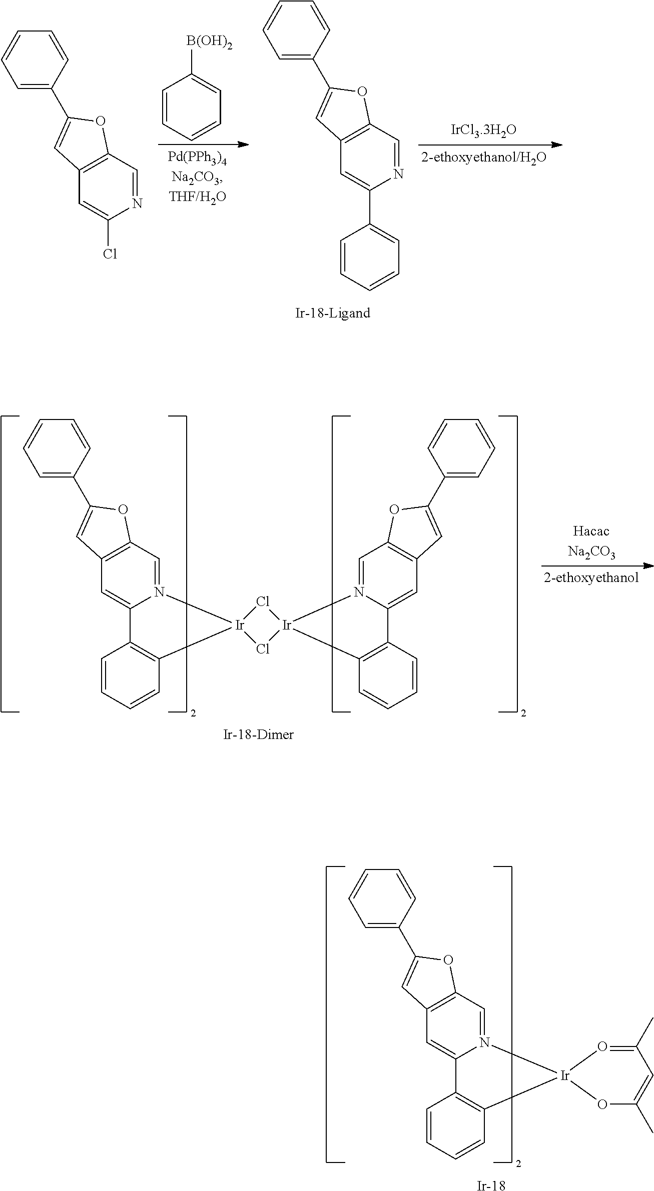

Synthesis of Intermediate Ir-18-Ligand

5-chloro-2-phenylfuro[2,3-c]pyridine (2.55 g, 11.1 mmol), phenylboronic acid (2.603 g, 16.64 mmol), Pd(PPh₃)₄ (1.03 g, 0.89 mmol), and K₂CO₃ (3.83 g, 27.7 mmol) were mixed with 60 mL of tetrahydrofuran and 30 mL of distilled water, stirred at a temperature of 90° C. for 18 hours, and then cooled to room temperature. The reaction mixture was extracted with ethyl acetate, dried by using anhydrous magnesium sulfate (MgSO₄), and filtered to obtain a filtrate. The filtrate was concentrated under vacuum to obtain a residue. The residue was purified by column chromatography with ethyl acetate:hexane=1:2 (v/v) as an eluent to obtain Intermediate Ir-18-Ligand (2.90 g, yield: 83%).

LC-MS m/z=272.31 (M+H)⁺.

Synthesis of Intermediate Ir-18-Dimer

Intermediate Ir-18-Ligand (1.99 g, 7.32 mmol) and Iridium chloride hydrate (1.15 g, 3.25 mmol) were mixed with 21 mL of 2-ethoxy ethanol and 7 mL of distilled water, stirred at a temperature of 120° C. for 24 hours under reflux, and then cooled to room temperature. A solid obtained therefrom was filtered, and the filtered solid was sufficiently washed in the order of water/methanol/hexane. The solid was dried in a vacuum oven to obtain Intermediate Ir-18-Dimer (1.95 g, yield: 78%). The obtained compound was used in a next reaction without additional purification.

Synthesis of Compound Ir-18

30 mL of 2-ethoxy ethanol was added to Intermediate Ir-18-Dimer (1.94 g, 1.26 mmol), acetyl acetone (1.26 g, 12.6 mmol), and Na₂CO₃ (1.33 g, 12.6 mmol), and stirred at room temperature for 12 hours. The reaction mixture was extracted using ethyl acetate, dried by using anhydrous magnesium sulfate (MgSO₄), and filtered to obtain a filtrate. The filtrate was concentrated under vacuum to obtain a residue. The residue was purified by column chromatography with methylene chloride:hexane=1:4 (v/v) as an eluent to obtain Compound Ir-18 (0.453 g, yield: 22%). The obtained compound was identified by MS and HPLC analysis.

HRMS(MALDI-TOF) calcd for C₄₃H₃₁IrN₂O₄: m/z 832.1913, Found: 832.1912.

### Synthesis Example of Compound Ir-19

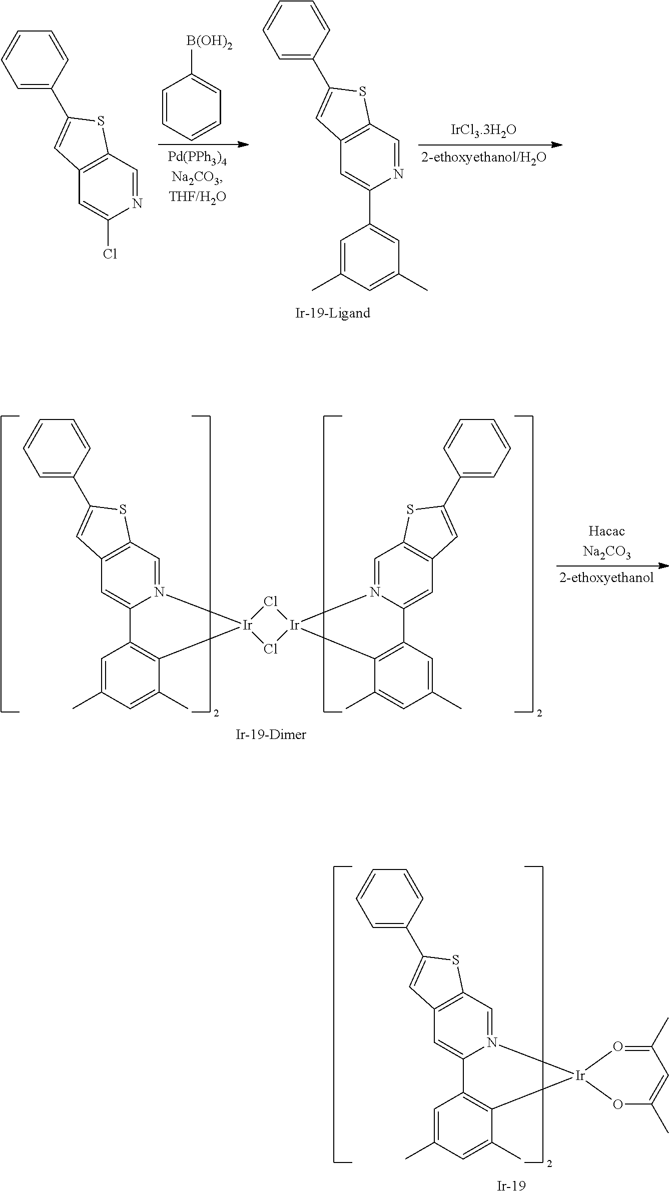

Synthesis of Intermediate Ir-19-Ligand

5-chloro-2-phenylthieno[2,3-c]pyridine (2.34 g, 9.51 mmol), (3,5-dimethylphenyl)boronic acid (2.64 g, 17.56 mmol), Pd(PPh₃)₄ (1.08 g, 0.94 mmol), and K₂CO₃ (4.05 g, 29.3 mmol) were mixed with 60 mL of tetrahydrofuran and 30 mL of distilled water, stirred at a temperature of 90° C. for 18 hours, and then cooled to room temperature. The reaction mixture was extracted using ethyl acetate, dried by using anhydrous magnesium sulfate (MgSO₄), and filtered to obtain a filtrate. The filtrate was concentrated under vacuum to obtain a residue. The residue was purified by column chromatography with ethyl acetate:hexane=1:2 (v/v) as an eluent to obtain Intermediate Ir-19-Ligand (2.54 g, yield: 85%).

LC-MS m/z=316 (M+H)⁺.

Synthesis of Intermediate Ir-19-Dimer

Intermediate Ir-19-Ligand (2.07 g, 6.57 mmol) and iridium chloride hydrate (1.07 g, 3.03 mmol) were mixed with 21 mL of 2-ethoxy ethanol and 7 mL of distilled water, stirred at a temperature of 120° C. for 24 hours under reflux, and then cooled to room temperature. A solid obtained therefrom was filtered, and the filtered solid sufficiently washed in the order of water/methanol/hexane. The solid was dried in a vacuum oven to obtain Intermediate Ir-19-Dimer (2.11 g, yield: 84%). The obtained compound was used in a next reaction without additional purification.

Synthesis of Compound Ir-19

30 mL of 2-ethoxy ethanol was added to Intermediate Ir-19-Dimer (2.05 g, 1.20 mmol), acetyl acetone (1.29 g, 12.9 mmol), and Na₂CO₃ (1.37 g, 12.9 mmol), and stirred at room temperature for 12 hours. The reaction mixture was extracted using ethyl acetate, dried by using anhydrous magnesium sulfate (MgSO₄), and filtered to obtain a filtrate. The filtrate was concentrated under vacuum to obtain a residue. The residue was purified by column chromatography with methylene chloride:hexane=1:4 (v/v) as an eluent to obtain Compound Ir-19 (0.41 g, yield: 19%). The obtained compound was identified by MS and HPLC analysis.

HRMS (MALDI-TOF) calcd for C₄₇H₃₉IrN₂O₂ S₂: m/z 920.2082, Found: 920.2080.

### Synthesis Example of Compound Ir-20

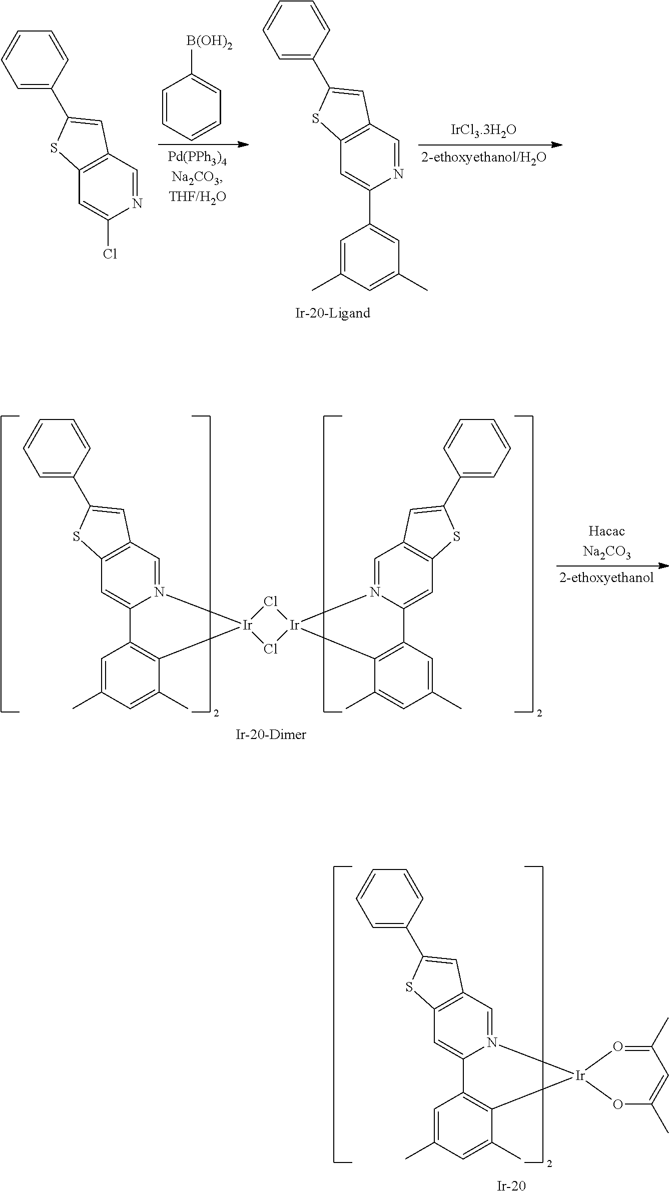

Synthesis of Intermediate Ir-20-Ligand

6-chloro-2-phenylthieno[3,2-c]pyridine (2.34 g, 9.51 mmol), (3,5-dimethylphenyl)boronic acid (2.64 g, 17.56 mmol), Pd(PPh₃)₄ (1.08 g, 0.94 mmol), and K₂CO₃ (4.05 g, 29.3 mmol) were mixed with 60 mL of tetrahydrofuran and 30 mL of distilled water, stirred at a temperature of 90° C. for 18 hours, and then cooled to room temperature. The reaction mixture was extracted using ethyl acetate, dried by using anhydrous magnesium sulfate (MgSO₄), and filtered to obtain a filtrate. The filtrate was concentrated under vacuum to obtain a residue. The residue was purified by column chromatography with ethyl acetate:hexane=1:2 (v/v) as an eluent to obtain Intermediate Ir-20-Ligand (2.67 g, yield: 87%).

LC-MS m/z=316 (M+H

Synthesis of Intermediate Ir-20-Dimer

Intermediate Ir-20-Ligand (2.32 g, 7.36 mmol) and iridium chloride hydrate (1.07 g, 3.03 mmol) were mixed with 21 mL of 2-ethoxy ethanol and 7 mL of distilled water, stirred at a temperature of 120° C. for 24 hours under reflux, and then cooled to room temperature. A solid obtained therefrom was filtered, and the filtered solid sufficiently washed in the order of water/methanol/hexane. The solid was dried in a vacuum oven to obtain Intermediate Ir-20-Dimer (2.25 g, yield: 80%). The obtained compound was used in a next reaction without additional purification.

Synthesis of Compound Ir-20

30 mL of 2-ethoxy ethanol was added to Intermediate Ir-20-Dimer (2.14 g, 1.25 mmol), acetyl acetone (1.29 g, 12.9 mmol), and Na₂CO₃ (1.37 g, 12.9 mmol), and stirred at room temperature for 12 hours. The reaction mixture was extracted using ethyl acetate, dried by using anhydrous magnesium sulfate (MgSO₄), and filtered to obtain a filtrate. The filtrate was concentrated under vacuum to obtain a residue. The residue was purified by column chromatography with methylene chloride:hexane=1:4 (v/v) as an eluent to obtain Compound Ir-20 (0.526 g, yield: 23%). The obtained compound was identified by MS and HPLC analysis.

HRMS (MALDI-TOF) calcd for C₄₇H₃₉IrN₂O₂S₂: m/z 920.2082, Found: 920.2081.

### Synthesis Example of Compound Ir-21

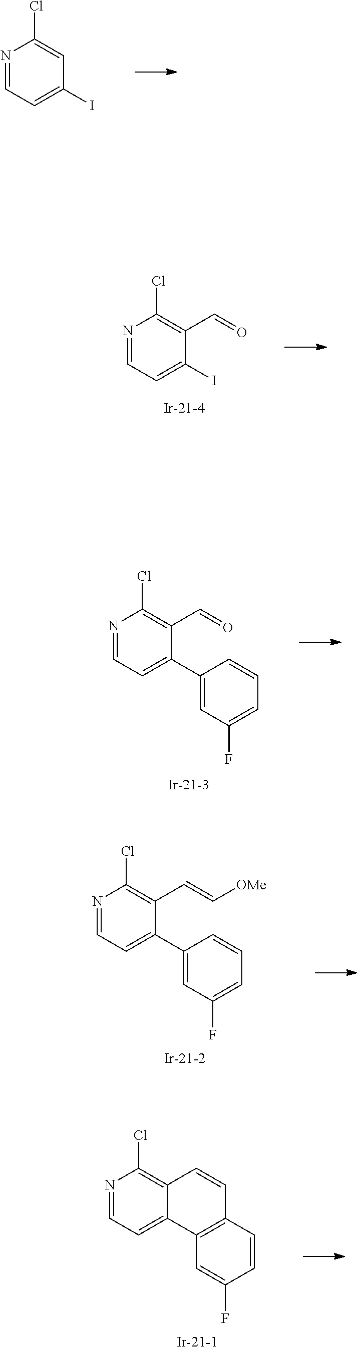

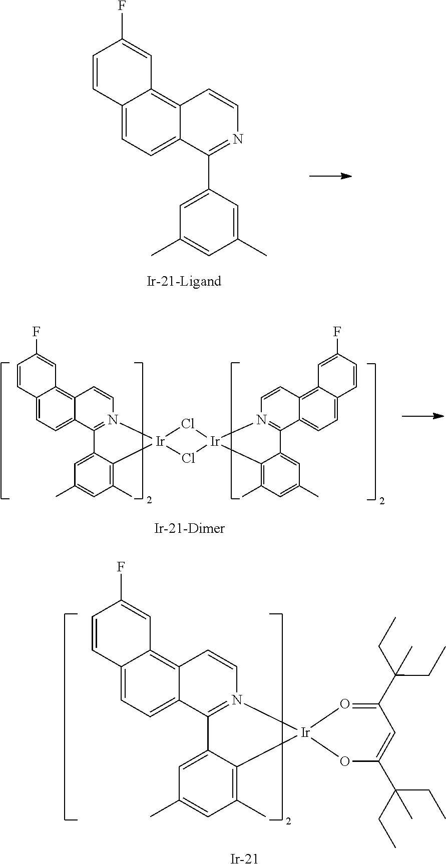

Synthesis of Intermediate Ir-21-4

5 g (20.9 mmol) of 2-chloro-4-iodopyridine was mixed with 50 ml of anhydrous THF, and then 12.5 ml (25 mmol) of lithium diisopropylamide in THF was slowly added dropwise thereto at a temperature of −78° C. . After 3 hours, 2.5 ml (32 mmol) of ethylformate was slowly added dropwise thereto and then stirred at room temperature for 18 hours. The organic layer was extracted from the resulting mixture using water and ethyl acetate and dried by using magnesium sulfate (MgSO₄). The solvent was removed under reduced pressure, and the residue obtained therefrom was purified by column chromatography to obtain 2.2 g (yield: 40%) of Intermediate Ir-21-4.

LC-MS m/z=268(M+H)⁺

Synthesis of Intermediate Ir-21-3

1.9 g (7.2 mmol) of Intermediate Ir-21-4 was mixed with 60 mL of acetonitrile and 15 mL of water, 0.4 g (0.5 mmol) of PdCl₂(PPh₃)₂, 1.0 g (7.2 mmol) of 3-fluorophenylboronic acid and 2.5 g (18.0 mmol) of K₂CO₃ were added thereto and the reaction mixture was stirred at a temperature of 80° C. for 18 hours under reflux. The resulting mixture was concentrated under reduced pressure and an extraction process was performed thereon using dichloromethane and water. The resulting organic layer was dried by using magnesium sulfate (MgSO₄), the solvent was removed from the resulting organic layer under reduced pressure, and the residue obtained therefrom was purified by column chromatography to obtain 1.4 g (yield: 78%) of Intermediate Ir-21-3.

LC-MS m/z=236(M+H)⁺

Synthesis of Intermediate Ir-21-2

5.4 g (15.8 mmol) of (methoxymethyl)triphenylphosphonium chloride was mixed with 50 mL of anhydrous ethyl ether, 16 mL of 1.0 M Potassium tert-butoxide solution was added dropwise thereto and was stirred at a room temperature for 1 hour. Then, a mixture of 30 mL of anhydrous THF and 1.5 g (6.3 mmol) of Intermediate Ir-21-3 was slowly added dropwise thereto and was stirred at a room temperature for 18 hours. The organic layer was extracted from the resulting mixture using water and ethyl acetate and dried by using magnesium sulfate (MgSO₄). The solvent was removed under reduced pressure, and the residue obtained therefrom was purified by column chromatography to obtain 1.6 g (yield: 95%) of Intermediate Ir-21-2.

LC-MS m/z=264(M+H)⁺

Synthesis of Intermediate Ir-21-1

1.4 g (5.1 mmol) of Intermediate Ir-21-2 was mixed with 40 mL of dichloromethane, 3.0 mL of methanesulfonic acid was slowly dropwise thereto and was stirred at a room temperature for 18 hours. The organic layer was extracted from the resulting mixture using saturated sodium hydrogen carbonate aqueous solution and dried by using magnesium sulfate (MgSO₄). The solvent was removed under reduced pressure, and the residue obtained therefrom was purified by column chromatography to obtain 1.0 g (yield: 90%) of Intermediate Ir-21-1.

LC-MS m/z=232(M+H)⁺

Synthesis of Intermediate Ir-21-Ligand

1.0 g (4.1 mmol) of Intermediate Ir-21-1 was mixed with 40 mL of THF and 10 mL of water, 0.9 g (6.2 mmol) of 3, 5-dimethylphenylboronic acid, 0.09 g (0.4 mmol) of Pd(OAc)₂, 0.35 g (0.82 mmol) of Sphos and 1.4 g (10.3 mmol) of K₂CO₃ were added thereto and was stirred for 1 day under reflux. The organic layer was extracted from the resulting mixture using water and ethyl acetate and dried by using magnesium sulfate (MgSO₄). The solvent was removed under reduced pressure, and the residue obtained therefrom was purified by column chromatography to obtain 1.1 g (yield: 85%) of Intermediate Ir-21-Ligand.

LC-MS m/z=302(M+H)⁺

Synthesis of Intermediate Ir-21-Dimer

1.05 g (3.4 mmol) of Intermediate Ir-21-Ligand and 0.6 g (1.6 mmol) of iridium chloride were mixed with 40 mL of 2-ethoxyethanol and 15 mL of distilled water, and the resulting solution was stirred under reflux for 24 hours. When the reaction was complete, the temperature was lowered to room temperature. A solid produced therefrom was separated by filtration, and then, sufficiently washed using water/methanol/hexane in the stated order. The resulting solid was dried in a vacuum oven, thereby obtaining 1.1 g of Ir-21-Dimer.

Synthesis of Compound Ir-21

1.0 g (0.63 mmol) of Ir-21-Dimer, 0.9 g (4.5 mmol) of 3,7-diethyl-3,7-dimethylnonane-4,6-dione, and 0.48 g (4.5 mmol) of Na₂CO₃ were mixed with 40 mL of 2-ethoxyethanol, and the mixed solution was stirred for 24 hours at a temperature of 90° C. When the reaction was complete, a solid obtained by filtering the reaction mixture was subjected to column chromatography, thereby obtaining 1.0 g of Compound Ir-21 (yield: 80%).

LC-MS m/z=1035(M+H)⁺

### Synthesis Example of Compound Ir-22

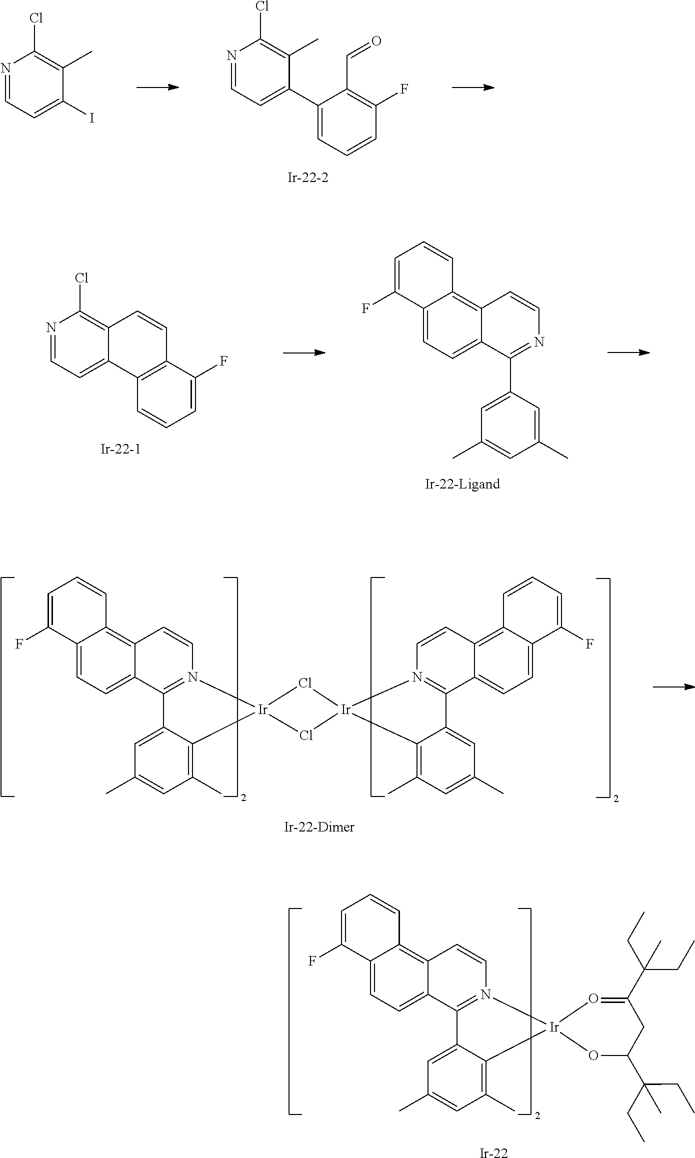

Synthesis of Intermediate Ir-22-2

6.0 g (23.7 mmol) of 2-chloro-4-iodo-3-methylpyridine was mixed with 80 mL of acetonitrile and 20 ml of water, 1.2 g (1.6 mmol) of PdCl₂(PPh₃)₂, 4.4 g (26.1 mmol) of 3-fluoro-2-formylphenyl)boronic acid, and 8.2 g (59.2 mmol) of K₂CO₃ were added thereto and stirred for 18 hours at a temperature of 80° C. The resulting mixture was concentrated under reduced pressure and an extraction process was performed thereon using water and ethyl acetate. The resulting organic layer was dried by using magnesium sulfate (MgSO₄), the solvent was removed from the resulting organic layer under reduced pressure, and the residue obtained therefrom was purified by column chromatography to obtain 5.0 g (yield: 85%) of Intermediate Ir-22-2.

LC-MS m/z=250(M+H)⁺

Synthesis of Intermediate Ir-22-1

4.0 g (16.0 mmol) of Intermediate Ir-22-2 was mixed with 150 mL of anhydrous N,N-dimethylformamide, 19 ml (19.2 mmol) of 1.0 M potassium tert-butoxide solution in THF was slowly added dropwise, and heated for 6 hours at a temperature of 80° C. When the reaction was complete, the organic layer was extracted from the resulting mixture using water and ethyl acetate, dried by using magnesium sulfate (MgSO₄) and filtered. From the resultant, the solvent was removed under reduced pressure, and the residue obtained therefrom was purified by column chromatography to obtain 1.3 g (yield: 35%) of Intermediate Ir-22-1.

LC-MS m/z=232(M+H)⁺

Synthesis of Intermediate Ir-22-Ligand

1.4 g (yield: 85%) of Intermediate Ir-22-Ligand was synthesized in the same manner as Synthesis of Intermediate Ir-21-Ligand, except that Intermediate Ir-22-1 was used instead of Intermediate Ir-21-1.

LC-MS m/z=303(M+H)⁺

Synthesis of Intermediate Ir-22-Dimer

Intermediate Ir-22-Dimer was synthesized in the same manner as Synthesis of Intermediate Ir-21-Dimer, except that Intermediate Ir-22-Ligand was used instead of Intermediate Ir-21-Ligand.

Synthesis of Compound Ir-22

0.6 g (yield: 47%) of Compound Ir-22 was synthesized in the same manner as Synthesis of Compound Ir-21, except that Intermediate Ir-22-Dimer was used instead of Intermediate Ir-21-Dimer.

LC-MS m/z=1035(M+H)⁺

### Synthesis Example of Compound Ir-23

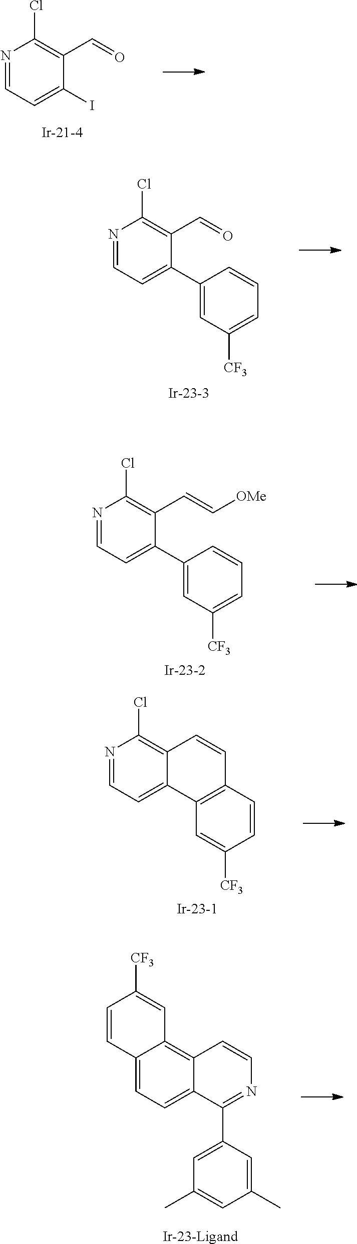

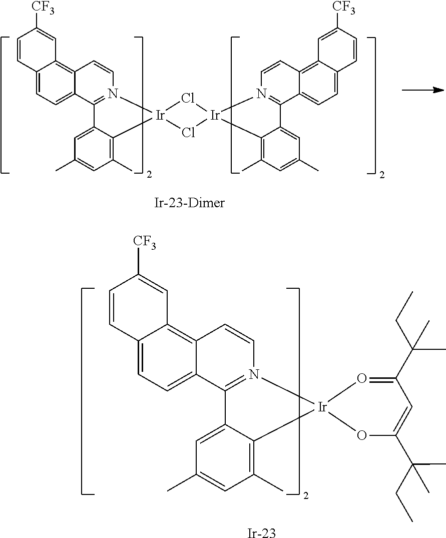

Synthesis of Intermediate Ir-23-3

2.5 g (yield: 73%) of Intermediate Ir-23-3 was synthesized in the same manner as Synthesis of Intermediate Ir-21-3, except that 3-(trifluoromethyl)phenylboronic acid was used instead of 3-fluorophenylboronic acid.

LC-MS m/z=286(M+H)⁺

Synthesis of Intermediate Ir-23-2

2.7 g (yield: 99%) of Intermediate Ir-23-2 was synthesized in the same manner as Synthesis of Intermediate Ir-21-2, except that Intermediate Ir-23-3 was used instead of Intermediate Ir-21-3.

LC-MS m/z=314(M+H)⁺

Synthesis of Intermediate Ir-23-1

1.1 g (yield: 45%) of Intermediate Ir-23-1 was synthesized in the same manner as Synthesis of Intermediate Ir-21-1, except that Intermediate Ir-23-2 was used instead of Intermediate Ir-21-2.

LC-MS m/z=282(M+H)⁺

Synthesis of Intermediate Ir-23-Ligand

1.1 g (yield: 80%) of Intermediate Ir-23-Ligand was synthesized in the same manner as Synthesis of Intermediate Ir-21-Ligand, except that Intermediate Ir-23-1 was used instead of Intermediate Ir-21-1.

LC-MS m/z=352(M+H)⁺

Synthesis of Intermediate Ir-23-Dimer

Intermediate Ir-23-Dimer was synthesized in the same manner as Synthesis of Intermediate Ir-21-Dimer, except that Intermediate Ir-23-Ligand was used instead of Intermediate Ir-21-Ligand.

Synthesis of Compound Ir-23

0.7 g (yield: 43%) of Compound Ir-23 was synthesized in the same manner as Synthesis of Compound Ir-21, except that Intermediate Ir-23-Dimer and 3,3,7,7-tetramethylnonane-4,6-dione were used instead of Intermediate Ir-21-Dimer and 3,7-diethyl-3,7-dimethylnonane-4,6-dione, respectively.

LC-MS m/z=1107(M+H)⁺

### Synthesis Example of Compound Ir-24

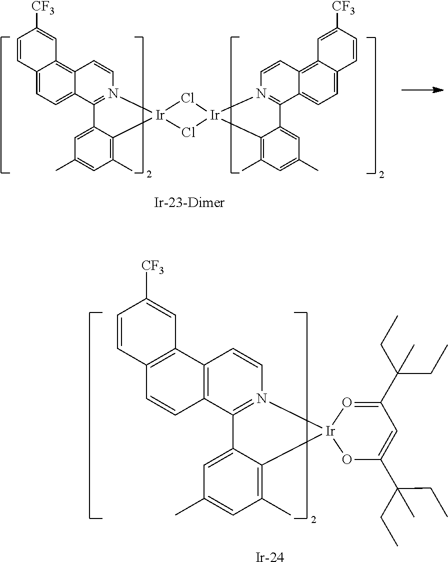

19.00 g (11.48 mmol) of Ir-23-Dimer, 13.80 g (57.40 mmol) of 3,7-diethyl-3,7-dimethylnonane-4,6-dione, and 12.17 g (114.80 mmol) of Na₂CO₃ were mixed with 300 mL of 2-ethoxyethanol, and the mixed solution was stirred for 24 hours. When the reaction was complete, a solid produced therefrom was separated by filtration, and then, sufficiently washed using methanol and hexane. The resulting solid was subjected to column chromatography under conditions of dichloromethane: n-hexane=1:1(v/v), thereby obtaining 13.00 g of Compound Ir-24 (yield: 55%).

HRMS(MALDI) calcd for C₅₉H₅₇F₆IrN₂O₂: m/z 1132.38, Found: 1132.35.

### Synthesis Example of Compound Ir-25

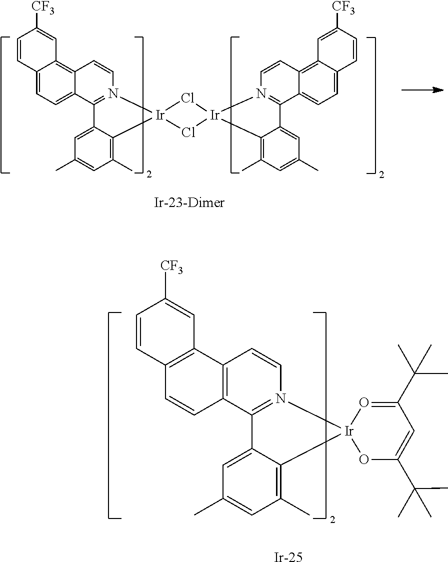

5 g (yield: 50%) of Compound Ir-25 was synthesized in the same manner as Synthesis of Compound Ir-24, except that 2,2,6,6-tetramethylheptane-3,5-dione was used instead of 3,7-diethyl-3,7-dimethylnonane-4,6-dione.

HRMS(MALDI) calcd for C₅₅H₄₉F₆IrN₂O₂: m/z 1076.33, Found: 1076.35.

### Evaluation Example 1-1: Evaluation of x Coordinate Value and y Coordinate Value of PMI Diagram

A molecular structure of Compound Pt-A was optimized by using a B3LYP/LanL2DZ function with respect to a transition metal (Pt) included in Compound Pt-A and a B3LYP/6-31G(D,P) function with respect to an organic ligand included in Compound Pt-A, and a DFT calculation was performed by using Gaussian program to evaluate three PMIs of Compound Pt-A. The smallest value among the evaluated three PMIs of Compound Pt-A was defined as I₁, and the greatest value was defined as I₃. A value between I₁ and I₃ was defined as I₂. I₁/I₃ of Compound Pt-A was defined as x that is a x coordinate value in the PMI diagram of Compound Pt-A, and I₂/I₃ of Compound Pt-A was defined as y that is a y coordinate value in the PMI diagram of Compound Pt-A. This process was sequentially performed on Compounds Pt-B to Pt-I and Pt-1 to Pt-2, and results of the study are shown in Table 1 to 4.

TABLE 1

| | | | | | 1.02 − x ≤ y ≤ 1.95 − 2.7x |
|---|---|---|---|---|---|
| | | | | | Satisfaction status |
| Compound | | | 1.95 − | | ◯: Satisfied |
| No. | x | 1.02 − x | 2.7x | y | X: Not satisfied |
| Pt-A | 0.414 | 0.606 | 0.8322 | 0.610 | ◯ |
| Pt-B | 0.416 | 0.604 | 0.8268 | 0.599 | X |
| Pt-C | 0.523 | 0.497 | 0.5379 | 0.524 | ◯ |
| Pt-D | 0.493 | 0.527 | 0.6189 | 0.607 | ◯ |
| Pt-E | 0.262 | 0.758 | 1.2426 | 0.805 | ◯ |
| Pt-F | 0.361 | 0.659 | 0.9753 | 0.664 | ◯ |
| Pt-G | 0.243 | 0.777 | 1.2939 | 0.805 | ◯ |
| Pt-H | 0.398 | 0.622 | 0.8754 | 0.667 | ◯ |
| Pt-I | 0.273 | 0.747 | 1.2129 | 0.86 | ◯ |
| Pt-1 | 0.326 | 0.694 | 1.0698 | 0.779 | ◯ |
| Pt-2 | 0.276 | 0.744 | 1.2048 | 0.784 | ◯ |

TABLE 2

| | | | | | 1.06 − x ≤ y ≤ 1.95 − 2.7x |
|---|---|---|---|---|---|
| | | | | | Satisfaction status |
| Compound | | | 1.95 − | | ◯: Satisfied |
| No. | x | 1.06 − x | 2.7x | y | X: Not satisfied |
| Pt-A | 0.414 | 0.646 | 0.8322 | 0.61 | X |
| Pt-B | 0.416 | 0.644 | 0.8268 | 0.599 | X |
| Pt-C | 0.523 | 0.537 | 0.5379 | 0.524 | X |
| Pt-D | 0.493 | 0.567 | 0.6189 | 0.607 | ◯ |
| Pt-E | 0.262 | 0.798 | 1.2426 | 0.805 | ◯ |
| Pt-F | 0.361 | 0.70 | 0.9753 | 0.664 | X |
| Pt-G | 0.243 | 0.817 | 1.2939 | 0.805 | X |
| Pt-H | 0.398 | 0.662 | 0.8754 | 0.667 | ◯ |
| Pt-I | 0.273 | 0.787 | 1.2129 | 0.86 | ◯ |
| Pt-1 | 0.326 | 0.734 | 1.0698 | 0.779 | ◯ |
| Pt-2 | 0.276 | 0.784 | 1.2048 | 0.784 | ◯ |

TABLE 3

| | | | | | 1.06 − x ≤ y ≤ 4.70 − 10.0x |
|---|---|---|---|---|---|
| | | | | | Satisfaction status |
| Compound | | | 4.70 − | | ◯: Satisfied |
| No. | x | 1.06 − x | 10.0x | y | X: Not satisfied |
| Pt-A | 0.414 | 0.646 | 0.56 | 0.61 | X |
| Pt-B | 0.416 | 0.644 | 0.54 | 0.599 | X |
| Pt-C | 0.523 | 0.537 | −0.53 | 0.524 | X |
| Pt-D | 0.493 | 0.567 | −0.23 | 0.607 | X |
| Pt-E | 0.262 | 0.798 | 2.08 | 0.805 | ◯ |
| Pt-F | 0.361 | 0.70 | 1.09 | 0.664 | X |
| Pt-G | 0.243 | 0.817 | 2.27 | 0.805 | X |
| Pt-H | 0.398 | 0.662 | 0.72 | 0.667 | ◯ |
| Pt-I | 0.273 | 0.787 | 1.97 | 0.86 | ◯ |
| Pt-1 | 0.326 | 0.734 | 1.44 | 0.779 | ◯ |
| Pt-2 | 0.276 | 0.784 | 1.94 | 0.784 | ◯ |

TABLE 4

| | | | | | 1.02 − x ≤ y ≤ 1.16 − x |
|---|---|---|---|---|---|
| | | | | | Satisfaction status |
| Compound | | | | | ◯: Satisfied |
| No. | x | 1.02 − x | 1.16 − x | y | X: Not satisfied |
| Pt-A | 0.414 | 0.606 | 0.746 | 0.61 | ◯ |
| Pt-B | 0.416 | 0.604 | 0.744 | 0.599 | X |
| Pt-C | 0.523 | 0.497 | 0.637 | 0.524 | ◯ |
| Pt-D | 0.493 | 0.527 | 0.667 | 0.607 | ◯ |
| Pt-E | 0.262 | 0.758 | 0.898 | 0.805 | ◯ |
| Pt-F | 0.361 | 0.66 | 0.799 | 0.664 | ◯ |
| Pt-G | 0.243 | 0.777 | 0.917 | 0.805 | ◯ |
| Pt-H | 0.398 | 0.622 | 0.762 | 0.667 | ◯ |
| Pt-I | 0.273 | 0.747 | 0.887 | 0.86 | ◯ |
| Pt-1 | 0.326 | 0.694 | 0.834 | 0.779 | ◯ |
| Pt-2 | 0.276 | 0.744 | 0.884 | 0.784 | ◯ |

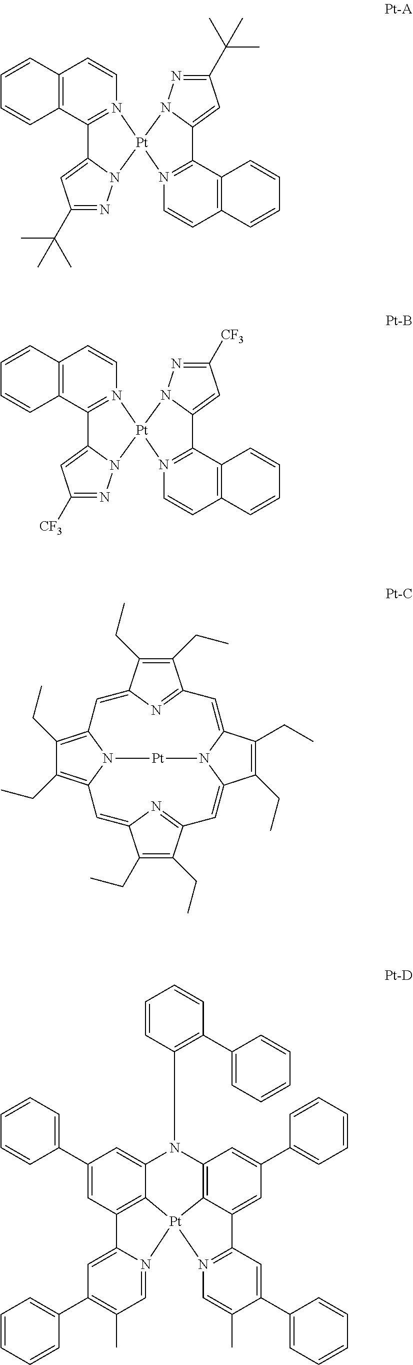

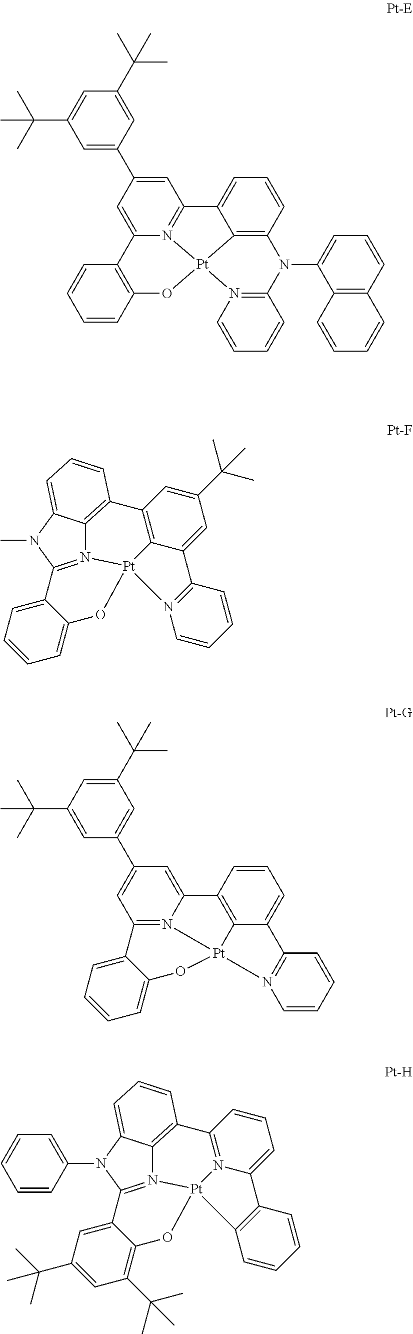

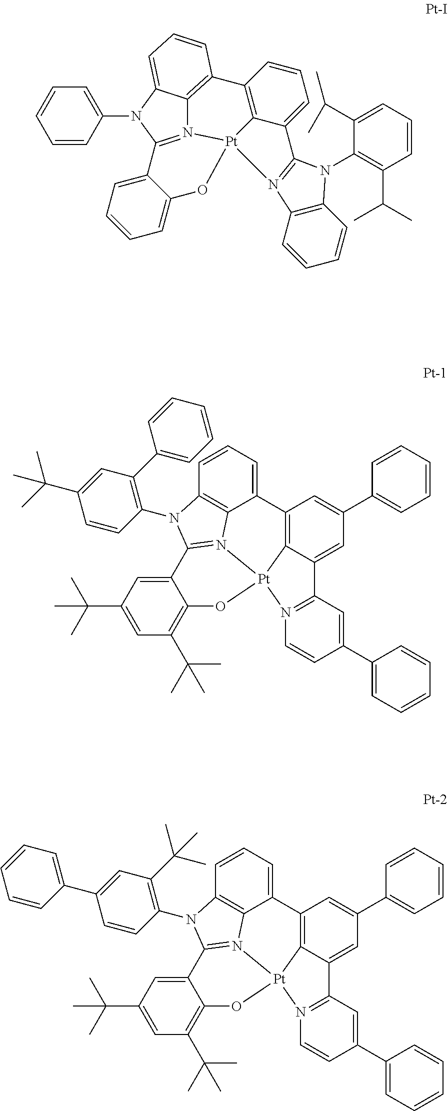

### Evaluation Example 2-1: Evaluation of Radiative Decay Rate

mCP and Compound Pt-A were co-deposited on a quartz substrate at a weight ratio of 96:4 at a vacuum degree of 10⁻⁷ torr to form a film having a thickness of 40 nanometers (nm).

A PL spectrum of the film was evaluated at room temperature by using a PicoQuant TRPL measurement system FluoTime 300 and a PicoQuant pumping source PLS340 (excitation wavelength=340 nm, spectral width=20 nm), a wavelength of a main peak of the spectrum was determined, and PLS340 repeatedly measured the number of photons emitted from the film at the wavelength of the main peak due to a photon pulse (pulse width=500 picoseconds, ps) applied to the film according to time based on time-correlated single photon counting (TCSPC), thereby obtaining a sufficiently fittable TRPL curve. T_{decay}(Ex) (decay time) of the film was obtained by fitting one or more exponential decay functions to the result obtained therefrom, and the radiative decay rate that is a reciprocal of T_{decay}(Ex) was calculated. Then, the radiative decay rate of Compound Pt-A was evaluated. The function used for fitting is expressed by Equation 20, and the greatest value of T_{decay} obtained from each exponential decay function used for fitting was taken as T_{decay}(Ex). At this time, a baseline or background signal curve was obtained by repeating the same measurement once more for the same measurement time as the measurement time for obtaining the TRPL curve in a dark state (a state in which a pumping signal applied to the predetermined film was blocked), and the baseline or background signal curve was used for fitting as a baseline.

$$f ( t ) = {\sum }_{i = 1}^{n} {A}_{i} exp ( - t / {T}_{decay , i} ) \qquad Equation 20$$

The measurement of the radiative decay time was performed on Compounds Pt-B to Pt-I and Pt-1 to Pt-2, and results of the study are shown in Table 5.

TABLE 5

| Compound No. | Radiative decay rate (s⁻¹) |
|---|---|
| Pt-A | 8.60 × 10⁴ |
| Pt-B | 3.00 × 10⁴ |
| Pt-C | 5.80 × 10³ |
| Pt-D | 2.10 × 10⁵ |
| Pt-E | 2.42 × 10⁵ |
| Pt-F | 1.37 × 10⁵ |
| Pt-G | 1.25 × 10⁵ |
| Pt-H | 1.02 × 10⁵ |
| Pt-I | 1.21 × 10⁵ |
| Pt-1 | 4.79 × 10⁵ |
| Pt-2 | 4.09 × 10⁵ |

*s⁻¹ = reverse seconds

Referring to Table 5, it is confirmed that all of Compounds Pt-A to Pt-I have a radiative decay rate of less than 2.5×10⁵s⁻¹.

### Evaluation Example 3-1: Evaluation of Horizontal Orientation Ratio

mCP and Compound Pt-1 were co-deposited on a quartz substrate at a weight ratio of 96:4 at a vacuum degree of 10⁻⁷ torr to form a film having a thickness of 40 nm, and a sealing glass plate was attached to the film to seal the film.

A PL of the film for each angle was measured from −150° to +150° by using a CoCoLink Luxol-OLED/analyzer LOA-100, and a horizontal orientation ratio of Compound Pt-1 was calculated by using a fitting program of an analyzer. Results of the study are shown in Table 6. This process was repeated on Compound Pt-2, and results of the study are also shown in Table 6.

TABLE 6

| | | Horizontal |
|---|---|---|
| | | orientation |
| Sample No. | Co-deposition materials | ratio (%) |
| Pt-1 | mCP: Compound Pt-1 (4 weight %) | 88 |
| Pt-2 | mCP: Compound Pt-2 (4 weight %) | 90 |

Referring to Table 6, it is confirmed that Compounds Pt-1 to Pt-2 have an excellent horizontal orientation ratio, that is, excellent horizontal optical orientation.

### Comparative Example Pt-A

A glass substrate on which an ITO electrode (1500 Å thick) was patterned as an anode was cut to a size of 50 mm×50 mm×0.5 mm (mm=millimeters), sonicated with iso-propyl alcohol, and pure water each for 5 minutes, and then cleaned by exposure to ultraviolet rays and ozone for 30 minutes.

Then, HT3 and F6-TCNNQ were co-deposited on the ITO electrode at a weight ratio of 98:2 to form a hole injection layer having a thickness of 100 Å, and HT3 was deposited on the hole injection layer to form a hole transport layer having a thickness of 1,650 Å.

CBP (host) and Pt-A (dopant) were co-deposited on the hole transport layer at a weight ratio of 90:10 to form an emission layer having a thickness of 400 Å.

Then, ET3 and ET-D1 were co-deposited on the emission layer at a volume ratio of 50:50 to form an electron transport layer having a thickness of 350 Å, ET-D1 was deposited on the electron transport layer to form an electron injection layer having a thickness of 10 Å, A₁ was vacuum-deposited on the electron injection layer to form a cathode having a thickness of 1000 Å, thereby completing the manufacture of an organic light-emitting device having a structure of ITO (1500 Å)/HT3+F6TCNNQ (2 wt %) (100 Å)/HT3 (1650 Å)/CBP+Pt-A (10 wt %) (400 Å)/ET3+ET-D1 (50%) (350 Å)/ET-D1 (10 Å)/A1(1000 Å).

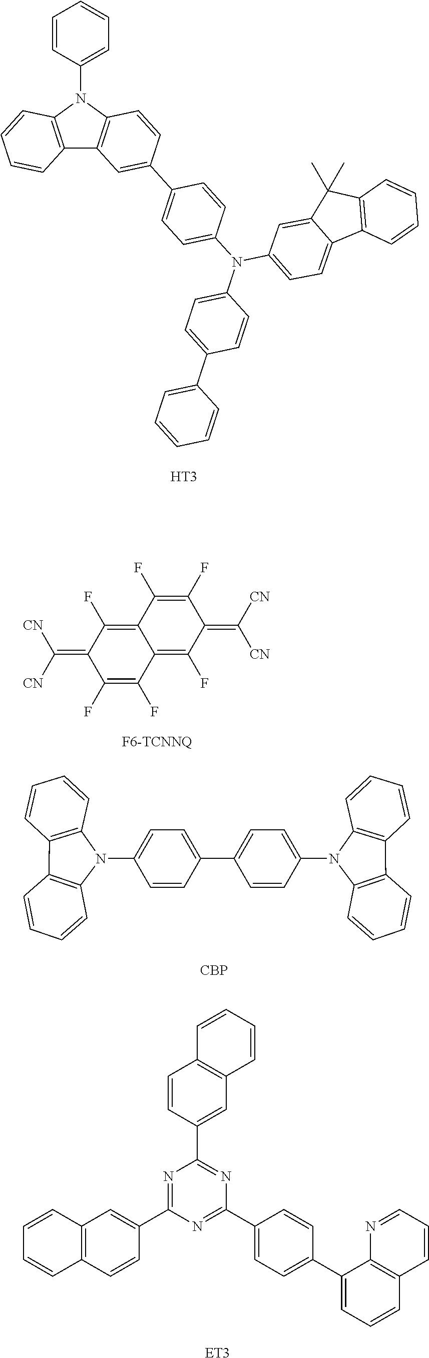

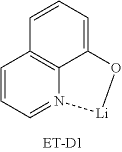

### Comparative Examples Pt-B to Pt-I and Examples Pt-1 to Pt-2

Organic light-emitting devices were manufactured in the same manner as in Comparative Example Pt-A, except that Compounds shown in Table 7 were each used instead of Compound Pt-A as a dopant in forming an emission layer.

### Evaluation Example 4-1: Evaluation of Characteristics of Organic Light-Emitting Devices

The maximum quantum emission efficiency (relative value) and roll-off ratio of the organic light-emitting devices manufactured according to Comparative Examples Pt-A to Pt-I and Examples Pt-1 to Pt-2 were evaluated by using a current-voltage meter (Keithley 2400) and a luminance meter (Minolta Cs-1000A), and results of the study are shown in Table 7. The roll-off ratio was calculated by Equation 30.

Roll-off ratio={1−(efficiency at 8,000 nit/maximum luminescent efficiency)}×100% Equation 30

TABLE 7

| | Dopant | Maximum quantum | |
|---|---|---|---|
| | compound | emission efficiency | Roll-off ratio (%) |
| | No. | (relative value, %) | (at 8000 nit) |
| Comparative | Pt-A | 67 | 35 |
| Example Pt-A | | | |
| Comparative | Pt-B | 41 | 21 |
| Example Pt-B | | | |
| Comparative | Pt-C | 52 | 89 |
| Example Pt-C | | | |
| Comparative | Pt-D | 96 | 25 |
| Example Pt-D | | | |
| Comparative | Pt-E | 63 | 13 |
| Example Pt-E | | | |
| Comparative | Pt-F | 70 | 11 |
| Example Pt-F | | | |
| Comparative | Pt-G | 67 | 13 |
| Example Pt-G | | | |
| Comparative | Pt-H | 67 | 37 |
| Example Pt-H | | | |
| Comparative | Pt-I | 59 | 21 |
| Example Pt-I | | | |
| Example Pt-1 | Pt-1 | 100 | 8 |
| Example Pt-2 | Pt-2 | 96 | 4 |

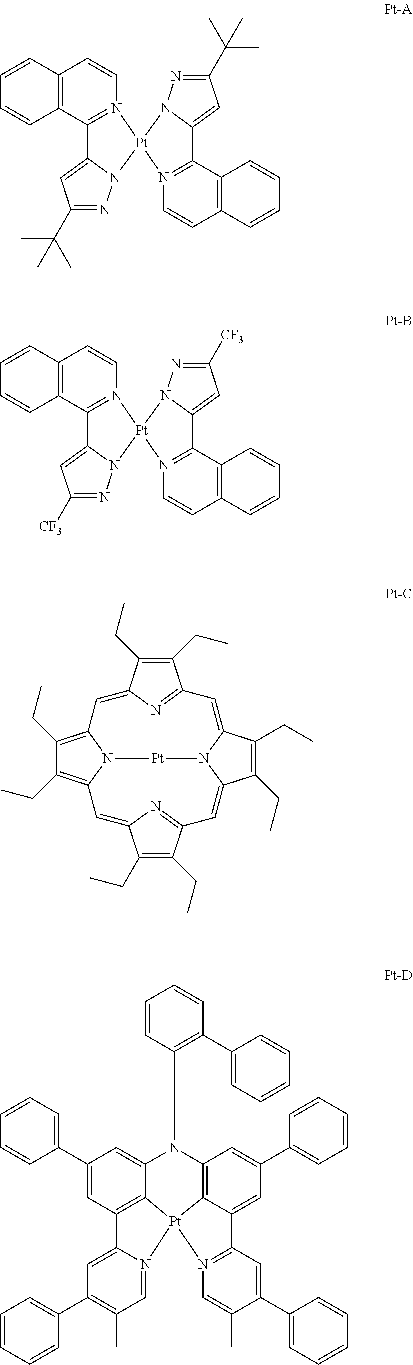

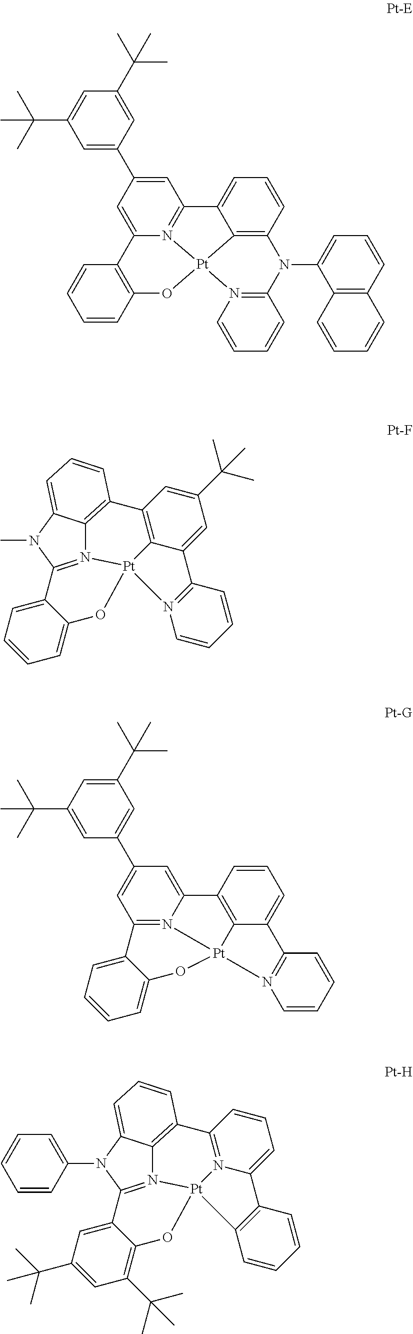

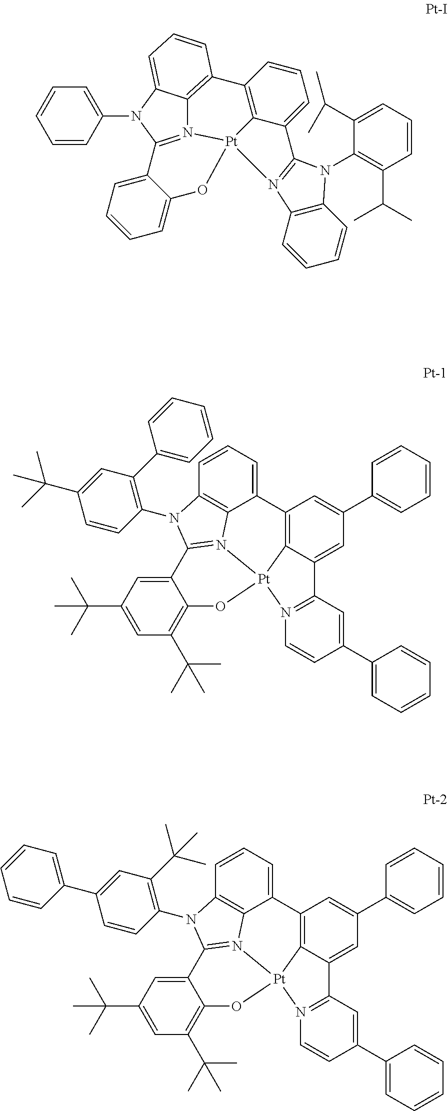

Referring to Table 7, it is confirmed that the organic light-emitting devices of Examples Pt-1 to Pt-2 have improved quantum emission efficiency and improved roll-off ratio, as compared with those of the organic light-emitting devices of Comparative Examples Pt-A to Pt-I.

### Evaluation Example 1-2: Evaluation of x Coordinate Value and y Coordinate Value of PMI Diagram

x and y in the PMI diagrams of Compounds Ir-A to Ir-L and Ir-1 to Ir-25 were evaluated using the same manner as Evaluation Example 1-1 and results of the study are shown in Tables 8 to 11.

TABLE 8

| | | | | | 1.02 − x ≤ y ≤ 1.95 − 2.7x |
|---|---|---|---|---|---|
| | | | | | Satisfaction status |
| Compound | | | 1.95 − | | ◯: Satisfied |
| No. | x | 1.02 − x | 2.7x | y | X: Not satisfied |
| Ir-A | 0.422 | 0.597 | 0.8106 | 0.963 | X |
| Ir-B | 0.390 | 0.630 | 0.897 | 0.926 | X |
| Ir-C | 0.591 | 0.429 | 0.3543 | 0.869 | X |
| Ir-D | 0.487 | 0.533 | 0.6351 | 0.999 | X |
| Ir-E | 0.711 | 0.310 | 0.0303 | 0.953 | X |
| Ir-F | 0.635 | 0.385 | 0.2355 | 0.649 | X |
| Ir-G | 0.417 | 0.603 | 0.8241 | 0.864 | X |
| Ir-H | 0.384 | 0.640 | 0.9132 | 0.922 | X |
| Ir-I | 0.383 | 0.637 | 0.9159 | 0.936 | X |
| Ir-J | 0.392 | 0.628 | 0.8916 | 0.956 | X |
| Ir-K | 0.412 | 0.608 | 0.8376 | 0.954 | X |
| Ir-L | 0.480 | 0.540 | 0.654 | 0.895 | X |
| Ir-1 | 0.325 | 0.695 | 1.0725 | 0.912 | ◯ |
| Ir-2 | 0.274 | 0.746 | 1.2102 | 0.974 | ◯ |
| Ir-3 | 0.246 | 0.774 | 1.2858 | 0.992 | ◯ |
| Ir-4 | 0.319 | 0.701 | 1.0887 | 0.971 | ◯ |
| Ir-5 | 0.303 | 0.717 | 1.1319 | 0.968 | ◯ |
| Ir-6 | 0.342 | 0.678 | 1.0266 | 0.986 | ◯ |
| Ir-7 | 0.110 | 0.910 | 1.653 | 0.993 | ◯ |
| Ir-8 | 0.131 | 0.889 | 1.5963 | 0.986 | ◯ |
| Ir-9 | 0.322 | 0.698 | 1.0806 | 0.954 | ◯ |
| Ir-10 | 0.248 | 0.772 | 1.2804 | 0.938 | ◯ |
| Ir-11 | 0.350 | 0.670 | 1.005 | 0.918 | ◯ |
| Ir-12 | 0.353 | 0.667 | 0.9969 | 0.914 | ◯ |
| Ir-13 | 0.267 | 0.753 | 1.2291 | 0.944 | ◯ |
| Ir-14 | 0.251 | 0.769 | 1.2723 | 0.948 | ◯ |
| Ir-15 | 0.350 | 0.670 | 1.0050 | 0.936 | ◯ |
| Ir-16 | 0.338 | 0.680 | 1.0374 | 0.942 | ◯ |
| Ir-17 | 0.253 | 0.767 | 1.2669 | 0.965 | ◯ |
| Ir-18 | 0.220 | 0.800 | 1.356 | 0.963 | ◯ |
| Ir-19 | 0.268 | 0.752 | 1.2264 | 0.968 | ◯ |
| Ir-20 | 0.299 | 0.721 | 1.1427 | 0.961 | ◯ |
| Ir-21 | 0.385 | 0.635 | 0.9105 | 0.902 | ◯ |
| Ir-22 | 0.383 | 0.637 | 0.9159 | 0.909 | ◯ |
| Ir-23 | 0.319 | 0.701 | 1.0887 | 0.970 | ◯ |
| Ir-24 | 0.347 | 0.670 | 1.0131 | 0.971 | ◯ |
| Ir-25 | 0.294 | 0.726 | 1.1562 | 0.959 | ◯ |

TABLE 9

| | | | | | 1.06 − x ≤ y ≤ 1.95 − 2.7x |
|---|---|---|---|---|---|
| | | | | | Satisfaction status |
| Compound | | | 1.95 − | | ◯: Satisfied |
| No. | x | 1.06 − x | 2.7x | y | X: Not satisfied |
| Ir-A | 0.422 | 0.638 | 0.8106 | 0.963 | X |
| Ir-B | 0.39 | 0.67 | 0.897 | 0.926 | X |
| Ir-C | 0.591 | 0.469 | 0.3543 | 0.869 | X |
| Ir-D | 0.487 | 0.573 | 0.6351 | 0.999 | X |
| Ir-E | 0.711 | 0.35 | 0.0303 | 0.953 | X |
| Ir-F | 0.635 | 0.425 | 0.2355 | 0.649 | X |
| Ir-G | 0.417 | 0.643 | 0.8241 | 0.864 | X |
| Ir-H | 0.384 | 0.676 | 0.9132 | 0.922 | X |
| Ir-I | 0.383 | 0.677 | 0.9159 | 0.936 | X |
| Ir-J | 0.392 | 0.668 | 0.8916 | 0.956 | X |
| Ir-K | 0.412 | 0.648 | 0.8376 | 0.954 | X |
| Ir-L | 0.48 | 0.58 | 0.654 | 0.895 | X |
| Ir-1 | 0.325 | 0.735 | 1.0725 | 0.912 | ◯ |
| Ir-2 | 0.274 | 0.786 | 1.2102 | 0.974 | ◯ |
| Ir-3 | 0.246 | 0.814 | 1.2858 | 0.992 | ◯ |
| Ir-4 | 0.319 | 0.741 | 1.0887 | 0.971 | ◯ |
| Ir-5 | 0.303 | 0.757 | 1.1319 | 0.968 | ◯ |
| Ir-6 | 0.342 | 0.718 | 1.0266 | 0.986 | ◯ |
| Ir-7 | 0.11 | 0.95 | 1.653 | 0.993 | ◯ |
| Ir-8 | 0.131 | 0.93 | 1.5963 | 0.986 | ◯ |
| Ir-9 | 0.322 | 0.738 | 1.0806 | 0.954 | ◯ |
| Ir-10 | 0.248 | 0.812 | 1.2804 | 0.938 | ◯ |
| Ir-11 | 0.35 | 0.71 | 1.005 | 0.918 | ◯ |
| Ir-12 | 0.353 | 0.707 | 0.9969 | 0.914 | ◯ |
| Ir-13 | 0.267 | 0.793 | 1.2291 | 0.944 | ◯ |
| Ir-14 | 0.251 | 0.809 | 1.2723 | 0.948 | ◯ |
| Ir-15 | 0.35 | 0.71 | 1.005 | 0.936 | ◯ |
| Ir-16 | 0.338 | 0.722 | 1.0374 | 0.942 | ◯ |
| Ir-17 | 0.253 | 0.807 | 1.2669 | 0.965 | ◯ |
| Ir-18 | 0.22 | 0.84 | 1.356 | 0.963 | ◯ |
| Ir-19 | 0.268 | 0.792 | 1.2264 | 0.968 | ◯ |
| Ir-20 | 0.299 | 0.76 | 1.1427 | 0.961 | ◯ |
| Ir-21 | 0.385 | 0.675 | 0.9105 | 0.902 | ◯ |
| Ir-22 | 0.383 | 0.677 | 0.9159 | 0.909 | ◯ |
| Ir-23 | 0.319 | 0.741 | 1.0887 | 0.97 | ◯ |
| Ir-24 | 0.347 | 0.713 | 1.0131 | 0.971 | ◯ |
| Ir-25 | 0.294 | 0.766 | 1.1562 | 0.959 | ◯ |

TABLE 10

| | | | | | 1.06 − x ≤ y ≤ 4.7 − 10x |
|---|---|---|---|---|---|
| | | | | | Satisfaction status |
| Compound | | | 4.7 − | | ◯: Satisfied |
| No. | x | 1.06 − x | 10x | y | X: Not satisfied |
| Ir-A | 0.422 | 0.638 | 0.48 | 0.963 | X |
| Ir-B | 0.39 | 0.67 | 0.8 | 0.926 | X |
| Ir-C | 0.591 | 0.469 | −1.21 | 0.869 | X |
| Ir-D | 0.487 | 0.573 | −0.17 | 0.999 | X |
| Ir-E | 0.711 | 0.35 | −2.41 | 0.953 | X |
| Ir-F | 0.635 | 0.425 | −1.65 | 0.649 | X |
| Ir-G | 0.417 | 0.643 | 0.53 | 0.864 | X |
| Ir-H | 0.384 | 0.676 | 0.86 | 0.922 | X |
| Ir-I | 0.383 | 0.677 | 0.87 | 0.936 | X |
| Ir-J | 0.392 | 0.668 | 0.78 | 0.956 | X |
| Ir-K | 0.412 | 0.648 | 0.58 | 0.954 | X |
| Ir-L | 0.48 | 0.58 | −0.1 | 0.895 | X |
| Ir-1 | 0.325 | 0.735 | 1.45 | 0.912 | ◯ |
| Ir-2 | 0.274 | 0.786 | 1.96 | 0.974 | ◯ |
| Ir-3 | 0.246 | 0.814 | 2.24 | 0.992 | ◯ |
| Ir-4 | 0.319 | 0.741 | 1.51 | 0.971 | ◯ |
| Ir-5 | 0.303 | 0.757 | 1.67 | 0.968 | ◯ |
| Ir-6 | 0.342 | 0.718 | 1.28 | 0.986 | ◯ |
| Ir-7 | 0.11 | 0.95 | 3.6 | 0.993 | ◯ |
| Ir-8 | 0.131 | 0.93 | 3.39 | 0.986 | ◯ |
| Ir-9 | 0.322 | 0.738 | 1.48 | 0.954 | ◯ |
| Ir-10 | 0.248 | 0.812 | 2.22 | 0.938 | ◯ |
| Ir-11 | 0.35 | 0.71 | 1.2 | 0.918 | ◯ |
| Ir-12 | 0.353 | 0.707 | 1.17 | 0.914 | ◯ |
| Ir-13 | 0.267 | 0.793 | 2.03 | 0.944 | ◯ |
| Ir-14 | 0.251 | 0.809 | 2.19 | 0.948 | ◯ |
| Ir-15 | 0.35 | 0.71 | 1.2 | 0.936 | ◯ |
| Ir-16 | 0.338 | 0.722 | 1.32 | 0.942 | ◯ |
| Ir-17 | 0.253 | 0.807 | 2.17 | 0.965 | ◯ |
| Ir-18 | 0.22 | 0.84 | 2.5 | 0.963 | ◯ |
| Ir-19 | 0.268 | 0.792 | 2.02 | 0.968 | ◯ |
| Ir-20 | 0.299 | 0.76 | 1.71 | 0.961 | ◯ |
| Ir-21 | 0.385 | 0.675 | 0.85 | 0.902 | X |
| Ir-22 | 0.383 | 0.677 | 0.87 | 0.909 | X |
| Ir-23 | 0.319 | 0.741 | 1.51 | 0.97 | ◯ |
| Ir-24 | 0.347 | 0.713 | 1.23 | 0.971 | ◯ |
| Ir-25 | 0.294 | 0.766 | 1.76 | 0.959 | ◯ |

TABLE 11

| | | | | | 1.0 − 0.5x ≤ y ≤ 1.95 − 2.7x |
|---|---|---|---|---|---|
| | | | | | Satisfaction status |
| Compound | | 1.0 − | 1.95 − | | ◯: Satisfied |
| No. | x | 0.5x | 2.7x | y | X: Not satisfied |
| Ir-A | 0.422 | 0.789 | 0.8106 | 0.963 | X |
| Ir-B | 0.39 | 0.805 | 0.897 | 0.926 | X |
| Ir-C | 0.591 | 0.7045 | 0.3543 | 0.869 | X |
| Ir-D | 0.487 | 0.7565 | 0.6351 | 0.999 | X |
| Ir-E | 0.711 | 0.64 | 0.0303 | 0.953 | X |
| Ir-F | 0.635 | 0.6825 | 0.2355 | 0.649 | X |
| Ir-G | 0.417 | 0.7915 | 0.8241 | 0.864 | X |
| Ir-H | 0.384 | 0.808 | 0.9132 | 0.922 | X |
| Ir-I | 0.383 | 0.8085 | 0.9159 | 0.936 | X |
| Ir-J | 0.392 | 0.804 | 0.8916 | 0.956 | X |
| Ir-K | 0.412 | 0.794 | 0.8376 | 0.954 | X |
| Ir-L | 0.48 | 0.76 | 0.654 | 0.895 | X |
| Ir-1 | 0.325 | 0.8375 | 1.0725 | 0.912 | ◯ |
| Ir-2 | 0.274 | 0.863 | 1.2102 | 0.974 | ◯ |
| Ir-3 | 0.246 | 0.877 | 1.2858 | 0.992 | ◯ |
| Ir-4 | 0.319 | 0.8405 | 1.0887 | 0.971 | ◯ |
| Ir-5 | 0.303 | 0.8485 | 1.1319 | 0.968 | ◯ |
| Ir-6 | 0.342 | 0.829 | 1.0266 | 0.986 | ◯ |
| Ir-7 | 0.11 | 0.945 | 1.653 | 0.993 | ◯ |
| Ir-8 | 0.131 | 0.93 | 1.5963 | 0.986 | ◯ |
| Ir-9 | 0.322 | 0.839 | 1.0806 | 0.954 | ◯ |
| Ir-10 | 0.248 | 0.876 | 1.2804 | 0.938 | ◯ |
| Ir-11 | 0.35 | 0.825 | 1.005 | 0.918 | ◯ |
| Ir-12 | 0.353 | 0.8235 | 0.9969 | 0.914 | ◯ |
| Ir-13 | 0.267 | 0.8665 | 1.2291 | 0.944 | ◯ |
| Ir-14 | 0.251 | 0.8745 | 1.2723 | 0.948 | ◯ |
| Ir-15 | 0.35 | 0.825 | 1.005 | 0.936 | ◯ |
| Ir-16 | 0.338 | 0.831 | 1.0374 | 0.942 | ◯ |
| Ir-17 | 0.253 | 0.8735 | 1.2669 | 0.965 | ◯ |
| Ir-18 | 0.22 | 0.89 | 1.356 | 0.963 | ◯ |
| Ir-19 | 0.268 | 0.866 | 1.2264 | 0.968 | ◯ |
| Ir-20 | 0.299 | 0.85 | 1.1427 | 0.961 | ◯ |
| Ir-21 | 0.385 | 0.8075 | 0.9105 | 0.902 | ◯ |
| Ir-22 | 0.383 | 0.8085 | 0.9159 | 0.909 | ◯ |
| Ir-23 | 0.319 | 0.8405 | 1.0887 | 0.97 | ◯ |
| Ir-24 | 0.347 | 0.8265 | 1.0131 | 0.971 | ◯ |
| Ir-25 | 0.294 | 0.853 | 1.1562 | 0.959 | ◯ |

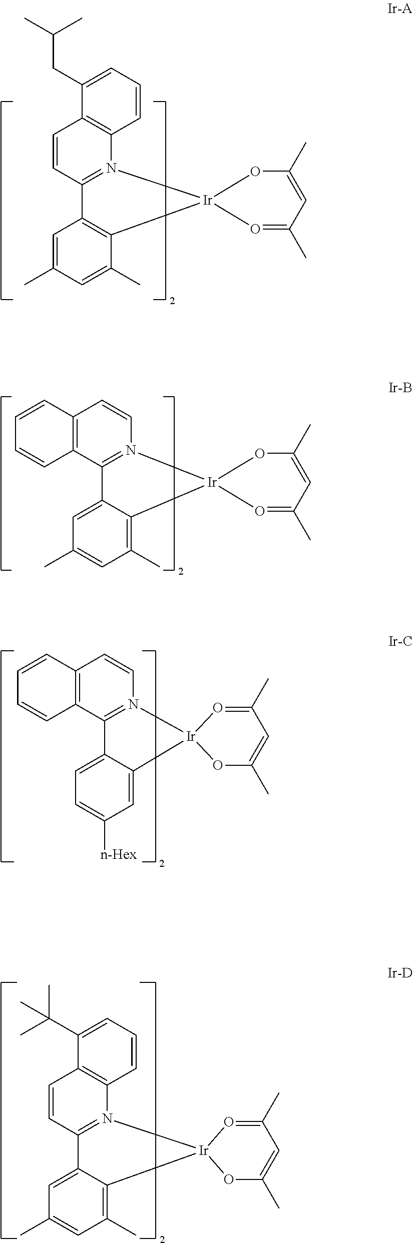

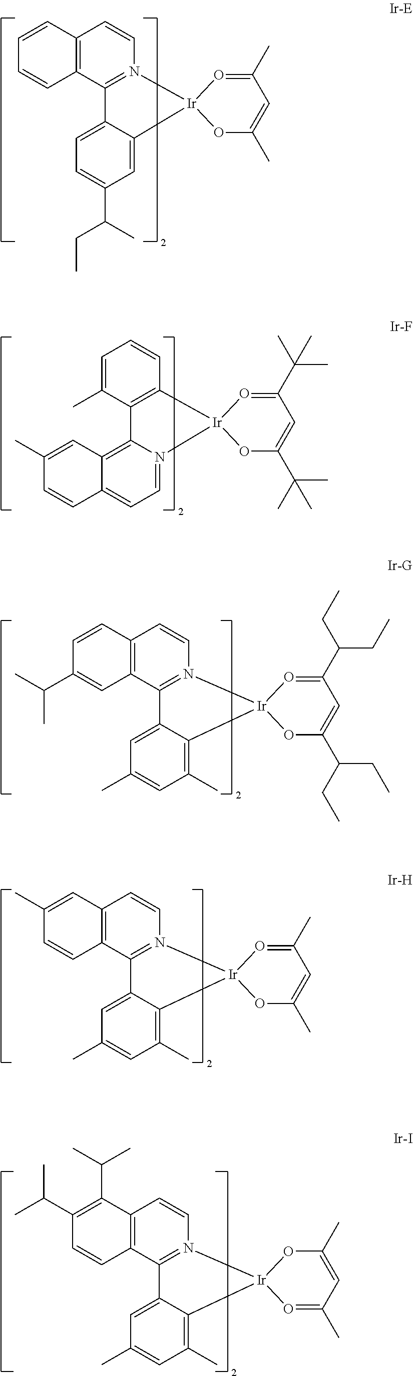

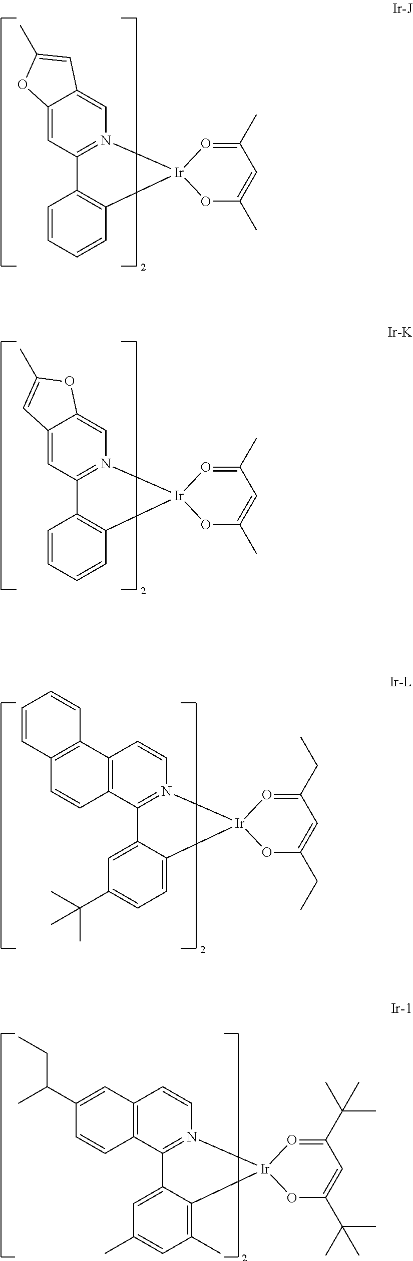

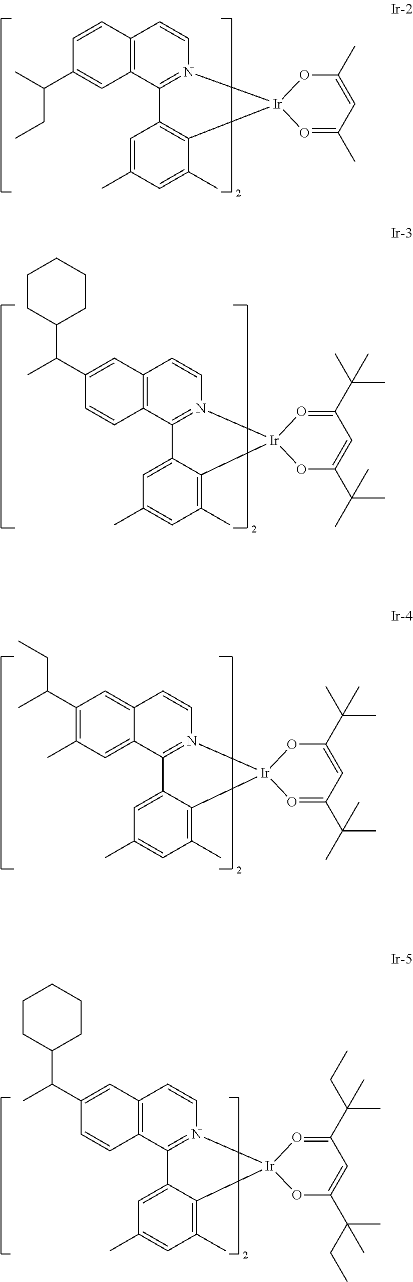

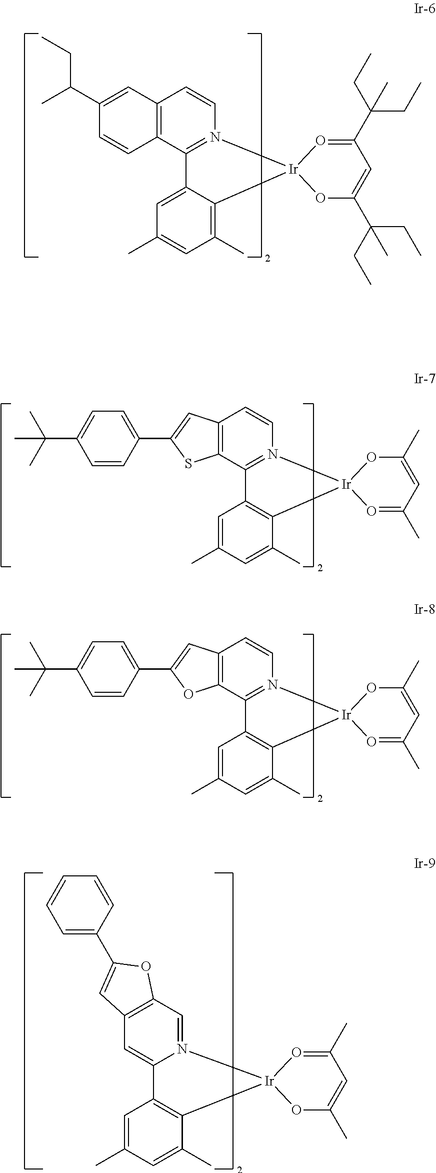

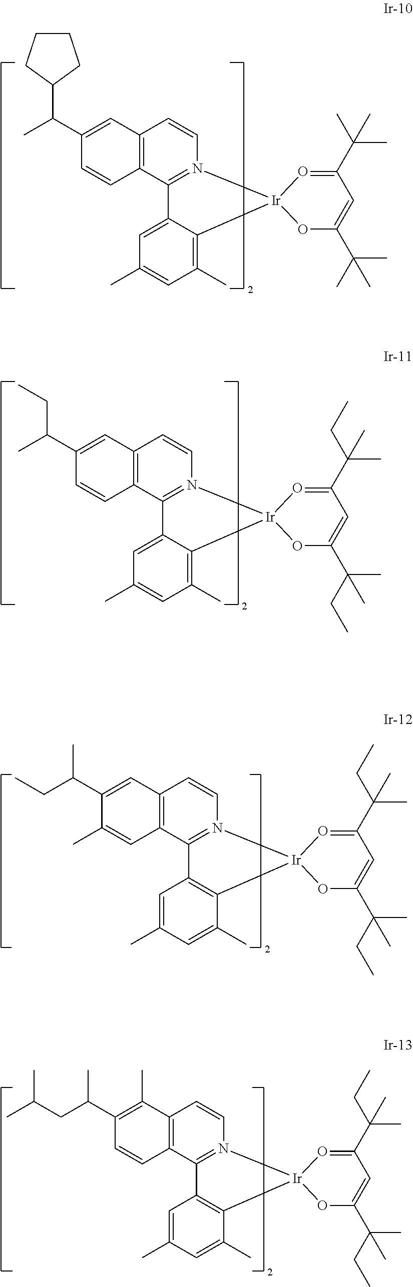

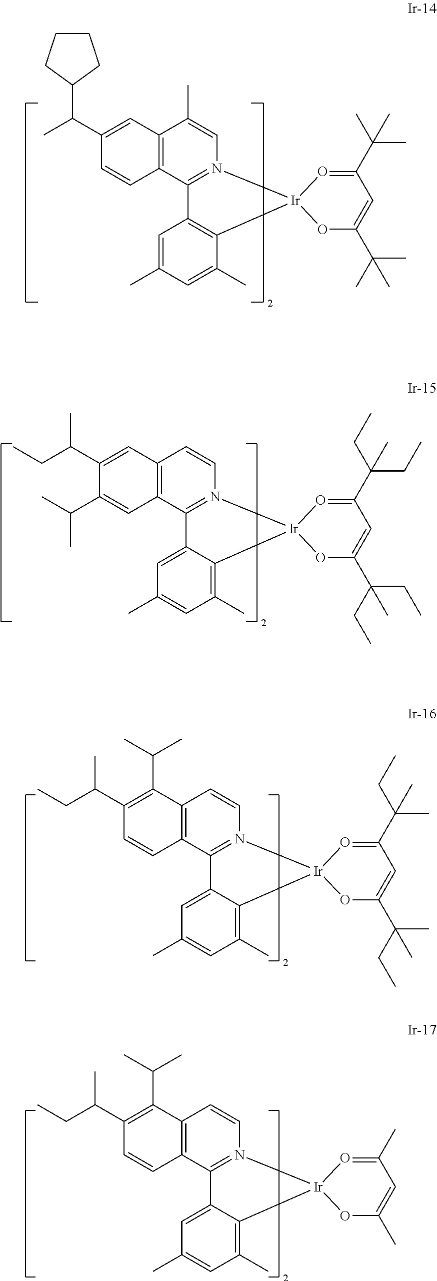

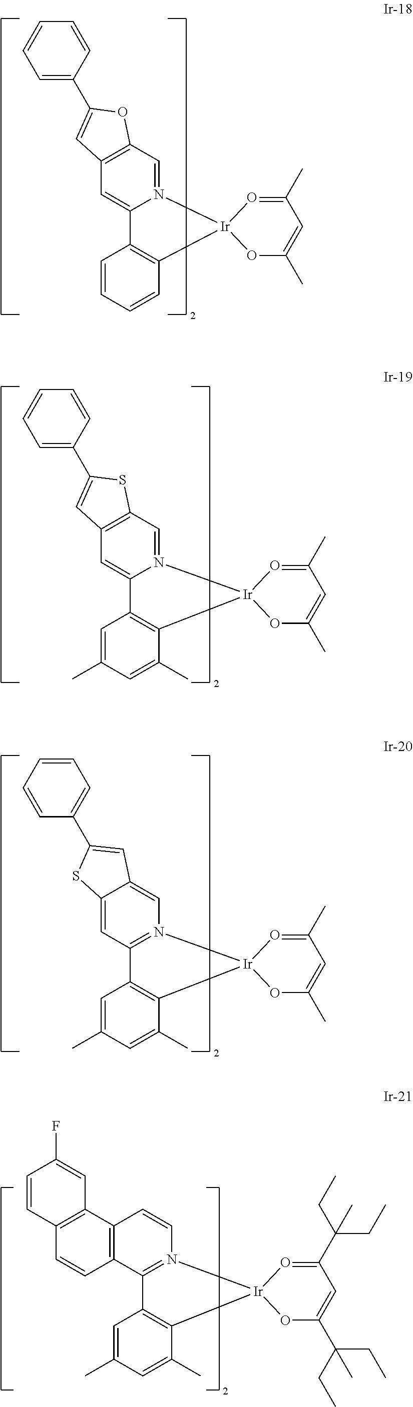

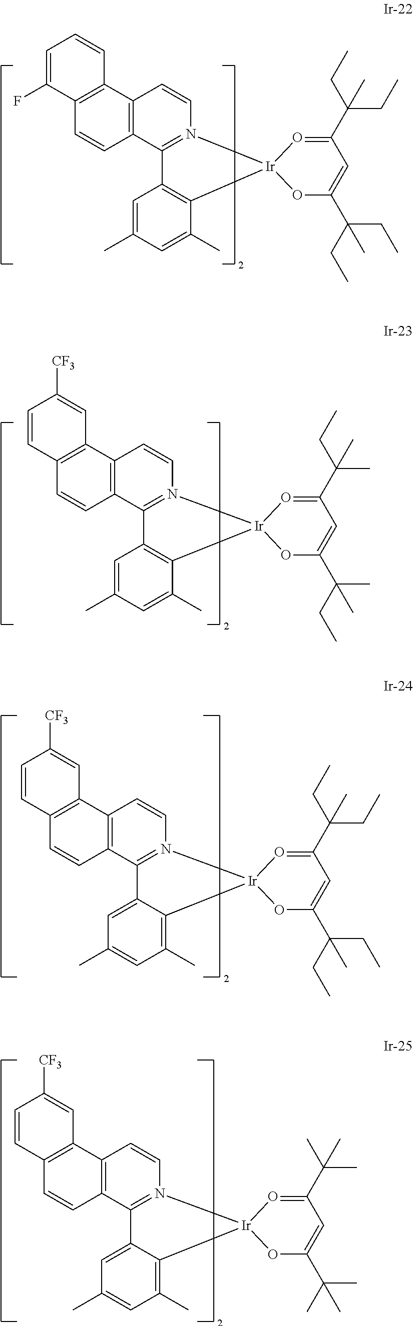

Referring to Tables 8 to 11, it is confirmed that x and y in the PMI diagram of Compounds Ir-A to Ir-L do not satisfy relationships of 1.02−x≤y≤1.95−2.7x, 1.06−x≤y≤1.95−2.7x, 1.06−x≤y≤4.7−10x, and 1.0−0.5x≤y≤1.95−2.7x.

### Evaluation Example 2-2: Evaluation of Radiative Decay Rate

Radiative decay rates of Compounds Ir-A to Ir-L and Ir-1 to Ir-25 were evaluated using the same manner as Evaluation Example 2-1, except that a weight ratio of mCP and Ir Compound is changed to 98:2, and results of the study are shown in Table 12.

TABLE 12

| Compound No. | Radiative decay rate (s⁻¹) |
|---|---|
| Ir-A | 5.81 × 10⁵ |
| Ir-B | 7.42 × 10⁵ |
| Ir-C | 6.83 × 10⁵ |
| Ir-D | 5.81 × 10⁵ |
| Ir-E | 6.92 × 10⁵ |
| Ir-F | 6.88 × 10⁵ |
| Ir-G | 7.21 × 10⁵ |
| Ir-H | 8.02 × 10⁵ |
| Ir-I | 7.28 × 10⁵ |
| Ir-J | 1.27 × 10⁵ |
| Ir-K | 2.93 × 10⁵ |
| Ir-L | 1.15 × 10⁶ |
| Ir-1 | 8.81 × 10⁵ |
| Ir-2 | 7.25 × 10⁵ |
| Ir-3 | 9.00 × 10⁵ |
| Ir-4 | 8.04 × 10⁵ |
| Ir-5 | 9.19 × 10⁵ |
| Ir-6 | 8.23 × 10⁵ |
| Ir-7 | 1.49 × 10⁶ |
| Ir-8 | 1.02 × 10⁶ |
| Ir-9 | 2.67 × 10⁵ |
| Ir-10 | 8.55 × 10⁵ |
| Ir-11 | 9.10 × 10⁵ |
| Ir-12 | 8.04 × 10⁵ |
| Ir-13 | 9.05 × 10⁵ |
| Ir-14 | 8.25 × 10⁵ |
| Ir-15 | 8.28 × 10⁵ |
| Ir-16 | 7.95 × 10⁵ |
| Ir-17 | 7.82 × 10⁵ |
| Ir-18 | 6.70 × 10⁵ |
| Ir-19 | 1.36 × 10⁶ |
| Ir-20 | 1.17 × 10⁶ |
| Ir-21 | 1.26 × 10⁶ |
| Ir-22 | 1.38 × 10⁶ |
| Ir-23 | 1.35 × 10⁶ |
| Ir-24 | 1.45 × 10⁶ |
| Ir-25 | 1.29 × 10⁶ |

### Evaluation Example 3-2: Evaluation of Horizontal Orientation Ratio

Horizontal orientation ratio of Compounds Ir-1 to Ir-25 were evaluated using the same manner as Evaluation Example 3-1, except that a weight ratio of mCP and Ir Compound is changed to 98:2, and results of the study are shown in Table 13.

TABLE 13

| | | Horizontal |
|---|---|---|
| | | orientation ratio |
| Sample No. | Co-deposition materials | (%) |
| Ir-1 | mCP: Compound Ir-1 (2 wt %) | 86 |
| Ir-2 | mCP: Compound Ir-2 (2 wt %) | 85 |
| Ir-3 | mCP: Compound Ir-3 (2 wt %) | 94 |
| Ir-4 | mCP: Compound Ir-4 (2 wt %) | 91 |
| Ir-5 | mCP: Compound Ir-5 (2 wt %) | 93 |
| Ir-6 | mCP: Compound Ir-6 (2 wt %) | 92 |
| Ir-7 | mCP: Compound Ir-7 (2 wt %) | 92 |
| Ir-8 | mCP: Compound Ir-8 (2 wt %) | 91 |
| Ir-9 | mCP: Compound Ir-9 (2 wt %) | 85 |
| Ir-10 | mCP: Compound Ir-10 (2 wt %) | 93 |
| Ir-11 | mCP: Compound Ir-11 (2 wt %) | 91 |
| Ir-12 | mCP: Compound Ir-12 (2 wt %) | 91 |
| Ir-13 | mCP: Compound Ir-13 (2 wt %) | 92 |
| Ir-14 | mCP: Compound Ir-14 (2 wt %) | 92 |
| Ir-15 | mCP: Compound Ir-15 (2 wt %) | 93 |
| Ir-16 | mCP: Compound Ir-16 (2 wt %) | 93 |
| Ir-17 | mCP: Compound Ir-17 (2 wt %) | 91 |
| Ir-18 | mCP: Compound Ir-18 (2 wt %) | 85 |
| Ir-19 | mCP: Compound Ir-19 (2 wt %) | 87 |
| Ir-20 | mCP: Compound Ir-20 (2 wt %) | 86 |
| Ir-21 | mCP: Compound Ir-21 (2 wt %) | 91 |
| Ir-22 | mCP: Compound Ir-22 (2 wt %) | 91 |
| Ir-23 | mCP: Compound Ir-23 (2 wt %) | 93 |
| Ir-24 | mCP: Compound Ir-24 (2 wt %) | 93 |
| Ir-25 | mCP: Compound Ir-25 (2 wt %) | 93 |

Referring to Table 13, it is confirmed that Compounds Ir-1 to Ir-25 have an excellent horizontal orientation ratio, that is, excellent horizontal optical orientation.

### Comparative Example Ir-A

A glass substrate on which an ITO electrode (1500 Å thick) was patterned as an anode was cut to a size of 50 mm×50 mm×0.5 mm (mm=millimeters), sonicated with iso-propyl alcohol, and pure water each for 5 minutes, and then cleaned by exposure to ultraviolet rays and ozone for 30 minutes.

Then, HT3 and F6-TCNNQ were co-deposited on the ITO electrode at a weight ratio of 98:2 to form a hole injection layer having a thickness of 100 Å, HT3 was deposited on the hole injection layer to form a hole transport layer having a thickness of 1,350 Å and HT21 was deposited on the hole transport layer to form an electron blocking layer having a thickness of 300 Å.

H52 (host) and Ir-A (dopant) were co-deposited on the electron blocking layer at a weight ratio of 98:2 to form an emission layer having a thickness of 400 Å.

Then, ET3 and ET-D1 were co-deposited on the emission layer at a volume ratio of 50:50 to form an electron transport layer having a thickness of 350 Å, ET-D1 was deposited on the electron transport layer to form an electron injection layer having a thickness of 10 Å, A₁ was vacuum-deposited on the electron injection layer to form a cathode having a thickness of 1000 Å, thereby completing the manufacture of an organic light-emitting device having a structure of ITO (1500 Å)/HT3+F6TCNNQ (2 wt %) (100 Å)/HT3 (1350 Å)/HT21 (300 Å)/H52+Ir-A (2 wt %) (400 Å)/ET3+ET-D1 (50%) (350 Å)/ET-D1 (10 Å)/A1(1000 Å).

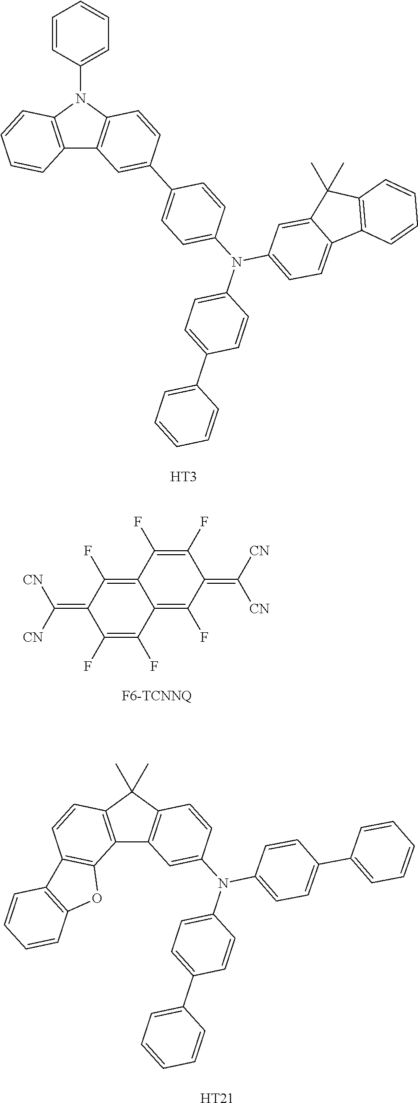

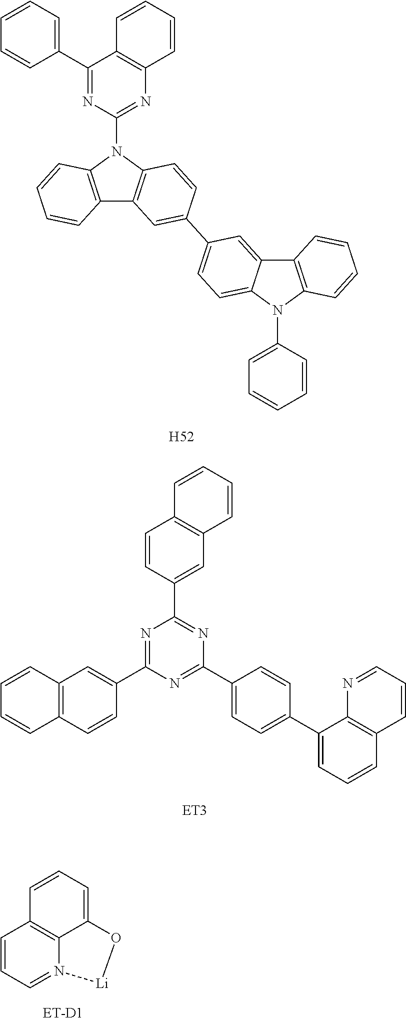

### Comparative Examples Ir-B to Ir-L and Examples Ir-1 to Ir-25

Organic light-emitting devices were manufactured in the same manner as in Comparative Example Ir-A, except that Compounds shown in Table 14 were each used instead of Compound Ir-A as a dopant in forming an emission layer.

### Evaluation Example 4-2: Evaluation of Characteristics of Organic Light-Emitting Devices

The maximum quantum emission efficiency (relative value) and roll-off ratio of the organic light-emitting devices manufactured according to Comparative Examples Ir-A to Ir-L and Examples Ir-1 to Ir-25 were evaluated by using the same manner as Evaluation Example 4-1, and results of the study are shown in Table 14. The roll-off ratio in this Evaluation Example 4-2 was evaluated at 3,500 nit.

TABLE 14

| | Dopant | Maximum quantum | |
|---|---|---|---|
| | compound | emission efficiency | Roll-off ratio (%) |
| | No. | (relative value, %) | (at 3500 nit) |
| Comparative | Ir-A | 77 | 16 |
| Example Ir-A | | | |
| Comparative | Ir-B | 71 | 19 |
| Example Ir-B | | | |
| Comparative | Ir-C | 58 | 18 |
| Example Ir-C | | | |
| Comparative | Ir-D | 77 | 17 |
| Example Ir-D | | | |
| Comparative | Ir-E | 65 | 15 |
| Example Ir-E | | | |
| Comparative | Ir-F | 71 | 14 |
| Example Ir-F | | | |
| Comparative | Ir-G | 74 | 15 |
| Example Ir-G | | | |
| Comparative | Ir-H | 77 | 14 |
| Example Ir-H | | | |
| Comparative | Ir-I | 77 | 16 |
| Example Ir-I | | | |
| Comparative | Ir-J | 55 | 18 |
| Example Ir-J | | | |
| Comparative | Ir-K | 58 | 19 |
| Example Ir-K | | | |
| Comparative | Ir-L | 77 | 14 |
| Example Ir-L | | | |
| Example Ir-1 | Ir-1 | 81 | 12 |
| Example Ir-2 | Ir-2 | 84 | 13 |
| Example Ir-3 | Ir-3 | 90 | 14 |
| Example Ir-4 | Ir-4 | 87 | 11 |
| Example Ir-5 | Ir-5 | 97 | 10 |
| Example Ir-6 | Ir-6 | 90 | 11 |
| Example Ir-7 | Ir-7 | 100 | 4 |
| Example Ir-8 | Ir-8 | 90 | 5 |
| Example Ir-9 | Ir-9 | 84 | 9 |
| Example Ir-10 | Ir-10 | 84 | 10 |
| Example Ir-11 | Ir-11 | 94 | 12 |
| Example Ir-12 | Ir-12 | 84 | 12 |
| Example Ir-13 | Ir-13 | 87 | 11 |
| Example Ir-14 | Ir-14 | 90 | 12 |
| Example Ir-15 | Ir-15 | 94 | 11 |
| Example Ir-16 | Ir-16 | 94 | 12 |
| Example Ir-17 | Ir-17 | 87 | 10 |
| Example Ir-18 | Ir-18 | 81 | 12 |
| Example Ir-19 | Ir-19 | 87 | 12 |
| Example Ir-20 | Ir-20 | 84 | 12 |
| Example Ir-21 | Ir-21 | 97 | 8 |
| Example Ir-22 | Ir-22 | 97 | 9 |
| Example Ir-23 | Ir-23 | 100 | 8 |
| Example Ir-24 | Ir-24 | 97 | 7 |
| Example Ir-25 | Ir-25 | 100 | 8 |

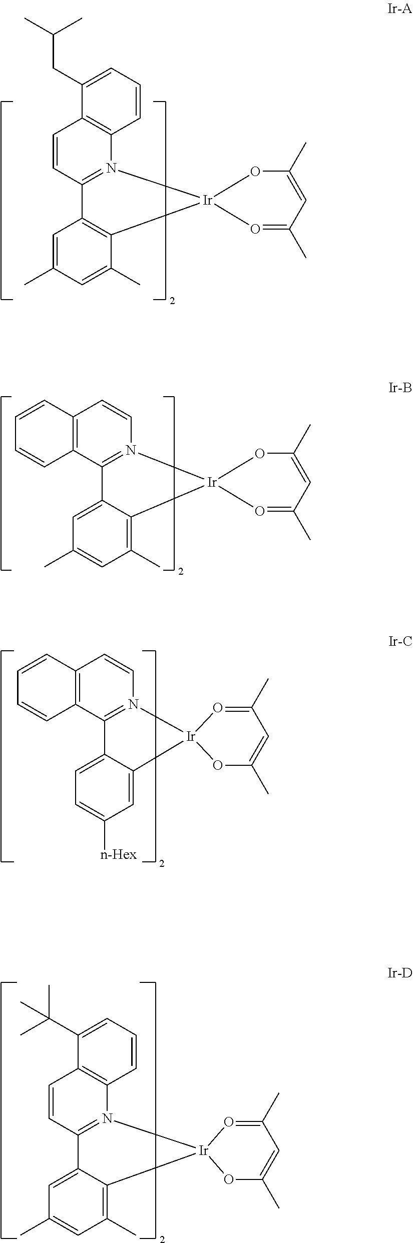

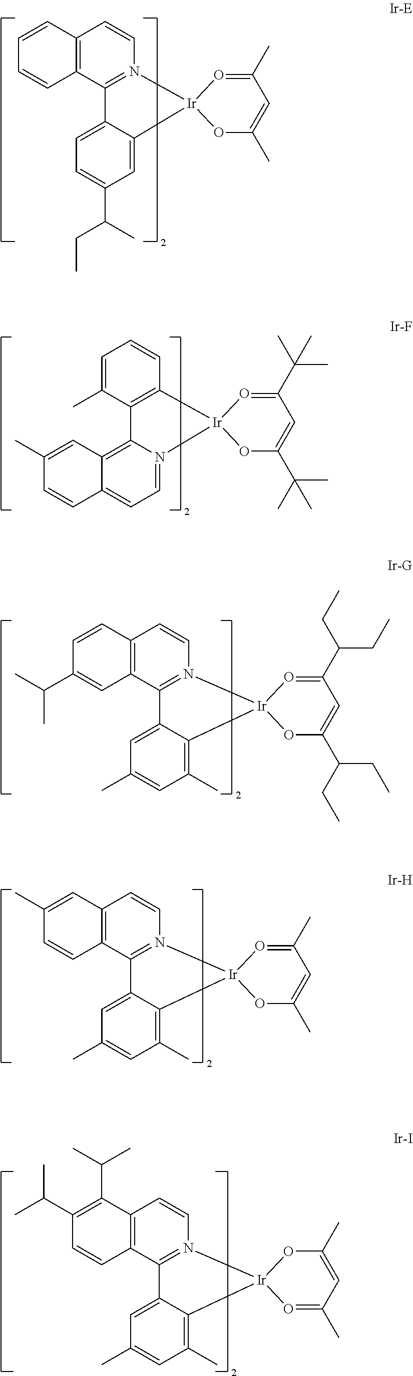

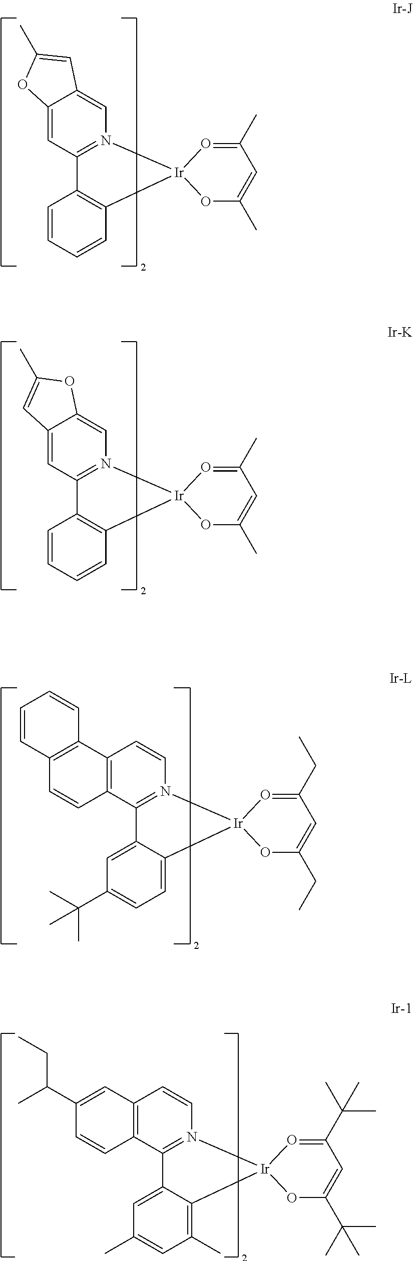

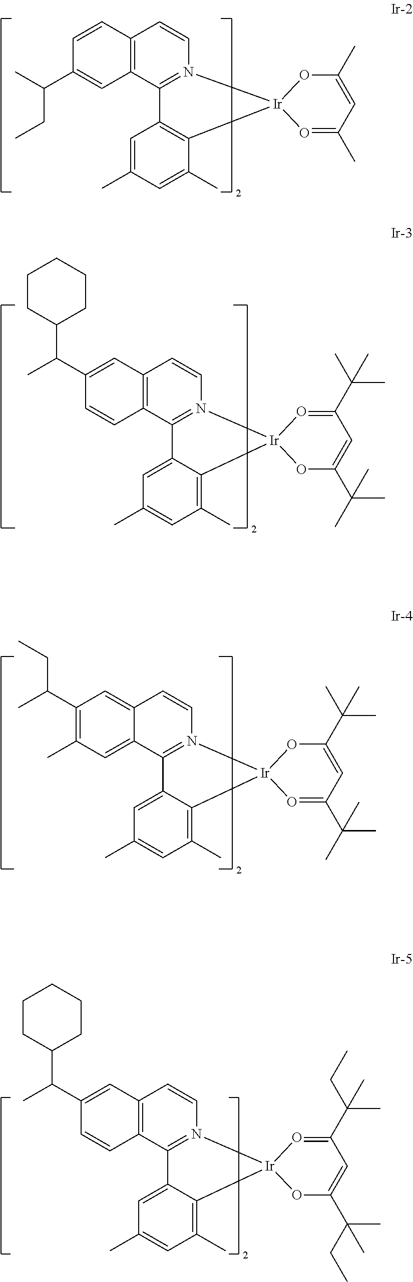

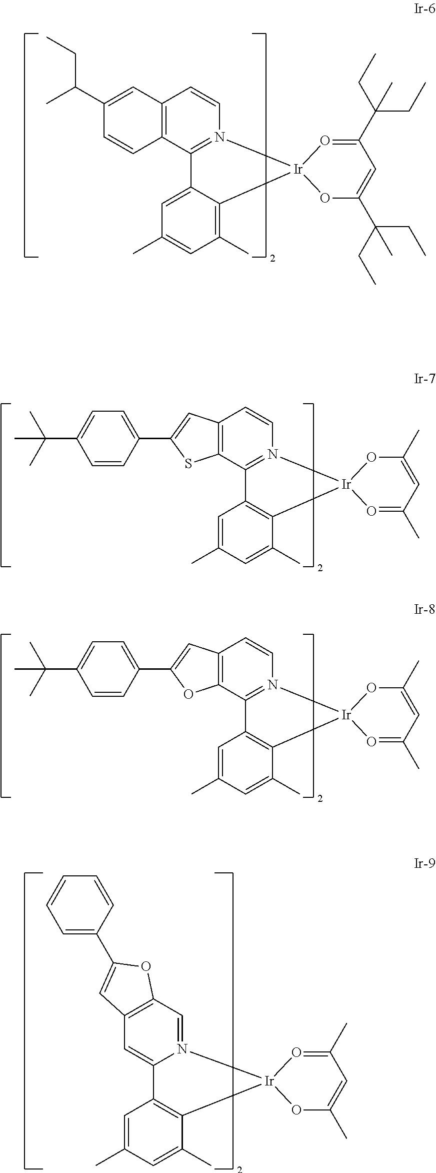

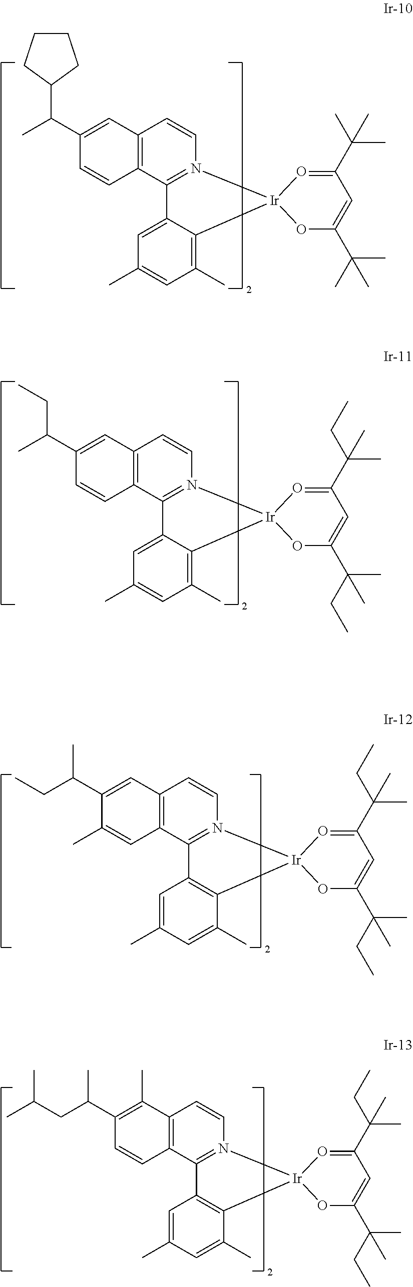

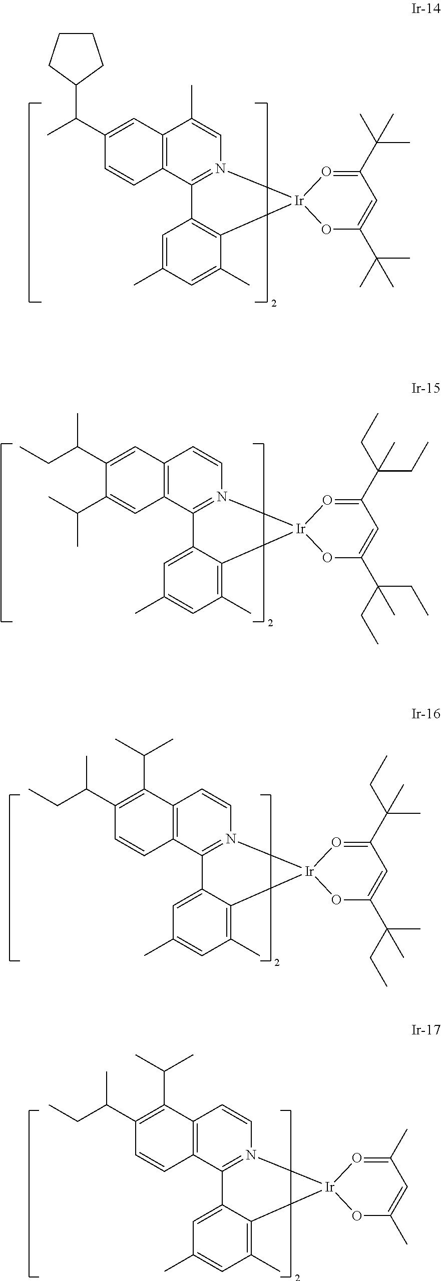

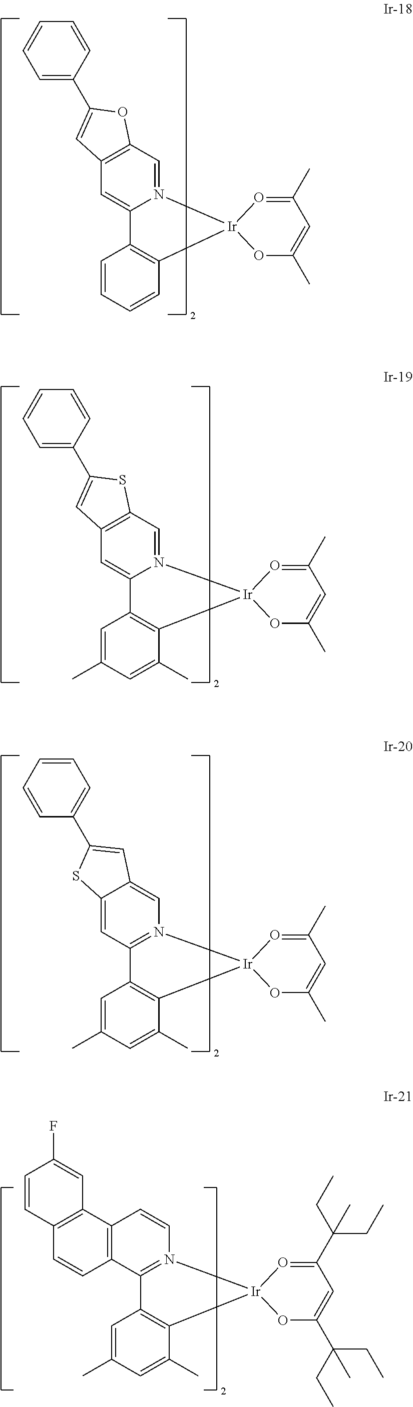

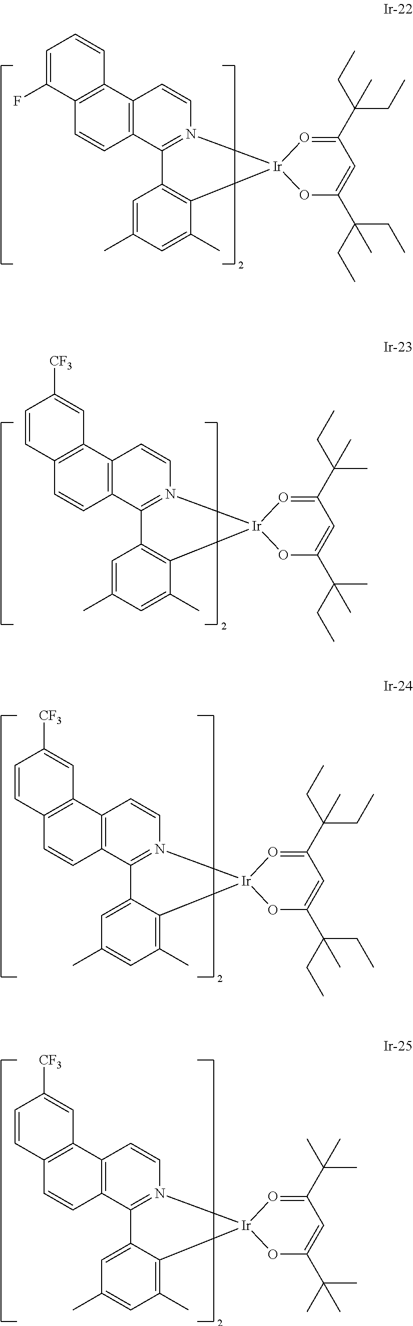

In Ir-C, n-Hex represents n-hexyl group.

Referring to Table 14, it is confirmed that the organic light-emitting devices of Examples Ir-1 to Ir-25 have improved quantum emission efficiency and improved roll-off ratio, as compared with those of the organic light-emitting devices of Comparative Examples Ir-A to Ir-L.

Since the organometallic compound has excellent internal quantum emission efficiency and optical orientation, an electronic device, for example, an organic light-emitting device, which includes the organometallic compound, may have excellent external quantum emission efficiency and excellent roll-off ratio.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present description as defined by the following claims.

1. An organometallic compound comprising a transition metal and at least one organic ligand,
wherein,
the organometallic compound satisfies Condition 1, and
the organometallic compound has a radiative decay rate of 2.5×10⁵ reverse seconds or more:
Condition 1
1.02−x≤y≤1.95−2.7x,
wherein,
in Condition 1, x is an x coordinate value in principal moments of inertia diagram of the organometallic compound, wherein x is I₁/I₃ of the organometallic compound,
in Condition 1, y is a y coordinate value in the principal moments of inertia diagram of the organometallic compound, wherein y is I₂/I₃ of the organometallic compound,
I₁, I₂, and I₃ are three principal moments of inertia of the organometallic compound, which satisfy a relationship of I₁≤I₂≤I₃,
I₁, I₂, and I₃ are evaluated using a density functional theory method for the organometallic compound,
the radiative decay rate of the organometallic compound is a value calculated from a time-resolved photoluminescence spectrum with respect to film 1, and
the film 1 is a 40-nanometer-thick film obtained by vacuum-codepositing 1,3-di(9H-carbazol-9-yl)benzene and the organometallic compound on a quartz substrate at a weight ratio of 90:10 to 99:1.

2. The organometallic compound of claim 1, wherein
the transition metal is platinum, palladium, gold, or iridium.

3. The organometallic compound of claim 1, wherein
the organometallic compound satisfies Condition 2:
Condition 2
1.06−x≤y≤1.95−2.7x,
wherein, in Condition 2, x and y are each independently the same as described in claim 1.

4. The organometallic compound of claim 1, wherein
the organometallic compound satisfies Condition 3:
Condition 3
1.06−x≤y≤4.70−10.0x,
wherein, in Condition 3, x and y are each independently the same as described in claim 1.

5. The organometallic compound of claim 1, wherein
the transition metal is platinum and the organometallic compound satisfies Condition 4:
Condition 4
1.02−x≤y≤1.16−x,
wherein, in Condition 4, x and y are each independently the same as described in claim 1.

6. The organometallic compound of claim 1, wherein
the transition metal is iridium, and the organometallic compound satisfies Condition 5:
Condition 5
1.00−0.5x≤y≤1.95−2.7x,
wherein, in Condition 5, x and y are each independently the same as described in claim 1.

7. The organometallic compound of claim 1, wherein
x is in a range of 0.08 to 0.39.

8. The organometallic compound of claim 1, wherein
y is in a range of 0.30 to 1.00.

9. The organometallic compound of claim 1, wherein
the organometallic compound has a radiative decay rate in a range of 2.5×10⁵ s⁻¹ to 2.0×10⁶ s⁻¹.

10. The organometallic compound of claim 1, wherein
the organometallic compound has a horizontal orientation ratio of a transition dipole moment in a range of 85% to 100%.

11. The organometallic compound of claim 1, wherein
the organic ligand comprises a tetradentate organic ligand, and
the tetradentate organic ligand comprises a C₃-C₈ nitrogen-containing condensed ring system in which a five membered ring and a six membered ring are condensed to each other.

12. The organometallic compound of claim 11, wherein
the tetradentate organic ligand comprises a benzimidazole ring system.

13. The organometallic compound of claim 12, wherein
the tetradentate organic ligand comprises a benzimidazole ring system substituted with a substituted phenyl group and
the substituted phenyl group is substituted with both at least one phenyl group and at least one tert-butyl group.

14. The organometallic compound of claim 1, wherein
the organic ligand comprises a bidentate organic ligand, and
the bidentate organic ligand comprises i) a C₃-C₁₅ nitrogen-containing condensed ring system in which at least two six membered rings are condensed to each other or ii) a C₃-C₈ condensed ring system in which a five membered ring and a six membered ring are condensed to each other.

15. The organometallic compound of claim 14, wherein
the organic ligand comprises
1) a bidentate organic ligand comprising a quinoline ring and a benzene ring, a bidentate organic ligand comprising an isoquinoline ring and a benzene ring, a bidentate organic ligand comprising an azabenzothiophene ring and a benzene ring, a bidentate organic ligand comprising an azabenzofuran ring and a benzene ring, a bidentate organic ligand comprising a benzoquinoline ring and a benzene ring, or a bidentate organic ligand comprising an benzoisoquinoline ring and a benzene ring; and
2) a bidentate organic ligand linked to the transition metal via oxygen.

16. An organic light-emitting device comprising:
a first electrode;
a second electrode; and
an organic layer disposed between the first electrode and the second electrode, wherein the organic layer comprises an emission layer, and wherein the organic layer comprises at least one organometallic compound of claim 1.

17. The organic light-emitting device of claim 16, wherein
the emission layer comprises the organometallic compound.

18. The organic light-emitting device of claim 17, wherein
a horizontal orientation ratio of a transition dipole moment of the organometallic compound with respect to a plane of the emission layer is in a range of 85% to 100%.

19. The organic light-emitting device of claim 18, wherein
the emission layer further comprises a host.

20. The organic light-emitting device of claim 19, wherein
the host comprises a carbazole group, a fluorene group, a spiro-bifluorene group, a dibenzofuran group, a dibenzothiophene group, a dibenzosilole group, an indenocarbazole group, an indolocarbazole group, a benzofurocarbazole group, a benzothienocarbazole group, an acridine group, a dihydroacridine group, a triindolobenzene group, an azadibenzofuran group, an azadibenzothiophene group, an azacarbazole group, an azafluorene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a phenazine group, a cinnoline group, a cyano group, a phosphine oxide group, a sulfoxide group, or any combination thereof.

21. The organic light-emitting device of claim 19, wherein
the host comprises a hole-transporting host and an electron-transporting host, and
the hole-transporting host and the electron-transporting host are different from each other.

22. The organic light-emitting device of claim 21, wherein
the electron-transporting host comprises at least one electron-transporting moiety,
the hole-transporting host does not comprise an electron-transporting moiety or an unsubstituted or substituted amine group, and
the electron-transporting moiety is a cyano group, a π electron-depleted nitrogen-containing cyclic group, a group represented by one of the following formulae, or any combination thereof: 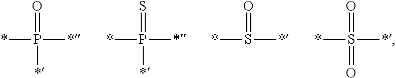
wherein, in the formulae, *, *′, and *″ each indicate a binding site to a neighboring atom.
